(19) United States
(12) Patent Application Publication
(10) Pub. No.: US 2023/0269996 A1
(43) Pub. Date: Aug. 24, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: CHANSEOK OH, Seoul (KR); TAEIL KIM, Hwaseong-si (KR); JUNHA PARK, Gwacheon-si (KR); JANG YEOL BAEK, Yongin-si (KR); MinJae SUNG, Hwaseong-si (KR); MINJUNG JUNG, Hongcheon-gun (KR)

(21) Appl. No.: 17/961,424

(22) Filed: Oct. 6, 2022

(30) Foreign Application Priority Data
Feb. 21, 2022 (KR) 10-2022-0022232

(51) Int. Cl. H01L 51/00; C07F 5/02; C09K 11/06

(52) U.S. Cl. CPC H01L 51/008; H01L 51/0072; H01L 51/0067; H01L 51/0087; H01L 51/0061; C07F 5/027; C09K 11/06; H01L 51/5028

(57) ABSTRACT

A light emitting element (that includes a first electrode, a second electrode, and an emission layer which is between the first electrode and the second electrode and includes a compound represented by Formula 1) is provided. The light emitting element concurrently (e.g., simultaneously) exhibits a high efficiency and a long service life characteristic.

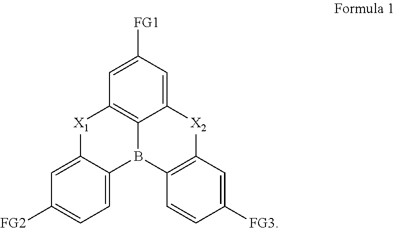

### CROSS-REFERENCE TO RELATED APPLICATION

This application claims priority to and the benefit of Korean Patent Application No. 10-2022-0022232, filed on Feb. 21, 2022, the entire content of which is hereby incorporated by reference.

### BACKGROUND

### 1. Field

Aspects of one or more embodiments of the present disclosure herein relate to a polycyclic compound and a light emitting element including the same, and for example, to a light emitting element including a novel polycyclic compound in an emission layer.

### 2. Description of the Related Art

Recently, the development of an organic electroluminescence display device as an image display device is being actively conducted. The organic electroluminescence display device includes a self-luminescent light emitting element in which holes and electrons injected from a first electrode and a second electrode recombine in an emission layer, and thus a luminescent material of the emission layer emits light to implement display (e.g., to display an image).

In the application of a light emitting element to a display device, there is a demand for a light emitting element having a low driving voltage, a high luminous efficiency, and a long service life, and development on materials for a light emitting element capable of stably attaining such characteristics is being continuously required (sought).

### SUMMARY

An aspect of one or more embodiments of the present disclosure is directed toward a light emitting element exhibiting high efficiency and long service life characteristics.

An aspect of one or more embodiments of the present disclosure is directed toward a polycyclic compound which is a material for a light emitting element having high luminous efficiency and improved service life characteristics.

Additional aspects will be set forth in part in the description which follows and, in part, will be apparent from the description, or may be learned by practice of the presented embodiments of the disclosure.

An embodiment of the present disclosure provides a polycyclic compound represented by Formula 1:

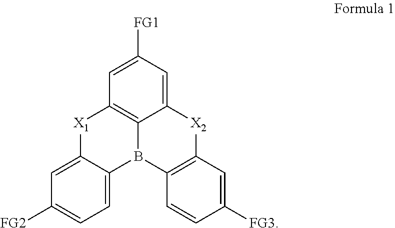

In Formula 1, X₁ and X₂ may each independently be NRₓ, O, or S, Rₓ may be a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, at least one of FG1, FG2, or FG3 is represented by Formula 2-1 or Formula 2-2, and the rest (the FG1, FG2, or FG3 that are not represented by Formula 2-1 or Formula 2-2) may each independently be a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

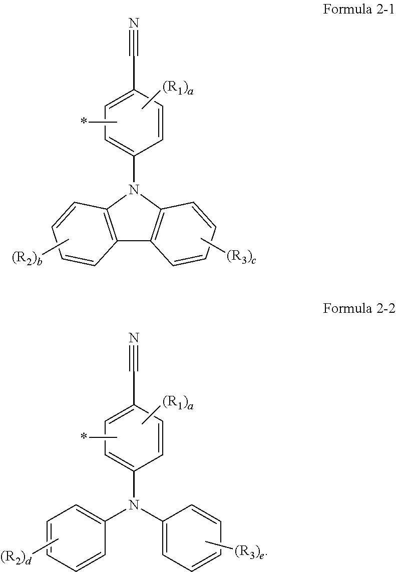

In Formula 2-1 and Formula 2-2, a is an integer from 0 to 3, b and c may each independently be an integer from 0 to 4, d and e may each independently be an integer from 0 to 5, and R₁ to R₃ may each independently be a hydrogen atom, a deuterium atom, a halogen atom, a cyano group, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

In an embodiment, Formula 1 may be represented by any one selected from among Formula 1-1 to Formula 1-3:

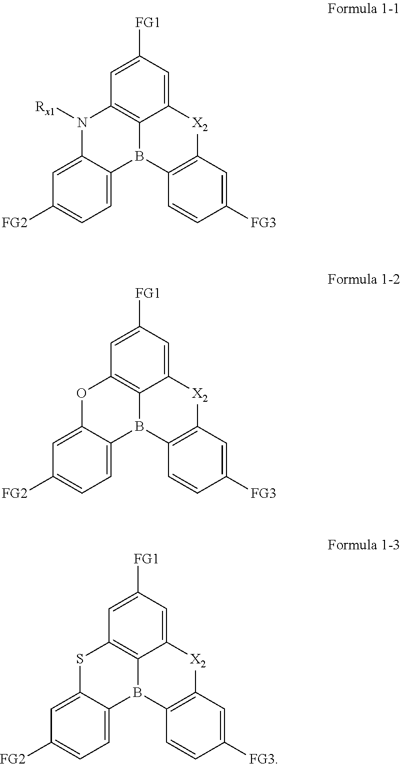

In Formula 1-1, X₂ may be NRₓ₂, O, or S, and Rₓ₁ and Rₓ₂ may each independently be a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, in Formula 1-2 and Formula 1-3, X₂ may be O or S, and in Formula 1-1 to Formula 1-3, FG1, FG2, and FG3 may each independently be the same as defined in Formula 1.

In an embodiment, Formula 1 may be represented by any one selected from among Formula 1A to Formula 1E:

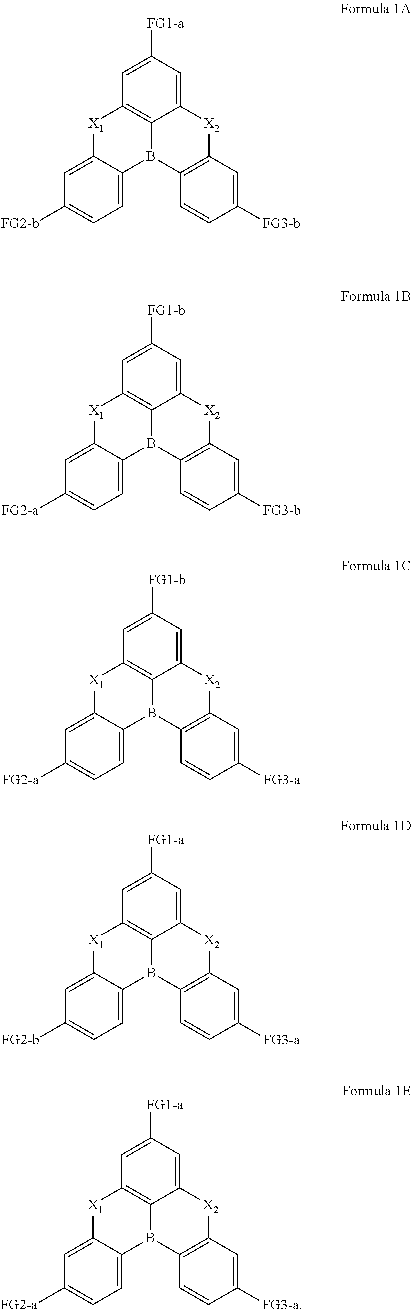

In Formula 1A to Formula 1, FG1-a, FG2-a, and Fg3-a may each independently be represented by Formula 2-1 or Formula 2-2, FG1-b, FG2-b, and FG3-b may each independently be a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, and X₁ and X₂ may each independently be the same as defined in Formula 1.

In an embodiment, FG1-b, FG2-b, and FG3-b may each independently be a hydrogen atom, an unsubstituted alkyl group having 1 to 10 carbon atoms, a deuterium-substituted alkyl group having 1 to 10 carbon atoms, a substituted or unsubstituted phenyl group, a substituted or unsubstituted terphenyl group, a substituted or unsubstituted diphenylamine group, or a substituted or unsubstituted carbazole group.

In an embodiment, Rₓ may be a substituted or unsubstituted phenyl group.

In an embodiment, R₁ may be represented by any one selected from among R₁₋ₐ to R_{1-c}, and in R_{1-b}, D is a deuterium atom:

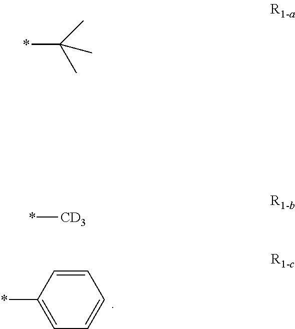

In an embodiment, at least one selected from among X₁, X₂, FG1 to FG3 in Formula 1 may include a deuterium atom, or a substituent containing a deuterium atom.

In an embodiment, the compound represented by Formula 1 may be a thermally activated delayed fluorescence emitting material.

In an embodiment of the present disclosure, a light emitting element includes: a first electrode; a second electrode on the first electrode; and an emission layer between the first electrode and the second electrode, wherein the emission layer includes a first compound that is the above-described polycyclic compound according to an embodiment, and at least one of a second compound represented by Formula HT-1, a third compound represented by Formula ET-1, or a fourth compound represented by Formula M-b:

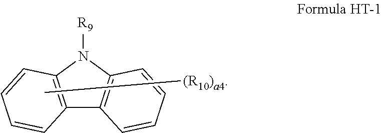

In Formula HT-1, a4 may be an integer from 0 to 8, and R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

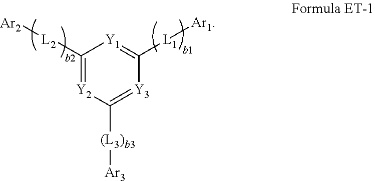

In Formula ET-1, at least one selected from among Y₁ to Y₃ is N, and the rest (the substituents that are not N) are CRₐ, and Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and b1 to b3 may each independently be an integer from 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

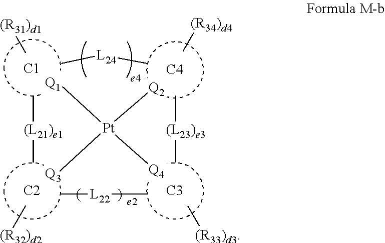

In Formula M-b, Q₁ to Q₄ may each independently be C or N, and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms. e1 to e4 may each independently be 0 or 1, and L₂₁ to L₂₄ may each independently be a direct linkage,

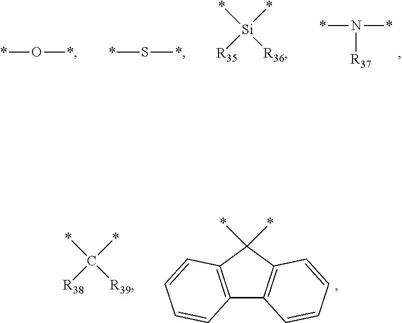

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. d1 to d4 may each independently be an integer from 0 to 4, and R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In an embodiment, the light emitting element may further include a hole transport region which is between the first electrode and the emission layer, and includes a hole transport compound represented by Formula H-1:

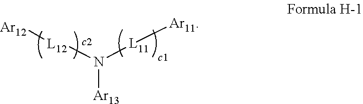

In Formula H-1, c1 and c2 may each independently be an integer from 0 to 10, L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms, and Ar₁₃ is a substituted or unsubstituted aryl group having 6 to 30 ring-forming carbon atoms.

In an embodiment, the emission layer may include the first compound, the second compound, and the third compound.

In an embodiment, the emission layer may include the first compound, the second compound, the third compound, and the fourth compound.

In an embodiment, the emission layer may emit blue light.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device according to an embodiment;

FIG. 2 is a cross-sectional view of a display device according to an embodiment;

FIG. 3 is a cross-sectional view schematically illustrating a light emitting element according to an embodiment;

FIG. 4 is a cross-sectional view schematically illustrating a light emitting element according to an embodiment;

FIG. 5 is a cross-sectional view schematically illustrating a light emitting element according to an embodiment;

FIG. 6 is a cross-sectional view schematically illustrating a light emitting element according to an embodiment;

FIG. 7 is a cross-sectional view of a display device according to an embodiment;

FIG. 8 is a cross-sectional view of a display device according to an embodiment;

FIG. 9 is a cross-sectional view illustrating a display device according to an embodiment; and

FIG. 10 is a cross-sectional view illustrating a display device according to an embodiment.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numerals are utilized for referring to like elements. In the accompanying drawings, the dimensions of each structure may be exaggeratingly illustrated for clarity of the present disclosure. It will be understood that, although the terms “first”, “second”, etc. may be utilized herein to describe one or more suitable elements, these elements should not be limited by these terms. These terms are only utilized to distinguish one element from another. For example, a first component could be termed a second component, and, similarly, a second component could be termed a first component, without departing from the scope of the present disclosure. As utilized herein, the singular forms, “a,” “an,” and “the” are intended to include the plural forms as well, unless the context clearly indicates otherwise.

In the present disclosure, it will be understood that the terms “include,” “comprise,” “have” etc., specify the presence of a feature, a fixed number, a step, an operation, an element, a component, or a combination thereof disclosed in the specification, but do not exclude the possibility of presence or addition of one or more other features, fixed numbers, steps, operations, elements, components, or combination thereof.

In the present disclosure, when a part such as a layer, a film, a region, or a plate is referred to as being “on” or “above” another part, it can be directly on the other part, or an intervening part may also be present. In contrast, when a part such as a layer, a film, a region, or a plate is referred to as being “under” or “below” another part, it can be directly under the other part, or an intervening part may also be present. In some embodiments, it will be understood that when a part is referred to as being “on” another part, it can be disposed above the other part, or disposed under the other part as well.

In the disclosure, the term “substituted or unsubstituted” may refer to substituted or unsubstituted with at least one substituent selected from the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the substituents exemplified above may be substituted or unsubstituted. For example, a biphenyl group may be an aryl group or a phenyl group substituted with a phenyl group.

In the disclosure, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may be monocyclic or polycyclic. In some embodiments, the rings formed by being bonded to each other may be connected to another ring to form a spiro structure.

In the disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the disclosure, examples of the halogen atom may include a fluorine atom, a chlorine atom, a bromine atom, or an iodine atom.

In the disclosure, the alkyl group may be a linear, branched, or cyclic type or kind. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the disclosure, the alkenyl group refers to a hydrocarbon group including one or more carbon double bonds in the middle of or at the terminal of an alkyl group having two or more carbon atoms. The alkenyl group may be a linear chain or a branched chain. The carbon number is not limited, but is 2 to 30, 2 to 20, or 2 to 10. Examples of the alkenyl group include a vinyl group, a 1-butenyl group, a 1-pentenyl group, a 1,3-butadienyl group, a styrenyl group, a styrylvinyl group, etc., without limitation.

In the disclosure, an alkynyl group refers to a hydrocarbon group including at least one carbon triple bond in the middle or terminal of an alkyl group having 2 or more carbon atoms. The alkynyl group may be a linear chain or a branched chain. The carbon number is not limited, but is 2 to 30, 2 to 20, or 2 to 10. Examples of the alkynyl group include an ethynyl group, a propynyl group, etc., without limitation.

The hydrocarbon ring group herein refers to any suitable functional group or substituent derived from an aliphatic hydrocarbon ring. The hydrocarbon ring group may be a saturated hydrocarbon ring group having 5 to 20 ring-forming carbon atoms.

In the disclosure, an aryl group refers to any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the disclosure, the fluorenyl group may be substituted, and two substituents may be bonded to each other to form a spiro structure. Examples of embodiments in which the fluorenyl group is substituted are as follows. However, the embodiment of the present disclosure is not limited thereto.

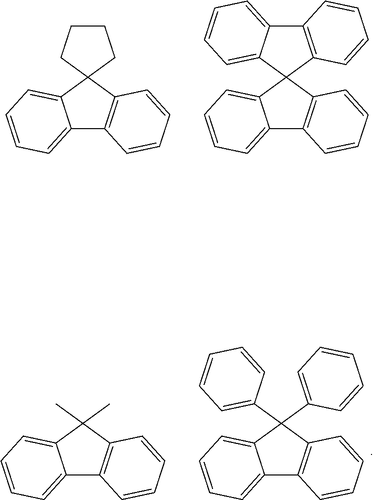

The heterocyclic group herein refers to any suitable functional group or substituent derived from a ring including at least one of B, O, N, P, Si, or Se as a heteroatom. The heterocyclic group includes an aliphatic heterocyclic group and/or an aromatic heterocyclic group. The aromatic heterocyclic group may be a heteroaryl group. The aliphatic heterocycle and the aromatic heterocycle may be monocyclic or polycyclic.

In the disclosure, the heterocyclic group may contain at least one of B, O, N, P, Si, or S as a heteroatom. When the heterocyclic group contains two or more heteroatoms, the two or more heteroatoms may be the same as or different from each other. In the disclosure, the heterocyclic group may be a monocyclic heterocyclic group or a polycyclic heterocyclic group, and is a concept including a heteroaryl group. The number of ring-forming carbon atoms in the heterocyclic group may be 2 to 30, 2 to 20, or 2 to 10.

In the disclosure, the aliphatic heterocyclic group may include one or more selected from among B, O, N, P, Si, and S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

The heteroaryl group herein may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the disclosure, the above description of the aryl group may be applied to an arylene group except that the arylene group is a divalent group. The above description of the heteroaryl group may be applied to a heteroarylene group except that the heteroarylene group is a divalent group.

The boron group herein may refer to a boron atom that is bonded to the alkyl group or the aryl group as defined above. The boron group includes an alkyl boron group and/or an aryl boron group. Examples of the boron group may include a dimethylboron group, a dimethylboron group, a t-butylmethylboron group, a diphenylboron group, a phenylboron group, etc., but the embodiment of the present disclosure is not limited thereto.

In the disclosure, a silyl group includes an alkyl silyl group and/or an aryl silyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, an embodiment of the present disclosure is not limited thereto.

In the disclosure, the number of ring-forming carbon atoms in the carbonyl group is not limited, but may be 1 to 40, 1 to 30, or 1 to 20. For example, the carbonyl group may have the following structures, but the embodiment of the present disclosure is not limited thereto:

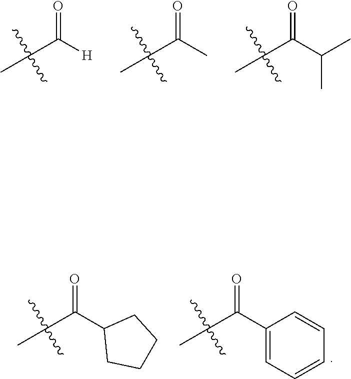

In the disclosure, the number of carbon atoms in the sulfinyl group and the sulfonyl group is not limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the disclosure, a thio group may include an alkylthio group and/or an arylthio group. The thio group may refer to a sulfur atom that is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but the embodiment of the present disclosure is not limited thereto.

In the disclosure, an oxy group may refer to an oxygen atom that is bonded to the alkyl group or the aryl group as defined above. The oxy group may include an alkoxy group and/or an aryl oxy group. The alkoxy group may be a linear chain, a branched chain, or a ring chain. The number of carbon atoms in the alkoxy group is not limited, but may be, for example, 1 to 20 or 1 to 10. Examples of the oxy group include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

In the disclosure, the number of carbon atoms in an amine group is not limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, etc., but the embodiment of the present disclosure is not limited thereto.

In the disclosure, the alkyl group selected from among an alkylthio group, an alkylsulfoxy group, an alkylaryl group, an alkylamino group, an alkyl boron group, an alkyl silyl group, and an alkyl amine group is the same as the examples of the alkyl group described above.

In the disclosure, the aryl group selected from among an aryloxy group, an arylthio group, an arylsulfoxy group, an arylamino group, an arylboron group, an arylsilyl group, and an arylamine group is the same as the examples of the aryl group described above.

In the disclosure, a direct linkage may refer to a single bond.

In some embodiments,

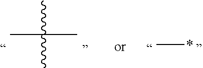

herein refers to a position to be connected.

Hereinafter, embodiments of the present disclosure will be described with reference to the accompanying drawings.

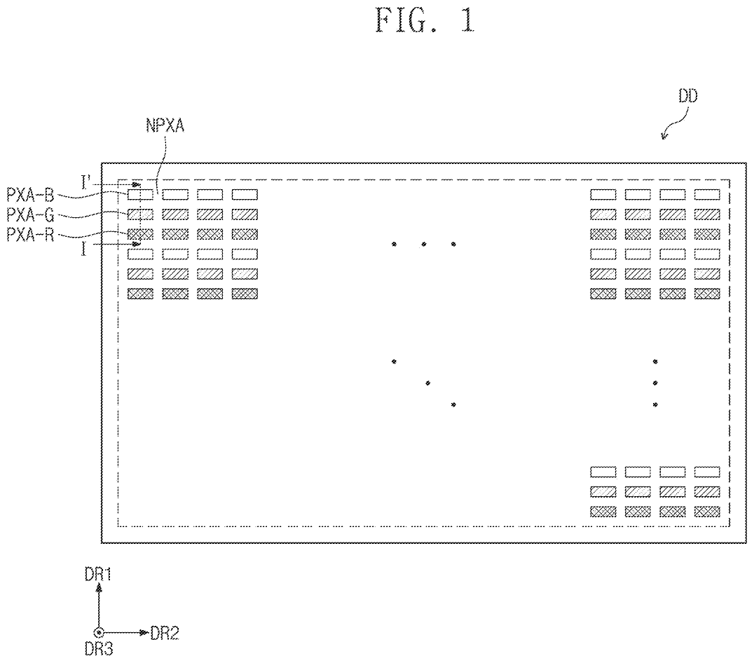

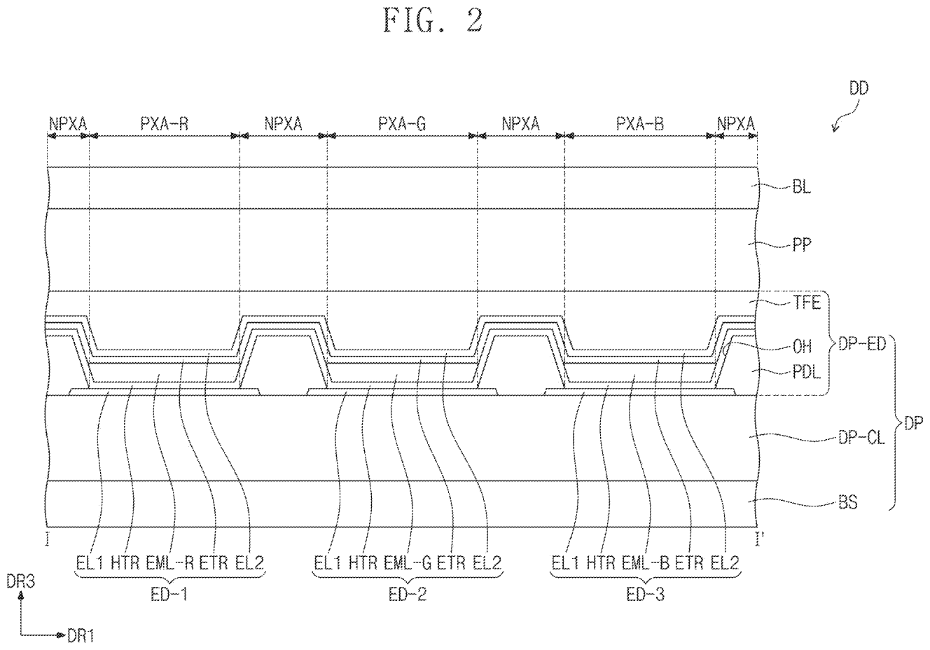

FIG. 1 is a plan view illustrating an embodiment of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP includes light emitting devices ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer or a color filter layer. In some embodiments, the optical layer PP may not be provided on the display device DD of an embodiment.

A base substrate BL may be on the optical layer PP. The base substrate BL may be a member which provides a base surface on which the optical layer PP disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between portions of the pixel defining film PDL, and an encapsulation layer TFE on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

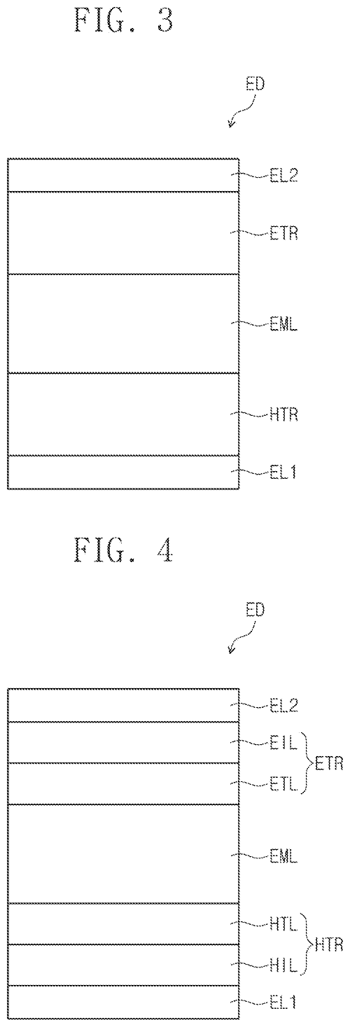

Each of the light emitting elements ED-1, ED-2, and ED-3 may have a structure of a light emitting element ED of an embodiment according to FIGS. 3 to 6, which will be described in more detail. Each of the light emitting elements ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects (reduces) the display element layer DP-ED from moisture/oxygen, and the encapsulation-organic film protects (reduces) the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not limited thereto. The encapsulation-organic film may include an acrylic-based compound, an epoxy-based compound, and/or the like. The encapsulation-organic film may include a photopolymerizable organic material, but the embodiment of the present disclosure is not limited thereto.

The encapsulation layer TFE may be on the second electrode EL2 and may be disposed filling the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2 and ED-3 is emitted. The light emitting regions PXA-R, PXA-G, and PXA-B may be spaced apart from (separated from) each other on a plane (e.g., in a plan view).

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In some embodiments, in the disclosure, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, respectively are illustrated as examples. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2, and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may emit light beams in substantially (e.g., may each emit) the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R may be arranged with each other along a second direction axis DR2, the plurality of green light emitting regions PXA-G may be arranged with each other along the second direction axis DR2, and the plurality of blue light emitting regions PXA-B each may be arranged with each other along the second direction axis DR2. In some embodiments, the red light emitting region PXA-R, the green light emitting region PXA-G, and the blue light emitting region PXA-B may be alternately arranged in this order along a first directional axis DR1. (DR3 is a third direction which is normal or perpendicular to the plane defined by the first direction DR1 and the second direction DR2).

FIGS. 1 and 2 illustrate that all the light emitting regions PXA-R, PXA-G, and PXA-B have substantially similar areas, but the embodiment of the present disclosure is not limited thereto. Thus, the light emitting regions PXA-R, PXA-G, and PXA-B may have different areas from each other according to the wavelength range of the emitted light. In this embodiment, the areas of the light emitting regions PXA-R, PXA-G, and PXA-B may refer to areas when viewed on a plane defined by the first direction axis DR1 and the second direction axis DR2 (e.g., when viewed in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a PENTILE® arrangement form (for example, an RGBG matrix, an RGBG structure, or RGBG matrix structure) or a diamond arrangement form (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

In the display device DD according to an embodiment illustrated in FIG. 2, at least one selected from among the first to third light emitting elements ED-1, ED-2, and ED-3 may include a polycyclic compound of an embodiment which will be described in more detail.

Hereinafter, FIGS. 3 to 6 are cross-sectional views schematically illustrating light emitting elements according to embodiments. The light emitting devices ED according to embodiments each may include a first electrode EL1, a second electrode EL2 facing the first electrode EL1, and at least one functional layer between the first electrode EL1 and the second electrode EL2. The light emitting element ED of an embodiment may include a polycyclic compound of an embodiment, which will be described in more detail, in at least one functional layer. In some embodiments, the polycyclic compound of an embodiment may be referred to as a first compound herein.

Each of the light emitting elements ED may include, as at least one functional layer, a hole transport region HTR, an emission layer EML, and an electron transport region ETR that are sequentially stacked (in the stated order). Referring to FIG. 3, the light emitting element ED of an embodiment may include a first electrode EL1, a hole transport region HTR, an emission layer EML, an electron transport region ETR, and a second electrode EL2 that are sequentially stacked (in the stated order). In some embodiments, the light emitting element ED of an embodiment may include the polycyclic compound of an embodiment, which will be described in more detail, in the emission layer EML.

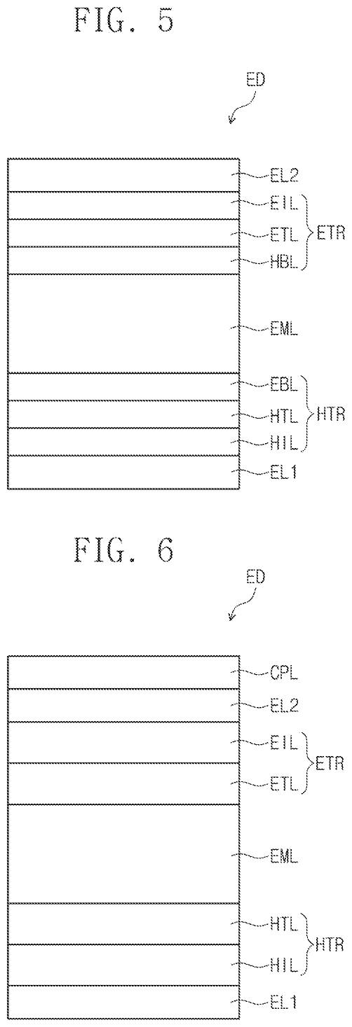

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of an embodiment including a capping layer CPL on a second electrode EL2.

In an embodiment, the emission layer EML may include the first compound that includes a core part containing a boron atom as a ring-forming atom, and includes at least one hetero substituent which is substituted at the core part and has benzonitrile as a linker. The hetero substituent in the first compound of the present disclosure may be a carbazole derivative or an arylamine derivative.

In some embodiments, the emission layer EML may include at least one of a second compound, a third compound, or a fourth compound. The second compound may include a substituted or unsubstituted carbazole. The third compound may include a hexagonal ring containing at least one nitrogen atom as a ring-forming atom. The fourth compound may be an organometallic complex compound. The fourth compound may be an organometallic complex compound containing platinum (Pt) or iridium (Ir) as a central metal.

In the light emitting element ED according to an embodiment, the first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or one or more oxides thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, one or more compounds or mixtures thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may have a single layer formed of a single material, a single layer formed of a plurality of different materials, or a multilayer structure including a plurality of layers formed of a plurality of different materials.

The hole transport region HTR may include at least one of a hole injection layer HIL, a hole transport layer HTL, a buffer layer, an emission-auxiliary layer, or an electron blocking layer EBL. In some embodiments, the hole transport region HTR may include a plurality of stacked hole transport layers.

In some embodiments, the hole transport region HTR may have a single layer structure of the hole injection layer HIL or the hole transport layer HTL, or may have a single layer structure formed of a hole injection material and a hole transport material. In an embodiment, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, or a hole transport layer HTL/buffer layer are stacked in order from the first electrode EL1, but the embodiment of the present disclosure is not limited thereto.

The thickness of the hole transport region HTR may be, for example, from about 50 Å to about 15,000 Å. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR in the light emitting element ED of an embodiment may include a compound represented by Formula H-1:

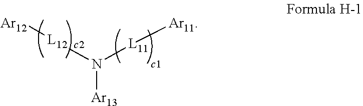

In Formula H-1, L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms. c1 and c2 may each independently be an integer from 0 to 10. In some embodiments, when c1 or c2 is an integer of 2 or more, a plurality of L₁₁s and L₁₂s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₁₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one selected from among Ar₁₁ to Ar₁₃ includes the amine group as a substituent. In some embodiments, the compound represented by Formula H-1 may be a carbazole-based compound including a substituted or unsubstituted carbazole group in at least one of Ar₁₁ or Ar₁₂, or a fluorene-based compound including a substituted or unsubstituted fluorene group in at least one of Ar₁₁ or Ar₁₂.

The compound represented by Formula H-1 may be represented by any one selected from among the compounds of Compound Group H. However, the compounds listed in Compound Group H are merely examples, and the compounds represented by Formula H-1 are not limited to those represented by Compound Group H:

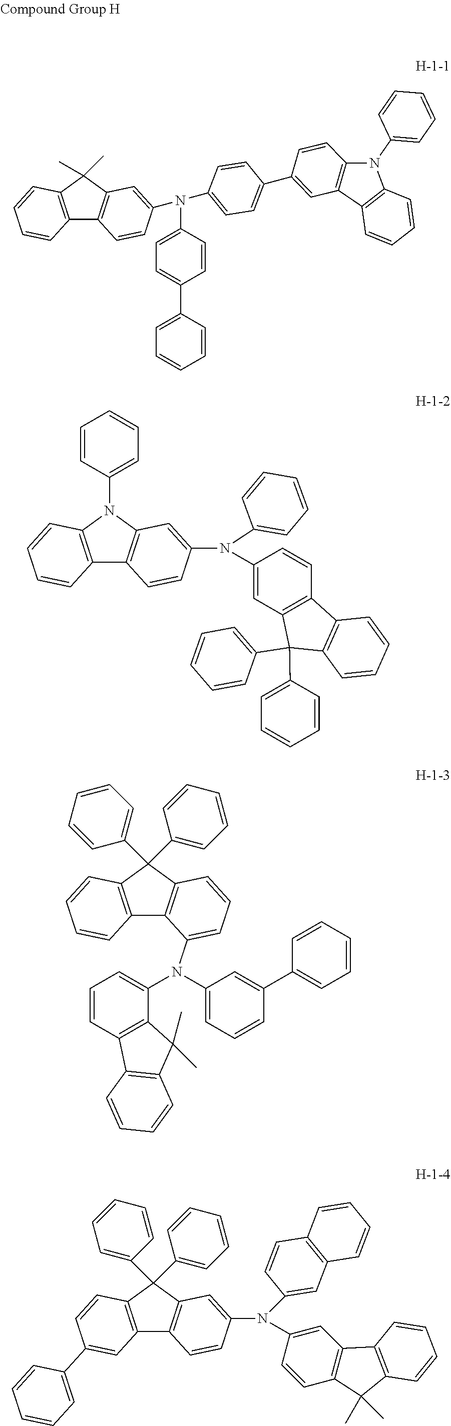 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

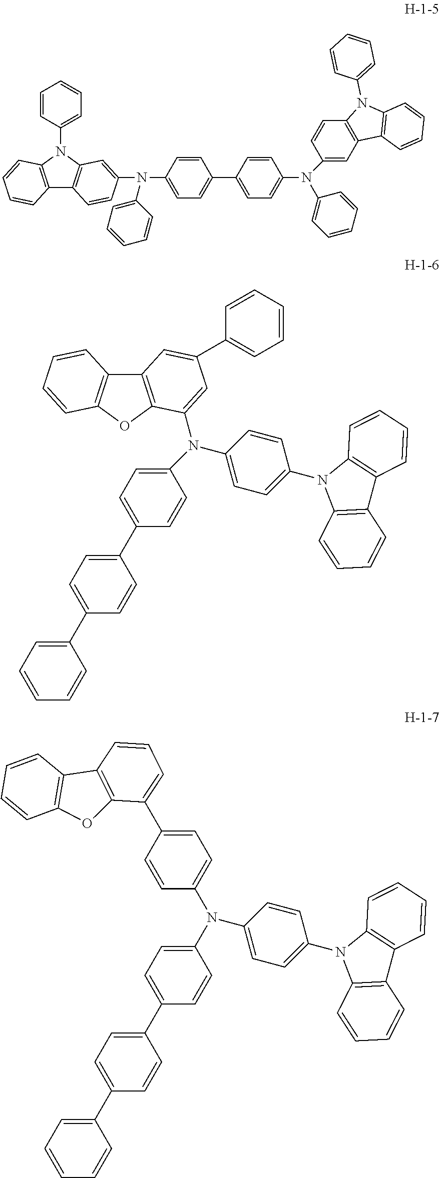 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

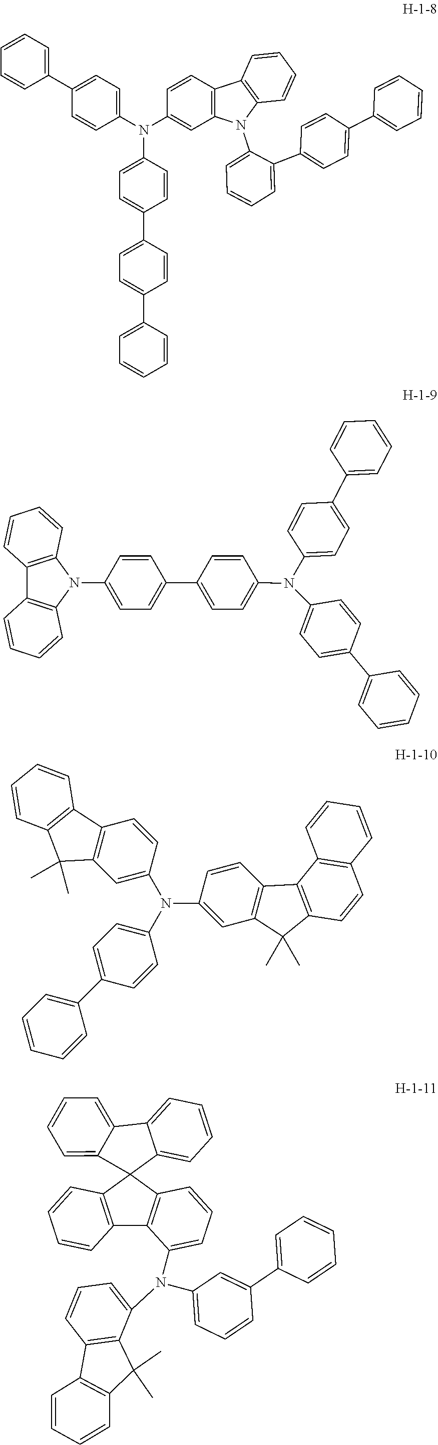

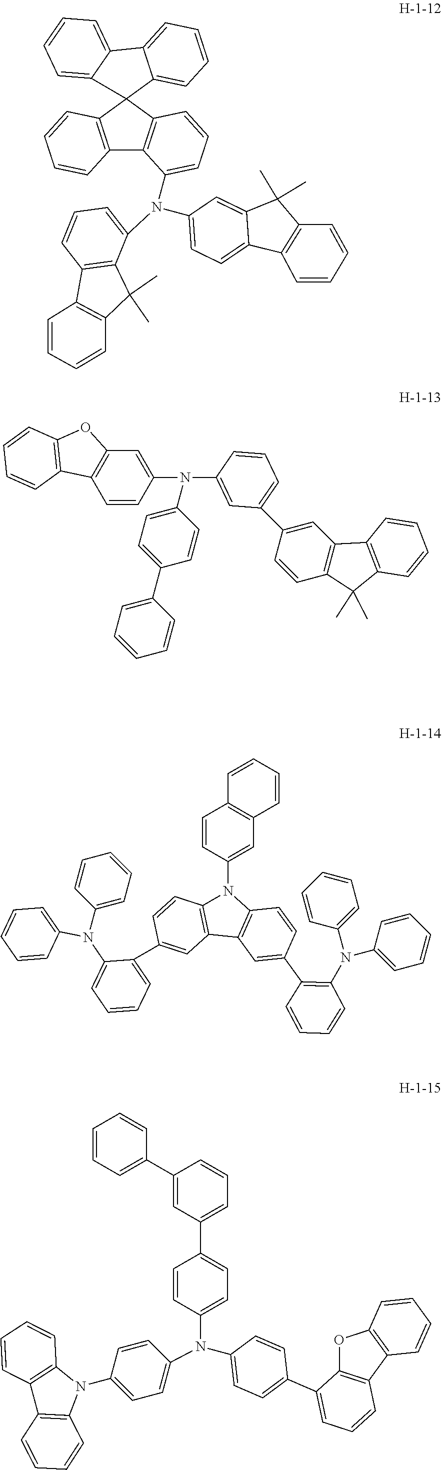 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

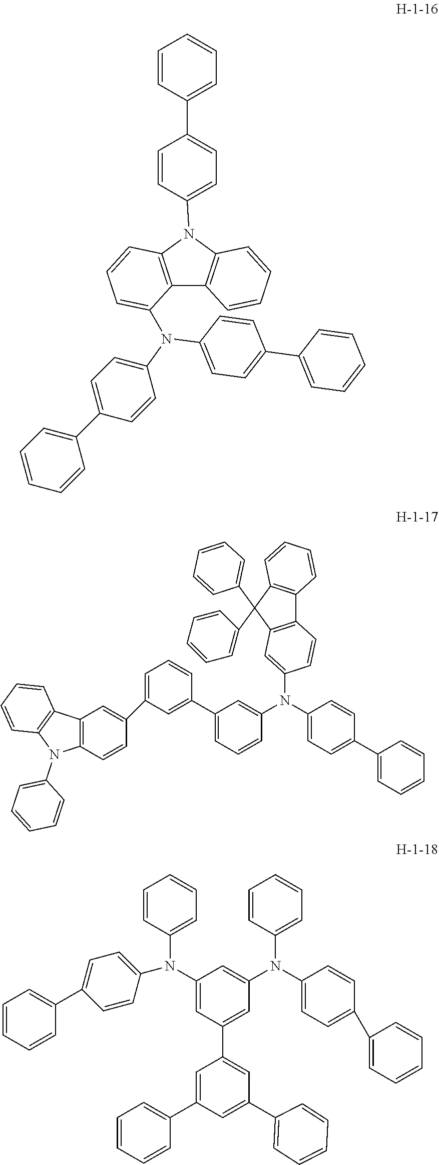 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

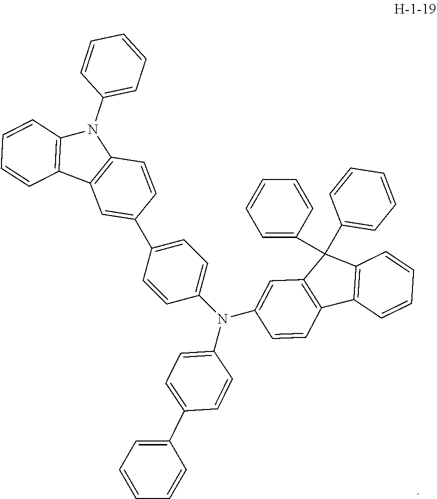 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-I-yl)-N,N′-diphenyl-benzidine (NPB or NPD of α-NPD), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without a substantial increase in driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer, the emission-auxiliary layer, or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be utilized as a material to be contained in the buffer layer. The electron blocking layer EBL is a layer that serves to prevent or reduce the electron injection from the electron transport region ETR to the hole transport region HTR. The emission-auxiliary layer may improve the charge balance between holes and electrons. When the hole transport region HTR includes the electron blocking layer EBL, the electron blocking layer EBL may include the function of the emission-auxiliary layer.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In an embodiment, the emission layer EML may include the first compound represented by Formula 1. The first compound corresponds to the polycyclic compound of an embodiment.

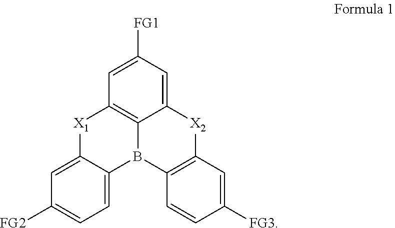

In Formula 1, X₁ and X₂ may each independently be NRₓ, O, or S. In the polycyclic compound of an embodiment, X₁ and X₂ may be the same as or different from each other. For example, in an embodiment, any one selected from among X₁ and X₂ may be NRₓ, and the other may be NRₓ, O, or S. In some embodiments, any one selected from among X₁ and X₂ may be O, and the other may be S.

In the polycyclic compound of an embodiment, Rₓ may be a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. For example, Rₓ may be a substituted or unsubstituted phenyl group. However, the embodiment of the present disclosure is not limited thereto.

In Formula 1, at least one of FG1, FG2, or FG3 may be represented by Formula 2-1 or Formula 2-2, and the rest may each independently be a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

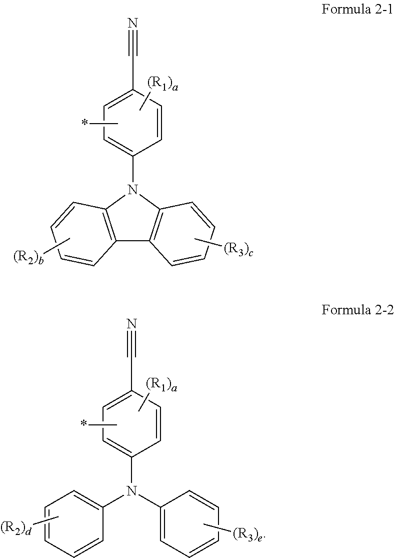

In Formula 2-1 and Formula 2-2, a may be an integer from 0 to 3, b and c may each independently be an integer from 0 to 4, and d and e may each independently be an integer from 0 to 5. In Formula 2-1 and Formula 2-2, R₁ to R₃ may each independently be a hydrogen atom, a deuterium atom, a halogen atom, a cyano group, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

In Formula 2-1 and Formula 2-2, when a is an integer of 2 or greater, a plurality of R₁s may all be the same or at least one may be different from the rest. For example, in an embodiment, a may be 0 or 1. In an embodiment, R₁ may be represented by any one selected from among R₁₋ₐ to R_{1-c}. However, the embodiment of the present disclosure is not limited thereto. In some embodiments, in R_{1-b}, D is a deuterium atom.

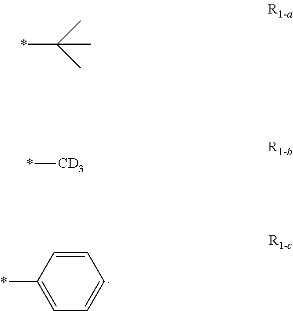

In some embodiments, in Formula 2-1 and Formula 2-2, when each of b and d is an integer of 2 or greater, a plurality of R₂s may all be the same or at least one may be different from the rest. In Formula 2-1 and Formula 2-2, when each of c and e is an integer of 2 or greater, a plurality of R₃s may all be the same or at least one may be different from the rest.

In some embodiments, the polycyclic compound of an embodiment may include at least one deuterium atom as a substituent. For example, in an embodiment, at least one selected from among X₁, X₂, FG1 to FG3 in Formula 1 may include a deuterium atom, or a substituent containing a deuterium atom. For example, in the polycyclic compound represented by Formula 1 of an embodiment, at least one selected from among Rₓ, and R₁ to R₃ may be a deuterium atom, or a substituent containing a deuterium atom.

The polycyclic compound represented by Formula 1 of an embodiment may include a core part of a fused ring containing a boron atom (B) as a ring-forming atom, and a substituent of a carbazole derivative or an arylamine derivative substituted at the para-position with the boron atom of the core part. The polycyclic compound of an embodiment may include a substituted or unsubstituted benzonitrile derivative between the core part containing a boron atom and a substituent of the carbazole derivative or arylamine derivative. The polycyclic compound of an embodiment includes the carbazole derivative or arylamine derivative as a substituent by utilizing the benzonitrile derivative as a linker, and thus the distortion in the molecule is controlled or selected, and the characteristics of improved molecular stability may be exhibited. In some embodiments, the polycyclic compound of an embodiment includes the carbazole derivative or arylamine derivative as a substituent, and thus multiple resonance(s) at the core part of the fused ring may be expanded or activated. Accordingly, the polycyclic compound of an embodiment may exhibit high oscillator strength (f) and absorbance.

The polycyclic compound of an embodiment may include the carbazole derivative or arylamine derivative as a substituent, further inducing HOMO-LUMO separation between the substituent and the core part in addition to HOMO-LUMO separation within the core part, and thus exhibiting the characteristics of an increase in delayed fluorescence phenomenon.

For example, the polycyclic compound of an embodiment may have a structure including a substituent of the carbazole derivative or arylamine derivative bonded to the boron-containing core part of the fused ring via the benzonitrile as a linker, and thus may exhibit the characteristics of an increase in the stability of the compound, light extraction efficiency, and delayed fluorescence. Accordingly, the polycyclic compound of an embodiment may make a contribution to improving luminous efficiency and service life of the light emitting element.

In an embodiment, Formula 1 may be represented by any one selected from among Formula 1-1 to Formula 1-3:

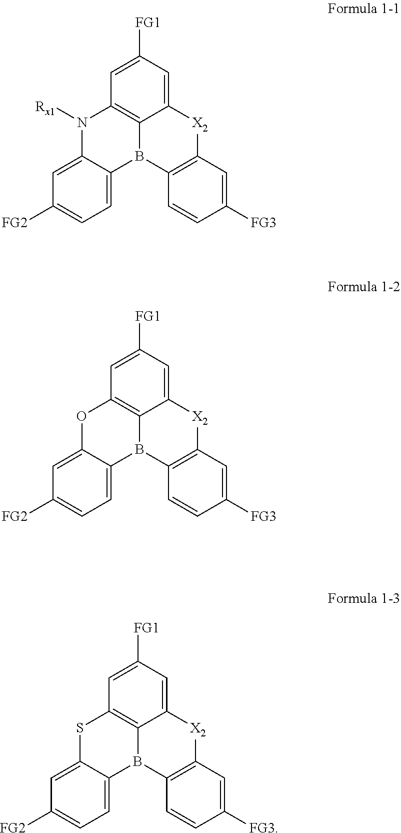

In Formula 1-1, X₂ may be NRₓ₂, O, or S. In Formula 1-1, Rₓ₁ and Rₓ₂ may each independently be a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. In some embodiments, in the polycyclic compound represented by Formula 1-1 of an embodiment, when X₂ is NRₓ₂, Rₓ₁ and Rₓ₂ may be the same as or different from each other.

In Formula 1-2 and Formula 1-3, X₂ may be O or S. For example, the polycyclic compound represented by Formula 1-2 or Formula 1-3 of an embodiment may include an oxygen atom (O) and a sulfur atom (S) arranged one by one (i.e., one O and one S) as a ring-forming atom, or may include two oxygen atoms, or two sulfur atoms.

In the polycyclic compounds represented by Formula 1-1 to Formula 1-3 of an embodiment, the same as described in Formula 1 as described above may be applied to FG1, FG2, and FG3.

In some embodiments, Formula 1 may be represented by any one selected from among Formula 1A to Formula 1E:

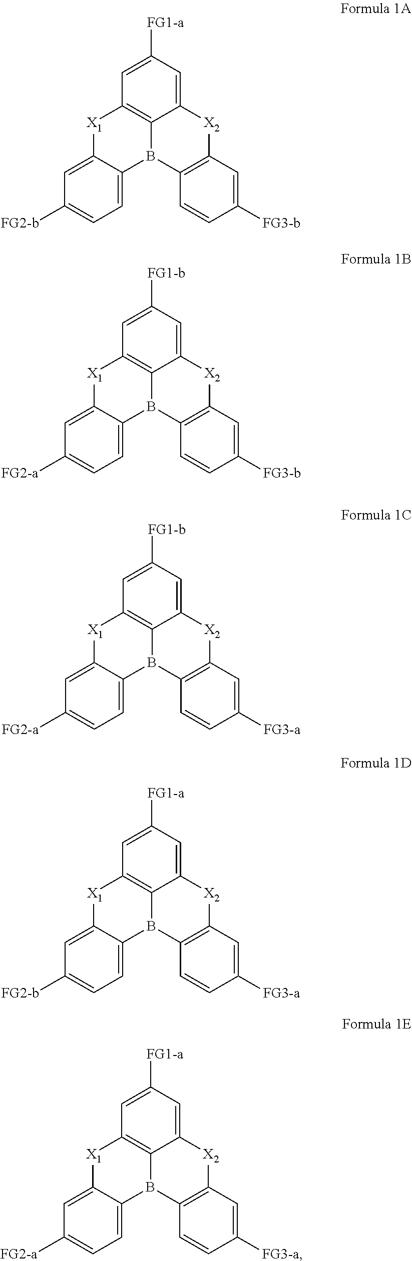

In Formula 1A to Formula 1E, FG1-a, FG2-a, and FG3-a may each independently be represented by Formula 2-1 or Formula 2-2 as described above. In some embodiments, in Formula 1A to Formula 1E, FG1-b, FG2-b, and FG3-b may each independently be a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

For example, the polycyclic compound represented by Formula 1A or Formula 1B of an embodiment may include one substituent represented by Formula 2-1 or Formula 2-2, the polycyclic compound represented by Formula 1C or Formula 1D of an embodiment may include two substituents represented by Formula 2-1 or Formula 2-2, and the polycyclic compound represented by Formula 1E of an embodiment may include three substituents represented by Formula 2-1 or Formula 2-2.

In Formula 1A to Formula 1E, the same as described in Formula 1 as described above may be applied to X₁ and X₂. In Formula 1A to Formula 1E, the same as described in Formula 2-1 or Formula 2-2 as described above may be applied to FG1-a, FG2-a, and FG3-a.

In an embodiment represented by Formula 1A to Formula 1E, FG1-b, FG2-b, and FG3-b may each independently be a hydrogen atom, an unsubstituted alkyl group having 1 to 10 carbon atoms, a deuterium-substituted alkyl group having 1 to 10 carbon atoms, a substituted or unsubstituted phenyl group, a substituted or unsubstituted terphenyl group, a substituted or unsubstituted diphenylamine group, or a substituted or unsubstituted carbazole group. However, the embodiment of the present disclosure is not limited thereto.

The polycyclic compound of an embodiment may be represented by any one selected from among compounds in Compound Group 1. The light emitting element ED of an embodiment may include any one selected from among the compounds of Compound Group 1. In Compound Group 1, D is a deuterium atom, and Ph is a phenyl group.

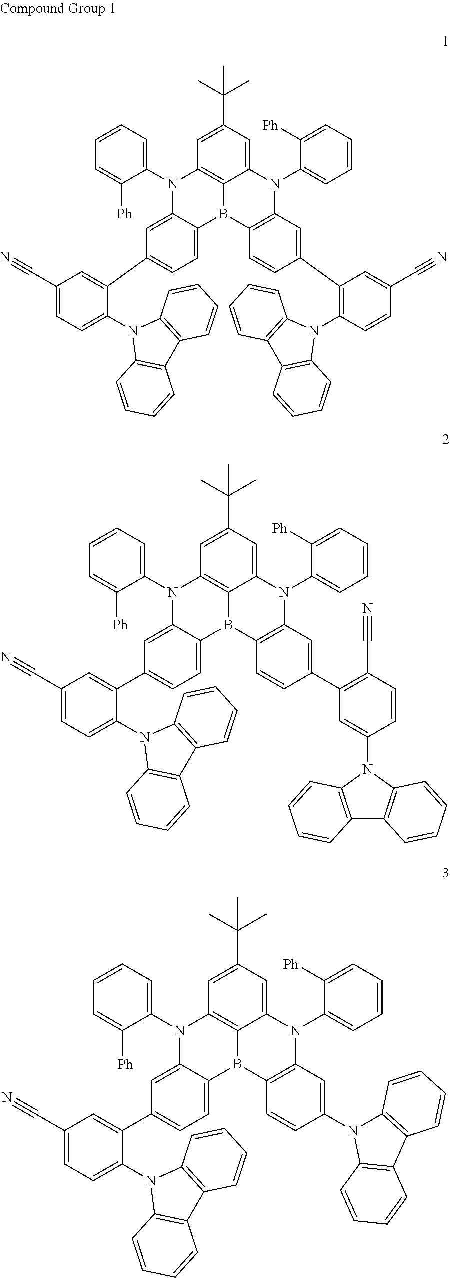 [SMILES: CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1N2c1ccccc1-c1ccccc1 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(-n4c5ccccc5c5ccccc54)ccc3C#N)cc1N2c1ccccc1-c1ccccc1 ; CC(C)(C)c1cc2c3c(c1)N(c1ccccc1-c1ccccc1)c1cc(-n4c5ccccc5c5ccccc54)ccc1B3c1ccc(-c3cc(C#N)ccc3-n3c4ccccc4c4ccccc43)cc1N2c1ccccc1-c1ccccc1]

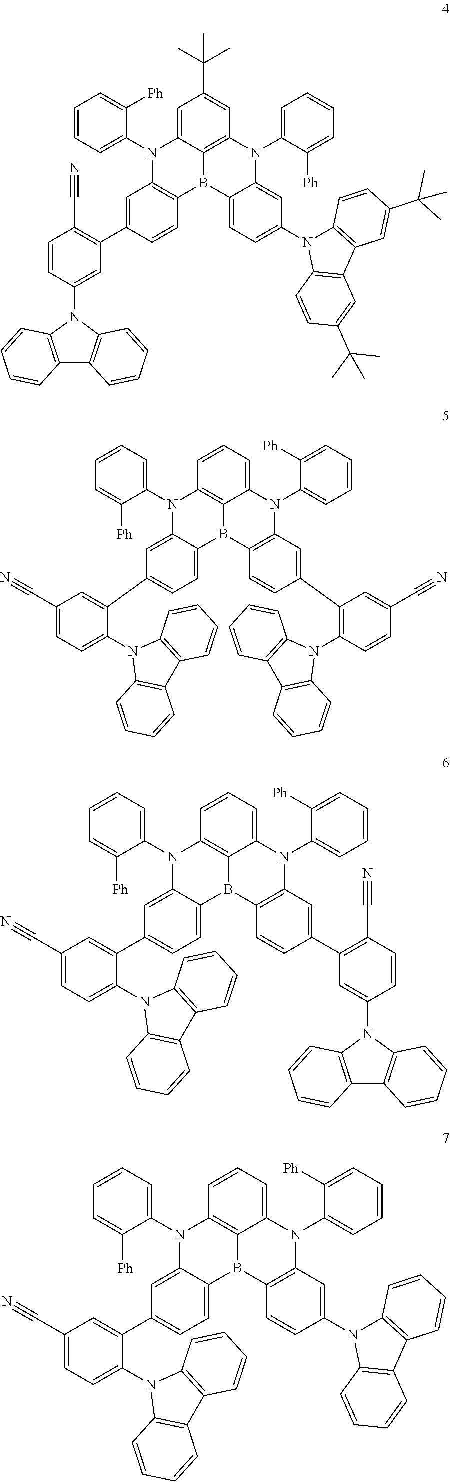

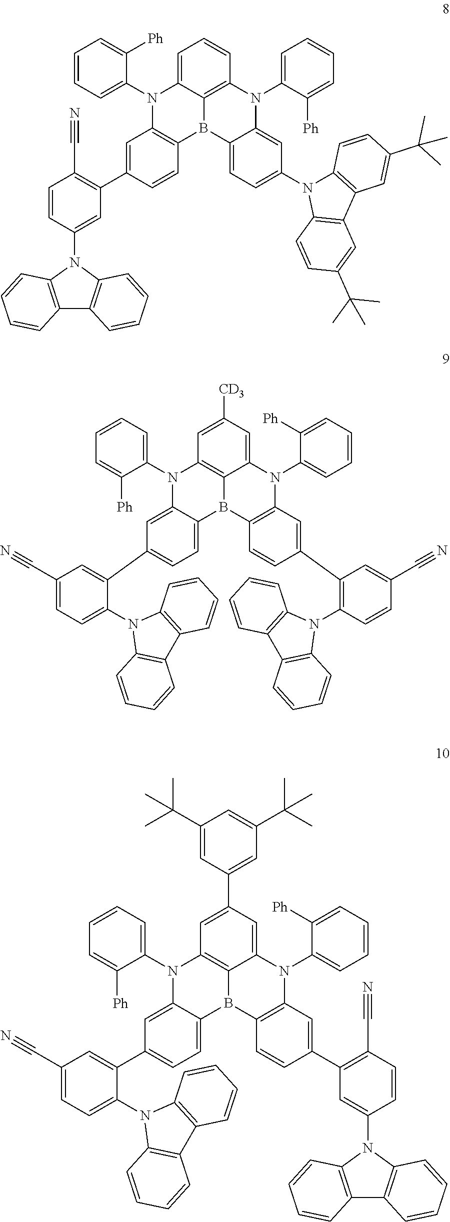 [SMILES: CC(C)(C)c1ccc2c(c1)c1cc(C(C)(C)C)ccc1n2-c1ccc2c(c1)N(c1ccccc1-c1ccccc1)c1cccc3c1B2c1ccc(-c2cc(-n4c5ccccc5c5ccccc54)ccc2C#N)cc1N3c1ccccc1-c1ccccc1 ; [2H]C([2H])([2H])c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1N2c1ccccc1-c1ccccc1 ; CC(C)(C)c1cc(-c2cc3c4c(c2)N(c2ccccc2-c2ccccc2)c2cc(-c5cc(C#N)ccc5-n5c6ccccc6c6ccccc65)ccc2B4c2ccc(-c4cc(-n5c6ccccc6c6ccccc65)ccc4C#N)cc2N3c2ccccc2-c2ccccc2)cc(C(C)(C)C)c1]

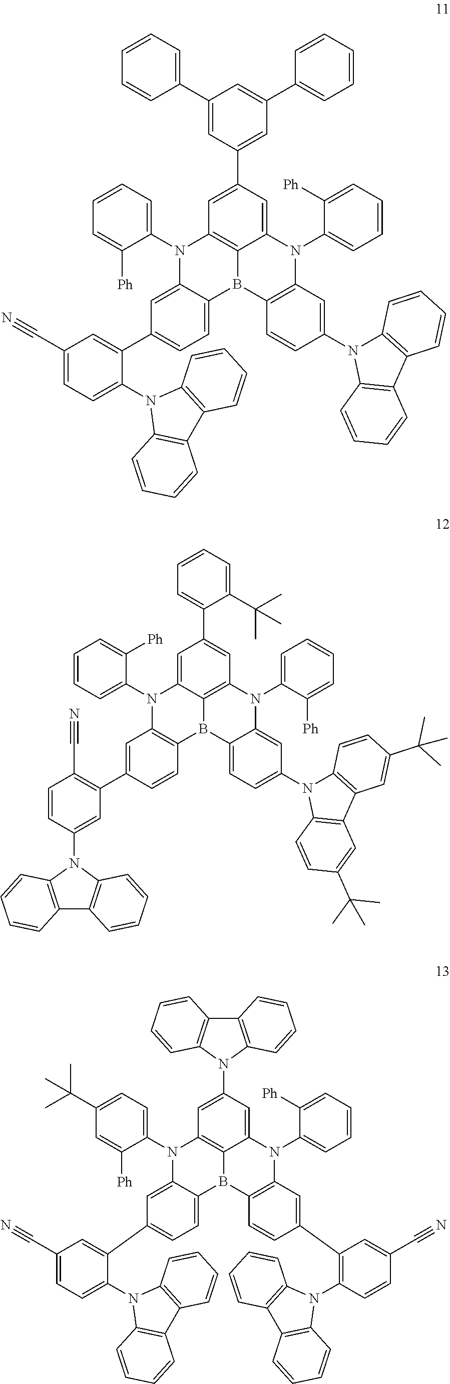

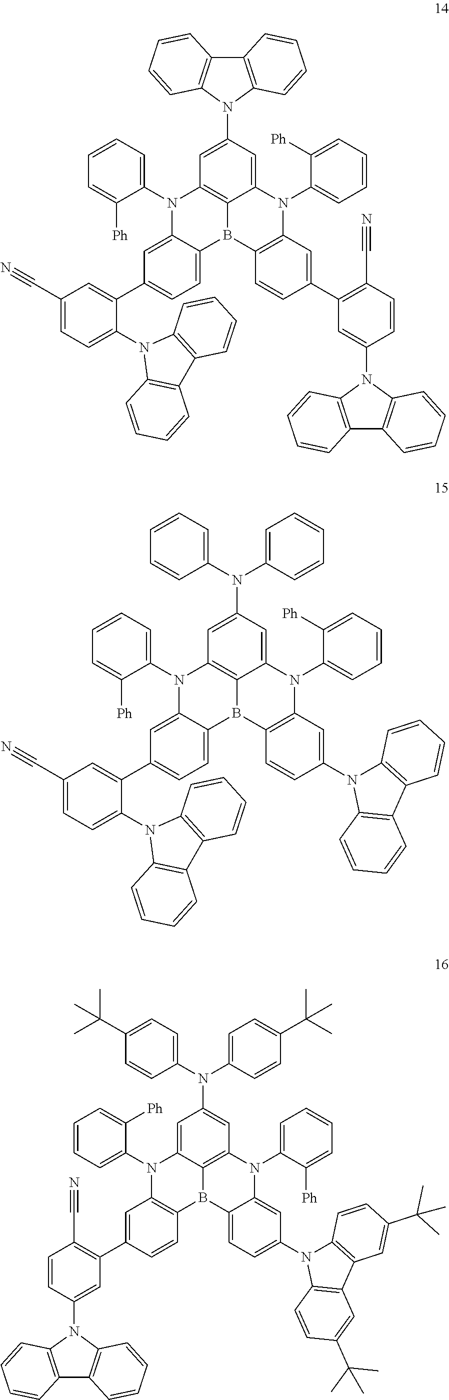

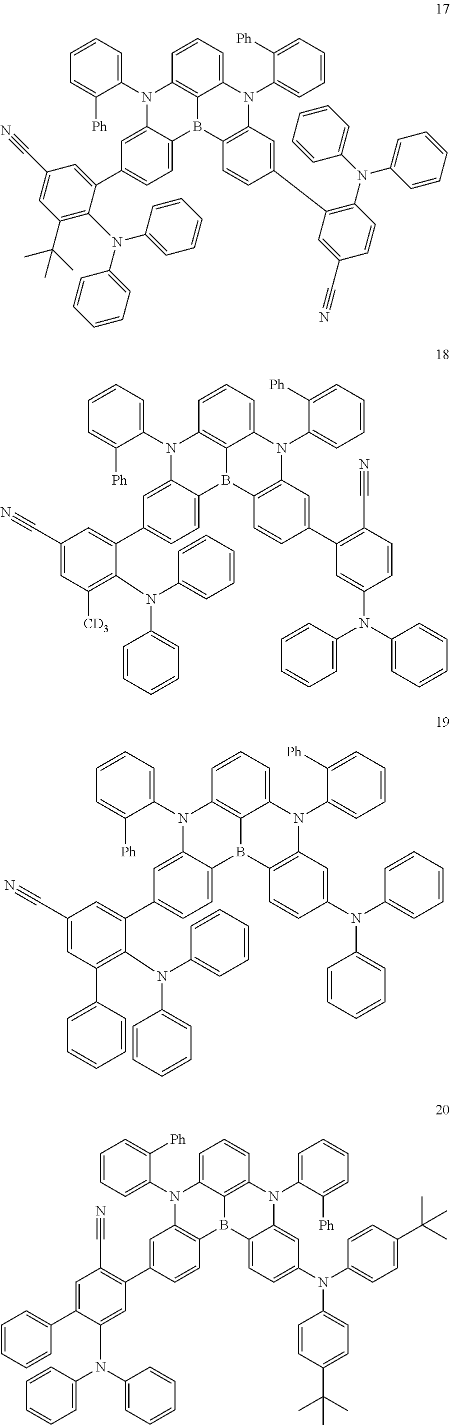

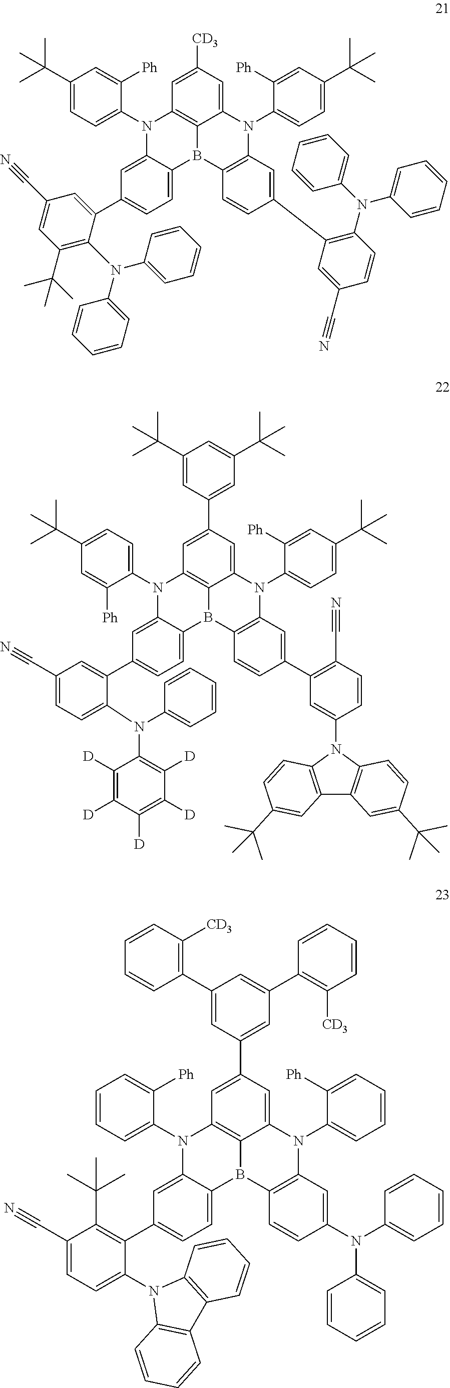

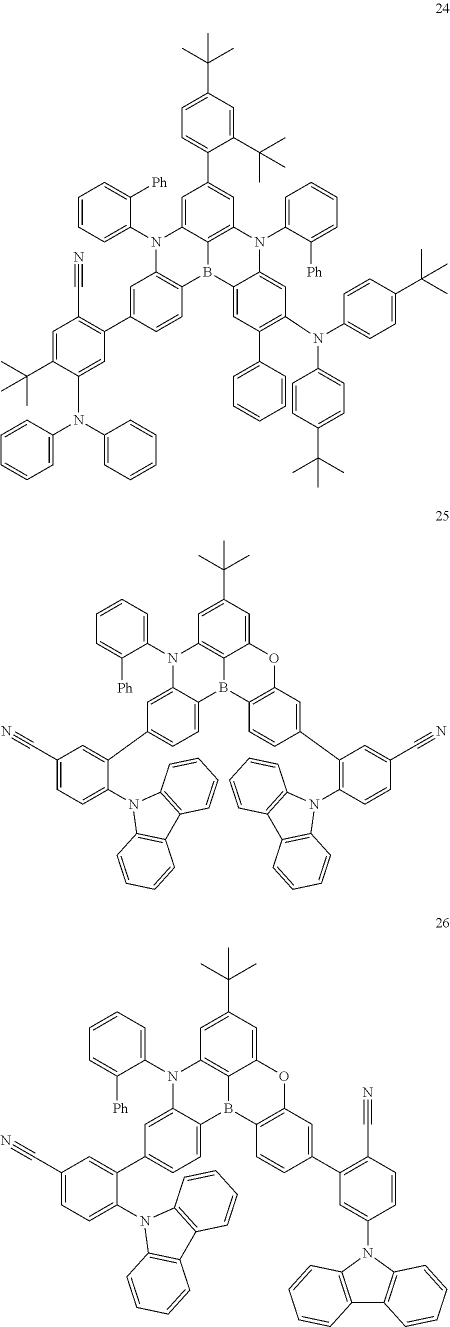 [SMILES: CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4N(c4ccccc4-c4ccccc4)c4cc(-c5ccc(C(C)(C)C)cc5C(C)(C)C)cc(c42)N3c2ccccc2-c2ccccc2)cc1 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(-n4c5ccccc5c5ccccc54)ccc3C#N)cc1O2]

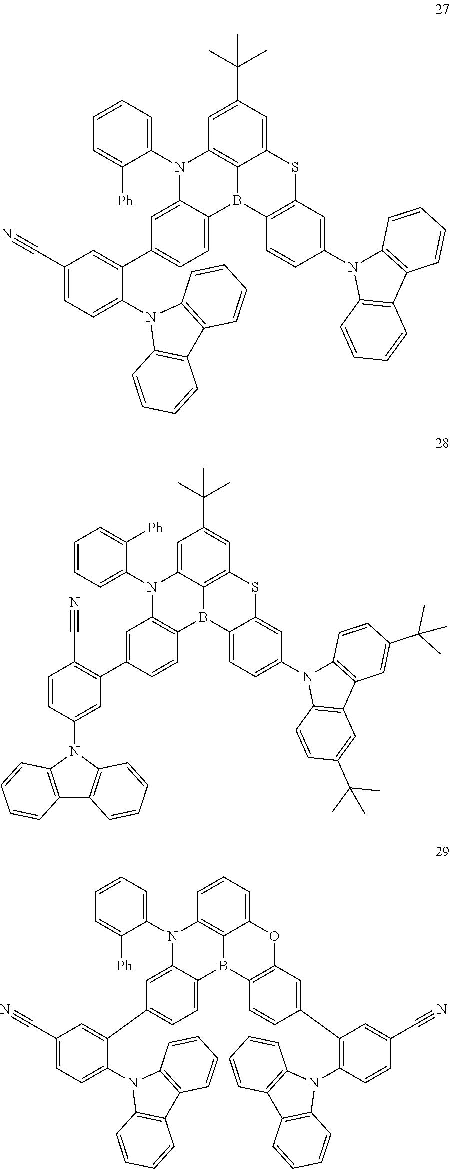 [SMILES: CC(C)(C)c1cc2c3c(c1)N(c1ccccc1-c1ccccc1)c1cc(-c4cc(C#N)ccc4-n4c5ccccc5c5ccccc54)ccc1B3c1ccc(-n3c4ccccc4c4ccccc43)cc1S2 ; CC(C)(C)c1cc2c3c(c1)N(c1ccccc1-c1ccccc1)c1cc(-c4cc(-n5c6ccccc6c6ccccc65)ccc4C#N)ccc1B3c1ccc(-n3c4ccc(C(C)(C)C)cc4c4cc(C(C)(C)C)ccc43)cc1S2 ; N#Cc1ccc(-n2c3ccccc3c3ccccc32)c(-c2ccc3c(c2)Oc2cccc4c2B3c2ccc(-c3cc(C#N)ccc3-n3c5ccccc5c5ccccc53)cc2N4c2ccccc2-c2ccccc2)c1]

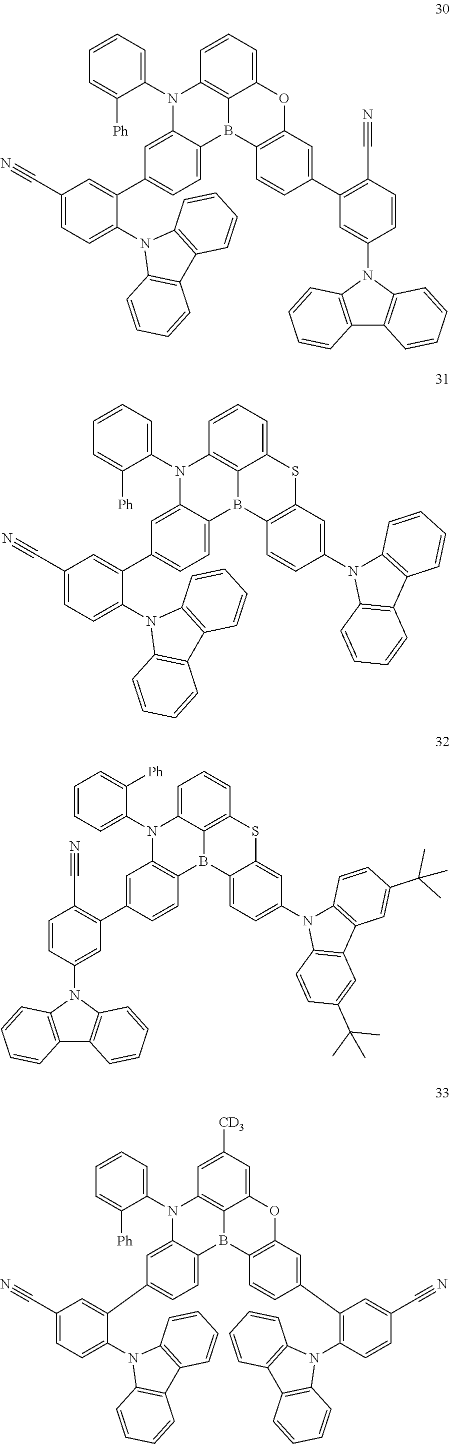

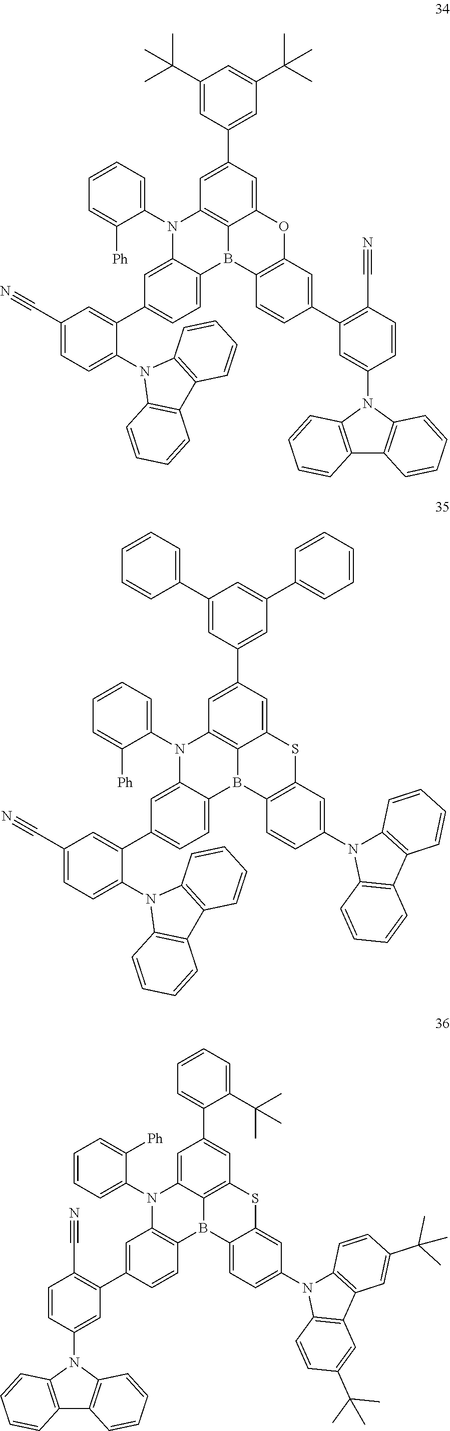 [SMILES: CC(C)(C)c1cc(-c2cc3c4c(c2)N(c2ccccc2-c2ccccc2)c2cc(-c5cc(C#N)ccc5-n5c6ccccc6c6ccccc65)ccc2B4c2ccc(-c4cc(-n5c6ccccc6c6ccccc65)ccc4C#N)cc2O3)cc(C(C)(C)C)c1 ; N#Cc1ccc(-n2c3ccccc3c3ccccc32)c(-c2ccc3c(c2)N(c2ccccc2-c2ccccc2)c2cc(-c4cc(-c5ccccc5)cc(-c5ccccc5)c4)cc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cc(-c3ccccc3C(C)(C)C)cc3c1B2c1ccc(-c2cc(-n4c5ccccc5c5ccccc54)ccc2C#N)cc1N3c1ccccc1-c1ccccc1]

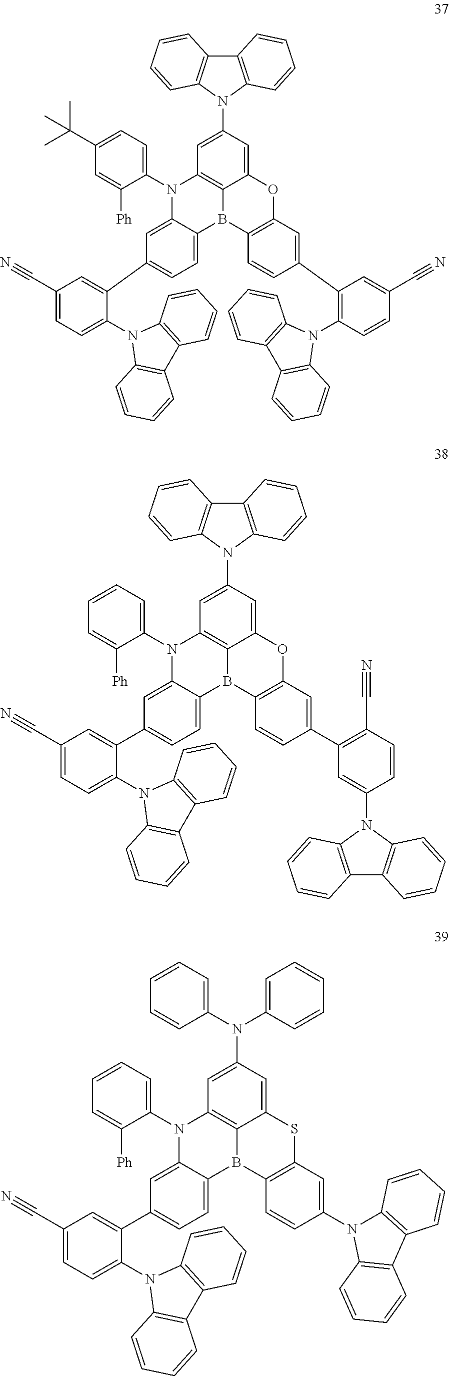 [SMILES: CC(C)(C)c1ccc(N2c3cc(-c4cc(C#N)ccc4-n4c5ccccc5c5ccccc54)ccc3B3c4ccc(-c5cc(C#N)ccc5-n5c6ccccc6c6ccccc65)cc4Oc4cc(-n5c6ccccc6c6ccccc65)cc2c43)c(-c2ccccc2)c1 ; N#Cc1ccc(-n2c3ccccc3c3ccccc32)c(-c2ccc3c(c2)N(c2ccccc2-c2ccccc2)c2cc(-n4c5ccccc5c5ccccc54)cc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)N(c2ccccc2-c2ccccc2)c2cc(N(c4ccccc4)c4ccccc4)cc4c2B3c2ccc(-n3c5ccccc5c5ccccc53)cc2S4)c1]

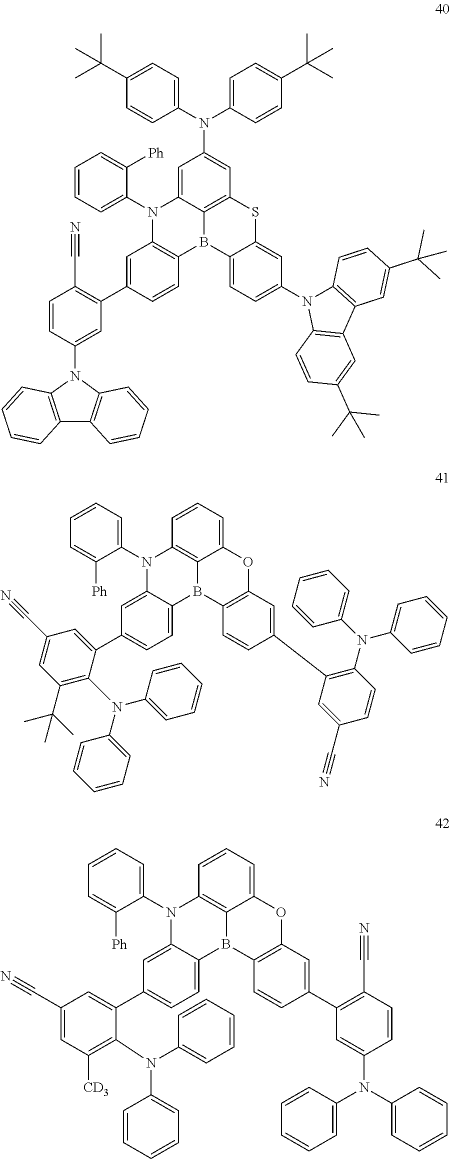 [SMILES: CC(C)(C)c1ccc(N(c2ccc(C(C)(C)C)cc2)c2cc3c4c(c2)N(c2ccccc2-c2ccccc2)c2cc(-c5cc(-n6c7ccccc7c7ccccc76)ccc5C#N)ccc2B4c2ccc(-n4c5ccc(C(C)(C)C)cc5c5cc(C(C)(C)C)ccc54)cc2S3)cc1 ; CC(C)(C)c1cc(C#N)cc(-c2ccc3c(c2)N(c2ccccc2-c2ccccc2)c2cccc4c2B3c2ccc(-c3cc(C#N)ccc3N(c3ccccc3)c3ccccc3)cc2O4)c1N(c1ccccc1)c1ccccc1 ; [2H]C([2H])([2H])c1cc(C#N)cc(-c2ccc3c(c2)N(c2ccccc2-c2ccccc2)c2cccc4c2B3c2ccc(-c3cc(N(c5ccccc5)c5ccccc5)ccc3C#N)cc2O4)c1N(c1ccccc1)c1ccccc1]

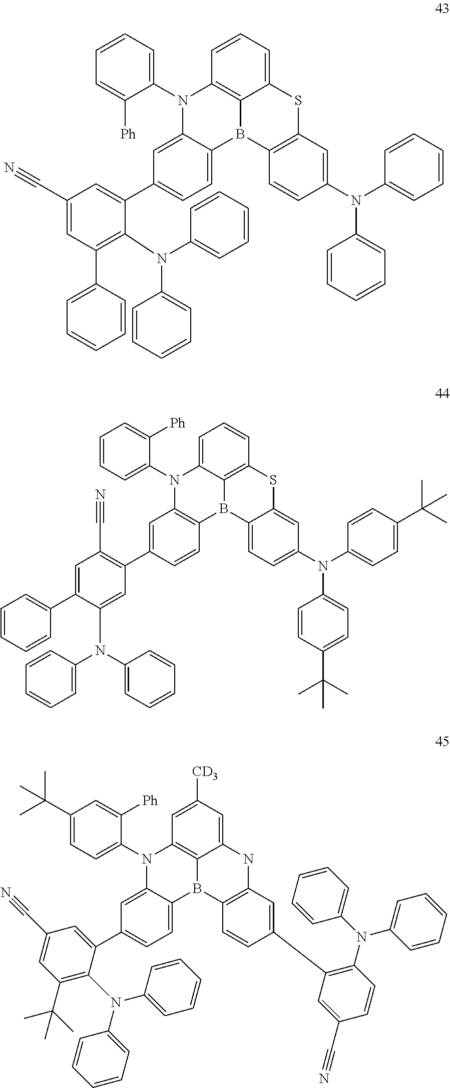 [SMILES: N#Cc1cc(-c2ccccc2)c(N(c2ccccc2)c2ccccc2)c(-c2ccc3c(c2)N(c2ccccc2-c2ccccc2)c2cccc4c2B3c2ccc(N(c3ccccc3)c3ccccc3)cc2S4)c1 ; CC(C)(C)c1ccc(N(c2ccc(C(C)(C)C)cc2)c2ccc3c(c2)Sc2cccc4c2B3c2ccc(-c3cc(N(c5ccccc5)c5ccccc5)c(-c5ccccc5)cc3C#N)cc2N4c2ccccc2-c2ccccc2)cc1 ; [2H]C([2H])([2H])c1cc2c3c(c1)N(c1ccc(C(C)(C)C)cc1-c1ccccc1)c1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1N2]

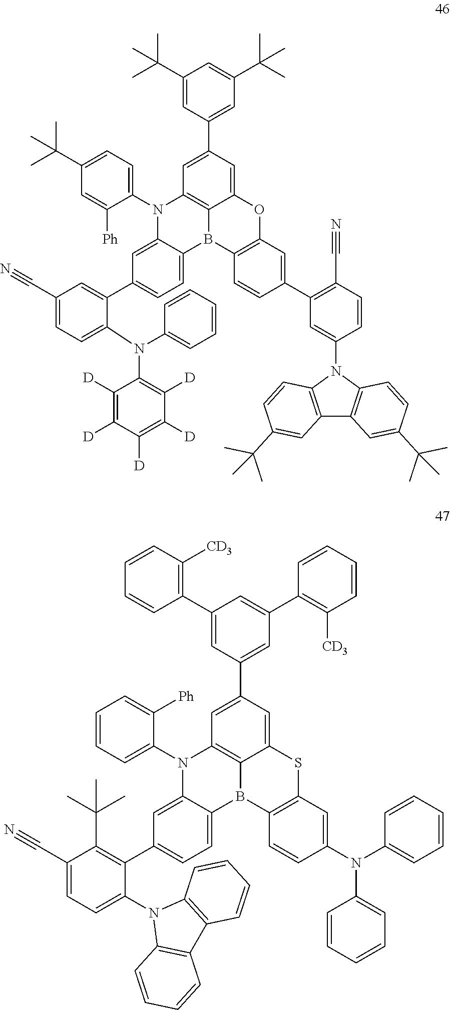 [SMILES: [2H]c1c([2H])c([2H])c(N(c2ccccc2)c2ccc(C#N)cc2-c2ccc3c(c2)N(c2ccc(C(C)(C)C)cc2-c2ccccc2)c2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2O4)c([2H])c1[2H] ; [2H]C([2H])([2H])c1ccccc1-c1cc(-c2cc3c4c(c2)N(c2ccccc2-c2ccccc2)c2cc(-c5c(-n6c7ccccc7c7ccccc76)ccc(C#N)c5C(C)(C)C)ccc2B4c2ccc(N(c4ccccc4)c4ccccc4)cc2S3)cc(-c2ccccc2C([2H])([2H])[2H])c1]

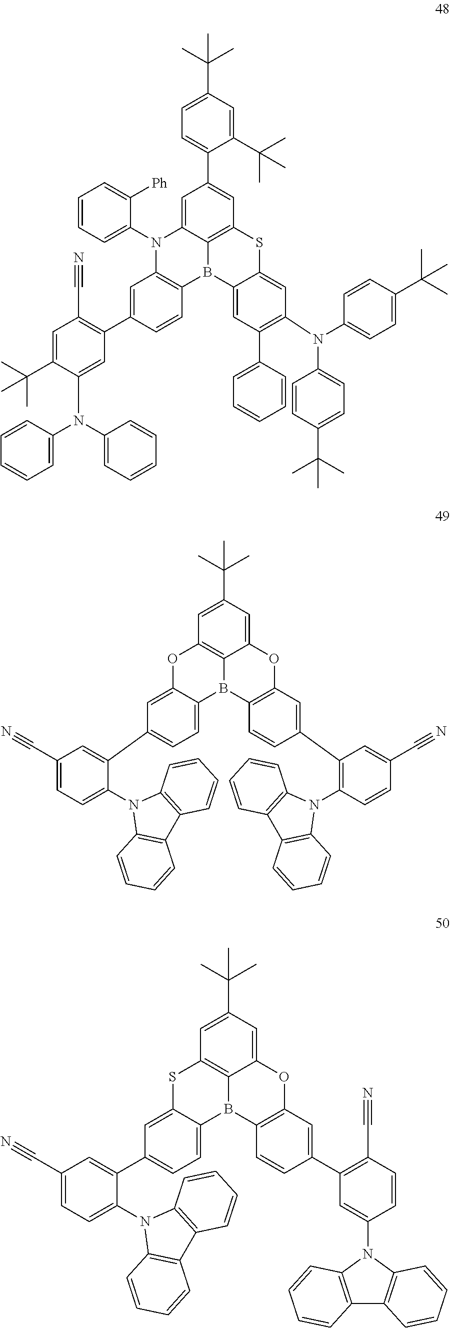 [SMILES: CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4N(c4ccccc4-c4ccccc4)c4cc(-c5ccc(C(C)(C)C)cc5C(C)(C)C)cc(c42)S3)cc1 ; CC(C)(C)c1cc2c3c(c1)Oc1cc(-c4cc(C#N)ccc4-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)Sc1cc(-c4cc(C#N)ccc4-n4c5ccccc5c5ccccc54)ccc1B3c1ccc(-c3cc(-n4c5ccccc5c5ccccc54)ccc3C#N)cc1O2]

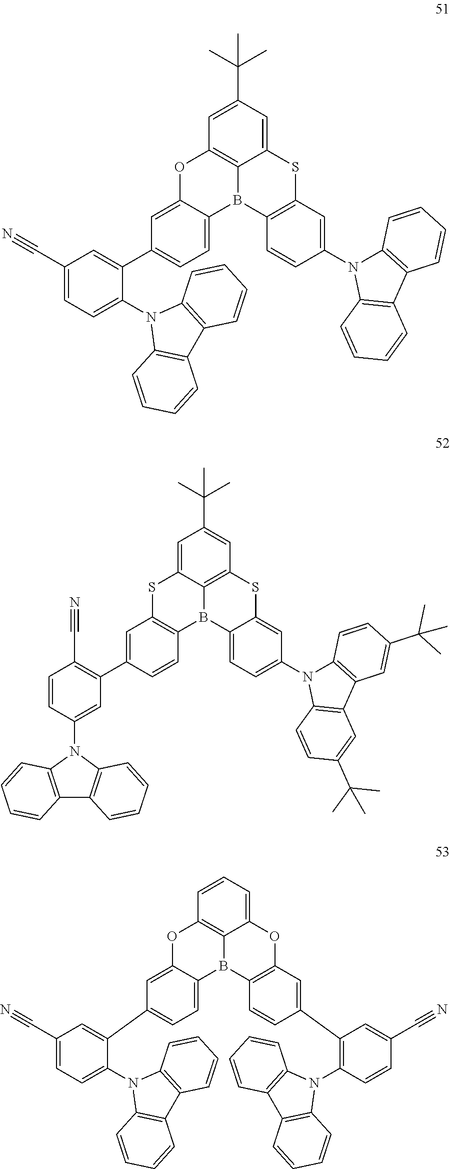 [SMILES: CC(C)(C)c1cc2c3c(c1)Sc1cc(-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)Sc1cc(-n4c5ccc(C(C)(C)C)cc5c5cc(C(C)(C)C)ccc54)ccc1B3c1ccc(-c3cc(-n4c5ccccc5c5ccccc54)ccc3C#N)cc1S2 ; N#Cc1ccc(-n2c3ccccc3c3ccccc32)c(-c2ccc3c(c2)Oc2cccc4c2B3c2ccc(-c3cc(C#N)ccc3-n3c5ccccc5c5ccccc53)cc2O4)c1]

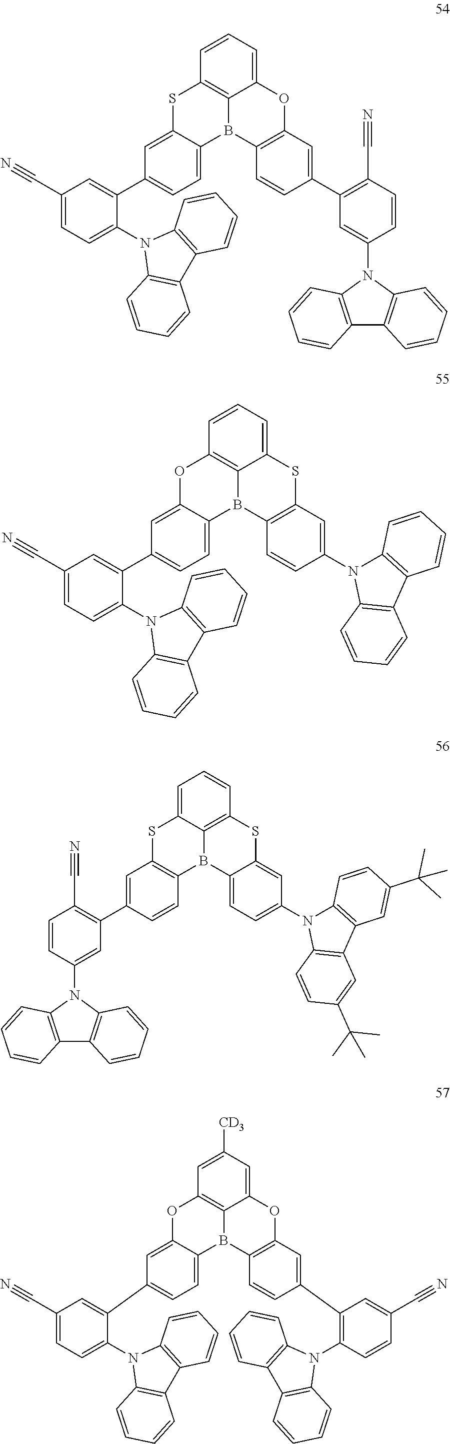 [SMILES: N#Cc1ccc(-n2c3ccccc3c3ccccc32)c(-c2ccc3c(c2)Sc2cccc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)Oc2cccc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cccc3c1B2c1ccc(-c2cc(-n4c5ccccc5c5ccccc54)ccc2C#N)cc1S3 ; [2H]C([2H])([2H])c1cc2c3c(c1)Oc1cc(-c4cc(C#N)ccc4-n4c5ccccc5c5ccccc54)ccc1B3c1ccc(-c3cc(C#N)ccc3-n3c4ccccc4c4ccccc43)cc1O2]

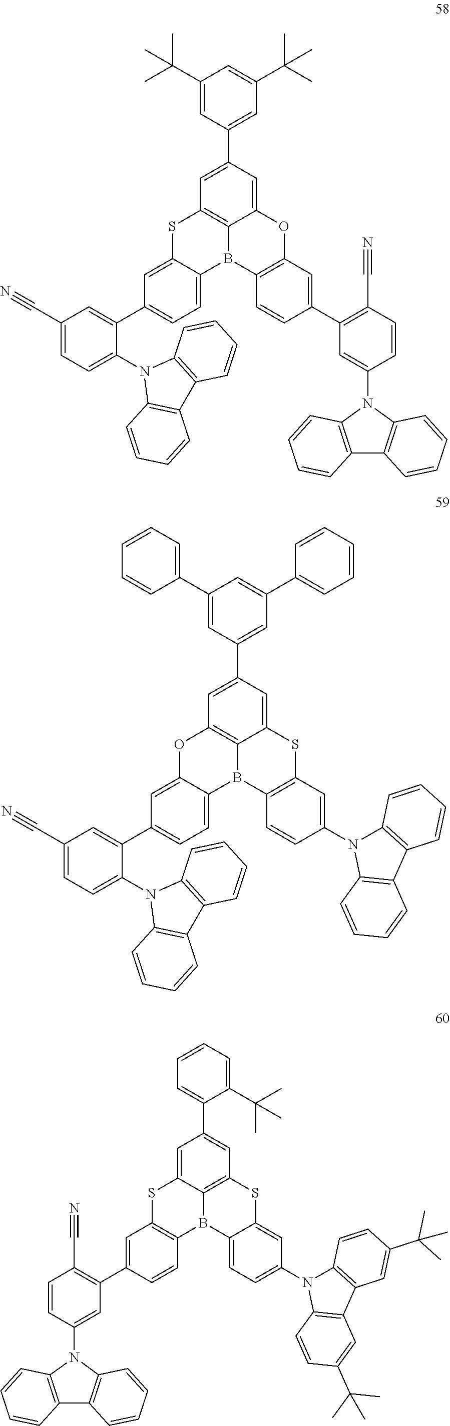 [SMILES: CC(C)(C)c1cc(-c2cc3c4c(c2)Sc2cc(-c5cc(C#N)ccc5-n5c6ccccc6c6ccccc65)ccc2B4c2ccc(-c4cc(-n5c6ccccc6c6ccccc65)ccc4C#N)cc2O3)cc(C(C)(C)C)c1 ; N#Cc1ccc(-n2c3ccccc3c3ccccc32)c(-c2ccc3c(c2)Oc2cc(-c4cc(-c5ccccc5)cc(-c5ccccc5)c4)cc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cc(-c3ccccc3C(C)(C)C)cc3c1B2c1ccc(-c2cc(-n4c5ccccc5c5ccccc54)ccc2C#N)cc1S3]

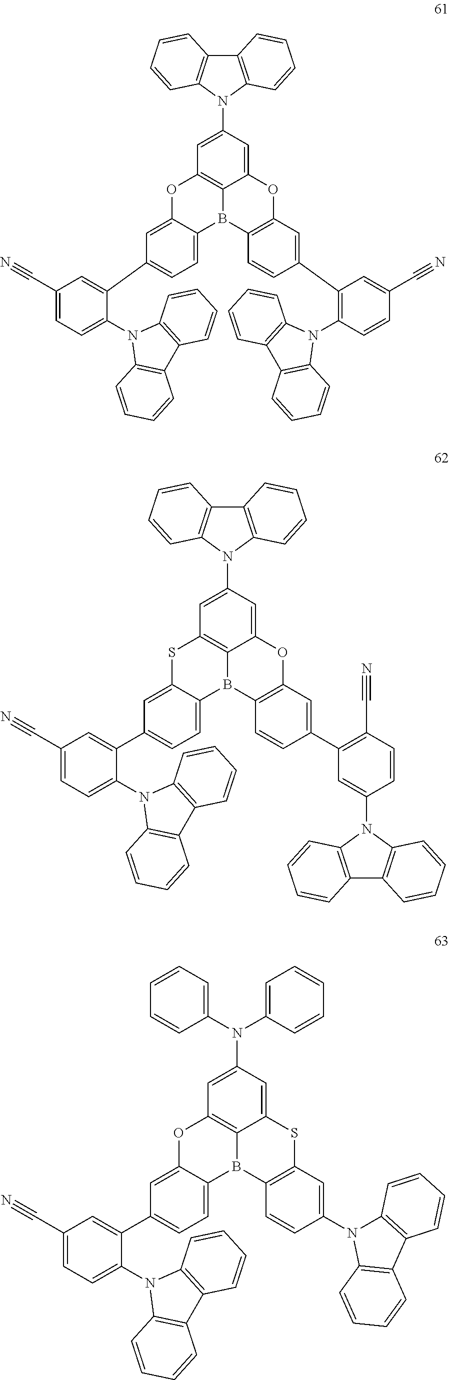 [SMILES: N#Cc1ccc(-n2c3ccccc3c3ccccc32)c(-c2ccc3c(c2)Oc2cc(-n4c5ccccc5c5ccccc54)cc4c2B3c2ccc(-c3cc(C#N)ccc3-n3c5ccccc5c5ccccc53)cc2O4)c1 ; N#Cc1ccc(-n2c3ccccc3c3ccccc32)c(-c2ccc3c(c2)Sc2cc(-n4c5ccccc5c5ccccc54)cc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)Oc2cc(N(c4ccccc4)c4ccccc4)cc4c2B3c2ccc(-n3c5ccccc5c5ccccc53)cc2S4)c1]

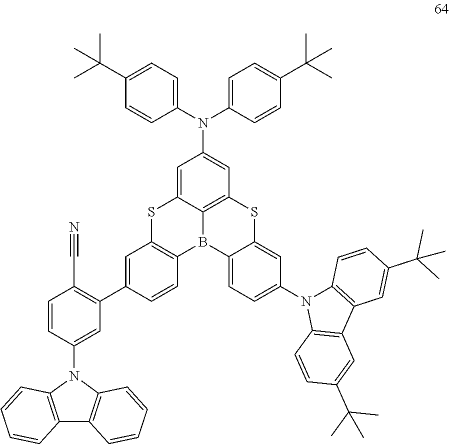 [SMILES: CC(C)(C)c1ccc(N(c2ccc(C(C)(C)C)cc2)c2cc3c4c(c2)Sc2cc(-n5c6ccc(C(C)(C)C)cc6c6cc(C(C)(C)C)ccc65)ccc2B4c2ccc(-c4cc(-n5c6ccccc6c6ccccc65)ccc4C#N)cc2S3)cc1]

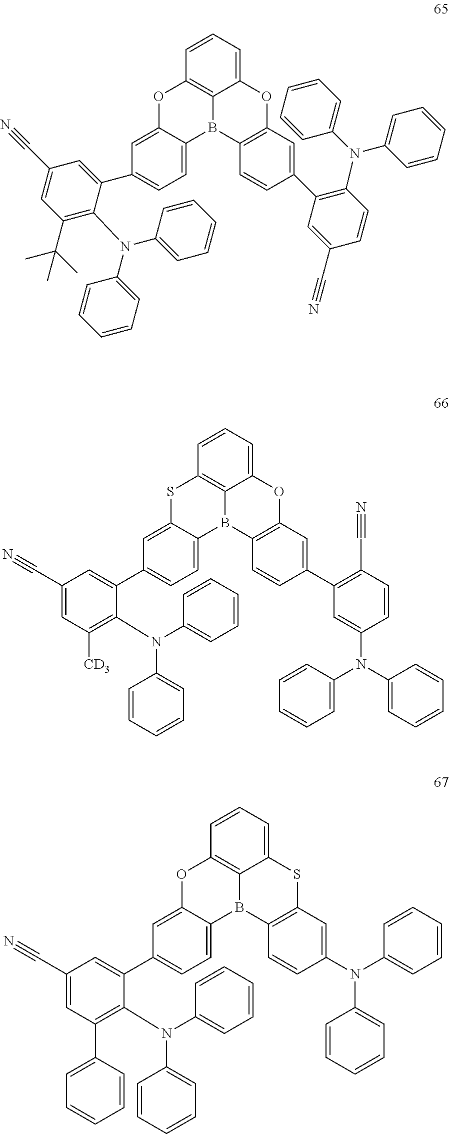 [SMILES: CC(C)(C)c1cc(C#N)cc(-c2ccc3c(c2)Oc2cccc4c2B3c2ccc(-c3cc(C#N)ccc3N(c3ccccc3)c3ccccc3)cc2O4)c1N(c1ccccc1)c1ccccc1 ; [2H]C([2H])([2H])c1cc(C#N)cc(-c2ccc3c(c2)Sc2cccc4c2B3c2ccc(-c3cc(N(c5ccccc5)c5ccccc5)ccc3C#N)cc2O4)c1N(c1ccccc1)c1ccccc1 ; N#Cc1cc(-c2ccccc2)c(N(c2ccccc2)c2ccccc2)c(-c2ccc3c(c2)Oc2cccc4c2B3c2ccc(N(c3ccccc3)c3ccccc3)cc2S4)c1]

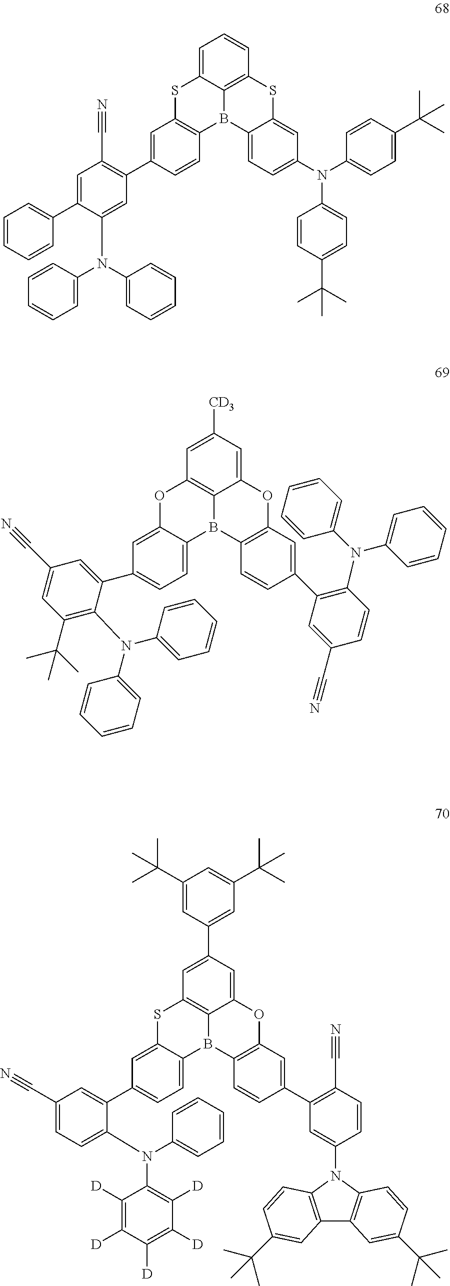 [SMILES: CC(C)(C)c1ccc(N(c2ccc(C(C)(C)C)cc2)c2ccc3c(c2)Sc2cccc4c2B3c2ccc(-c3cc(N(c5ccccc5)c5ccccc5)c(-c5ccccc5)cc3C#N)cc2S4)cc1 ; [2H]C([2H])([2H])c1cc2c3c(c1)Oc1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1O2 ; [2H]c1c([2H])c([2H])c(N(c2ccccc2)c2ccc(C#N)cc2-c2ccc3c(c2)Sc2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2O4)c([2H])c1[2H]]

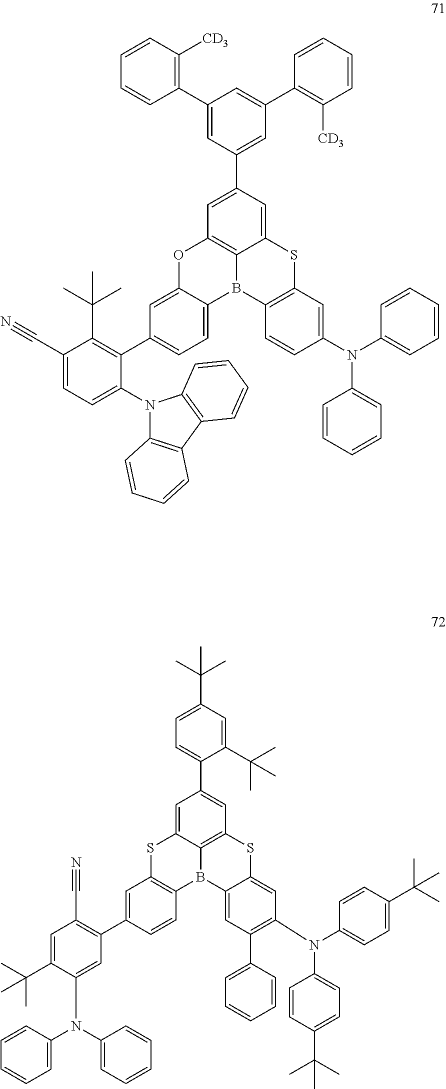 [SMILES: [2H]C([2H])([2H])c1ccccc1-c1cc(-c2cc3c4c(c2)Sc2cc(N(c5ccccc5)c5ccccc5)ccc2B4c2ccc(-c4c(-n5c6ccccc6c6ccccc65)ccc(C#N)c4C(C)(C)C)cc2O3)cc(-c2ccccc2C([2H])([2H])[2H])c1 ; CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4Sc4cc(-c5ccc(C(C)(C)C)cc5C(C)(C)C)cc(c42)S3)cc1]

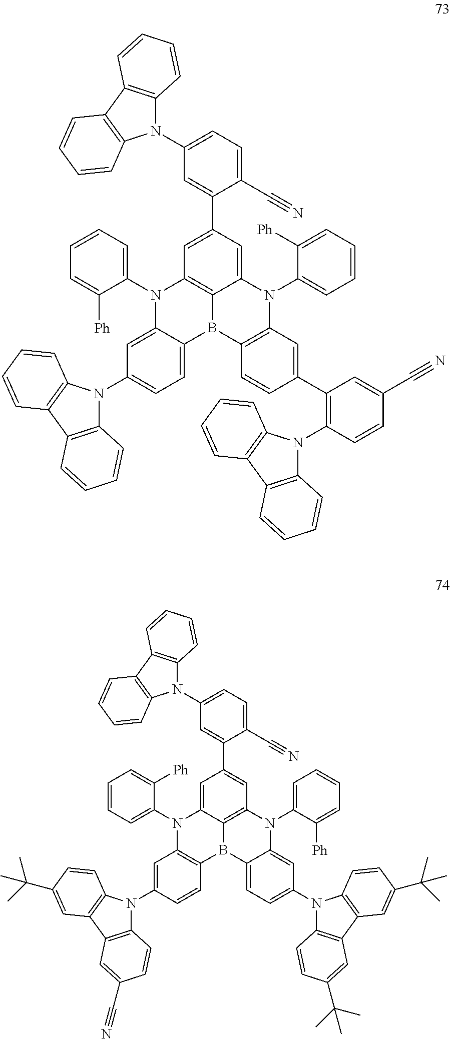 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1]

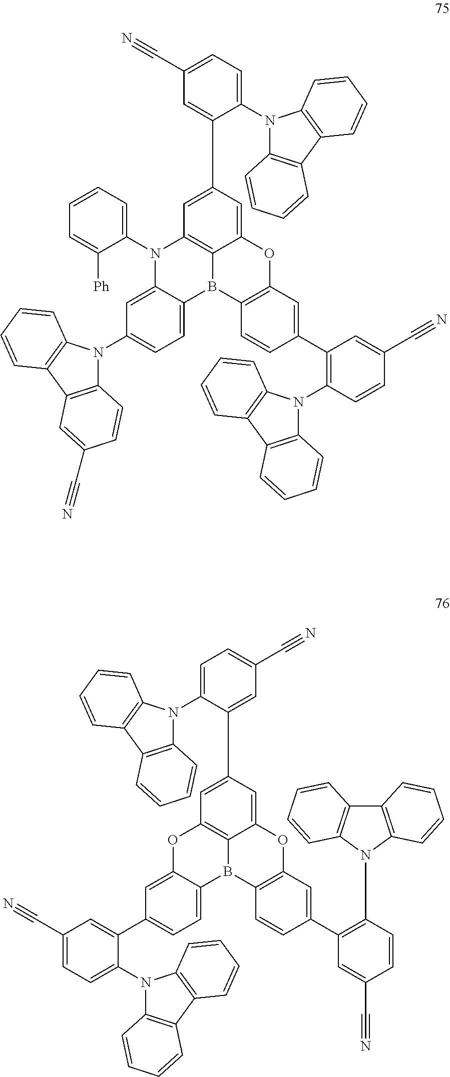 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1]

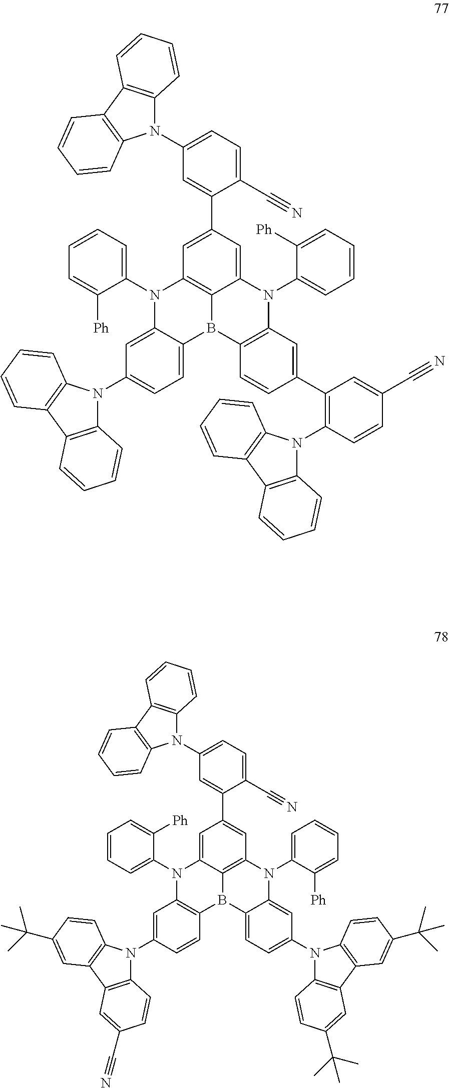 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1]

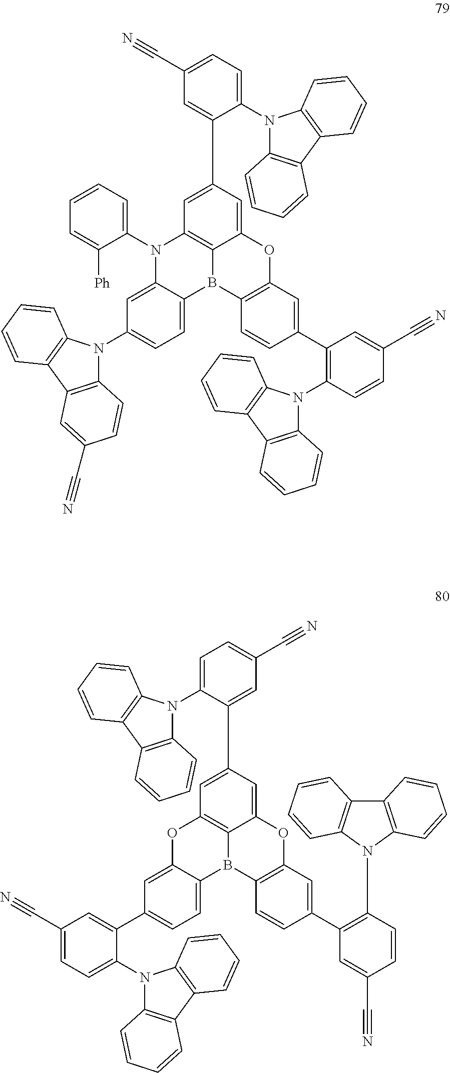 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1]

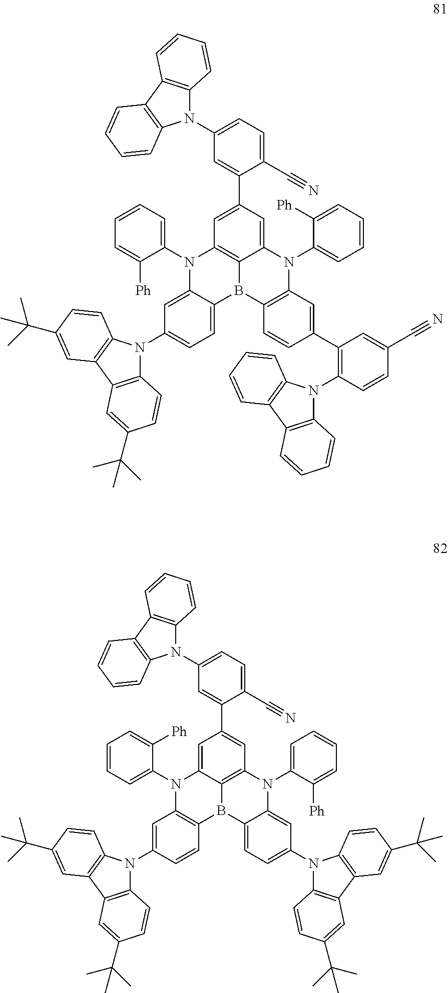 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2-n2c4ccccc4c4ccccc42)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1]

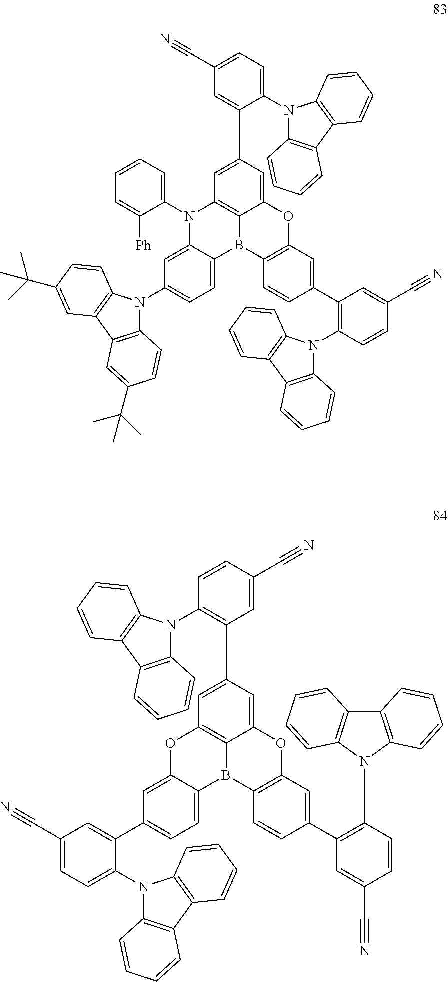 [SMILES: CC(C)(C)c1ccc2c(c1)c1cc(C(C)(C)C)ccc1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2-n2c4ccccc4c4ccccc42)cc1O3 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1]

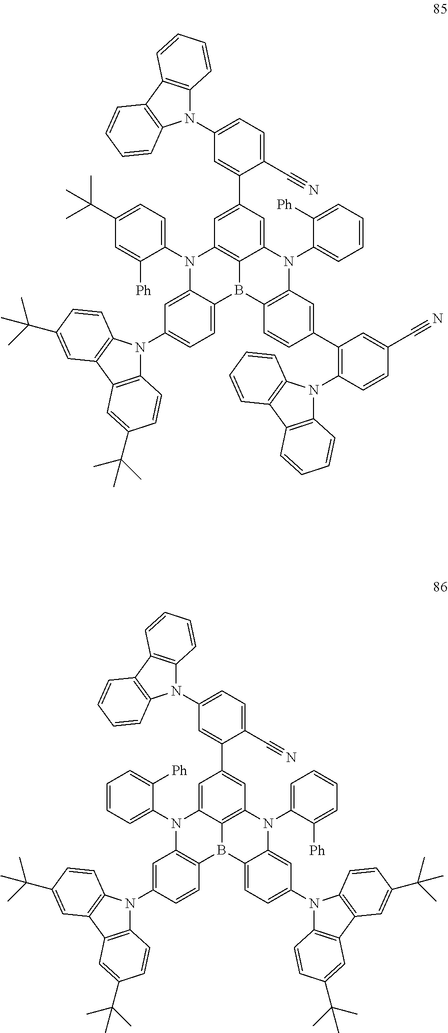 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4N(c4ccccc4-c4ccccc4)c4cc(-c5cc(-n6c7ccccc7c7ccccc76)ccc5C#N)cc2c43)c(-c2ccccc2)c1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1]

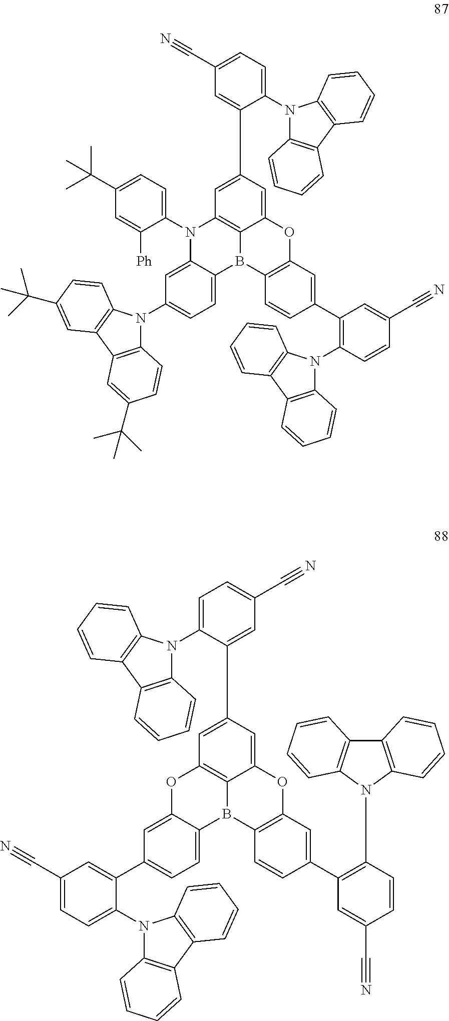 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4Oc4cc(-c5cc(C#N)ccc5-n5c6ccccc6c6ccccc65)cc2c43)c(-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1]

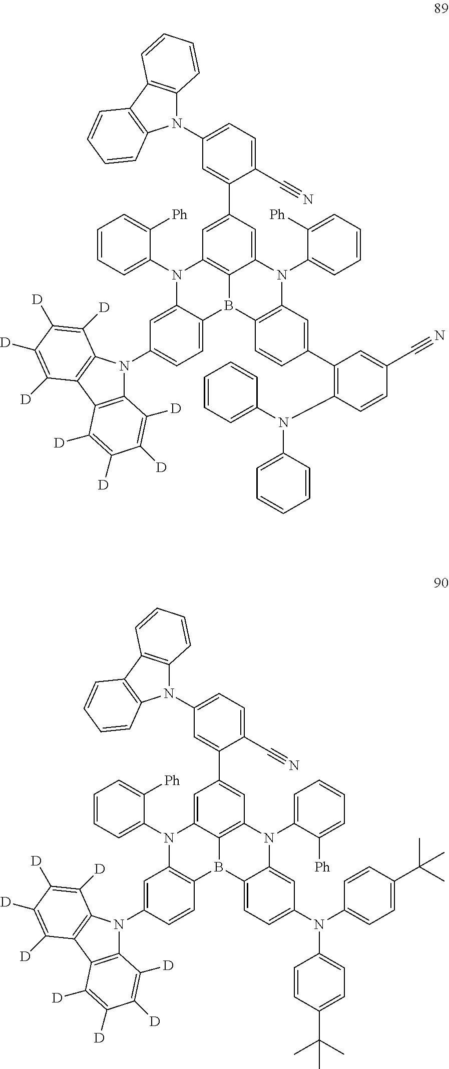 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(N(c2ccc(C(C)(C)C)cc2)c2ccc(C(C)(C)C)cc2)cc1N3c1ccccc1-c1ccccc1]

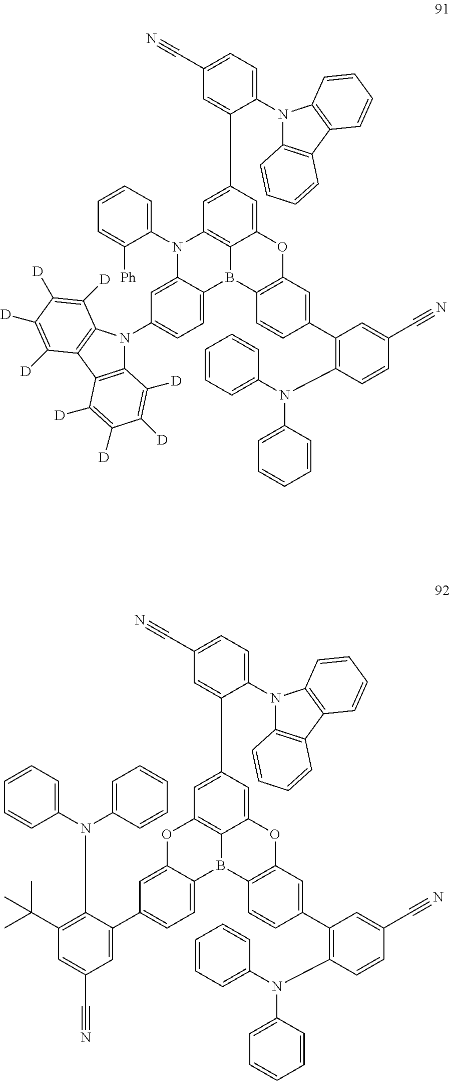 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1]

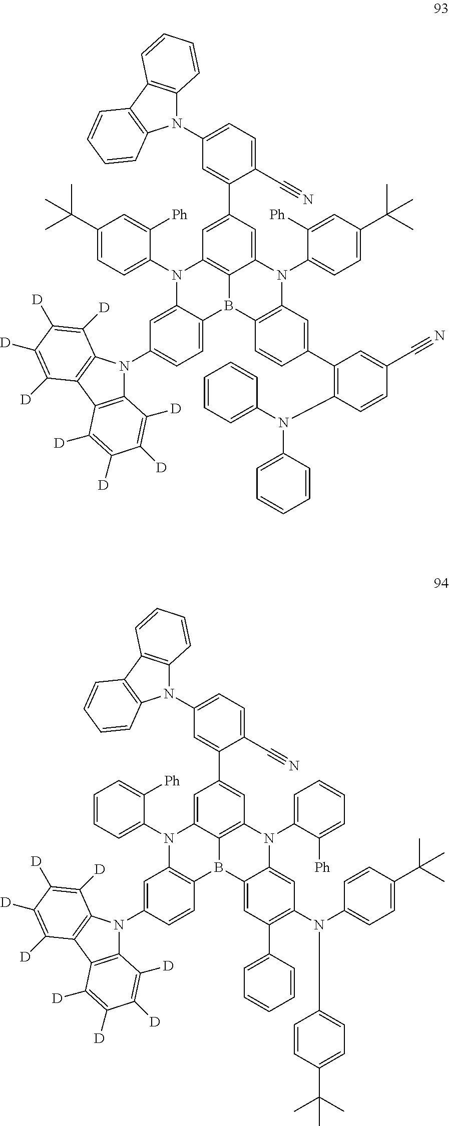 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1cc(-c2ccccc2)c(N(c2ccc(C(C)(C)C)cc2)c2ccc(C(C)(C)C)cc2)cc1N3c1ccccc1-c1ccccc1]

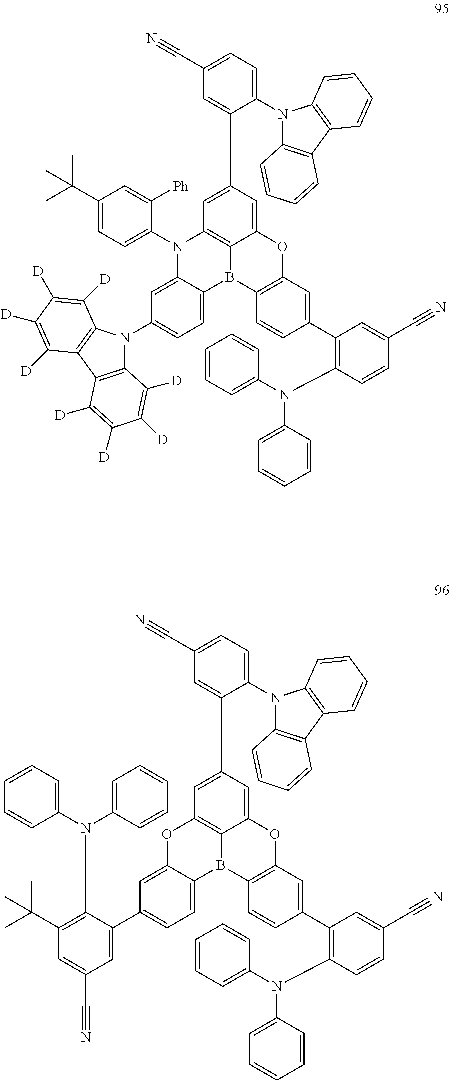 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1]

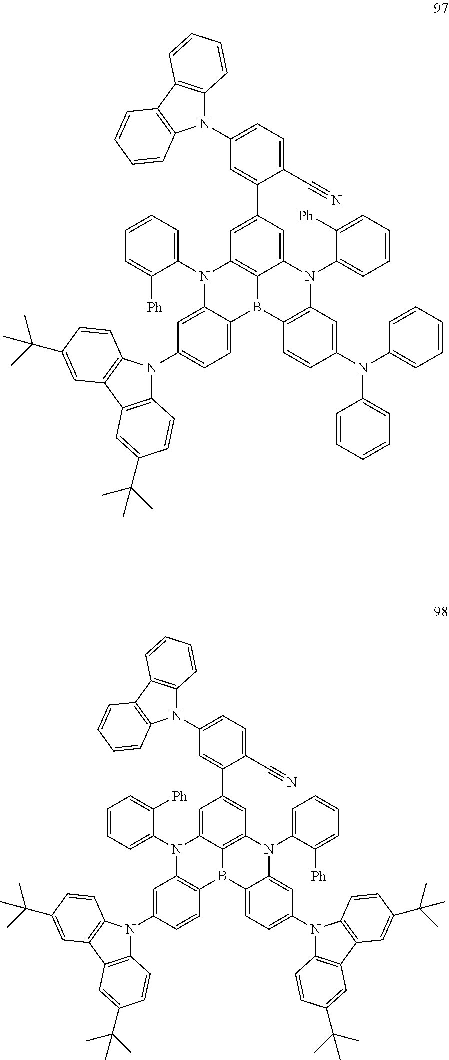 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(N(c2ccccc2)c2ccccc2)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1]

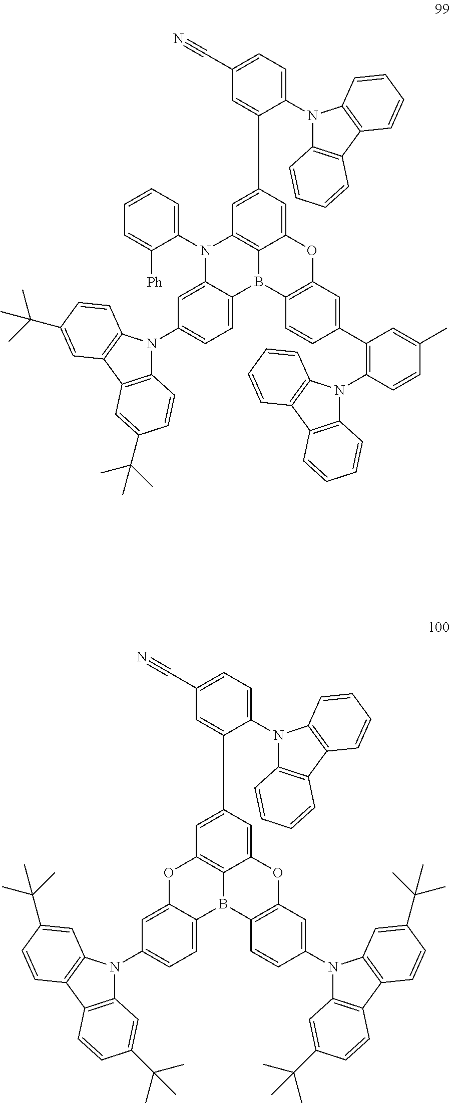

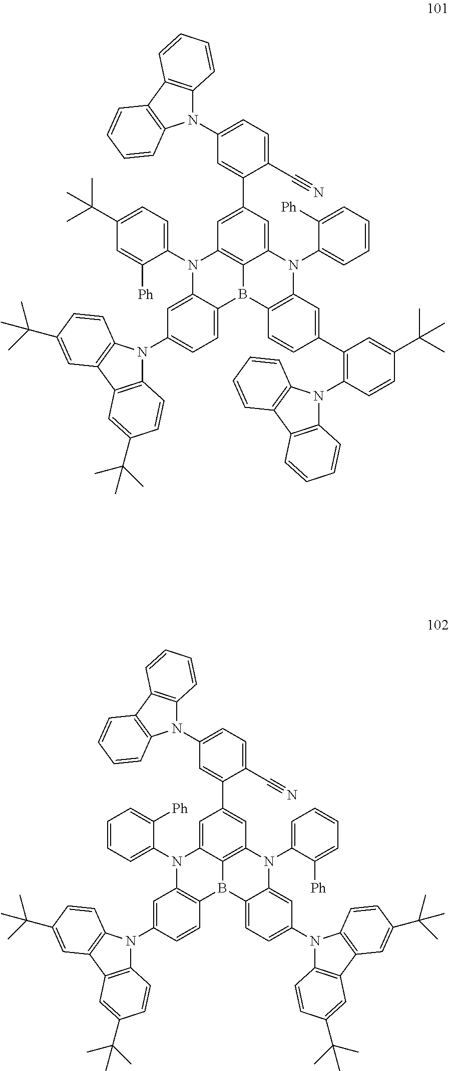

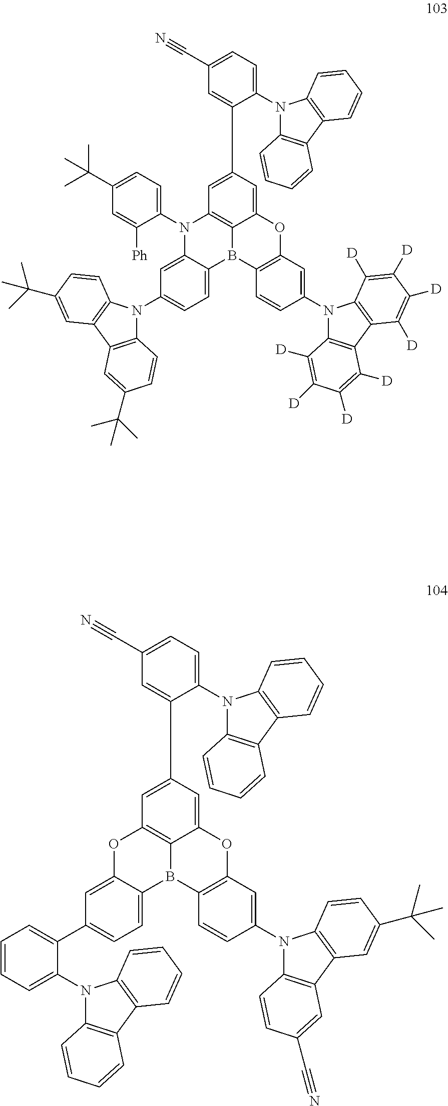 [SMILES: [2H]c1c([2H])c([2H])c2c(c1[2H])c1c([2H])c([2H])c([2H])c([2H])c1n2-c1ccc2c(c1)Oc1cc(-c3cc(C#N)ccc3-n3c4ccccc4c4ccccc43)cc3c1B2c1ccc(-n2c4ccc(C(C)(C)C)cc4c4cc(C(C)(C)C)ccc42)cc1N3c1ccc(C(C)(C)C)cc1-c1ccccc1 ; CC(C)(C)c1ccc2c(c1)c1cc(C#N)ccc1n2-c1ccc2c(c1)Oc1cc(-c3cc(C#N)ccc3-n3c4ccccc4c4ccccc43)cc3c1B2c1ccc(-c2ccccc2-n2c4ccccc4c4ccccc42)cc1O3]

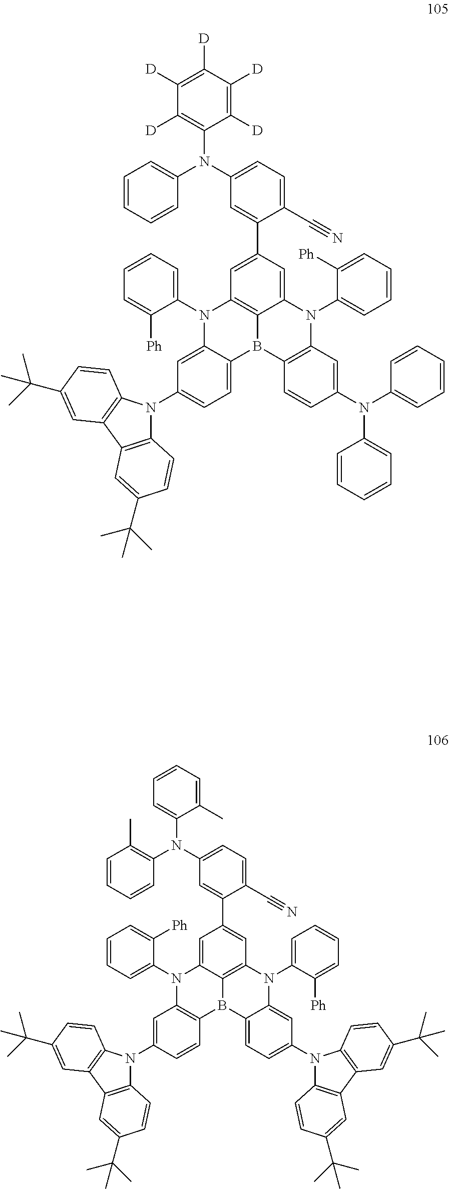 [SMILES: [2H]c1c([2H])c([2H])c(N(c2ccccc2)c2ccc(C#N)c(-c3cc4c5c(c3)N(c3ccccc3-c3ccccc3)c3cc(-n6c7ccc(C(C)(C)C)cc7c7cc(C(C)(C)C)ccc76)ccc3B5c3ccc(N(c5ccccc5)c5ccccc5)cc3N4c3ccccc3-c3ccccc3)c2)c([2H])c1[2H] ; Cc1ccccc1N(c1ccc(C#N)c(-c2cc3c4c(c2)N(c2ccccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccccc2-c2ccccc2)c1)c1ccccc1C]

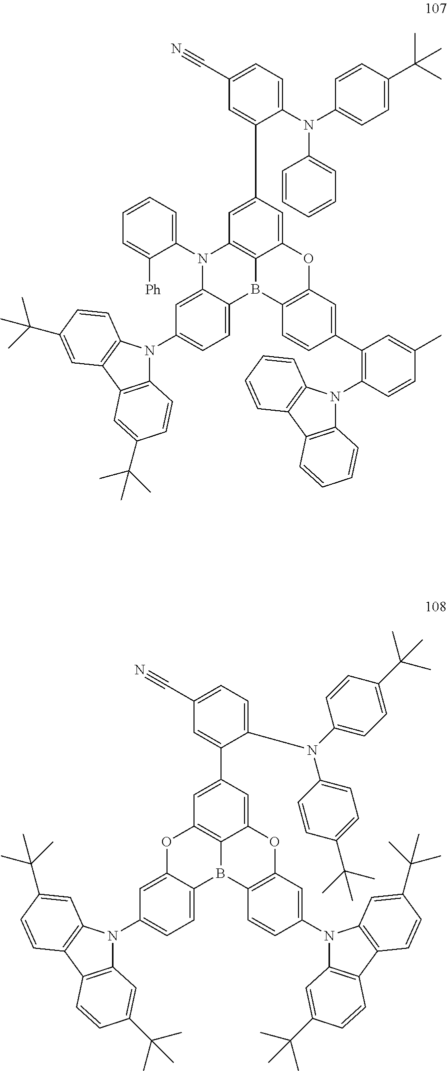

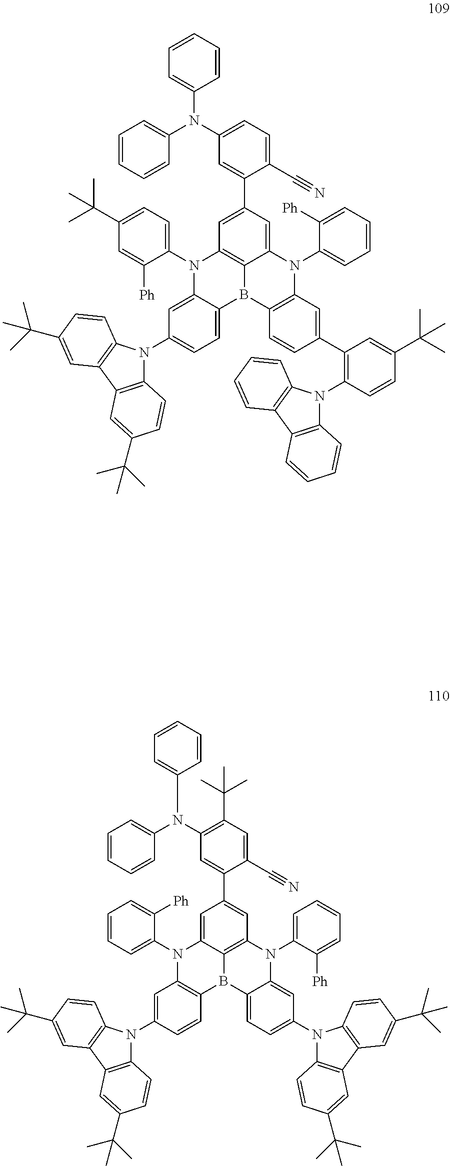

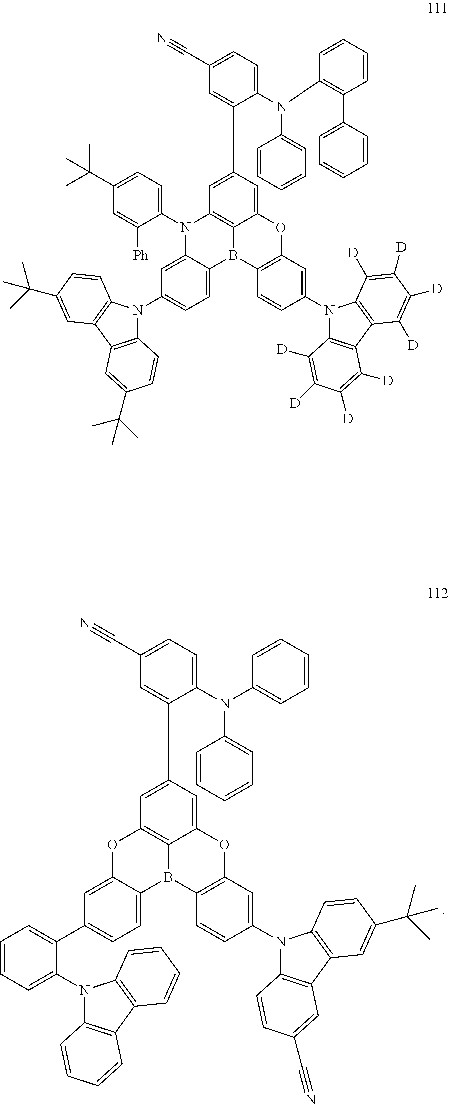 [SMILES: [2H]c1c([2H])c([2H])c2c(c1[2H])c1c([2H])c([2H])c([2H])c([2H])c1n2-c1ccc2c(c1)Oc1cc(-c3cc(C#N)ccc3N(c3ccccc3)c3ccccc3-c3ccccc3)cc3c1B2c1ccc(-n2c4ccc(C(C)(C)C)cc4c4cc(C(C)(C)C)ccc42)cc1N3c1ccc(C(C)(C)C)cc1-c1ccccc1 ; CC(C)(C)c1ccc2c(c1)c1cc(C#N)ccc1n2-c1ccc2c(c1)Oc1cc(-c3cc(C#N)ccc3N(c3ccccc3)c3ccccc3)cc3c1B2c1ccc(-c2ccccc2-n2c4ccccc4c4ccccc42)cc1O3]

The polycyclic compound of an embodiment may include a hetero substituent including a core part of the fused ring containing a boron atom as a ring-forming atom and a heteroatom substituted at the para-position with the boron atom of the core part, and a benzonitrile group between the hetero substituent and the core part, and may control the distortion between bonds in the molecule, thereby exhibiting high stability. In some embodiments, by the effect of the introduced hetero substituent, the polycyclic compound of an embodiment may have an increase in the delayed luminescence, thereby exhibiting improved luminous efficiency characteristics.

In some embodiments, the polycyclic compound of an embodiment may be utilized as a material for the light emitting element, thereby improving luminous efficiency and service life characteristics of the light emitting element.

In some embodiments, the polycyclic compound of an embodiment may be included in the emission layer EML. The polycyclic compound of an embodiment may be included as a dopant material in the emission layer EML. The polycyclic compound of an embodiment may be a thermally activated delayed fluorescence material. The polycyclic compound of an embodiment may be utilized as a thermally activated delayed fluorescence dopant. For example, in the light emitting element ED of an embodiment, the emission layer EML may include, as a thermally activated delayed fluorescence dopant, at least one selected from among the polycyclic compounds represented by Compound Group 1 as described above. However, embodiments of the present disclosure are not limited to the utilization of these polycyclic compounds.

The polycyclic compound of an embodiment may emit blue light. However, the embodiment of the present disclosure is not limited thereto.

In an embodiment, the emission layer EML may include the first compound represented by Formula 1, and at least one of the second compound represented by Formula HT-1, the third compound represented by Formula ET-1, or the fourth compound represented by Formula M-b:

For example, the second compound in an embodiment may be utilized as a hole transport host material of the emission layer EML.

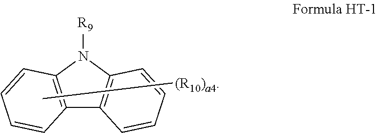

In Formula HT-1, a4 may be an integer from 0 to 8. When a4 is an integer of 2 or more, a plurality of R₁₀s may be the same as each other or at least one may be different from the others. R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₉ may be a substituted phenyl group, an unsubstituted dibenzofuran group, or a substituted fluorenyl group. R₁₀ may be a substituted or unsubstituted carbazole group.

The second compound may be represented by any one selected from among the compounds in Compound Group 2. The light emitting element ED of an embodiment may include any one selected from among the compounds of Compound Group 2: In Compound Group 2, “D” is a deuterium atom.

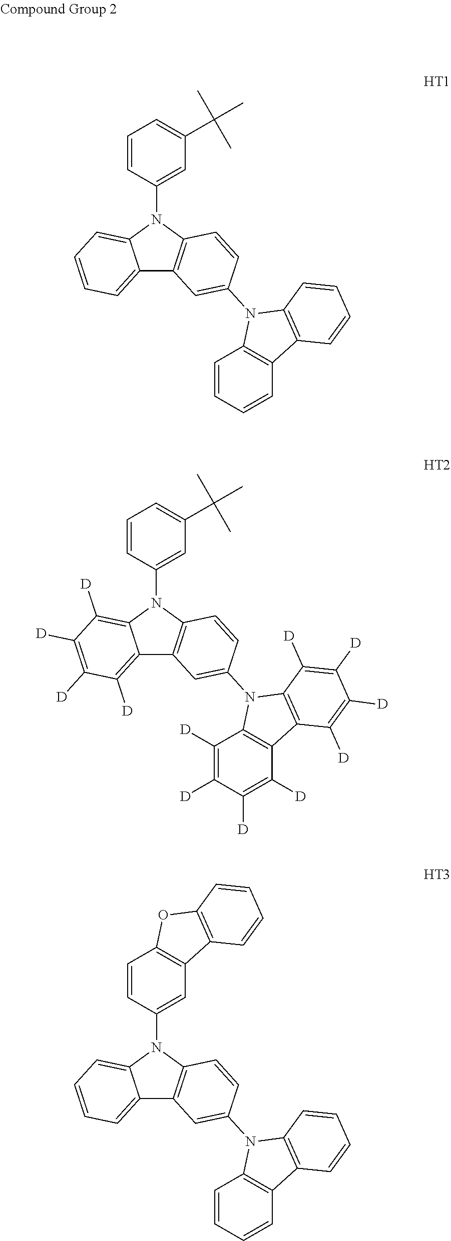 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

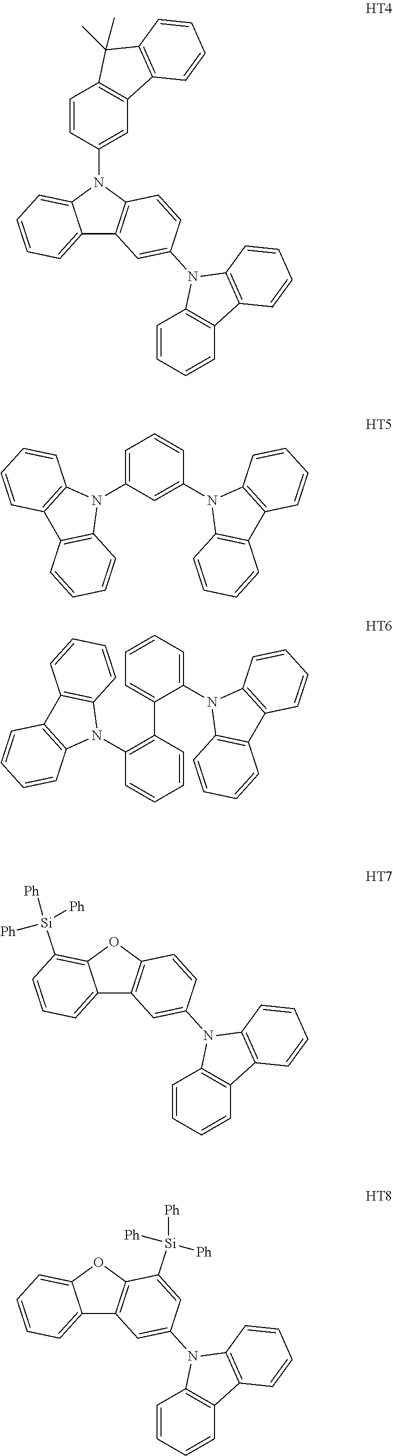

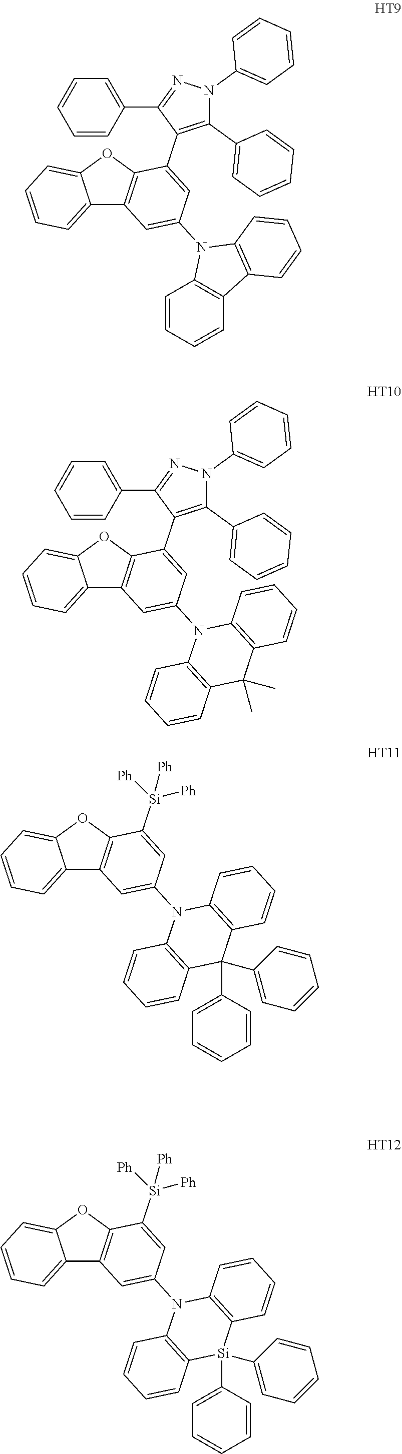

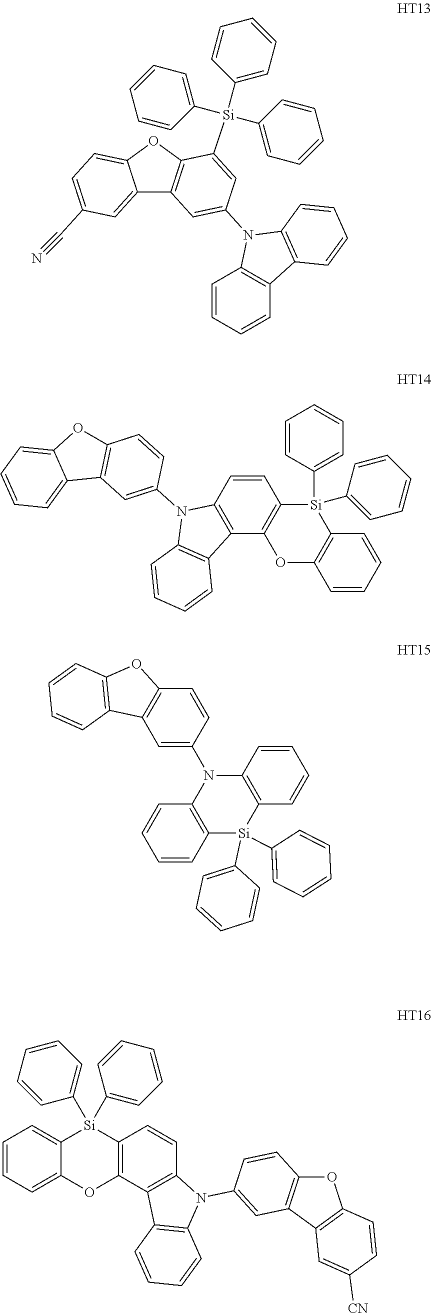 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

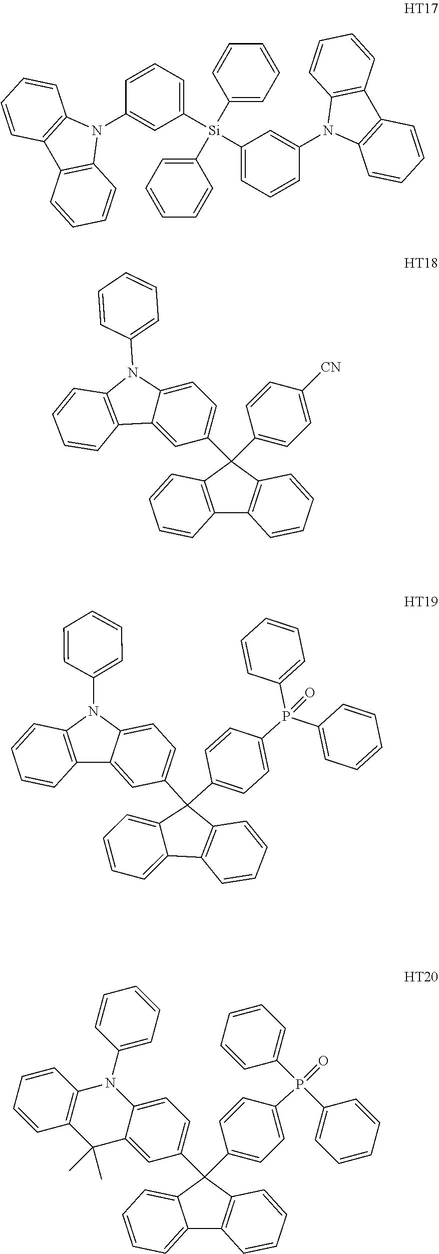 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

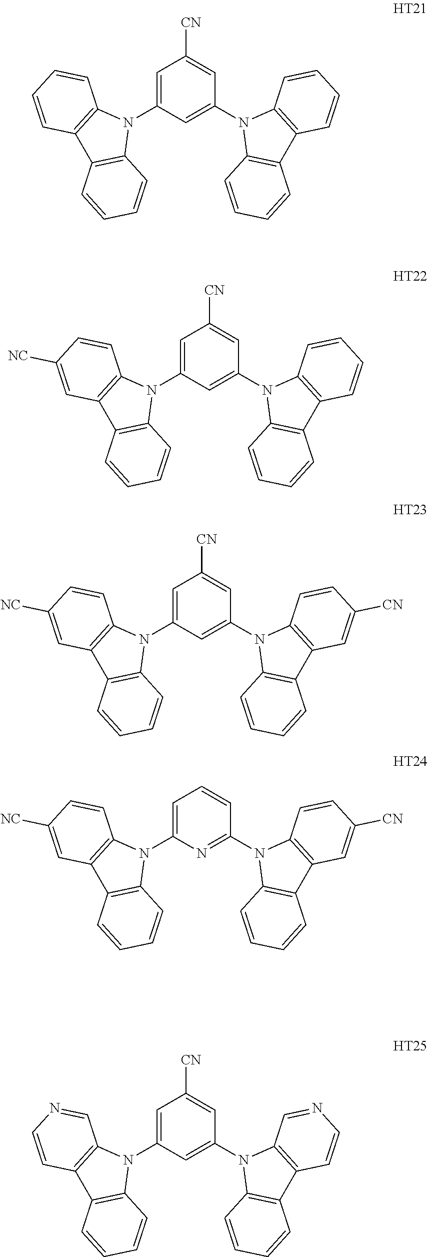 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

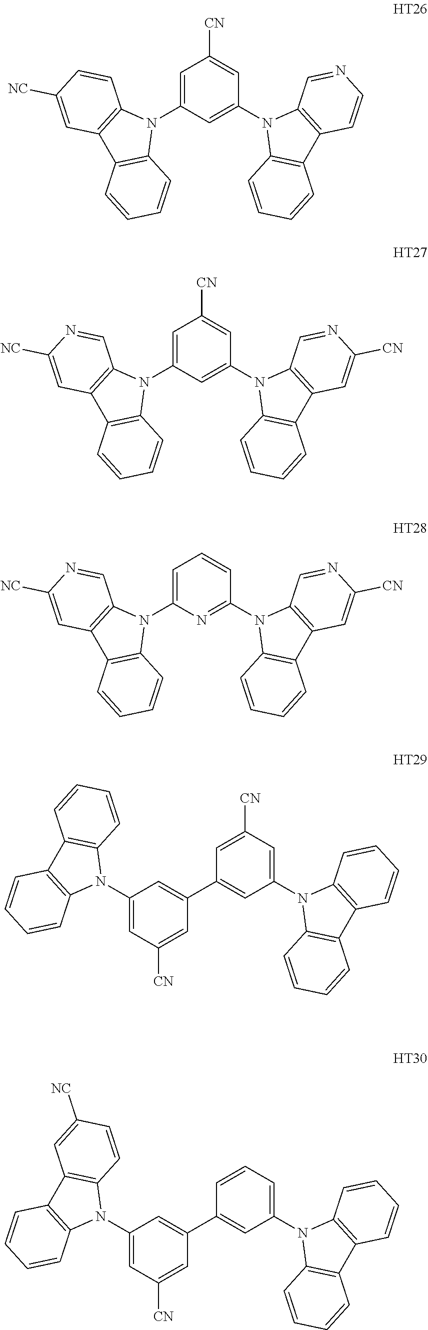 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

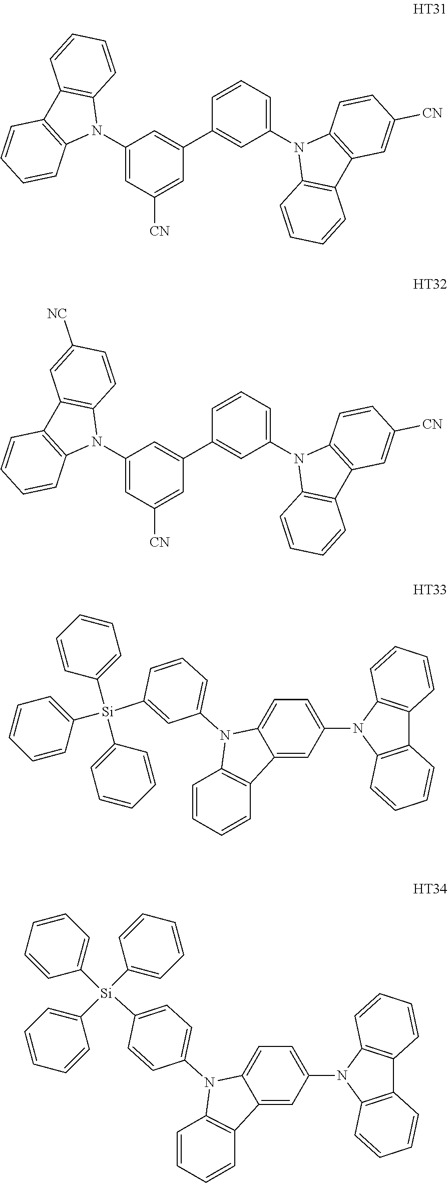 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

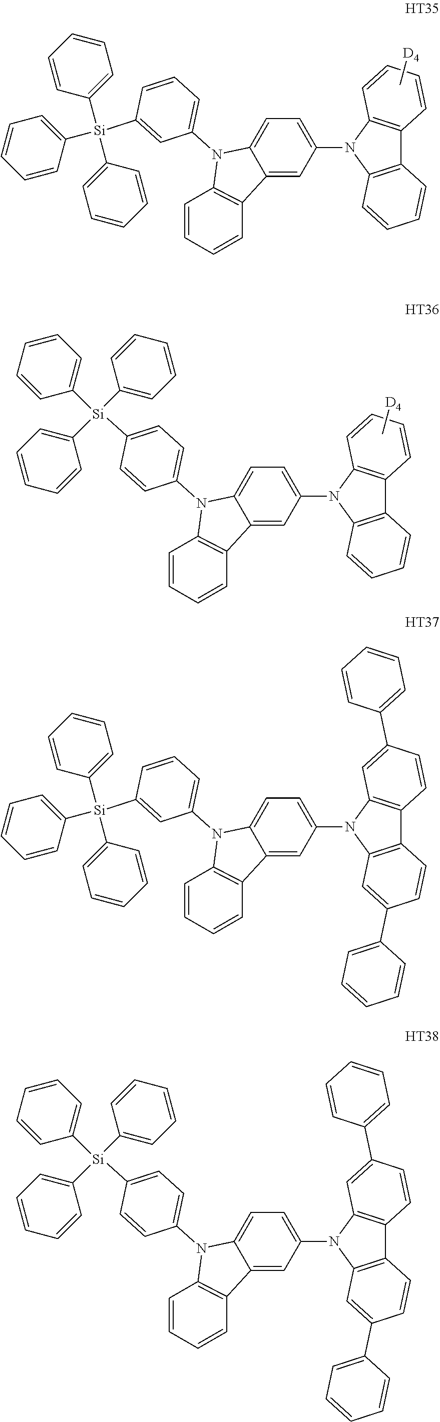

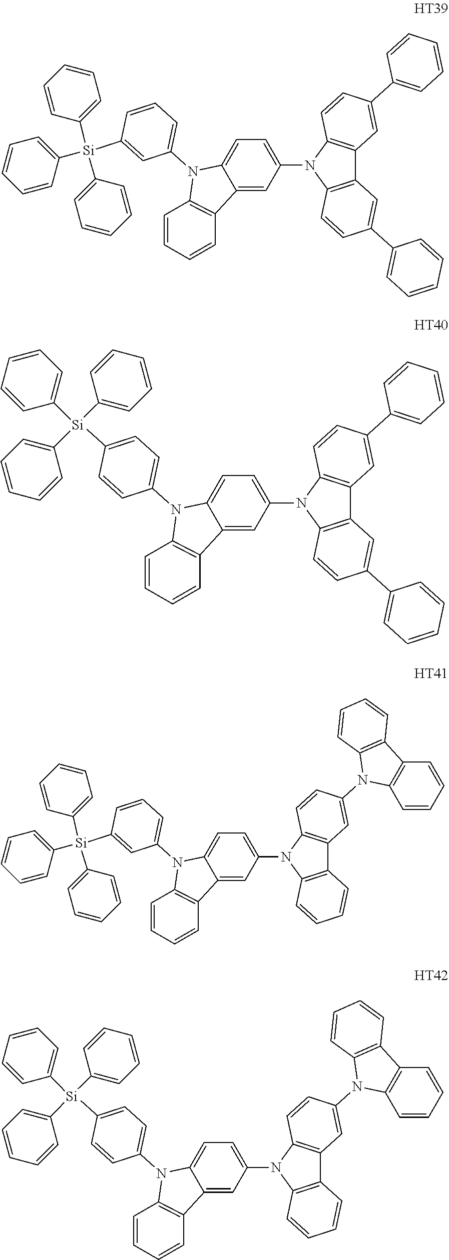 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

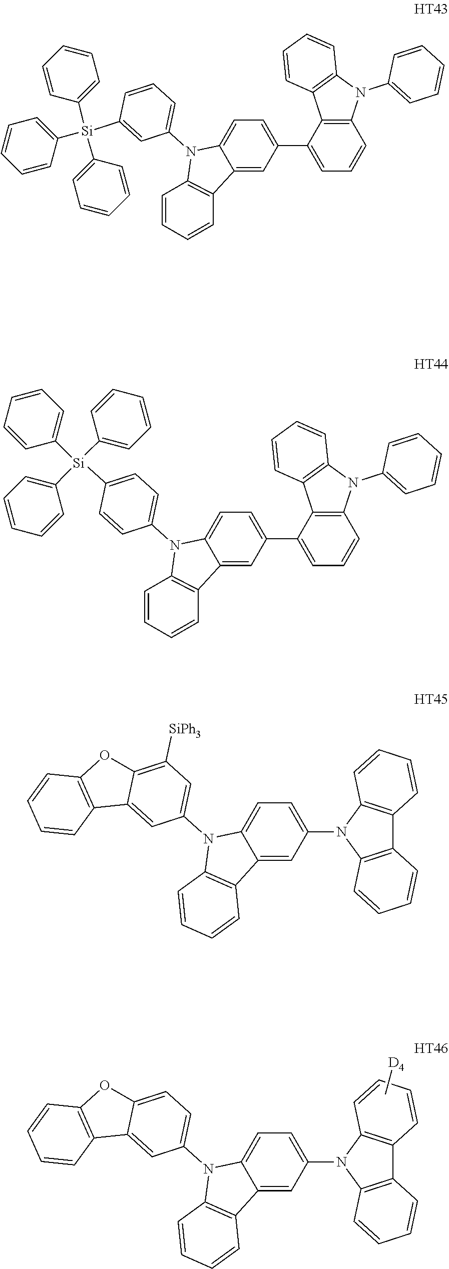

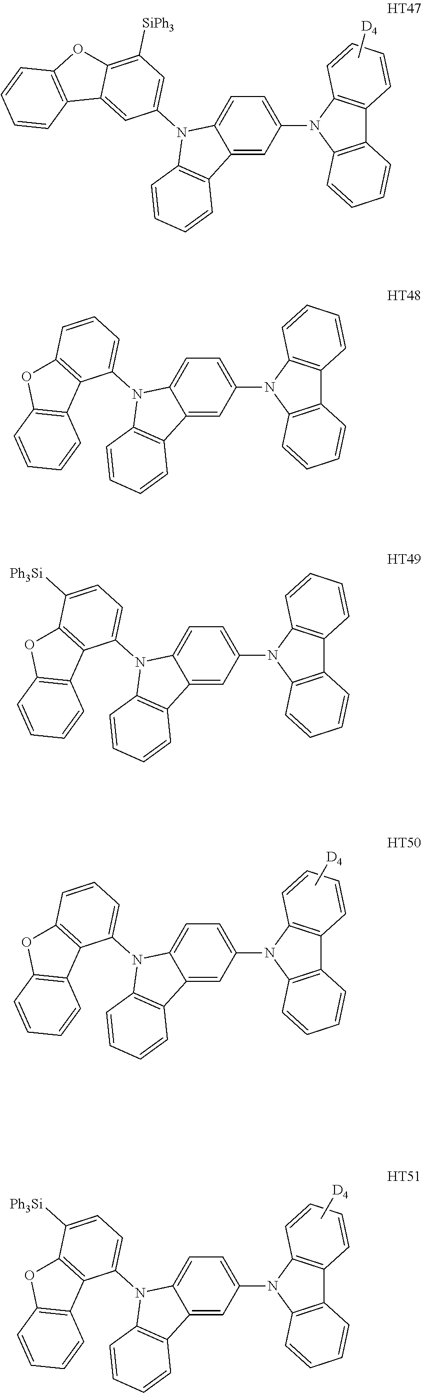

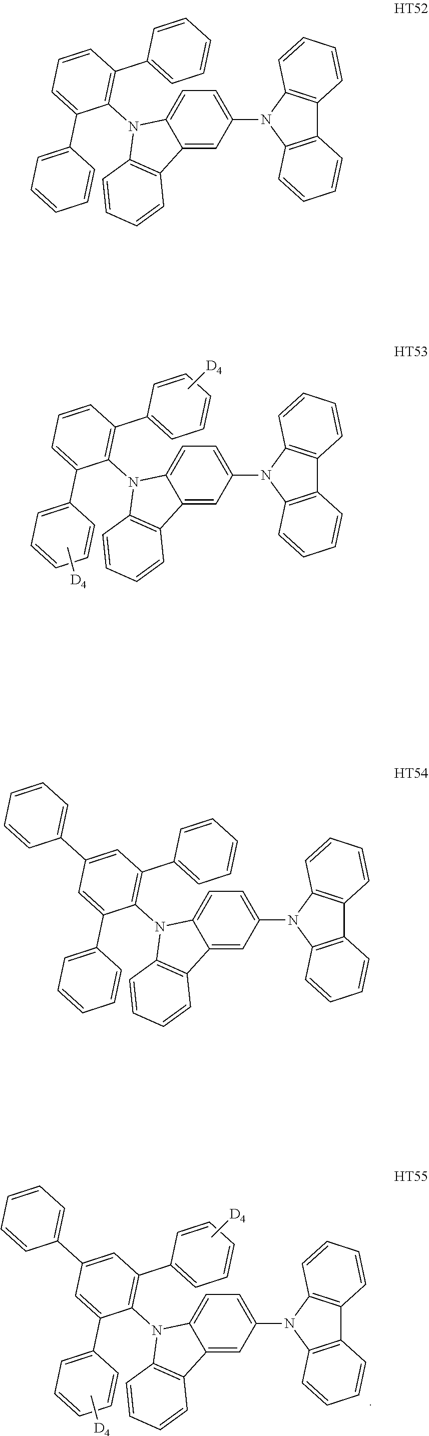

In an embodiment, the emission layer EML may include the third compound represented by Formula ET-1. For example, the third compound may be utilized as an electron transport host material of the emission layer EML.

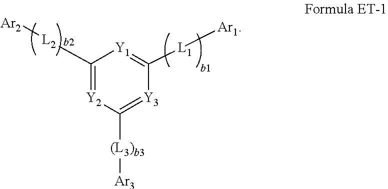

In Formula ET-1, at least one selected from among Y₁ to Y₃ may be N, and the rest may be CRₐ, and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer from 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group, or a substituted or unsubstituted carbazole group.

The third compound may be represented by any one selected from among the compounds in Compound Group 3. The light emitting element ED of an embodiment may include any one selected from among the compounds of Compound Group 3: In Compound Group 3, “D” is a deuterium atom.

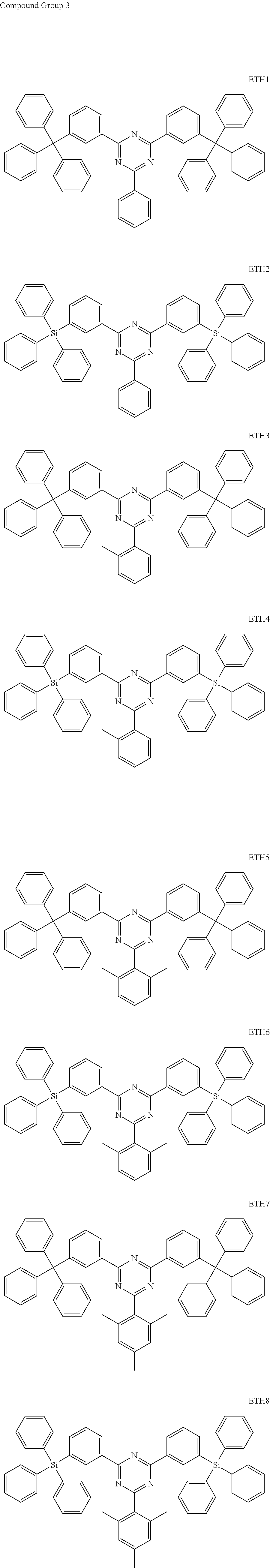

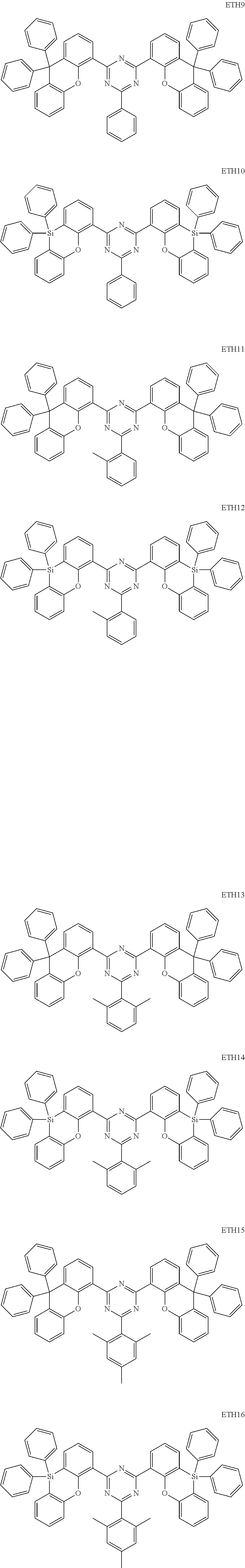

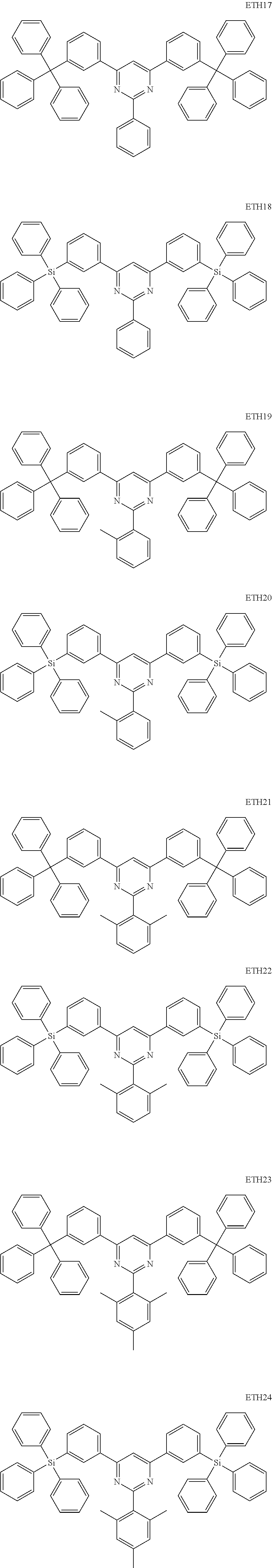

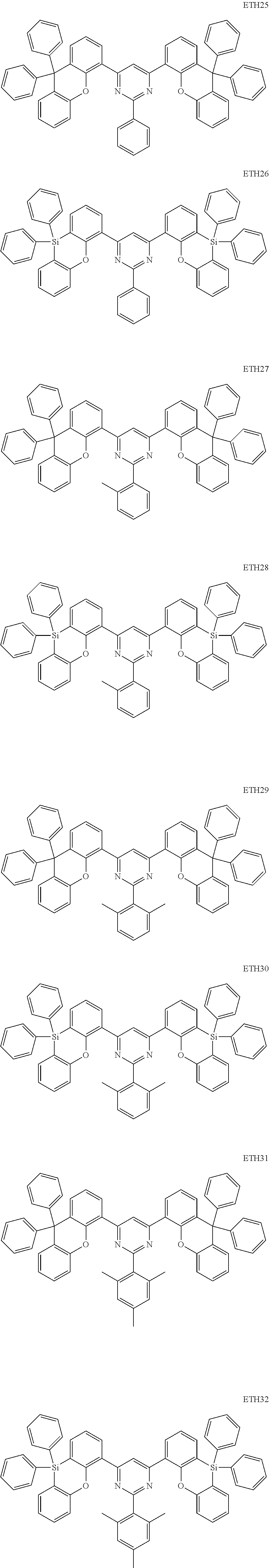

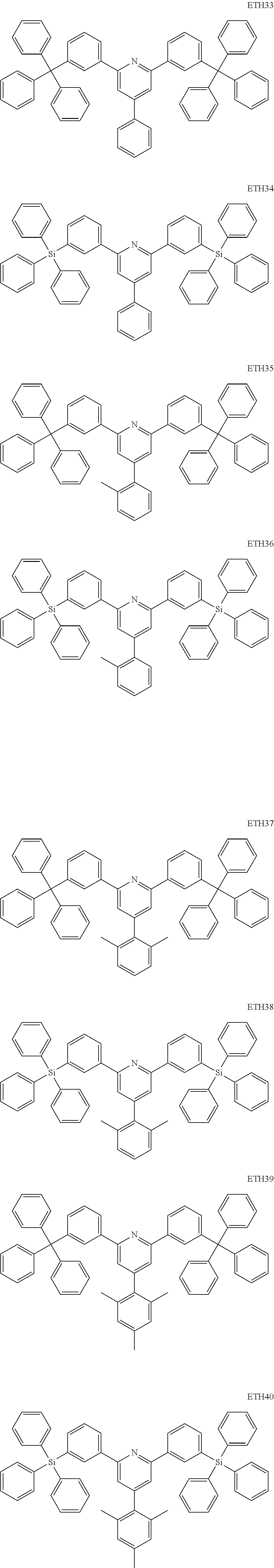

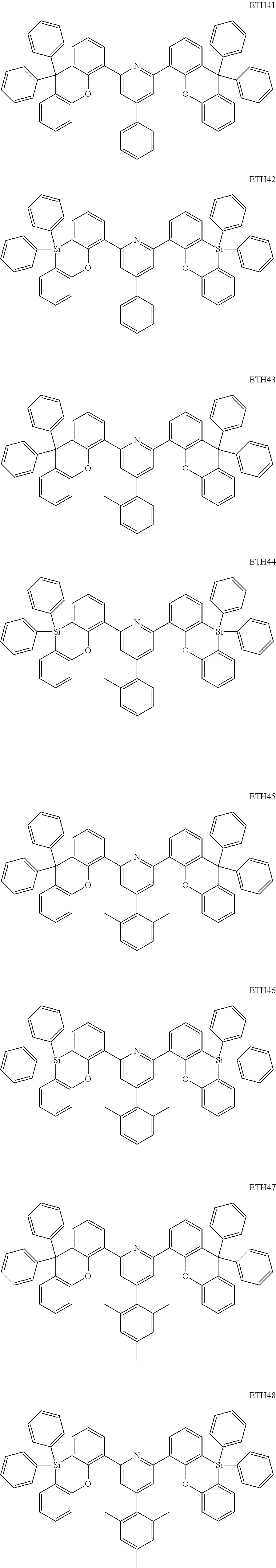

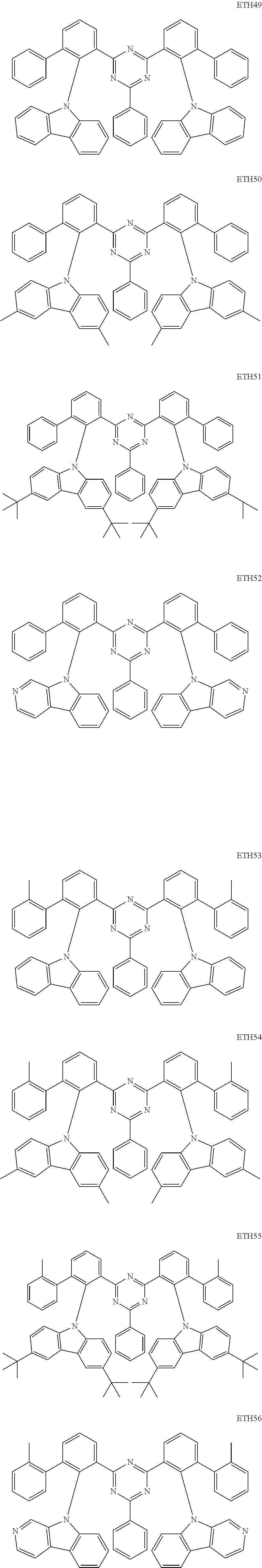

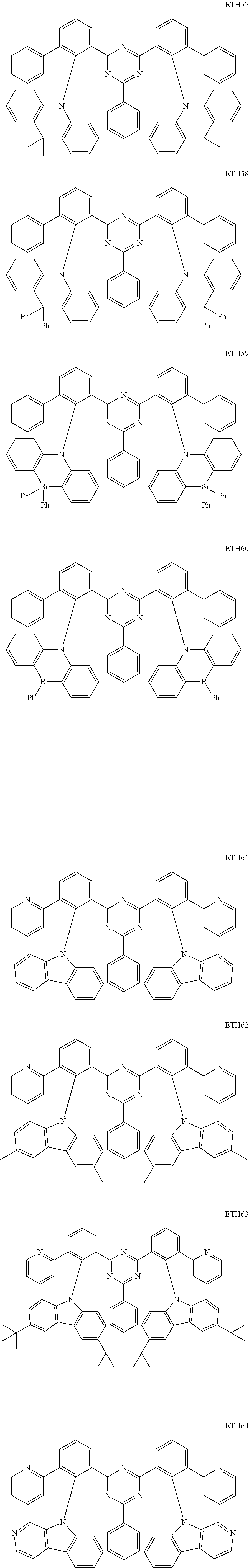

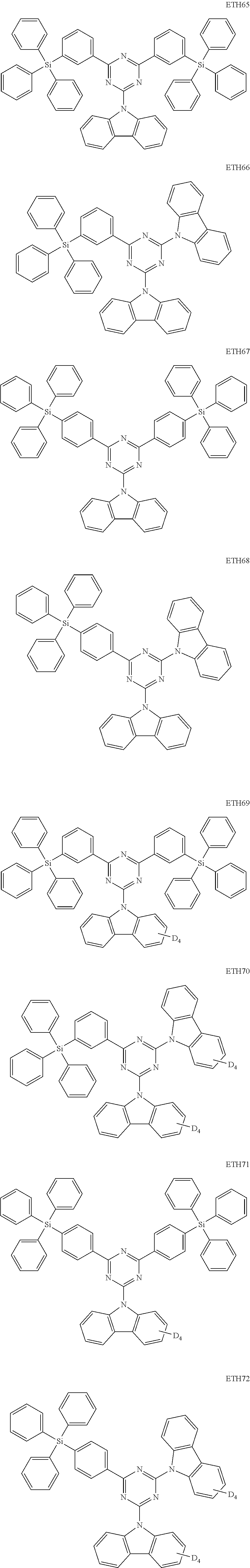

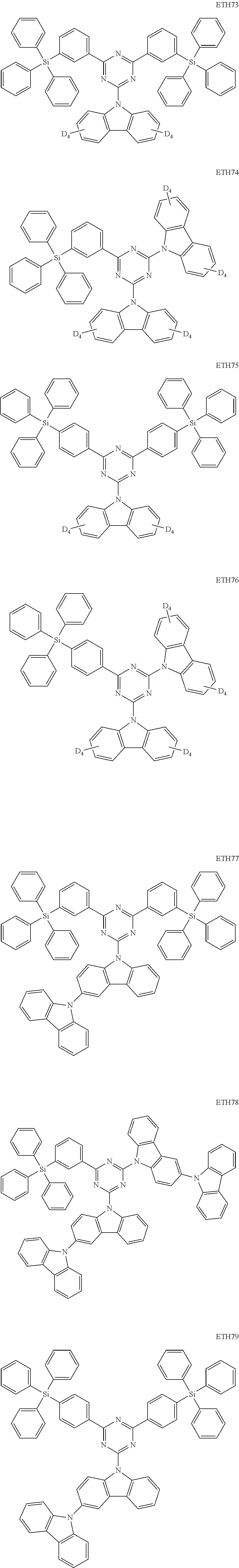

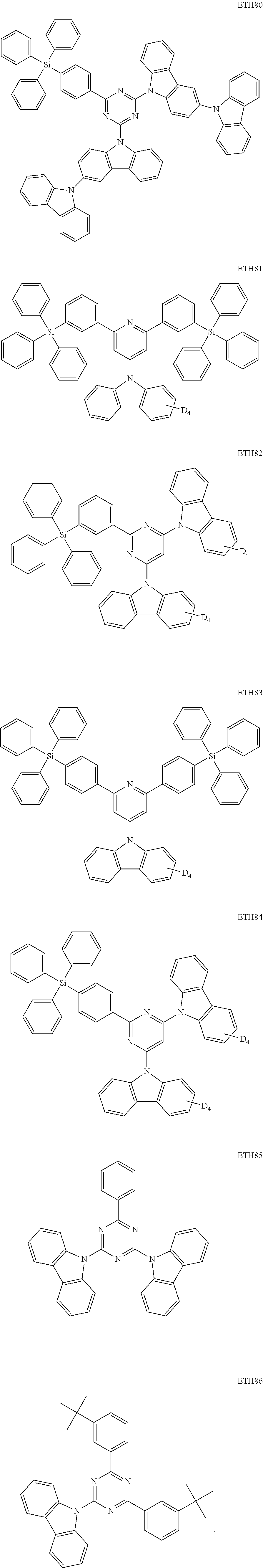

For example, the emission layer EML may include the second compound and the third compound, and the second compound and the third compound may form an exciplex. In the emission layer EML, an exciplex may be formed by the hole transport host and the electron transport host. In this embodiment, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include the fourth compound which is represented by Formula M-b. For example, the fourth compound may be utilized as a phosphorescent sensitizer of the emission layer EML. The energy may be transferred from the fourth compound to the first compound, thereby emitting light.

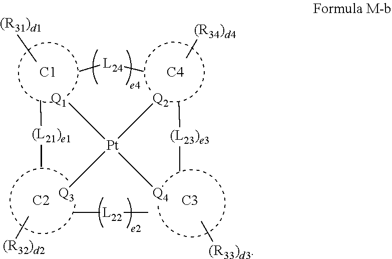

In Formula M-b, Q₁ to Q₄ may each independently be C or N, and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

e1 to e4 may each independently be 0 or 1, and L₂₁ to L₂₄ may each independently be a direct linkage,

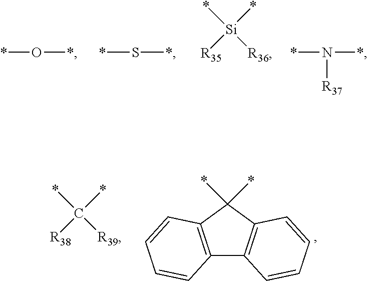

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

d1 to d4 may each independently be an integer from 0 to 4. When d1 is an integer of 2 or more, a plurality of R₃₁s may be the same as each other or at least one may be different from the others. When d2 is an integer of 2 or more, a plurality of R₃₂s may be the same as each other or at least one may be different from the others. When d3 is an integer of 2 or more, a plurality of R₃₃s may be the same as each other or at least one may be different from the others. When d4 is an integer of 2 or more, a plurality of R₃₄s may be the same as each other or at least one may be different from the others.

R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or be bonded to an adjacent group to form a ring.

The fourth compound may be represented by any one selected from among the compounds in Compound Group 4. The light emitting element ED of an embodiment may include any one selected from among the compounds of Compound Group 4:

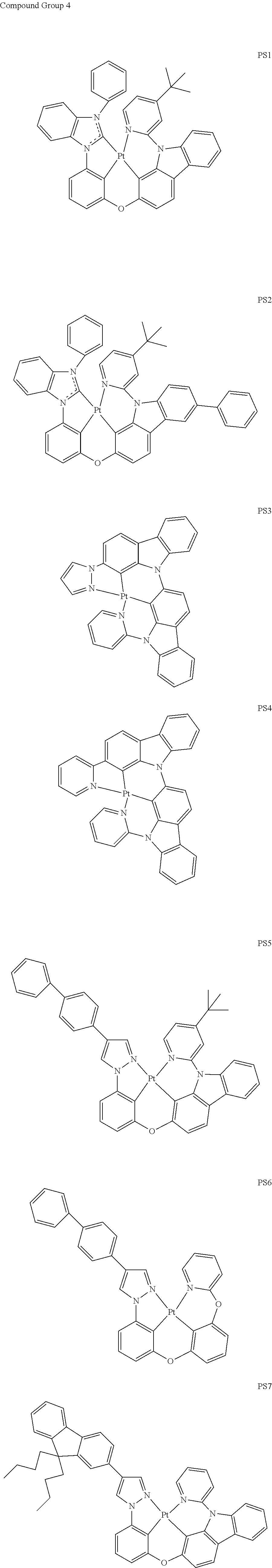

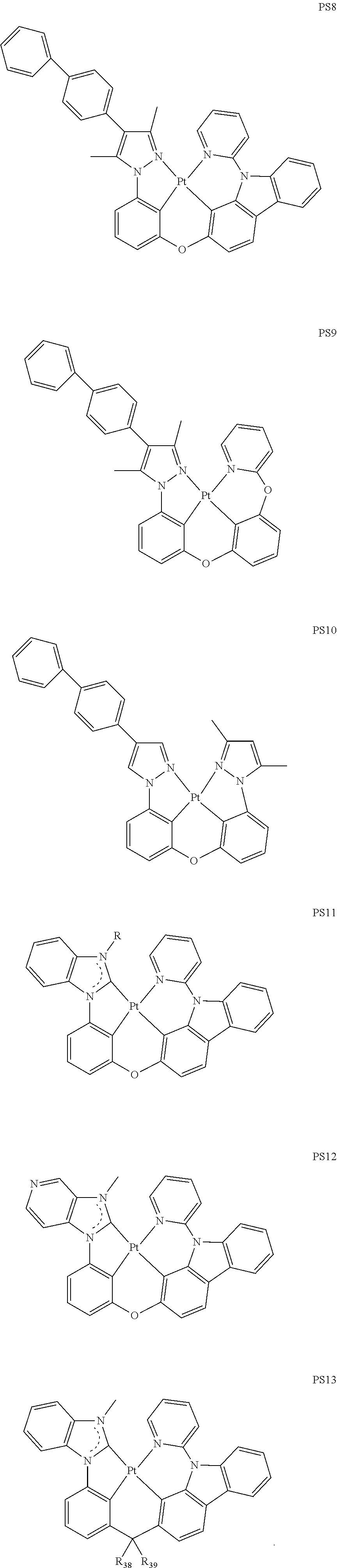

In the compounds, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML of an embodiment may include the first compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In some embodiments, the fourth compound may be referred to as a phosphorescent sensitizer. The fourth compound may emit phosphorescence or may transfer energy to the first compound as an auxiliary dopant. However, the presented functions of the compound are merely examples, and the embodiment of the present disclosure is not limited thereto.

In some embodiments, the emission layer EML may further include a generally utilized/generally available material for the emission layer in addition to the first to fourth compounds presented above. In the light emitting element ED of an embodiment, the emission layer EML may further include an anthracene derivative, a pyrene derivative, a fluoranthene derivative, a chrysene derivative, a dehydrobenzanthracene derivative, a triphenylene derivative, and/or the like. For example, the emission layer EML may further include an anthracene derivative or a pyrene derivative.

In each light emitting element ED of embodiments illustrated in FIGS. 3 to 6, the emission layer EML may include a compound represented by Formula E-1. The compound represented by Formula E-1 may be utilized as a fluorescent host material.

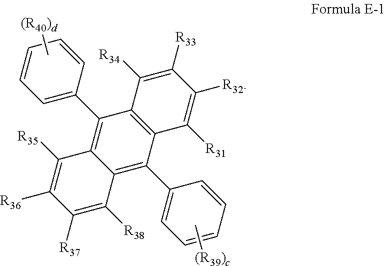

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5.

Formula E-1 may be represented by any one selected from among Compound E1 to Compound E19:

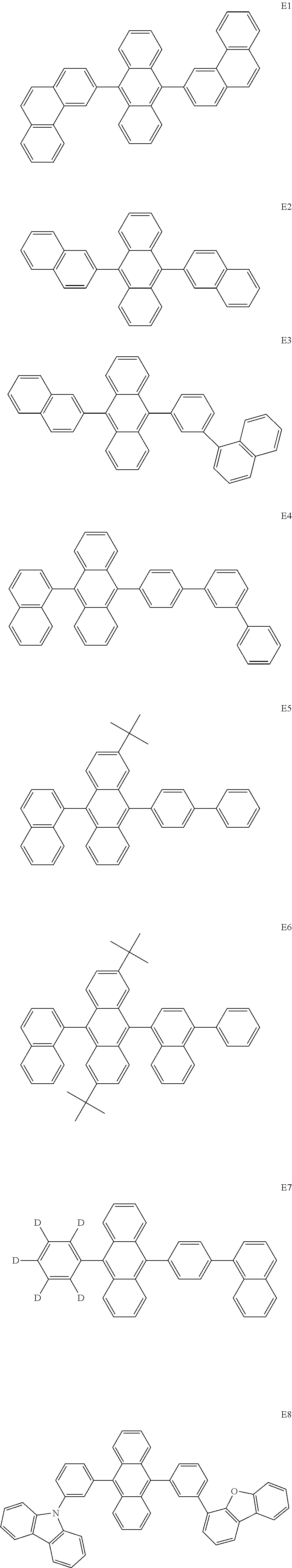

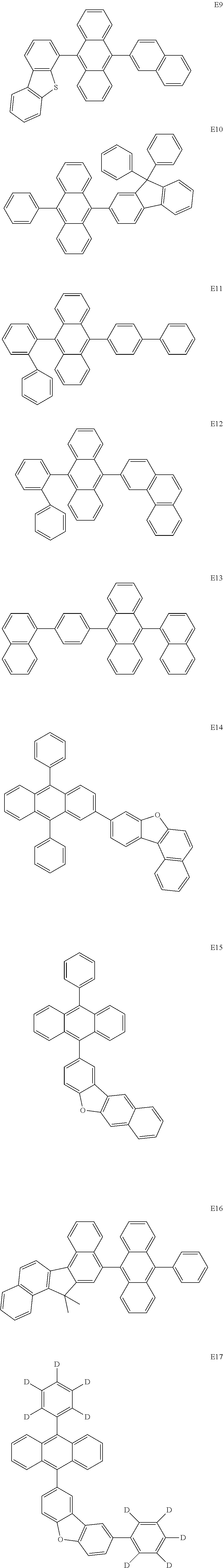

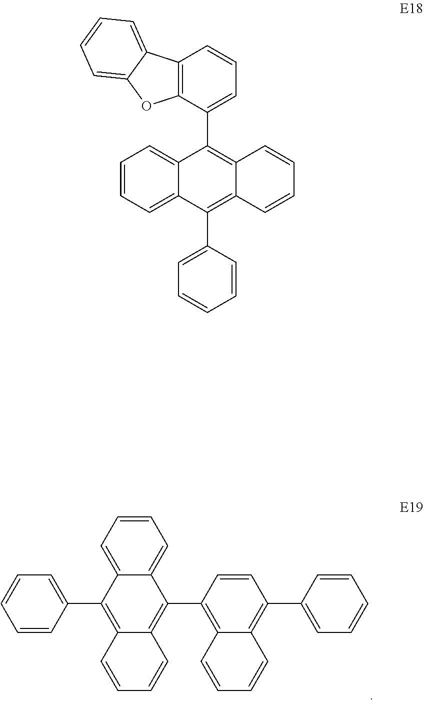

In an embodiment, the emission layer EML may include a compound represented by Formula E-2a or Formula E-2b. The compound represented by Formula E-2a or Formula E-2b may be utilized as a phosphorescent host material.

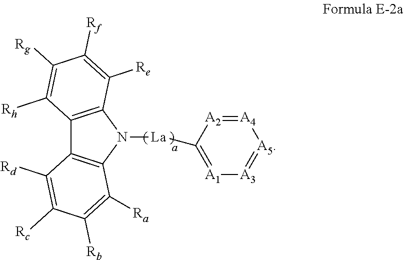

In Formula E-2a, a may be an integer from 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of Las may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or be bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest may be CRᵢ.

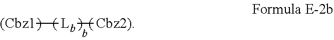

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer from 0 to 10, and when b is an integer of 2 or more, a plurality of L_{b}s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are merely examples, and the compound represented by Formula E-2a or Formula E-2b is not limited to those represented in Compound Group E-2.

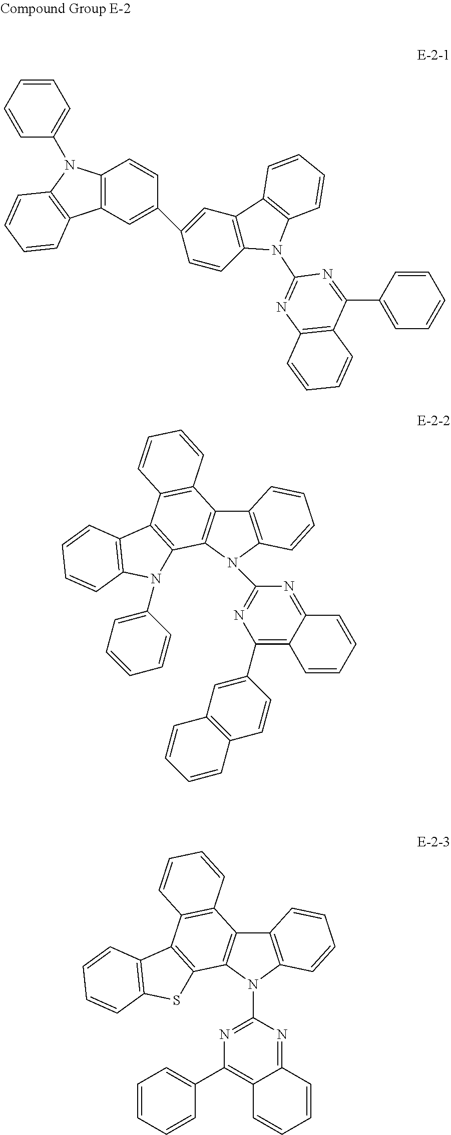 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

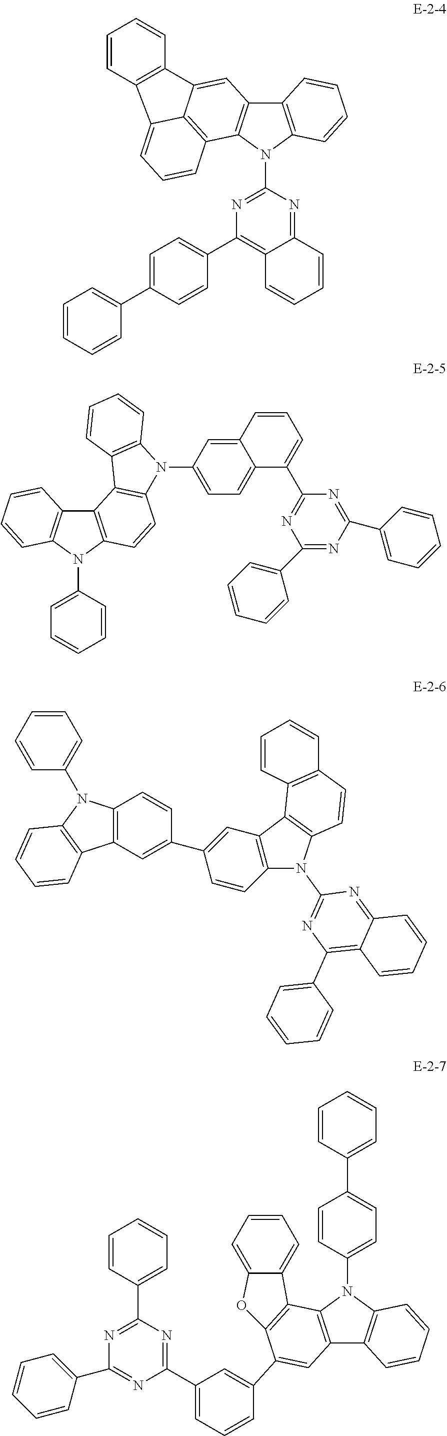 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

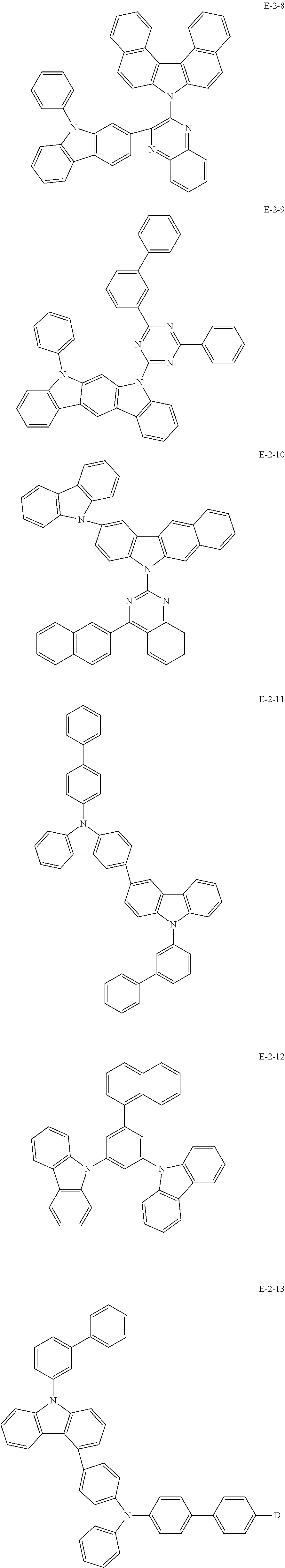

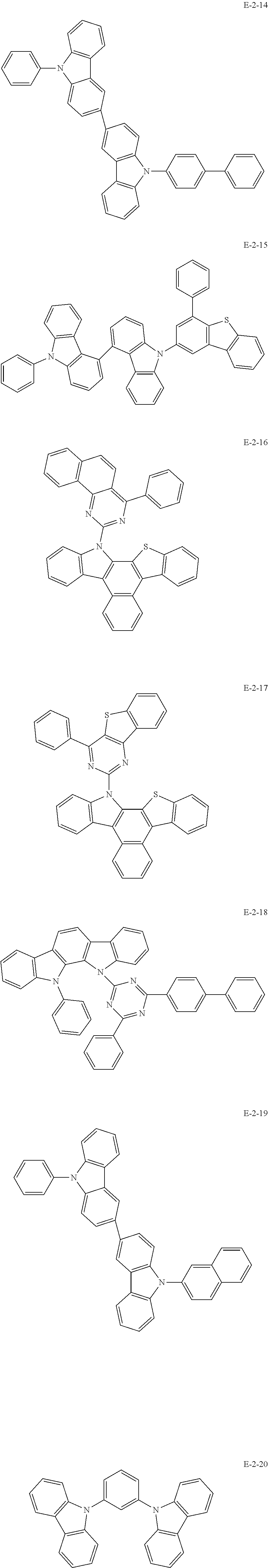

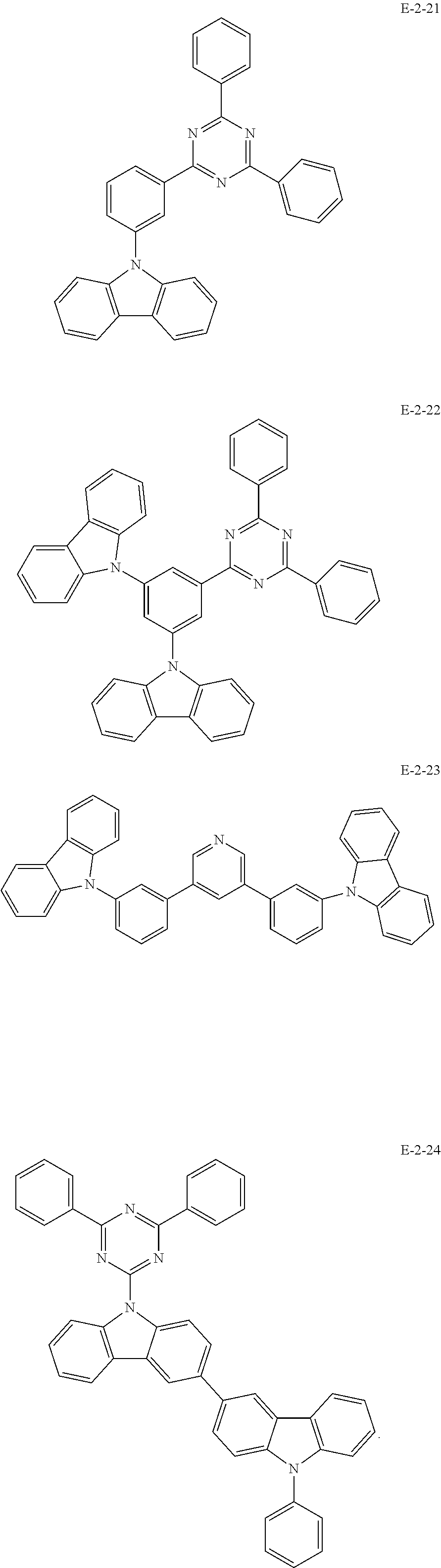 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material generally utilized/generally available in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may include the compound represented by Formula M-a. The compound represented by Formula M-a may be utilized as a phosphorescent dopant material. In some embodiments, the compound represented by Formula M-a in an embodiment may be utilized as an auxiliary dopant material.

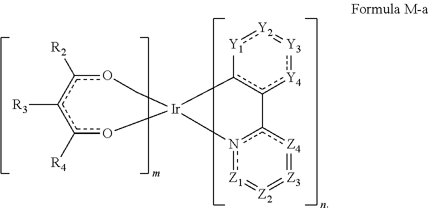

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or be bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be represented by any one selected from among Compound M-a1 to Compound M-a25. However, Compounds M-a1 to M-a25 are merely examples, and the compound represented by Formula M-a is not limited to those represented by Compounds M-a1 to M-a25.

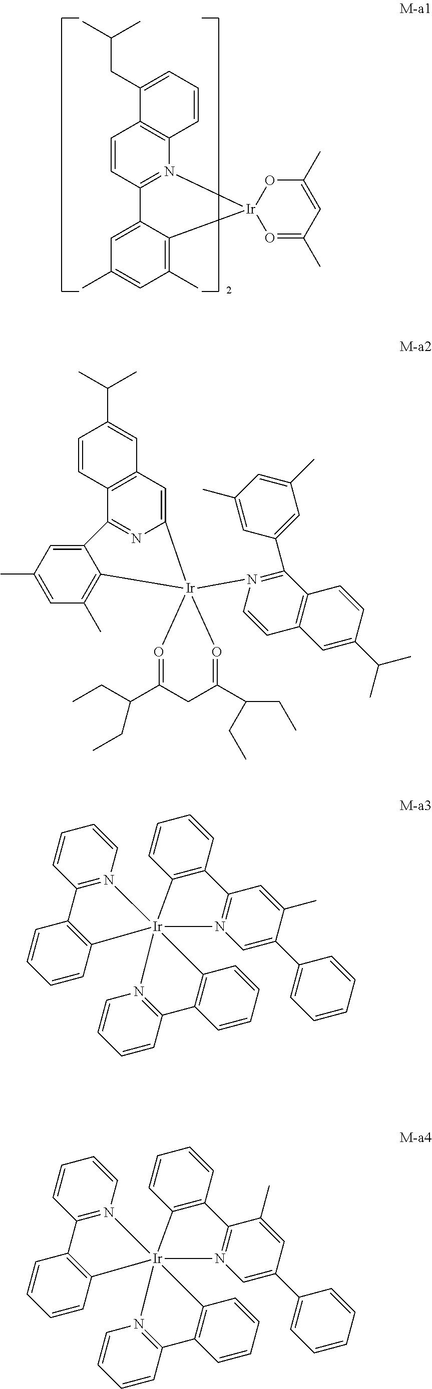

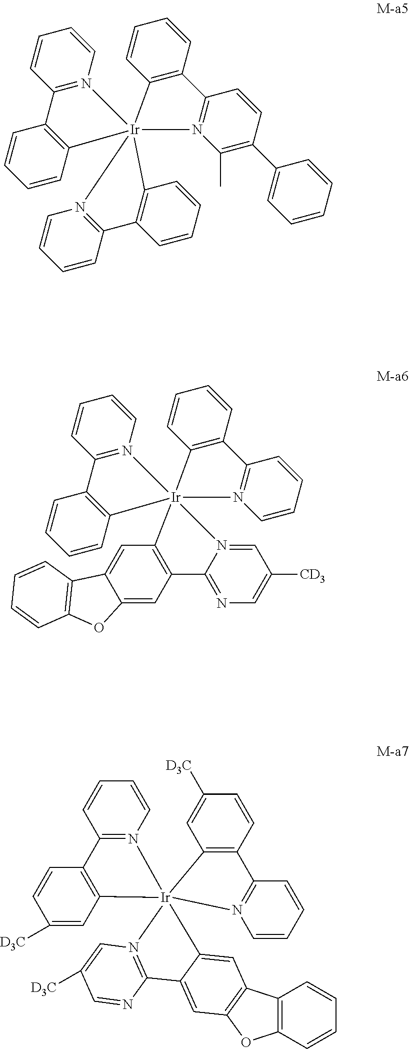

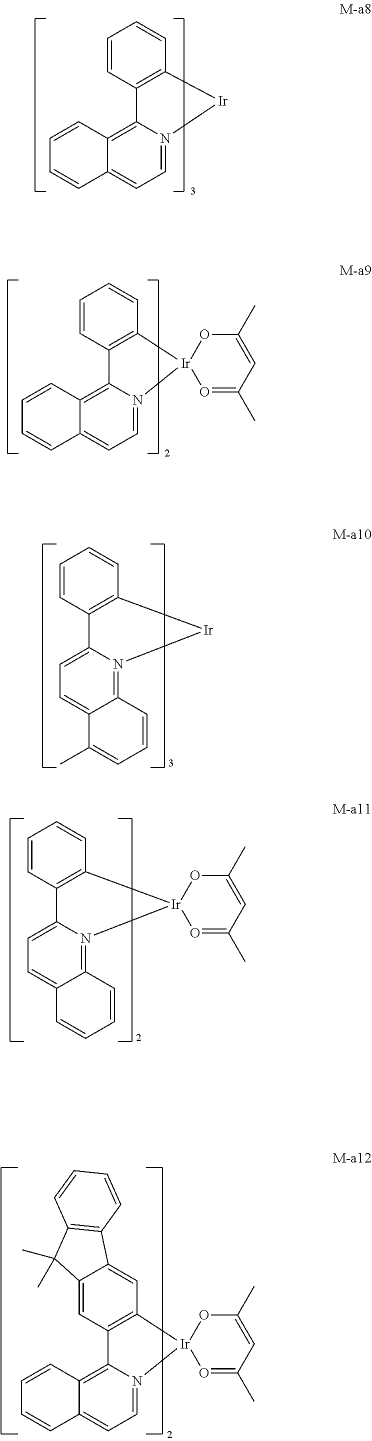

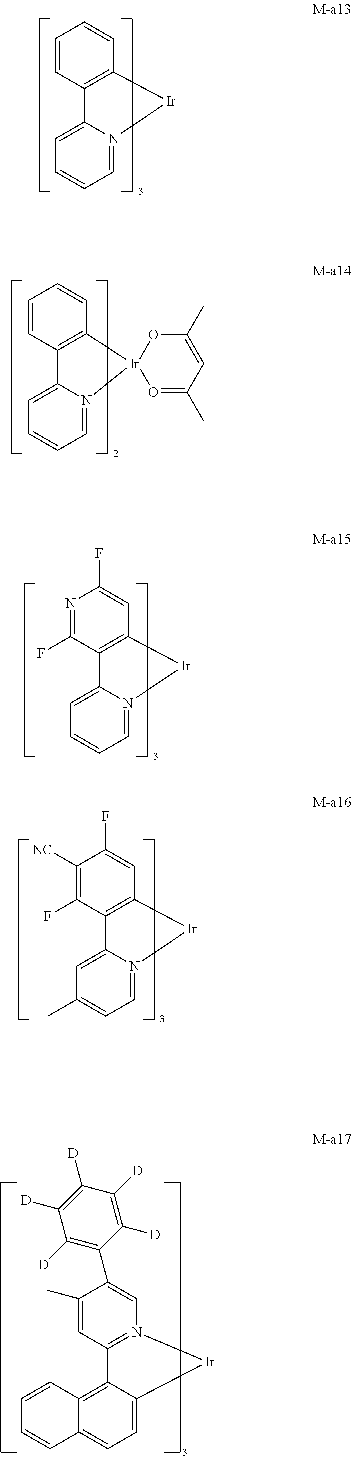

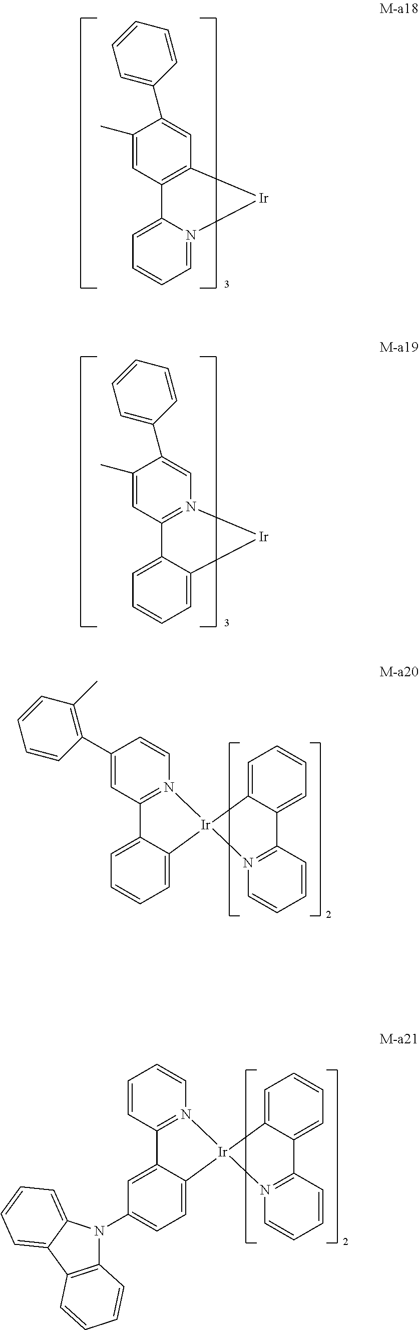

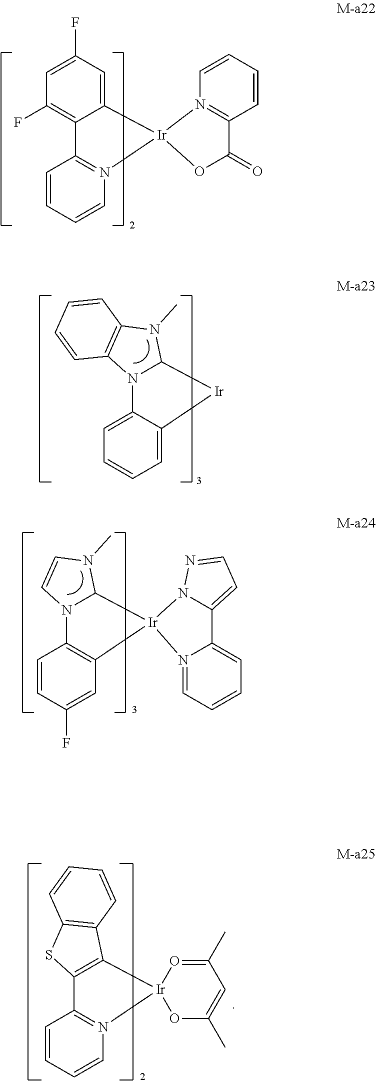

Compound M-a1 and Compound M-a2 may be utilized as a red dopant material, and Compound M-a3 to Compound M-a7 may be utilized as a green dopant material.

The emission layer EML may further include a compound represented by any one among Formula F-a to Formula F-c. The compound represented by Formula F-a or Formula F-c may be utilized as a fluorescence dopant material.

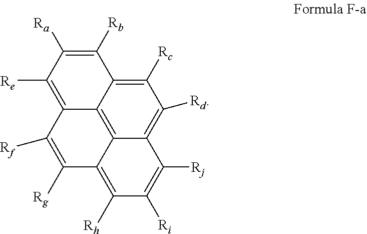

In Formula F-a, two selected from among Rₐ to Rⱼ may each independently be substituted with *—NAr₁Ar₂. The others, which are not substituted with *—NAr₁Ar₂, selected from among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

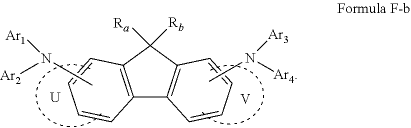

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

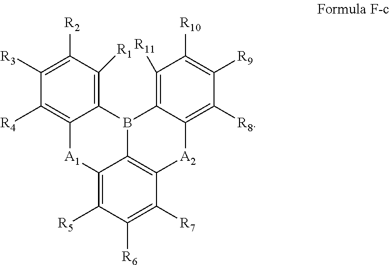

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In some embodiments, A₂ may be bonded to R₇ or R₈ to form a ring.

In an embodiment, the emission layer EML may include, as a generally utilized/generally available dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

In an embodiment, when a plurality of emission layers EML are included, at least one emission layer EML may include a generally utilized/generally available phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

In some embodiments, at least one emission layer EML may include a quantum dot material. The core of the quantum dot may be selected from a Group II-VI compound, a Group III-VI compound, a Group 1-III-IV compound, a Group III-V compound, a Group III-II-V compound, a Group IV-VI compound, a Group IV element, a Group IV compound, or one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The Group III-VI compound may include a binary compound such as In₂S₃ or In₂Se₃, a ternary compound such as InGaS₃ or InGaSe₃, or one or more combinations thereof.

The Group I-III-VI compound may be selected from a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more compounds or mixtures thereof, and/or a quaternary compound such as AgInGaS₂ or CuInGaS₂ (the quaternary compound may be used alone or in combination with any of the foregoing compounds or mixtures; and the quaternary compound may also be combined with other quaternary compounds).

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and a quaternary compound selected from the group including (e.g., consisting of) SnPbSSe, SnPbSeTe, SnPbSTe, and a mixture thereof. The Group IV element may be selected from the group including (e.g., consisting of) Si, Ge, and one or more elements or mixtures thereof. The Group IV compound may be a binary compound selected from the group including (e.g., consisting of) SiC, SiGe, and one or more compounds or mixtures thereof.

In this embodiment, a binary compound, a ternary compound, or a quaternary compound may be present in a particle form with a substantially uniform concentration distribution, or may be present in substantially the same particle form with a partially different concentration distribution. In some embodiments, a core/shell structure in which one quantum dot surrounds another quantum dot may also be possible. The core/shell structure may have a concentration gradient in which the concentration of elements present in the shell decreases toward the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less, and color purity or color reproducibility may be improved in the above ranges. In some embodiments, light emitted through such a quantum dot is emitted in all directions, and thus a wide viewing angle may be improved (increased).

In some embodiments, although the form of the quantum dot is not limited as long as it is a form commonly utilized in the art, for example, the quantum dot in the form of a substantially spherical, pyramidal, multi-arm, or cubic nanoparticles, nanotubes, nanowires, nanofibers, nanoplate particles, etc. may be utilized.

The quantum dot may control the color of emitted light according to the particle size thereof. Accordingly, the quantum dot may have one or more suitable light emission colors such as blue, red, and green.

In each of the light emitting elements ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL, an electron transport layer ETL/buffer layer/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET:

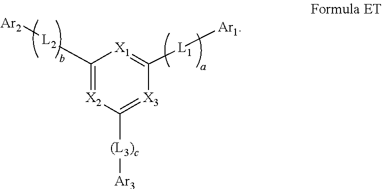

In Formula ET, at least one selected from among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET, a to c may each independently be an integer from 0 to 10. In Formula ET, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The electron transport region ETR may include at least one selected from among Compound ET1 to Compound ET36:

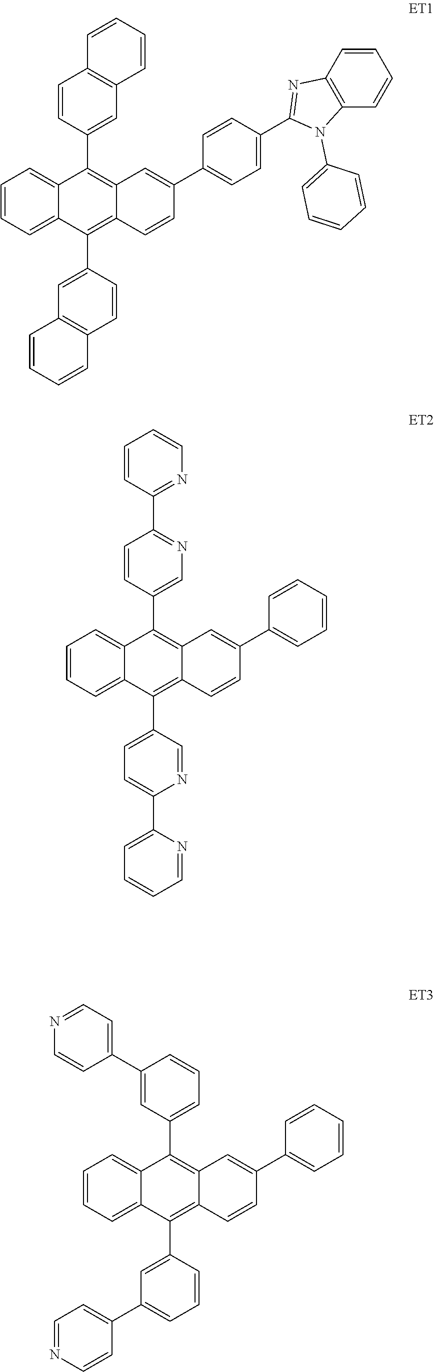 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

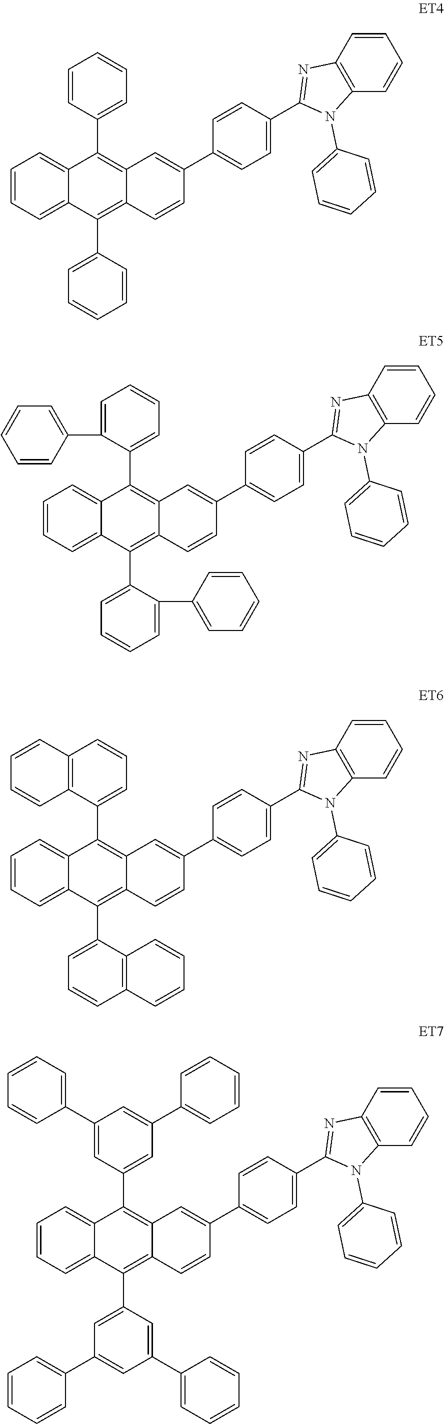 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

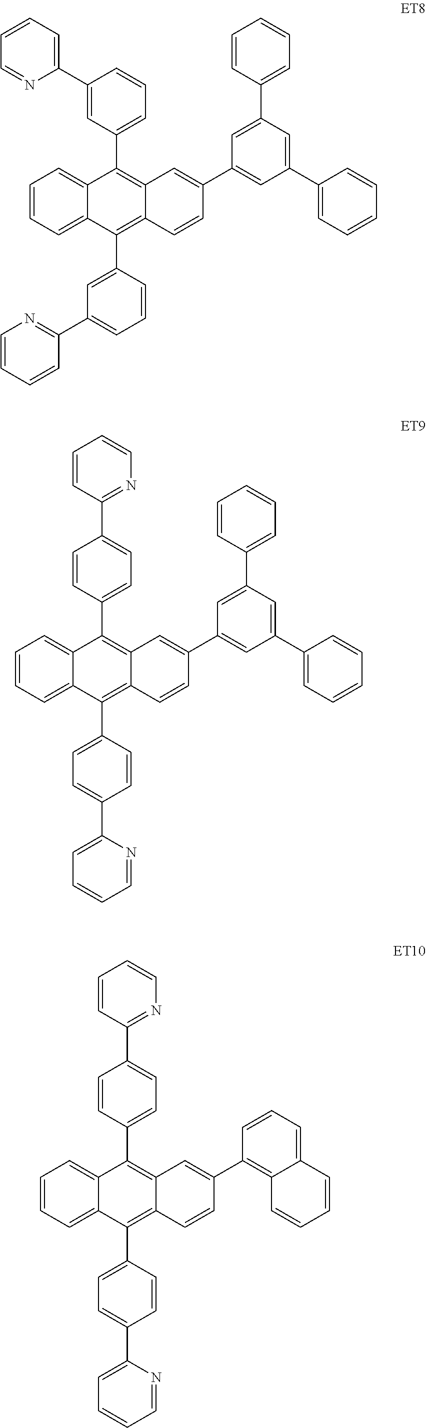 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

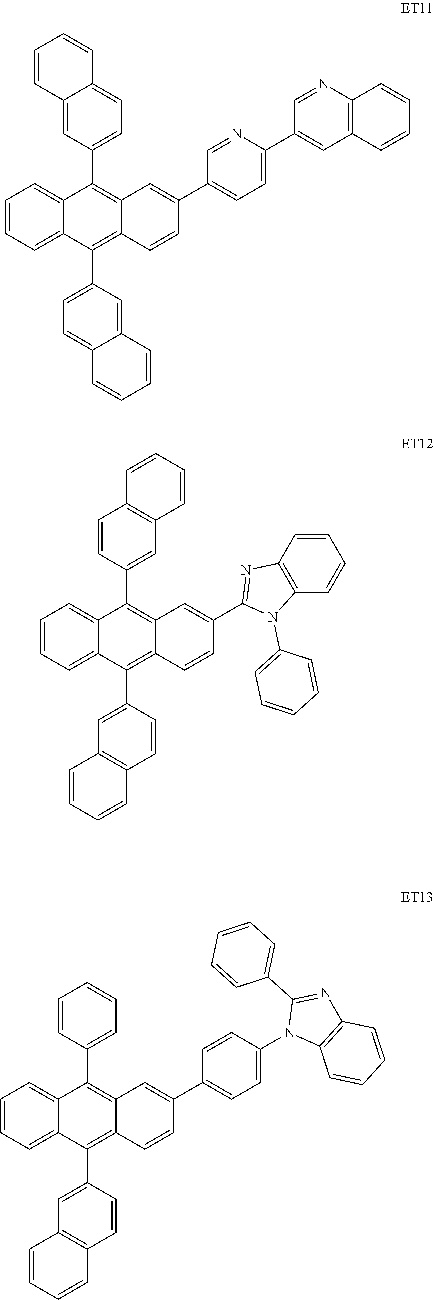 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

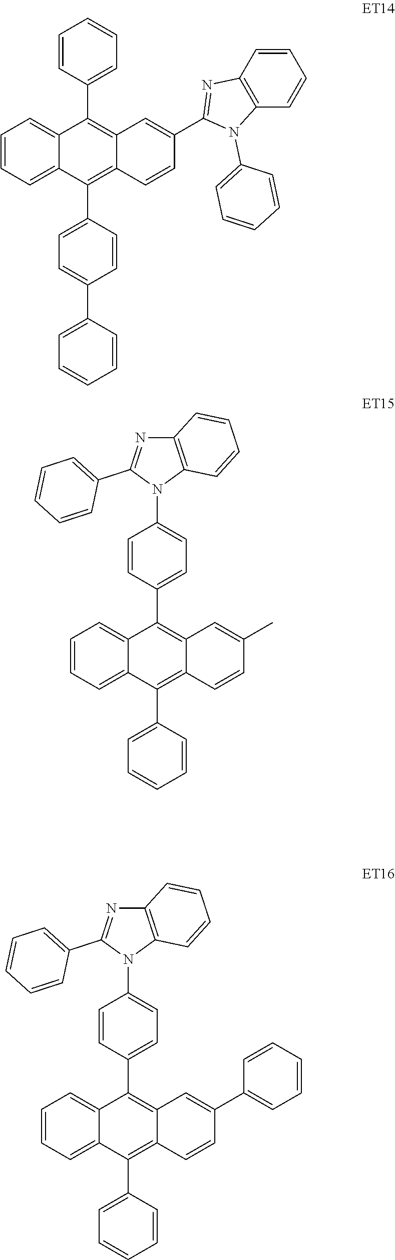 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

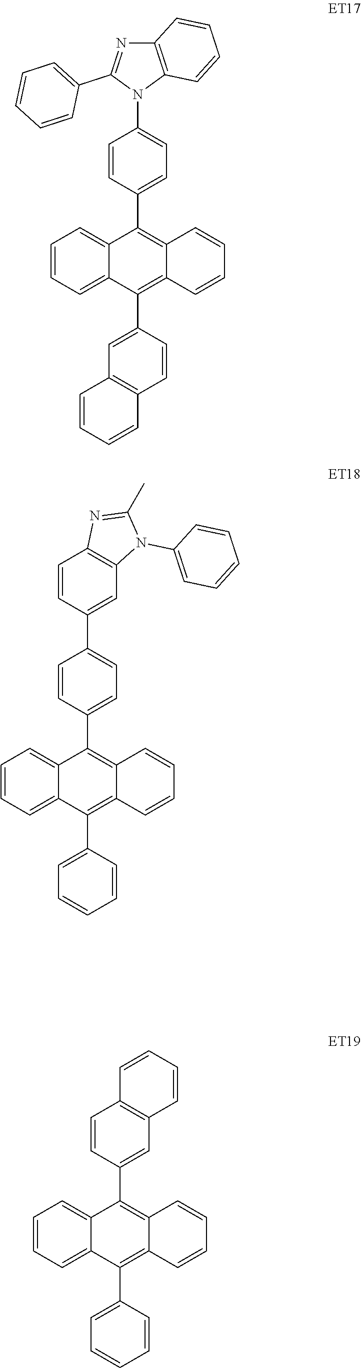

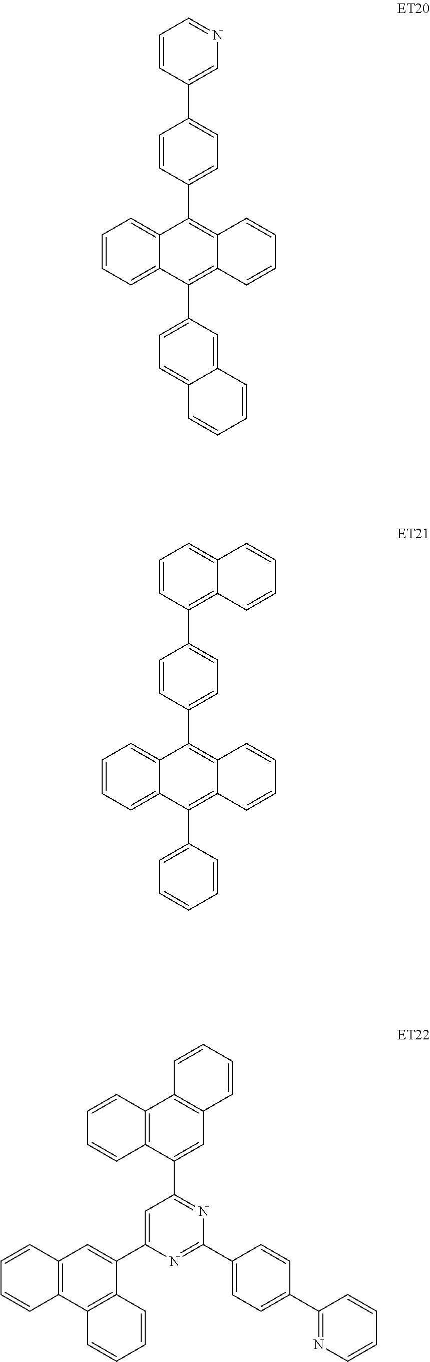

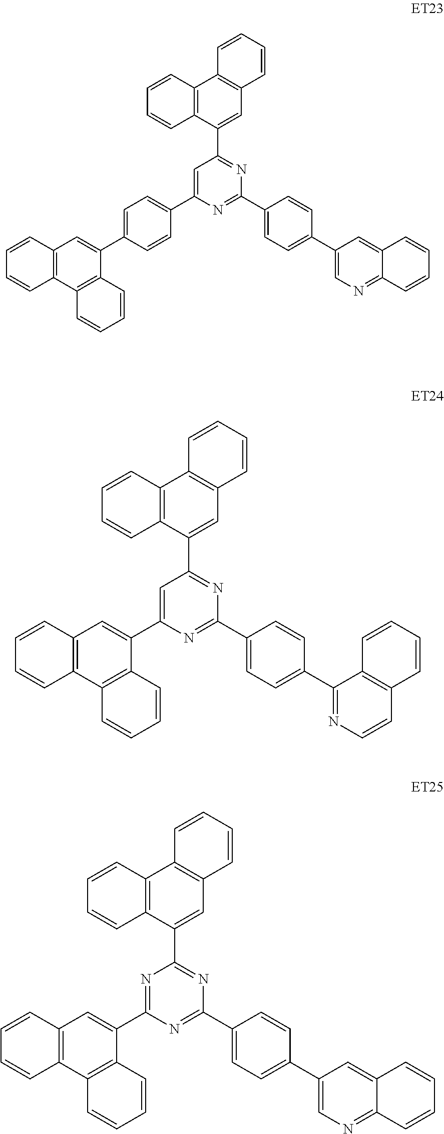 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

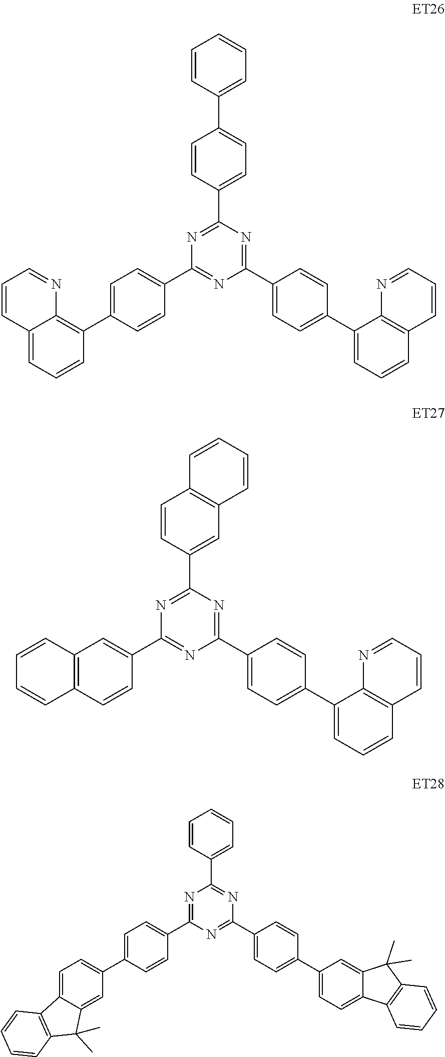 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

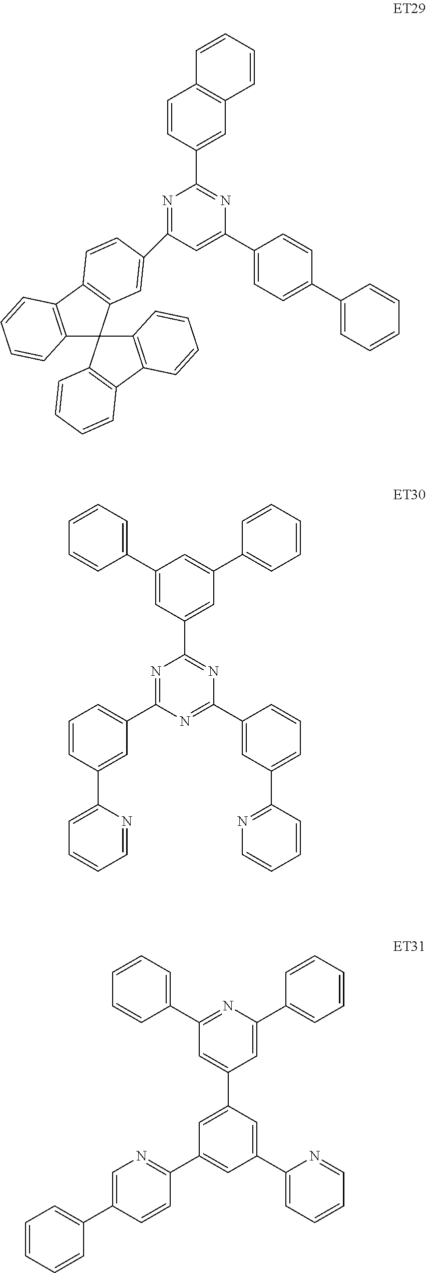 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

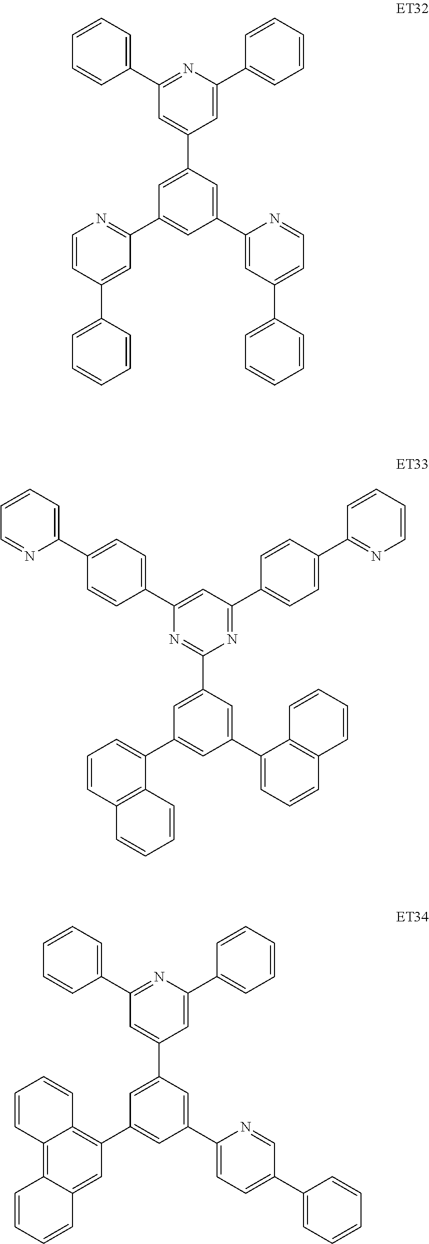 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

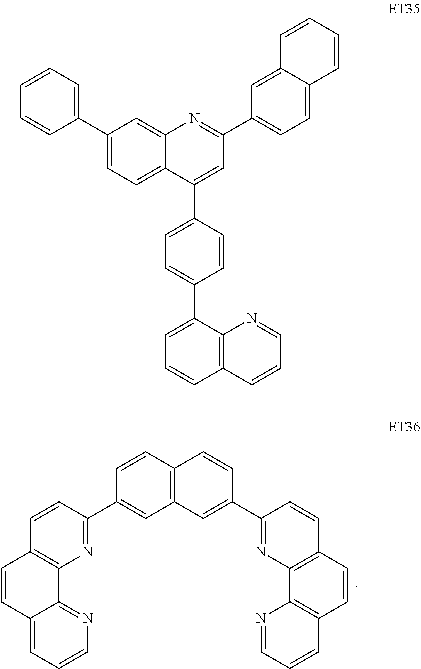 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCl, RbI, CuI, or KI, a lanthanide metal such as Yb, and a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed utilizing a metal oxide such as Li₂O or BaO, or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment of the present disclosure is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory (suitable) electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described range, satisfactory (suitable) electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or one or more oxides thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, or one or more compounds or mixtures including these (e.g., AgMg, AgYb, or MgYb). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

The second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiO_{y}, etc.

For example, when the capping layer CPL contains an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or may include an epoxy resin, or an acrylate such as a methacrylate. However, the embodiment of the present disclosure is not limited thereto, and the capping layer CPL may include at least one selected from among Compounds P1 to P5:

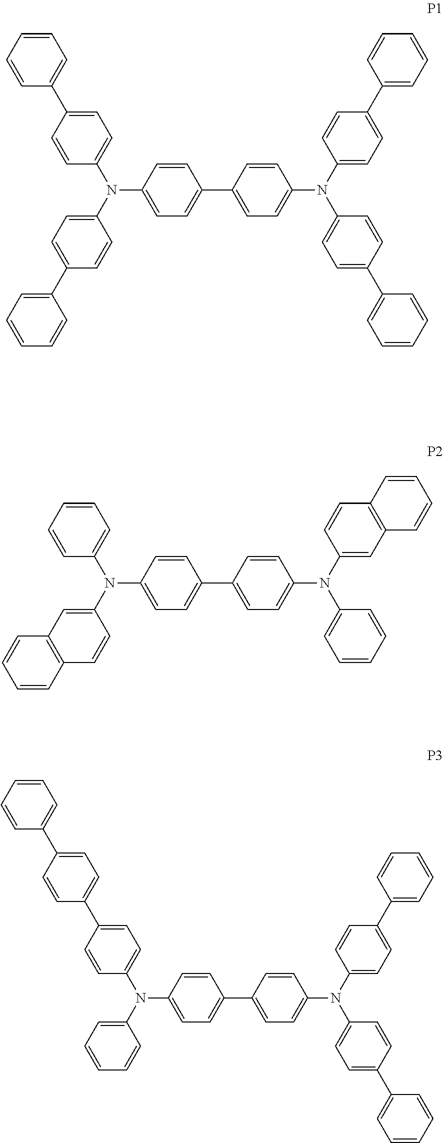 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

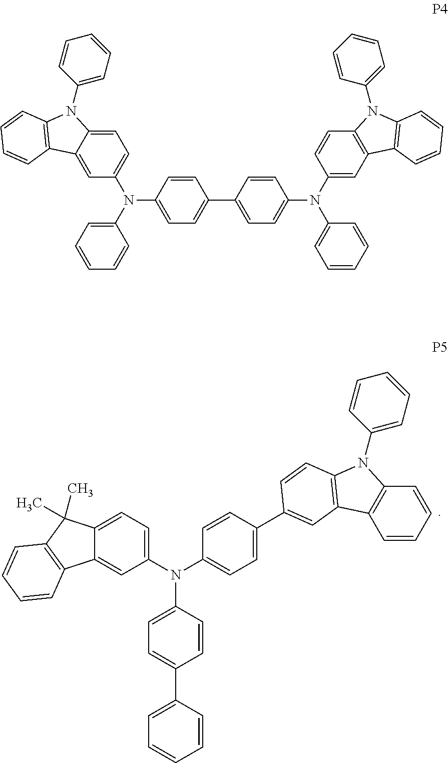 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

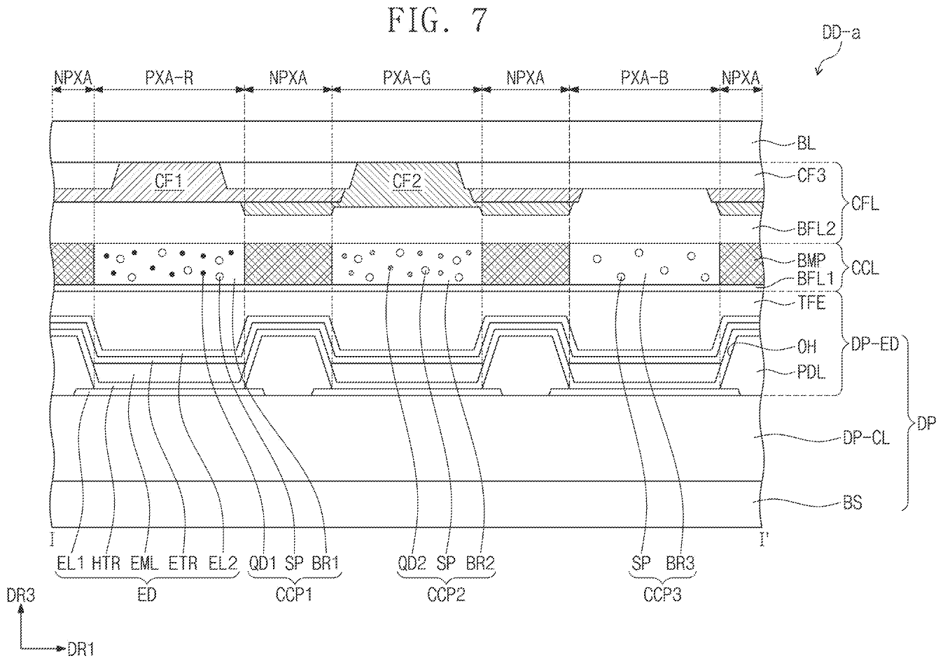

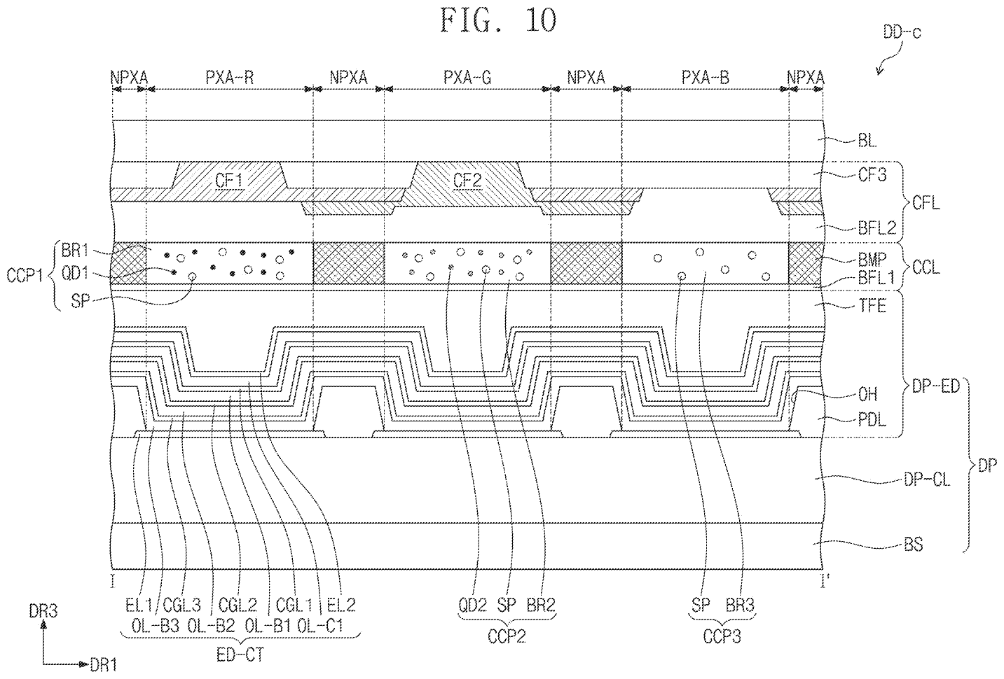

Each of FIGS. 7 to 10 is a cross-sectional view of a display device according to an embodiment of the present disclosure. Hereinafter, in describing the display devices of embodiments with reference to FIGS. 7 to 10, the duplicated features which have been described in FIGS. 1 to 6 may not be described again, but their differences will be primarily be described.

Referring to FIG. 7, the display device DD-a according to an embodiment may include a display panel DP including a display element layer DP-ED, a light control layer CCL on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In some embodiments, the structures of the light emitting elements of FIGS. 3 to 6 as described above may be equally applied to the structure of the light emitting element ED illustrated in FIG. 7.

The emission layer EML of the light emitting element ED included in the display device DD-a according to an embodiment may include the above-described polycyclic compound of an embodiment.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in substantially the same wavelength range. In the display device DD of an embodiment, the emission layer EML may emit blue light. In some embodiments, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. For example, the light control layer CCL may be a layer containing the quantum dot or a layer containing the phosphor.

The light control layer CCL may include a plurality of light control parts CCP1, CCP2, and CCP3. The light control parts CCP1, CCP2, and CCP3 may be spaced apart from (separated from) each other.

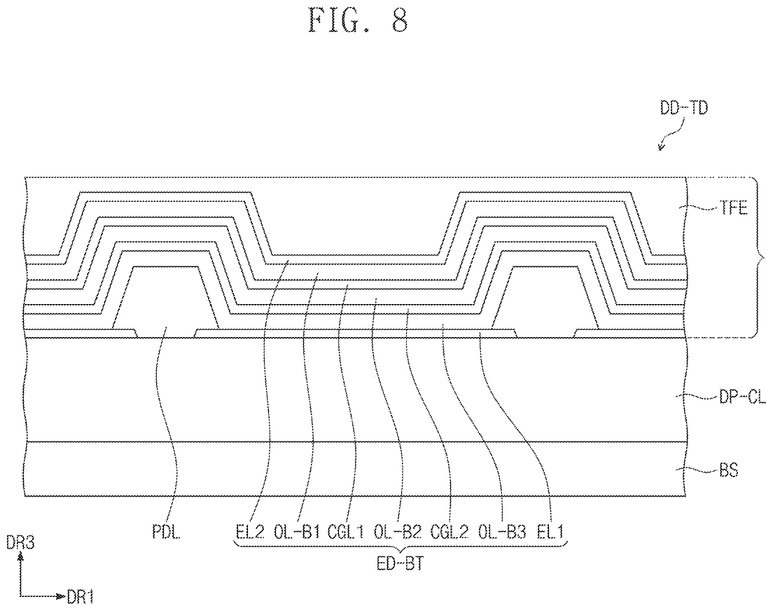

Referring to FIG. 7, divided patterns BMP may be disposed between the light control parts CCP1, CCP2, and CCP3 which are spaced apart from each other, but the embodiment of the present disclosure is not limited thereto. FIG. 8 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be on the light control parts CCP1, CCP2, and CCP3 to block or reduce the light control parts CCP1, CCP2, and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye. In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter. The first to third filters CF1, CF2, and CF3 may be disposed corresponding to the red light emitting region PXA-R, the green light emitting region PXA-G, and the blue light emitting region PXA-B, respectively.

In some embodiments, the color filter layer CFL may include a light shielding part. The color filter layer CFL may include a light shielding part disposed to overlap at the boundaries of neighboring filters CF1, CF2, and CF3. The light shielding part may be a black matrix. The light shielding part may include an organic light shielding material or an inorganic light shielding material containing a black pigment and/or dye. The light shielding part may separate boundaries between the adjacent filters CF1, CF2, and CF3. In some embodiments, the light shielding part may be formed of a blue filter.

A base substrate BL may be on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

FIG. 8 is a cross-sectional view illustrating a portion of a display device according to an embodiment of the present disclosure. FIG. 8 illustrates a cross-sectional view of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting element ED-BT included in the display device DD-TD of an embodiment may be a light emitting element having a tandem structure and including a plurality of emission layers.

In an embodiment illustrated in FIG. 8, all light beams respectively emitted from the light emitting structures (e.g., OL-B1, OL-B2, and/or OL-B3) may be blue light emitting structures (e.g., may each emit light in the blue wavelength range). However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light (e.g., a combined white light).

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer (e.g., P-charge generation layer) and/or an n-type or kind charge generation layer (e.g., N-charge generation layer).

At least one selected from among the light emitting structures OL-B1, OL-B2, and OL-B3 included in the display device DD-TD of an embodiment may include the above-described polycyclic compound of an embodiment. For example, at least one selected from among the plurality of emission layers included in the light emitting element ED-BT may include the polycyclic compound of an embodiment.

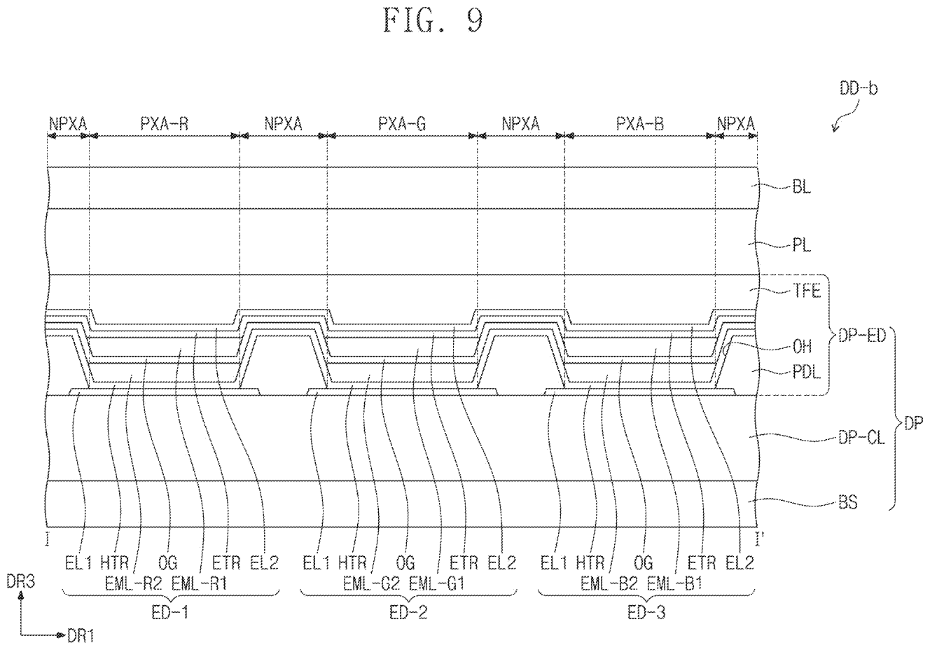

Referring to FIG. 9, the display device DD-b according to an embodiment may include light emitting elements ED-1, ED-2, and ED-3 in which two emission layers are stacked. Compared with the display device DD of an embodiment illustrated in FIG. 2, an embodiment illustrated in FIG. 9 has a difference in that the first to third light emitting elements ED-1, ED-2, and ED-3 each include two emission layers stacked in the thickness direction. In each of the first to third light emitting elements ED-1, ED-2, and ED-3, the two emission layers may emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer.

The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be between the electron transport region ETR and the emission auxiliary part OG. The second red emission layer EML-R2, the second green emission layer EML-G2, and the second blue emission layer EML-B2 may be between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display element layer DP-ED. The optical auxiliary layer PL may include a polarizing layer. The optical auxiliary layer PL may be on the display panel DP and control reflected light in the display panel DP due to external light. The optical auxiliary layer PL in the display device according to an embodiment may not be provided.

One or more emission layers included in the display device DD-b of an embodiment illustrated in FIG. 9 may include the above-described polycyclic compound of an embodiment. For example, in an embodiment, at least one of the first blue emission layer EML-B1 or the second blue emission layer may include the polycyclic compound of an embodiment.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, the embodiment of the present disclosure is not limited thereto, and the first to fourth light emitting structures OL-B1, OL-B2, OL-B3, and OL-C1 may emit light beams in different wavelength regions.

The charge generation layers CGL1, CGL2, and CGL3 disposed between adjacent light emitting structures OL-B1, OL-B2, OL-B3, and OL-C1 may include a p-type or kind charge generation layer (e.g., P-charge generation layer) and/or an n-type or kind charge generation layer (e.g., N-charge generation layer).

At least one among the light emitting structures OL-B1, OL-B2, OL-B3, and OL-C1 included in the display device DD-c of an embodiment may include the above-described polycyclic compound of an embodiment. For example, in an embodiment, at least one among the first to third light emitting structures OL-B1, OL-B2, and OL-B3 may include the above-described polycyclic compound of an embodiment.

The light emitting element ED according to an embodiment of the present disclosure may include the above-described polycyclic compound of an embodiment in at least one functional layer between the first electrode EL1 and the second electrode EL2, thereby exhibiting excellent or suitable luminous efficiency and improved service life characteristics. For example, the polycyclic compound according to an embodiment may be included in the emission layer EML of the light emitting element ED of an embodiment, and the light emitting element of an embodiment may concurrently (e.g., simultaneously) exhibit high efficiency and long service life characteristics.

The above-described polycyclic compound of an embodiment includes the substituent of the carbazole derivative or arylamine derivative, which is a bulky hetero substituent, the benzonitrile group, and the core part of the fused ring containing a boron atom, and thus may have high stability. In some embodiments, the polycyclic compound of an embodiment includes the core part of the fused ring containing a boron atom, and a nitrogen-containing heterocyclic group, thereby implementing both (e.g., simultaneously) short range charge transfer and long range charge transfer phenomena, and thus may be utilized as a thermally activated delayed fluorescence dopant material, thereby increasing luminous efficiency.

Hereinafter, with reference to Examples and Comparative Examples, a polycyclic compound according to an embodiment of the present disclosure and a light emitting element of an embodiment of the present disclosure will be described in more detail. In some embodiments, examples described below are merely illustrations to assist the understanding of the present disclosure, and the scope of the present disclosure is not limited thereto.

### Examples

### 1. Synthesis of Polycyclic Compound

First, a synthetic method of the polycyclic compound according to an embodiment will be described by illustrating synthetic methods of Compounds 1, 20, 34, 61, and 81. In some embodiments, in the following descriptions, the synthetic methods of the polycyclic compounds are provided as merely examples, but the synthetic method according to an embodiment of the present disclosure is not limited to Examples.

### (1) Synthesis of Compound 1

Polycyclic Compound 1 according to an example may be synthesized by, for example, the steps shown in Reaction Scheme 1:

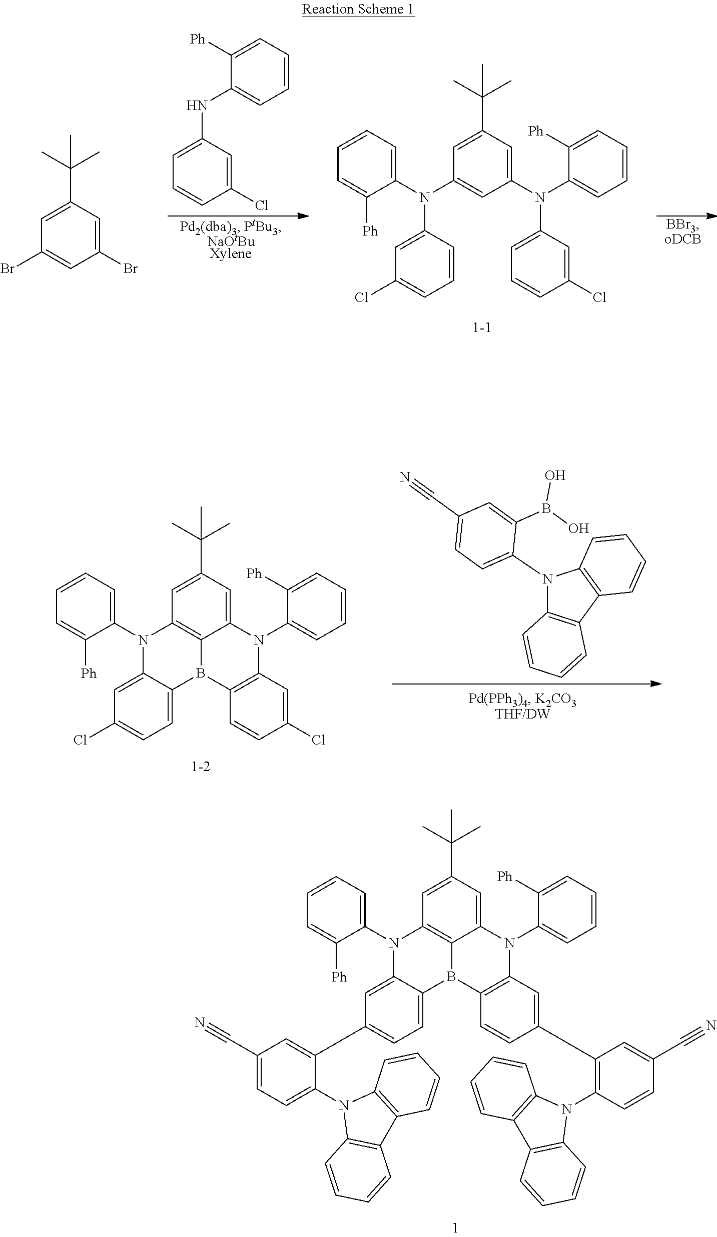

### Synthesis of Intermediate 1-1

1,3-dibromo-5-(tert-butyl)benzene (1 eq), N-(3-chlorophenyl)-[1,1′-biphenyl]-2-amine (2.1 eq), tris(dibenzylideneacetone)dipalladium(0) (0.05 eq), tri-tert-butylphosphine (0.2 eq), Sodium tert-butoxide (3 eq) xylene was dissolved in xylene, and then the resultant mixture was stirred in a nitrogen atmosphere at about 160° C. for about 24 hours. After being cooled, the resultant mixture was dried under reduced pressure, and the xylene was removed. Then, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 1-1 (yield: 71%).

### Synthesis of Intermediate 1-2

Intermediate 1-1 (1 eq) was dissolved in ortho dichlorobenezene (oDCB), and a flask was cooled to about 0° C. in a nitrogen atmosphere, and then BBr₃ (2.5 eq) dissolved in oDCB was slowly injected thereto. After dropping (addition) was completed, the temperature was elevated to about 180° C., and the mixture was stirred for about 20 hours. After being cooled to about 0° C., triethylamine was slowly dropped (added) to the flask until heating stopped to terminate the reaction, and then hexane was added to the flask, thereby extracting solids. The extracted solids were obtained by filtration. The obtained solids were purified with silica filtration, and then purified again through recrystallization in methylenechloride/hexane (MC/Hex) to obtain Intermediate 1-2. Thereafter, Intermediate 1-2 was finally purified by column chromatography (dichloromethane:n-hexane) (yield: 13%).

### Synthesis of Compound 1

Intermediate 1-2 (1 eq), (2-(9H-carbazol-9-yl)-5-cyanophenyl)boronic acid (1 eq), Pd(PPh₃)₄ (0.05 eq), and K₂CO₃ (3 eq) were dissolved in tetrahydrofuran/distilled water (THF/DW), and then the resultant mixture was stirred at about 80° C. for about 24 hours. After being cooled, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Compound 1 (yield: 42%). Then, the resulting product was further purified by sublimation purification to obtain final purity.

### (2) Synthesis of Compound 20

Polycyclic Compound 20 according to an example may be synthesized by, for example, the steps shown in Reaction Scheme 2:

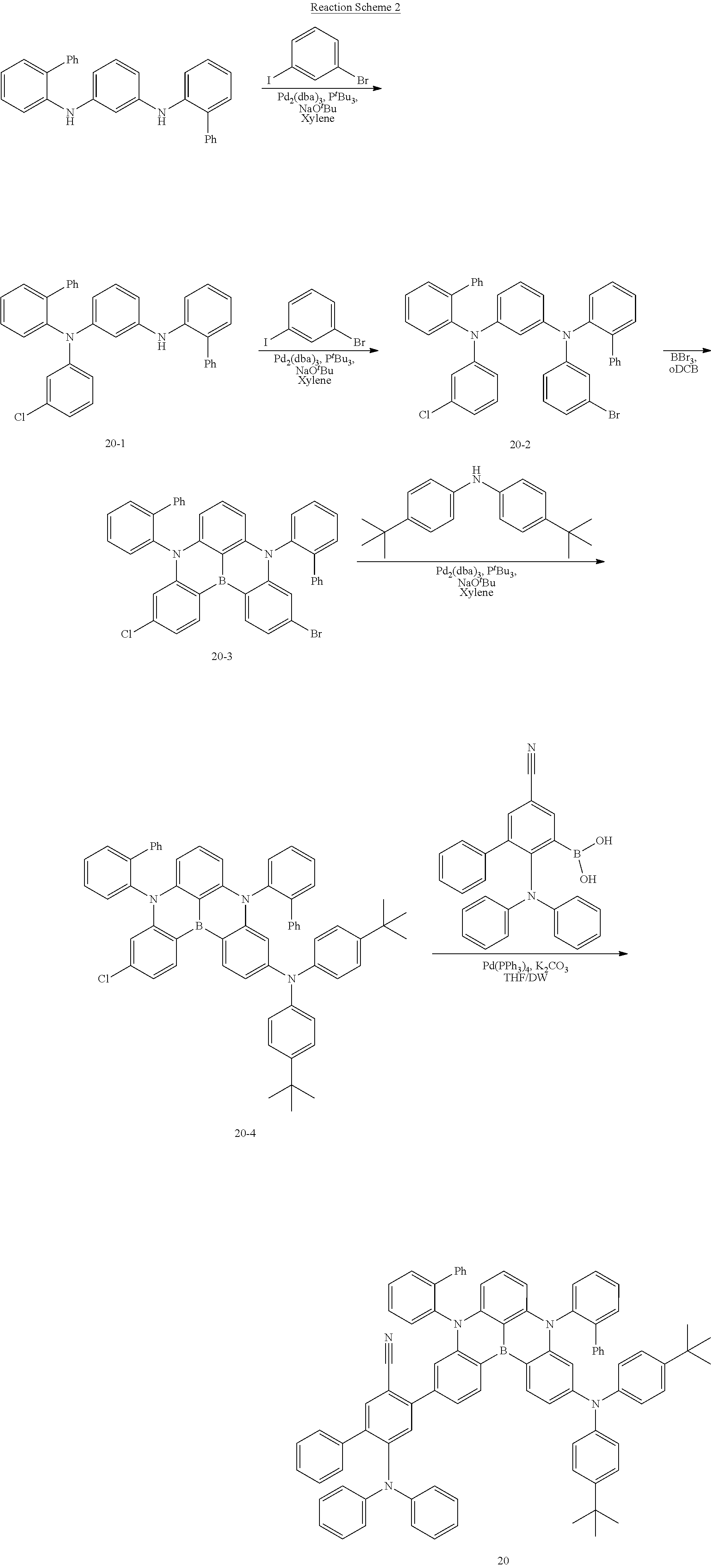

### Synthesis of Intermediate 20-1

N1,N3-di([1,1′-biphenyl]-2-yl)benzene-1,3-diamine (1 eq), 1-chloro-3-iodobenzene (0.9 eq), tris(dibenzylideneacetone)dipalladium(0) (0.05 eq), BINAP (0.1 eq), sodium tert-butoxide (1 eq) was dissolved in xylene, and then the resultant mixture was stirred in a nitrogen atmosphere at about 80° C. for about 6 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 20-1 (yield: 64%).

### Synthesis of Intermediate 20-2

Intermediate 20-1 (1 eq), 1-bromo-3-iodobenzene (1 eq), tri-tert-butylphosphine (0.1 eq), tris(dibenzylideneacetone)dipalladium(0) (0.05 eq), and sodium tert-butoxide (1 eq) were dissolved in xylene, and then the resultant mixture was stirred in a nitrogen atmosphere at about 80° C. for about 6 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 20-2 (yield: 57%).

### Synthesis of Intermediate 20-3

Intermediate 20-1 (1 eq) was dissolved in ortho dichlorobenezene (oDCB), and a flask was cooled to about 0° C. in a nitrogen atmosphere, and then BBr₃ (2.5 eq) dissolved in oDCB was slowly injected thereto. After dropping (addition) was completed, the temperature was elevated to about 180° C., and the mixture was stirred for about 20 hours. After being cooled to about 0° C., triethylamine was slowly dropped (added) to the flask until heating stopped to terminate the reaction, and then hexane was added to the flask, thereby extracting solids. The extracted solids were obtained by filtration. The obtained solids were purified with silica filtration, and then purified again through recrystallization in methylenechloride/hexane (MC/Hex) to obtain Intermediate 20-3. Thereafter, Intermediate 20-3 was finally purified by column chromatography (dichloromethane:n-hexane) (yield: 17%).

### Synthesis of Intermediate 20-4

Intermediate 20-3 (1 eq), bis(4-(tert-butyl)phenyl)amine (1 eq), tris(dibenzylideneacetone)dipalladium(0) (0.05 eq), tri-tert-butylphosphine (0.1 eq), and sodium tert-butoxide (2 eq) were dissolved in xylene, and then the resultant mixture was stirred in a nitrogen atmosphere at about 100° C. for about 6 hours. After being cooled, the resultant mixture was dried under reduced pressure, and the xylene was removed. Then, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 20-4 (yield: 67%).

### Synthesis of Compound 20

Intermediate 20-4 (1 eq), (5-cyano-2-(diphenylamino)-[1,1′-biphenyl]-3-yl)boronic acid (1 eq), Pd(PPh₃)₄ (0.05 eq), and K₂CO₃ (3 eq) were dissolved in tetrahydrofuran/distilled water (THF/DW), and then the resultant mixture was stirred at about 100° C. for about 24 hours. After being cooled, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Compound 20 (yield: 41%). Then, the resulting product was further purified by sublimation purification to obtain final purity.

### (3) Synthesis of Compound 34

Polycyclic Compound 34 according to an example may be synthesized by, for example, the steps shown in Reaction Scheme 3:

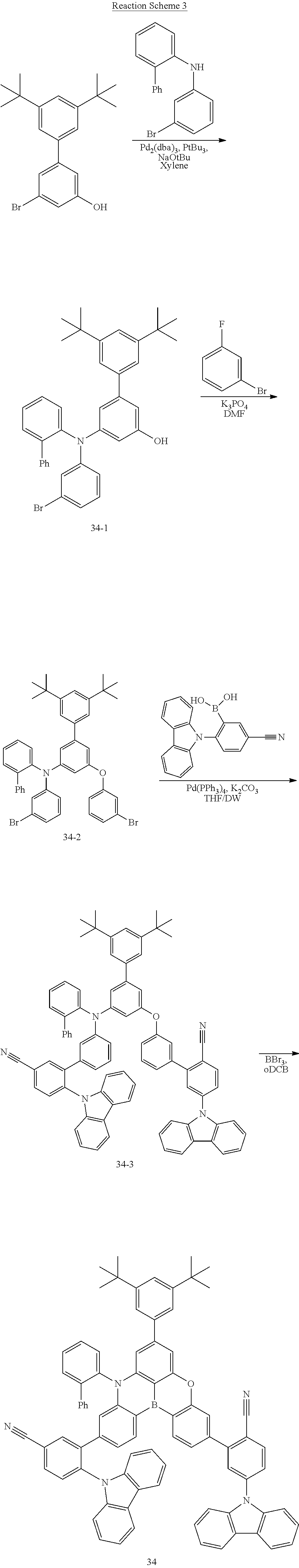

### Synthesis of Intermediate 34-1

5-bromo-3′,5′-di-tert-butyl-[1,1′-biphenyl]-3-ol (1 eq), N-(3-chlorophenyl)-[1,1′-biphenyl]-2-amine (1 eq), tris(dibenzylideneacetone)dipalladium(0) (0.05 eq), Tri-tert-butylphosphine (0.1 eq), and sodium tert-butoxide (2 eq) were dissolved in xylene, and then the resultant mixture was stirred in a nitrogen atmosphere at about 100° C. for about 8 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 34-1 (yield: 73%).

### Synthesis of Intermediate 34-2

Intermediate 34-1 (1 eq), 1-bromo-3-fluorobenzene (3 eq), and potassium phosphate (5 eq) were dissolved in N,N-dimethylformamide anhydrous, and then the resultant mixture was stirred in a nitrogen atmosphere at about 160° C. for about 20 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 34-2 (yield: 67%).

### Synthesis of Intermediate 34-3

Intermediate 34-2 (1 eq), 2-(9H-carbazol-9-yl)-5-cyanophenyl)boronic acid (2.2 eq), Pd(PPh₃)₄ (0.05 eq), and K₂CO₃ (3 eq) were dissolved in tetrahydrofuran/distilled water (THF/DW), and then the resultant mixture was stirred at about 100° C. for about 30 hours. After being cooled, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 34-3 (yield: 52%).

### Synthesis of Compound 34

Intermediate 34-3 (1 eq) was dissolved in ortho dichlorobenezene (oDCB), and a flask was cooled to about 0° C. in a nitrogen atmosphere, and then BBr₃ (2.5 eq) dissolved in oDCB was slowly injected thereto. After dropping (addition) was completed, the temperature was elevated to about 180° C., and the mixture was stirred for about 20 hours. After being cooled to about 0° C., triethylamine was slowly dropped (added) to the flask until heating stopped to terminate the reaction, and then hexane was added to the flask, thereby extracting solids. The extracted solids were obtained by filtration. The obtained solids were purified with silica filtration, and then purified again through recrystallization in methylenechloride/hexane (MC/Hex) to obtain Compound 34. Thereafter, Compound 34 was finally purified by column chromatography (dichloromethane:n-hexane) (yield: 7%).

### (4) Synthesis of Compound 61

Polycyclic Compound 61 according to an example may be synthesized by, for example, the steps shown in Reaction Scheme 4:

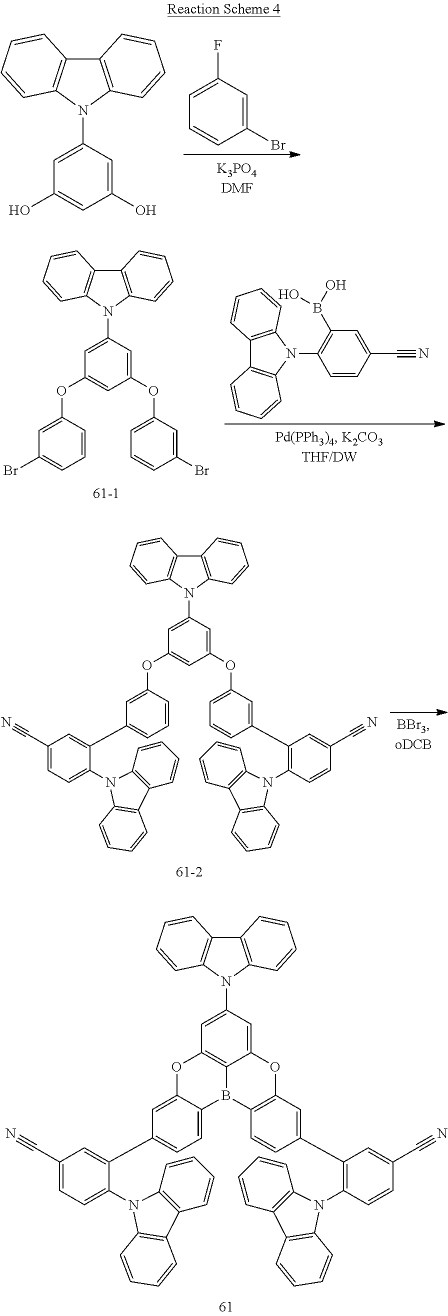

### Synthesis of Intermediate 61-1

5-(9H-carbazol-9-yl)benzene-1,3-diol (1 eq), 1-bromo-3-fluorobenzene (6 eq), and potassium phosphate (5 eq) were dissolved in N,N-dimethylformamide anhydrous, and then the resultant mixture was stirred in a nitrogen atmosphere at about 160° C. for about 24 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 61-1 (yield: 62%).

### Synthesis of Intermediate 61-2

Intermediate 61-1 (1 eq), (2-(9H-carbazol-9-yl)-5-cyanophenyl)boronic acid (2.2 eq), Pd(PPh₃)₄ (0.05 eq), and K₂CO₃ (3 eq) were dissolved in tetrahydrofuran/distilled water (THF/DW), and then the resultant mixture was stirred at about 100° C. for about 30 hours. After being cooled, the resulting product was washed three times with ethyl acetate and water to obtain organic layers. The obtained organic layers were dried over MgSO₄, and then dried under reduced pressure. The resulting product was purified and recrystallized (dichloromethane: n-Hexane) by column chromatography to obtain Intermediate 61-2 (yield: 57%).

### Synthesis of Compound 61

Intermediate 61-2 (1 eq) was dissolved in ortho dichlorobenezene (oDCB), and a flask was cooled to about 0° C. in a nitrogen atmosphere, and then BBr₃ (2.5 eq) dissolved in oDCB was slowly injected thereto. After dropping (addition) was completed, the temperature was elevated to about 180° C., and the mixture was stirred for about 20 hours. After being cooled to about 0° C., triethylamine was slowly dropped (added) to the flask until heating stopped to terminate the reaction, and then hexane was added to the flask, thereby extracting solids. The extracted solids were obtained by filtration. The obtained solids were purified with silica filtration, and then purified again through recrystallization in methylenechloride/hexane (MC/Hex) to obtain Compound 61. Thereafter, Compound 34 was further purified by column chromatography (dichloromethane:n-hexane) (yield: 15%).

### (5) Synthesis of Compound 81

Polycyclic Compound 81 according to an example may be synthesized by, for example, the steps shown in Reaction Scheme 5:

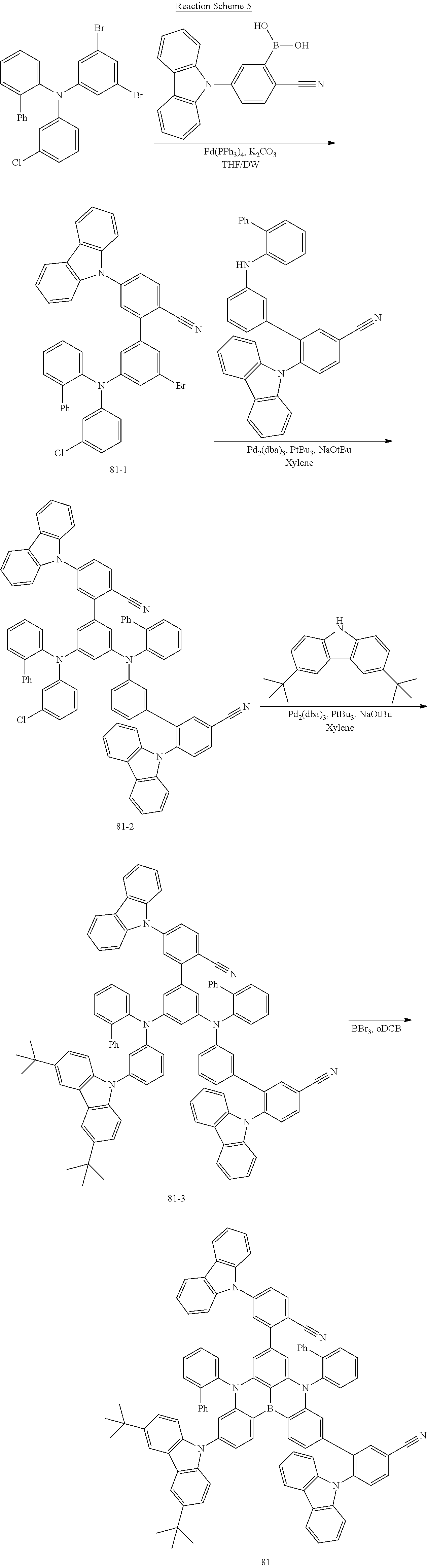

### Synthesis of Intermediate 81-1

N-(3-chlorophenyl)-N-(3,5-dibromophenyl)-[1,1′-biphenyl]-2-amine (1 eq), (5-(9H-carbazol-9-yl)-2-cyanophenyl)boronic acid (1 eq), Pd(PPh₃)₄ (0.05 eq), and K₂CO₃ (3 eq) were dissolved in tetrahydrofuran/distilled water (THF/DW), and then the resultant mixture was stirred at about 80° C. for about 16 hours. After being cooled, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 81-1 (yield: 61%).

### Synthesis of Intermediate 81-2

Intermediate 81-1 (1 eq), 3′-([1,1′-biphenyl]-2-ylamino)-6-(9H-carbazol-9-yl)-[1,1′-biphenyl]-3-carbonitrile, tris(dibenzylideneacetone)dipalladium(0) (0.05 eq), tri-tert-butylphosphine (0.1 eq), and sodium tert-butoxide (2 eq) were dissolved in xylene, and then the resultant mixture was stirred in a nitrogen atmosphere at about 100° C. for about 8 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 34-1 (yield: 73%).

### Synthesis of Intermediate 81-3

Intermediate 81-2 (1 eq), 3,6-di-tert-butyl-9H-carbazole, tris(dibenzylideneacetone)dipalladium(0) (0.05 eq), tri-tert-butylphosphine (0.1 eq), and sodium tert-butoxide (2 eq) were dissolved in xylene, and then the resultant mixture was stirred in a nitrogen atmosphere at about 150° C. for about 8 hours. After being cooled, the resultant mixture was dried under reduced pressure, and the xylene was removed. Thereafter, the resulting product was washed three times with ethyl acetate and water to obtain organic layers. The obtained organic layers were dried over MgSO₄, and then dried under reduced pressure. The resulting product was purified and recrystallized by column chromatography (dichloromethane:n-hexane) to obtain Intermediate 81-3 (yield: 62%).

### Synthesis of Compound 81

Intermediate 81-3 (1 eq) was dissolved in ortho dichlorobenezene (oDCB), and a flask was cooled to about 0° C. in a nitrogen atmosphere, and then BBr₃ (2.5 eq) dissolved in oDCB was slowly injected thereto. After dropping (addition) was completed, the temperature was elevated to about 180° C., and the mixture was stirred for about 20 hours. After being cooled to about 0° C., triethylamine was slowly dropped (added) to the flask until heating stopped to terminate the reaction, and then hexane was added to the flask, thereby extracting solids. The extracted solids were obtained by filtration. The obtained solids were purified with silica filtration, and then purified again through recrystallization in methylenechloride/hexane (MC/Hex) to obtain Compound 81. Thereafter, Compound 34 was further purified by column chromatography (dichloromethane:n-hexane) (yield: 8%).

### 2. Identification of Polycyclic Compound

The molecular weight of compounds synthesized by Synthetic Examples as described above was identified as follows.

TABLE 1

| Compound | Calc | Found |
|---|---|---|
| 1 | 1161.23 | 1162.46 |
| 20 | 1196.36 | 1196.78 |
| 34 | 1142.23 | 1142.87 |
| 61 | 967.90 | 968.56 |
| 81 | 1382.54 | 1383.12 |

### 3. Example and Comparative Example Compounds

Example Compounds and Comparative Example Compounds utilized to manufacture light emitting elements of Examples and Comparative Examples are listed in Table 2:

TABLE 2

| | |
|---|---|
| Compound 1 | 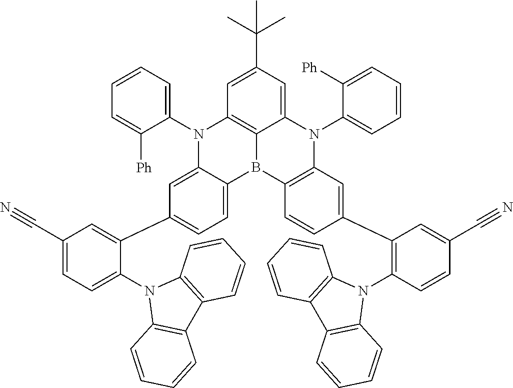 [SMILES: CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1N2c1ccccc1-c1ccccc1] |
| | 1 |
| Compound 20 | 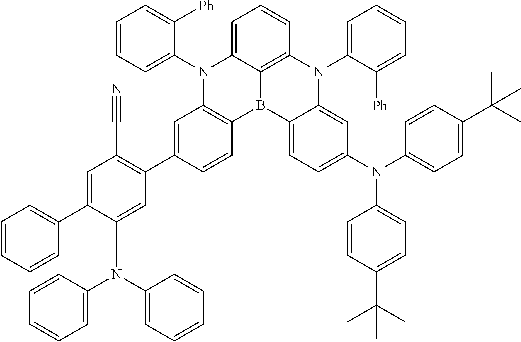 [SMILES: CC(C)(C)c1ccc(N(c2ccc(C(C)(C)C)cc2)c2ccc3c(c2)N(c2ccccc2-c2ccccc2)c2cccc4c2B3c2ccc(-c3cc(N(c5ccccc5)c5ccccc5)c(-c5ccccc5)cc3C#N)cc2N4c2ccccc2-c2ccccc2)cc1] |
| | 20 |
| Compound 34 | 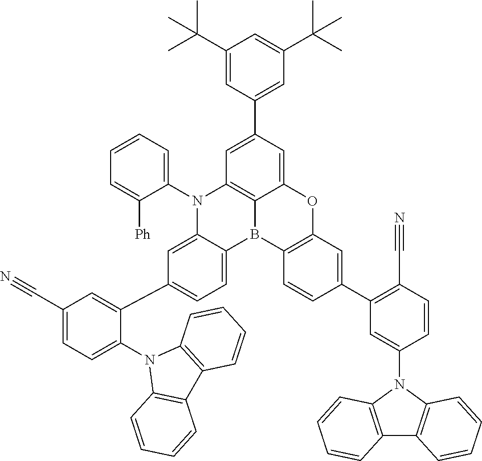 [SMILES: CC(C)(C)c1cc(-c2cc3c4c(c2)N(c2ccccc2-c2ccccc2)c2cc(-c5cc(C#N)ccc5-n5c6ccccc6c6ccccc65)ccc2B4c2ccc(-c4cc(-n5c6ccccc6c6ccccc65)ccc4C#N)cc2O3)cc(C(C)(C)C)c1] |
| | 34 |
| Compound 61 | 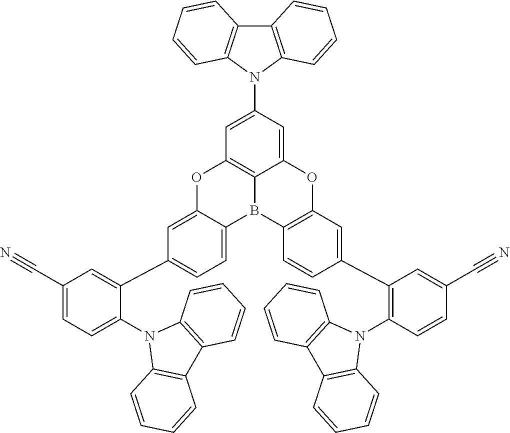 [SMILES: N#Cc1ccc(-n2c3ccccc3c3ccccc32)c(-c2ccc3c(c2)Oc2cc(-n4c5ccccc5c5ccccc54)cc4c2B3c2ccc(-c3cc(C#N)ccc3-n3c5ccccc5c5ccccc53)cc2O4)c1] |
| | 61 |
| Compound 81 | 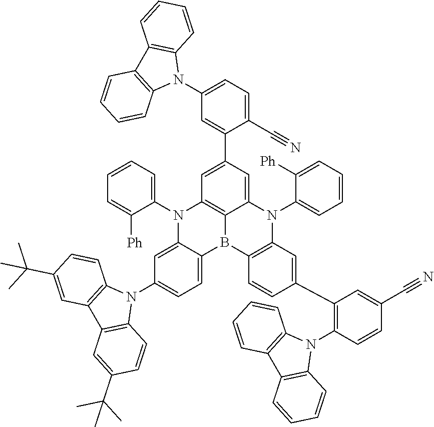 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2-n2c4ccccc4c4ccccc42)cc1N3c1ccccc1-c1ccccc1] |
| | 81 |
| Comparative Example Compound C1 | 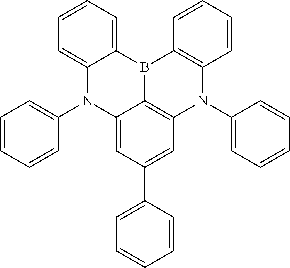 [SMILES: c1ccc(-c2cc3c4c(c2)N(c2ccccc2)c2ccccc2B4c2ccccc2N3c2ccccc2)cc1] |
| | C1 |
| Comparative Example Compound C2 | 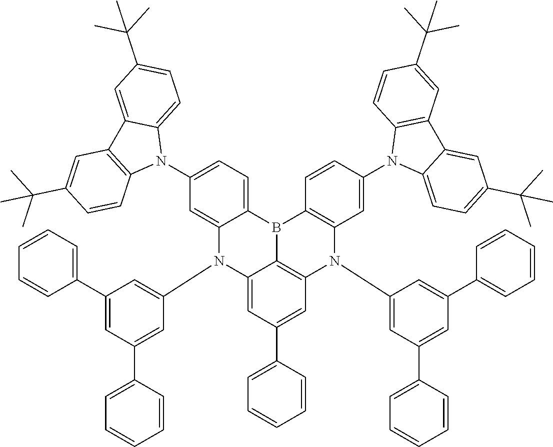 [SMILES: CC(C)(C)c1ccc2c(c1)c1cc(C(C)(C)C)ccc1n2-c1ccc2c(c1)N(c1cc(-c3ccccc3)cc(-c3ccccc3)c1)c1cc(-c3ccccc3)cc3c1B2c1ccc(-n2c4ccc(C(C)(C)C)cc4c4cc(C(C)(C)C)ccc42)cc1N3c1cc(-c2ccccc2)cc(-c2ccccc2)c1] |
| | C2 |
| Comparative Example Compound C3 | 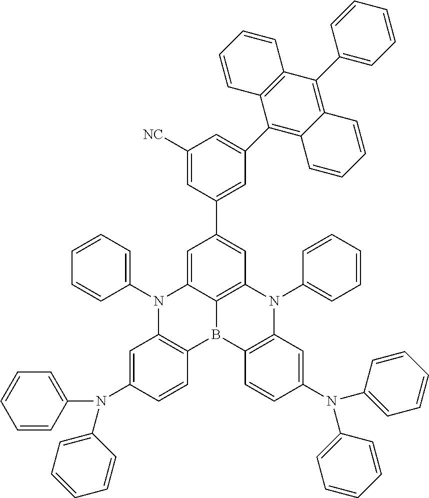 [SMILES: N#Cc1cc(-c2cc3c4c(c2)N(c2ccccc2)c2cc(N(c5ccccc5)c5ccccc5)ccc2B4c2ccc(N(c4ccccc4)c4ccccc4)cc2N3c2ccccc2)cc(-c2c3ccccc3c(-c3ccccc3)c3ccccc23)c1] |
| | C3 |
| Comparative Example Compound C4 | 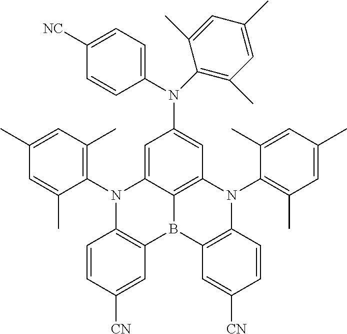 |
| | C4 |

### 4. Manufacture and Evaluation of Light Emitting Element 1

### (1) Manufacture of Light Emitting Element 1

Light emitting element 1 including the polycyclic compound of an example or Comparative Example Compound in the emission layer was manufactured as follows.

Compounds 1, 20, 34, 61, and 81 that are the polycyclic compounds of examples were utilized as a dopant material for the emission layer to manufacture the light emitting elements of Examples 1-1 to 1-5, respectively. Comparative Example Compound C1 to Comparative Example Compound C4 were utilized as a dopant material in the emission layer to manufacture the light emitting elements of Comparative Examples 1-1 to 1-4, respectively.

A glass substrate (made by Corning Co.), on which an ITO electrode of about 15 Ω/cm² (about 1200 Å) is formed as a first electrode, was cut to a size of about 50 mm×50 mm×0.7 mm, cleansed by ultrasonic waves utilizing isopropyl alcohol and pure water for about five minutes. Then, the glass substrate was irradiated with ultraviolet rays for about 30 minutes and exposed to ozone and cleansed, and was then installed on a vacuum deposition apparatus.

NPD was deposited in vacuum on the upper portion of the ITO glass substrate to form a 300 Å-thick hole injection layer. Next, H-1-19 was deposited in vacuum to form a 200 Å-thick hole transport layer. Thereafter, CzSi was deposited on the upper portion of the hole transport layer to form a 100 Å-thick emission-auxiliary layer.

On the upper portion of the emission-auxiliary layer, a host mixture, a phosphorescent sensitizer, and a dopant of Example Compound or Comparative Example Compound were co-deposited at a weight ratio of 85:14:1 to form a 200 Å-thick emission layer. The host mixture was provided by mixing HT1 and ET1 at a weight ratio of 1:1.

TSP01 was deposited on the upper portion of the emission layer to form a 200 Å-thick hole blocking layer, and TPBi was deposited on the upper portion of the hole blocking layer to form a 300 Å-thick electron transport layer. Then, LiF was deposited on the upper portion of the electron transport layer to form a 10 Å-thick electron injection layer, and Al was deposited on the upper portion of the electron injection layer to form a 3,000 Å-thick second electrode. Then, P4 was deposited on the upper portion of the second electrode to form a 700 Å-thick capping layer, thereby manufacturing light emitting element 1.

The compounds utilized to manufacture light emitting element 1 are as follows:

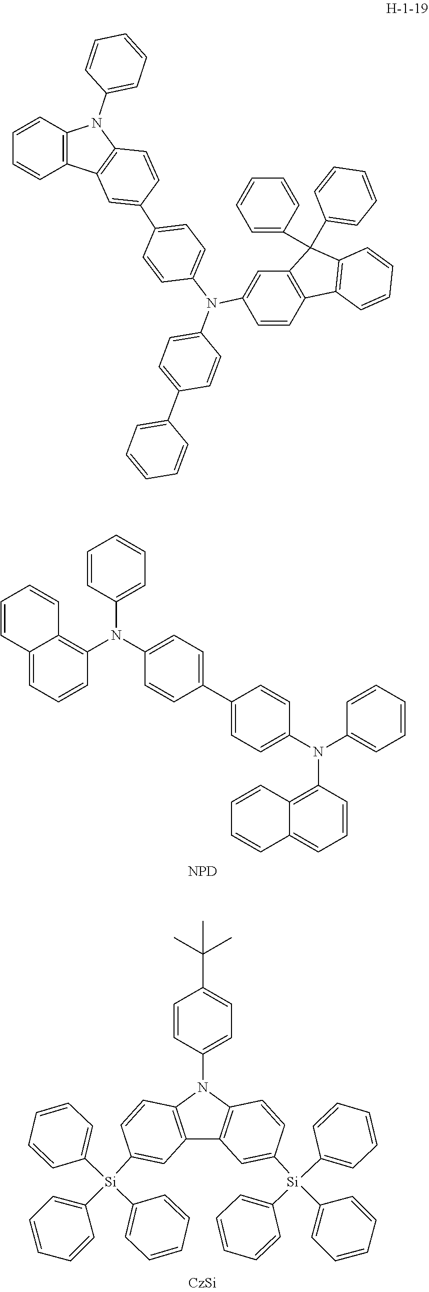 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4cccc5ccccc45)cc3)cc2)c2cccc3ccccc23)cc1 ; "NPD" ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

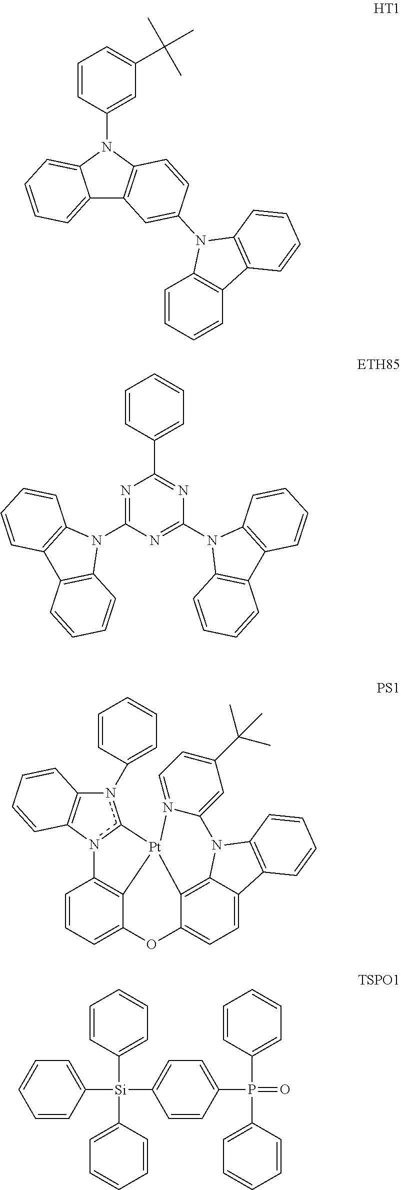

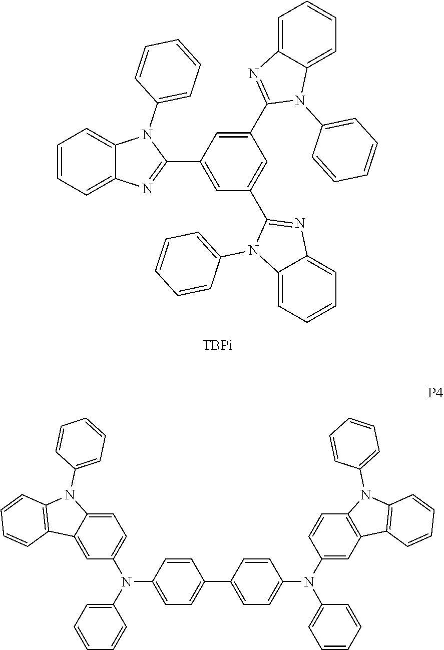 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### (2) Evaluation of Light Emitting Element 1

Driving voltages (V), luminous efficiencies (cd/A), maximum external quantum efficiencies (EQEmax, %), service life (%), and emission colors of the light emitting elements according to Examples 1-1 to 1-5 and Comparative Examples 1-1 to 1-4 are listed in Table 3. The driving voltages (V), luminous efficiencies (cd/A), maximum external quantum efficiencies (EQEmax, %), and emission colors of the light emitting elements were measured at a brightness of 1,0000 cd/m2 by utilizing Keithley MU 236 and a luminance meter PR650. For the element service life, the time taken to reach 95% brightness relative to an initial brightness was measured as a service life (T95), and shown as a relative value assuming the service life in Comparative Example 1-1 as 100%.

TABLE 3

| | | | | | Maximum | | |
|---|---|---|---|---|---|---|---|
| | | | | | external | | |
| | Hole | | Driving | Luminous | quantum | Service | |
| | transport | | voltage | efficiency | efficiency | life | Luminous |
| Division | layer | Dopant | (V) | (cd/A) | (%) | (%) | color |
| Example 1- | H-1-19 | Compound | 4.2 | 24.2 | 23.1 | 213 | Blue |
| 1 | | 1 | | | | | |
| Example 1- | H-1-19 | Compound | 4.3 | 23.8 | 22.6 | 164 | Blue |
| 2 | | 20 | | | | | |
| Example 1- | H-1-19 | Compound | 4.4 | 24.9 | 23.4 | 231 | Blue |
| 3 | | 34 | | | | | |
| Example 1- | H-1-19 | Compound | 4.4 | 22.8 | 21.5 | 187 | Blue |
| 4 | | 61 | | | | | |
| Example 1- | H-1-19 | Compound | 4.3 | 23.9 | 22.4 | 242 | Blue |
| 5 | | 81 | | | | | |
| Comparative | H-1-19 | Comparative | 4.5 | 16.5 | 15.3 | 100 | Blue |
| Example | | Example | | | | | |
| 1-1 | | Compound | | | | | |
| | | C1 | | | | | |
| Comparative | H-1-19 | Comparative | 4.1 | 25.8 | 24.2 | 135 | Blue |
| Example | | Example | | | | | |
| 1-2 | | Compound | | | | | |
| | | C2 | | | | | |
| Comparative | H-1-19 | Comparative | 4.6 | 25.8 | 24.2 | 164 | Blue |
| Example | | Example | | | | | |
| 1-3 | | Compound | | | | | |
| | | C3 | | | | | |
| Comparative | H-1-19 | Comparative | 4.7 | 22.0 | 20.8 | 141 | Blue |
| Example | | Example | | | | | |
| 1-4 | | Compound | | | | | |
| | | C4 | | | | | |

Referring to the results of Table 3, Examples 1-1 to 1-5 of the present disclosure exhibit the element characteristics of higher luminous efficiency, improved maximum external quantum efficiency, and long service life as compared with Comparative Example 1-1. In some embodiments, Examples 1-1 to 1-5 of the present disclosure exhibit similar levels of luminous efficiency and maximum external quantum efficiency and improved service life characteristics of the light emitting elements as compared with Comparative Example 1-2. Examples 1-1 to 1-5 exhibit improved levels of luminous efficiency and maximum external quantum efficiency and equivalent or improved service life characteristics of the light emitting elements as compared with Comparative Examples 1-3 and 1-4.

### 5. Manufacture and Evaluation of Light Emitting Element 2

### (1) Manufacture of Light Emitting Element 2

The light emitting elements of Examples 2-1 to 2-5 were manufactured in substantially the same manner as the light emitting elements of Examples 1-1 to 1-5 except that the phosphorescent sensitizer was not utilized when the emission layer was formed. The light emitting elements of Comparative Examples 2-1 to 2-4 were manufactured in substantially the same manner as the light emitting elements of Comparative Examples 1-1 to 1-4 except that the phosphorescent sensitizer was not utilized when the emission layer was formed. For the light emitting elements of Example Examples 2-1 to 2-5 and Comparative Example 2-1 to 2-4, when the emission layer was formed, a host mixture and a dopant were provided at a weight ratio of 99:1 and co-deposited to a thickness of about 200 Å.

### (2) Evaluation of Light Emitting Element 2

Driving voltages (V), luminous efficiencies (cd/A), maximum external quantum efficiencies (EQEmax, %), service life (%), and emission colors of the light emitting elements according to Examples 2-1 to 2-5 and Comparative Examples 2-1 to 2-4 are listed in Table 4. The driving voltages (V), luminous efficiencies (cd/A), maximum external quantum efficiencies (EQEmax, %), and emission colors of the light emitting elements were measured at a brightness of 1,0000 cd/m2 by utilizing Keithley MU 236 and a luminance meter PR650. For the element service life, the time taken to reach 95% brightness relative to an initial brightness was measured as a service life (T95), and shown as a relative value assuming the service life in Comparative Example 2-1 as 100%.

TABLE 4

| | | | | | Maximum | | |
|---|---|---|---|---|---|---|---|
| | | | | | external | | |
| | Hole | | Driving | Luminous | quantum | Service | |
| | transport | | voltage | efficiency | efficiency | life | Luminous |
| Division | layer | Dopant | (V) | (cd/A) | (%) | (%) | color |
| Example 2- | H-1-19 | Compound | 5.3 | 8.6 | 8.1 | 190 | Blue |
| 1 | | 1 | | | | | |
| Example 2- | H-1-19 | Compound | 5.1 | 8.7 | 8.5 | 153 | Blue |
| 2 | | 20 | | | | | |
| Example 2- | H-1-19 | Compound | 5.2 | 8.1 | 7.9 | 211 | Blue |
| 3 | | 34 | | | | | |
| Example 2- | H-1-19 | Compound | 5.1 | 7.9 | 7.5 | 164 | Blue |
| 4 | | 61 | | | | | |
| Example 2- | H-1-19 | Compound | 5.2 | 8.5 | 7.9 | 198 | Blue |
| 5 | | 81 | | | | | |
| Comparative | H-1-19 | Comparative | 5.3 | 6.6 | 6.3 | 100 | Blue |
| Example | | Example | | | | | |
| 2-1 | | Compound | | | | | |
| | | C1 | | | | | |
| Comparative | H-1-19 | Comparative | 5.3 | 7.8 | 7.6 | 161 | Blue |
| Example | | Example | | | | | |
| 2-2 | | Compound | | | | | |
| | | C2 | | | | | |
| Comparative | H-1-19 | Comparative | 5.3 | 7.8 | 7.6 | 122 | Blue |
| Example | | Example | | | | | |
| 2-3 | | Compound | | | | | |
| | | C3 | | | | | |
| Comparative | H-1-19 | Comparative | 5.3 | 8.6 | 8.1 | 87 | Blue |
| Example | | Example | | | | | |
| 2-4 | | Compound | | | | | |
| | | C4 | | | | | |

Referring to the results of Table 4, Examples 2-1 to 2-5 of the present disclosure exhibit the element characteristics of higher luminous efficiency, equivalent or improved maximum external quantum efficiency, and long service life as compared with Comparative Examples 2-1 and 2-3. Examples 2-1 to 2-5 of the present disclosure exhibit higher luminous efficiency and equivalent or improved maximum external quantum efficiency characteristics as compared with Comparative Example 2-2, and for example, Examples 2-1, and 2-3 to 2-5 have improved service life characteristics as compared with Comparative Example 2-2. Examples 2-1 to 2-5 exhibit equivalent luminous efficiency and maximum external quantum efficiency characteristics, and significantly improved service life characteristics as compared with Comparative Example 2-4.

The polycyclic compound of an example has, as a core, a planar pentacyclic fused ring containing a boron atom (B) as a ring-forming atom, and includes, as a substituent, a carbazole derivative or an arylamine derivative via a benzonitrile as a linker at the para-position with the boron atom of the core part, and when utilized as a material for the emission layer, may contribute to high efficiency and improving service life of the light emitting element. The polycyclic compound of an example includes the carbazole derivative or arylamine derivative as a substituent by utilizing the benzonitrile as a linker, thus the distortion in the molecule is controlled or selected, and thus the improved stability may be exhibited. Accordingly, the light emitting element including the polycyclic compound of an example may have improved luminous efficiency and service life characteristics.

In some embodiments, the polycyclic compound includes the carbazole derivative or arylamine derivative as a substituent by utilizing the benzonitrile as a linker so that the multiple resonance in the compound molecule is activated, and the polycyclic compound has high oscillator strength (f) and high absorbance, thus improving light extraction efficiency of the light emitting element and elevating the contribution of delayed fluorescence, thereby increasing luminous efficiency.

The polycyclic compound of an example has a structure including the core part of the fused ring containing a boron atom as a ring-forming atom and a hetero substituent substituted at the core part via the benzonitrile group as a linker so that the sterical structure due to the distortion between the hetero substituent and the core part improves the stability of the entire compound, and increased luminous efficiency characteristics due to the delayed fluorescence may be exhibited. In some embodiments, the light emitting element including this polycyclic compound of an example may exhibit long service life characteristics while maintaining excellent or suitable luminous efficiency.

The light emitting element of an embodiment may include the polycyclic compound of an embodiment, thereby exhibiting high efficiency and long service life characteristics.

The polycyclic compound of an embodiment may include a substituent including a boron-containing core part and benzonitrile, thereby contributing to service life improvement and luminous efficiency increase of the light emitting element.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1; and
at least one of a second compound represented by Formula HT-1, a third compound represented by Formula ET-1, or a fourth compound represented by Formula M-b: 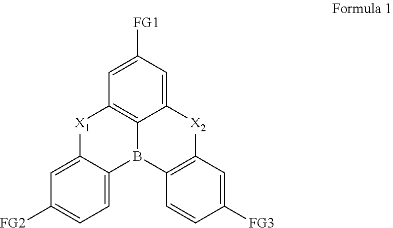
wherein, in Formula 1,
X₁ and X₂ are each independently NRₓ, O, or S,
Rₓ is a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
at least one of FG1, FG2, or FG3 is represented by Formula 2-1 or Formula 2-2, and the FG1, FG2, or FG3 that are not represented by Formula 2-1 or Formula 2-2 are each independently a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, 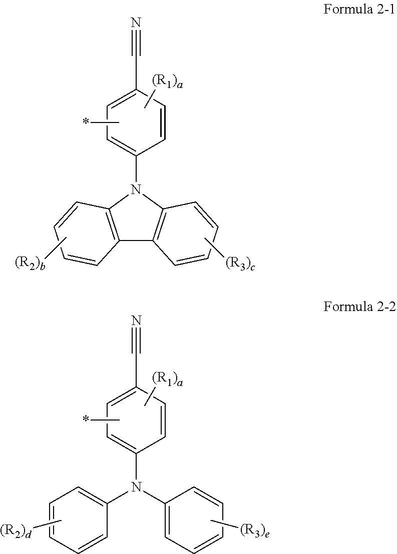
wherein, in Formula 2-1 and Formula 2-2,
a is an integer from 0 to 3,
b and c are each independently an integer from 0 to 4,
d and e are each independently an integer from 0 to 5,
R₁ to R₃ are each independently a hydrogen atom, a deuterium atom, a halogen atom, a cyano group, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, 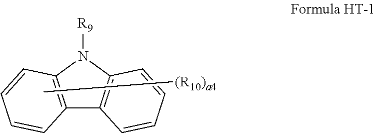
wherein, in Formula HT-1,
a4 is an integer from 0 to 8, and
R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms, 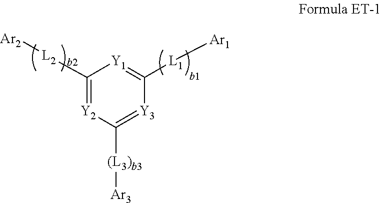
wherein, in Formula ET-1,
at least one selected from among Y₁ to Y₃ is N, and the Y₁ to Y₃ that are not N are CRₐ,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and Formula M-b 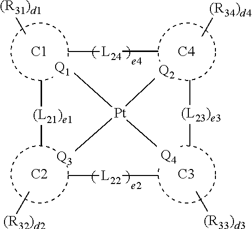
wherein, in Formula M-b,
Q₁ to C4 are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 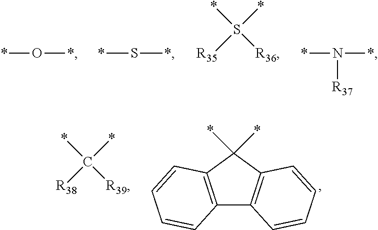
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

2. The light emitting element of claim 1, wherein Formula 1 is represented by any one selected from among Formula 1-1 to Formula 1-3: 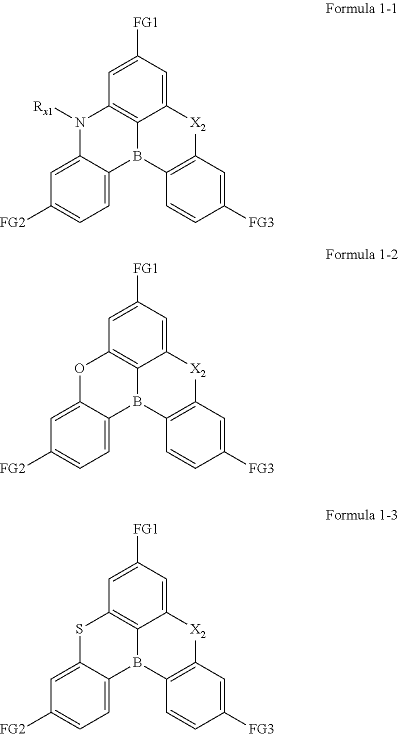
wherein, in Formula 1-1, X₂ is NRₓ₂, O, or S, and
Rₓ₁ and Rₓ₂ are each independently a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-2 and Formula 1-3, X₂ is O or S, and
in Formula 1-1 to Formula 1-3, FG1, FG2, and FG3 are the same as defined in Formula 1.

3. The light emitting element of claim 1, wherein Formula 1 is represented by any one selected from among Formula 1A to Formula 1E: 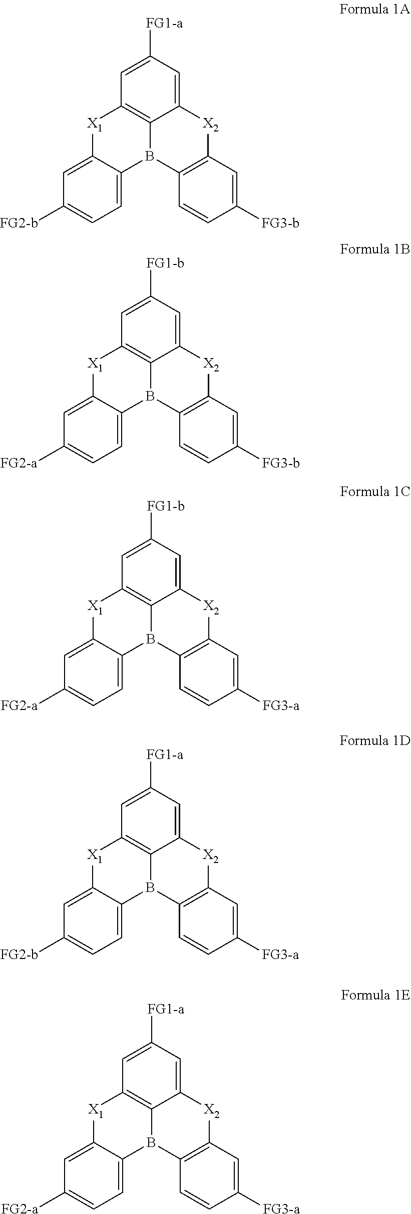
wherein, in Formula 1A to Formula 1E, FG1-a, FG2-a, and FG3-a are each independently represented by Formula 2-1 or Formula 2-2,
FG1-b, FG2-b, and FG3-b are each independently a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, and
X₁ and X₂ are the same as defined in Formula 1.

4. The light emitting element of claim 3, wherein FG1-b, FG2-b, and FG3-b are each independently a hydrogen atom, an unsubstituted alkyl group having 1 to 10 carbon atoms, a deuterium-substituted alkyl group having 1 to 10 carbon atoms, a substituted or unsubstituted phenyl group, a substituted or unsubstituted terphenyl group, a substituted or unsubstituted diphenylamine group, or a substituted or unsubstituted carbazole group.

5. The light emitting element of claim 1, wherein Rₓ is a substituted or unsubstituted phenyl group.

6. The light emitting element of claim 1, wherein R₁ is represented by any one selected from among R₁₋ₐ to R_{1-c}: 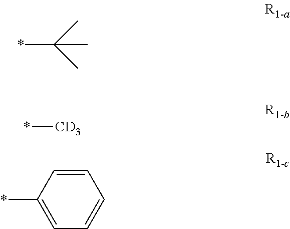
wherein, in R_{1-b}, D is a deuterium atom.

7. The light emitting element of claim 1, wherein at least one selected from among X₁, X₂, and FG1 to FG3 in Formula 1 comprises a deuterium atom, or a substituent containing a deuterium atom.

8. The light emitting element of claim 1, further comprising a hole transport region which is between the first electrode and the emission layer and comprises a hole transport compound represented by Formula H-1: 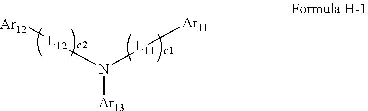
wherein, in Formula H-1,
c1 and c2 are each independently an integer from 0 to 10,
L₁₁ and L₁₂ are each independently a direct linkage, a substituted or unsubstituted arylene group having 6 to 30 ring-forming carbon atoms, or a substituted or unsubstituted heteroarylene group having 2 to 30 ring-forming carbon atoms,
Ar₁₁ and Ar₁₂ are each independently a substituted or unsubstituted aryl group having 6 to 30 ring-forming carbon atoms, or a substituted or unsubstituted heteroaryl group having 2 to 30 ring-forming carbon atoms, and
Ar₁₃ is a substituted or unsubstituted aryl group having 6 to 30 ring-forming carbon atoms.

9. The light emitting element of claim 1, wherein the emission layer comprises the first compound, the second compound, and the third compound.

10. The light emitting element of claim 1, wherein the emission layer comprises the first compound, the second compound, the third compound, and the fourth compound.

11. The light emitting element of claim 1, wherein the emission layer is configured to emit blue light.

12. The light emitting element of claim 1, wherein the first compound is represented by any one selected from among compounds of Compound Group 1: 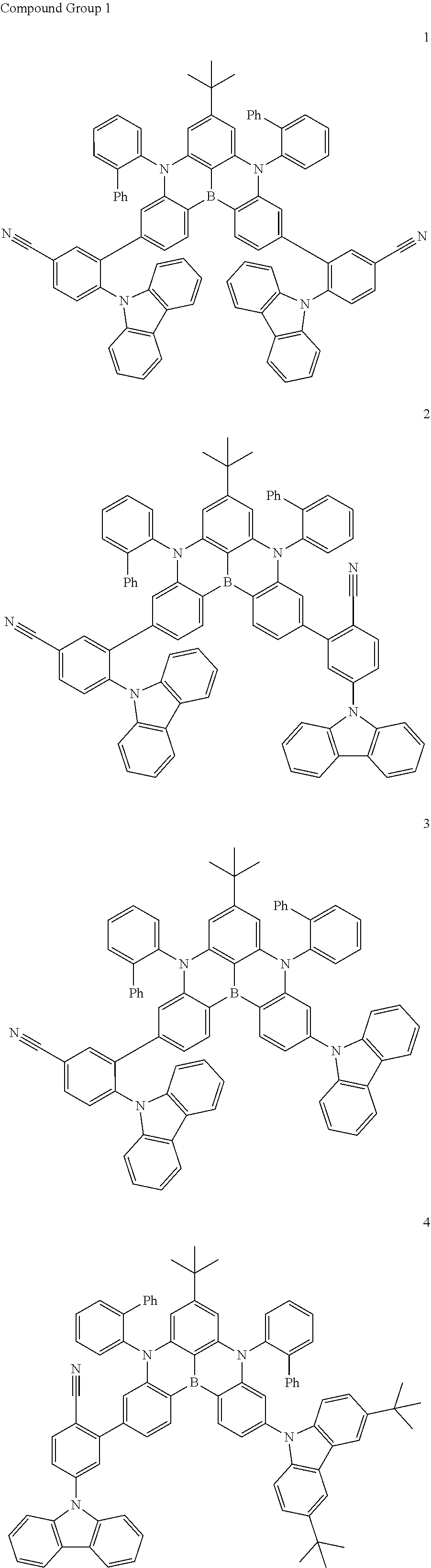 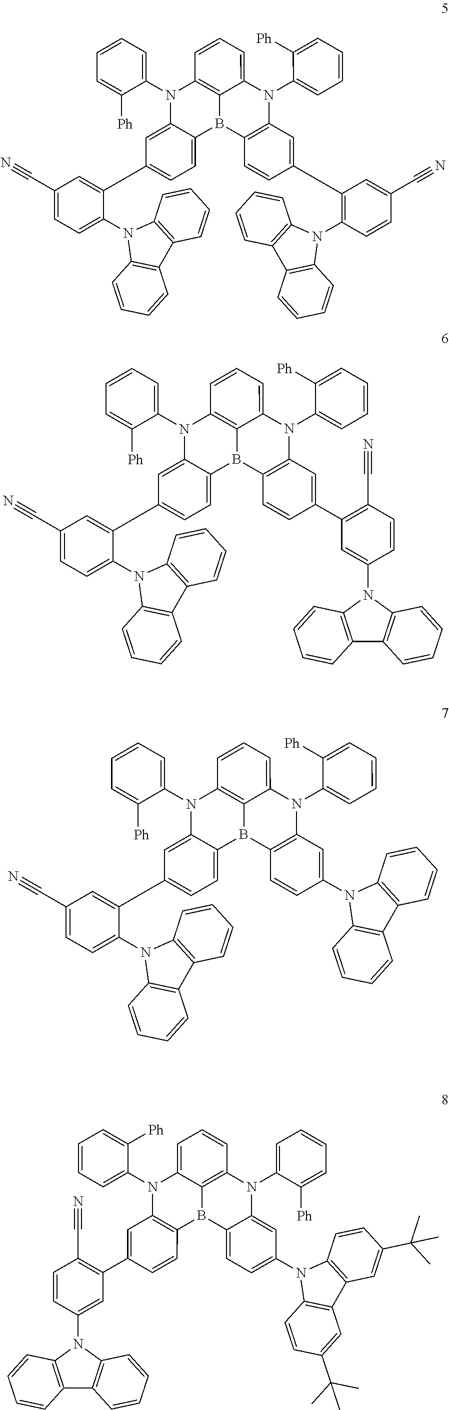 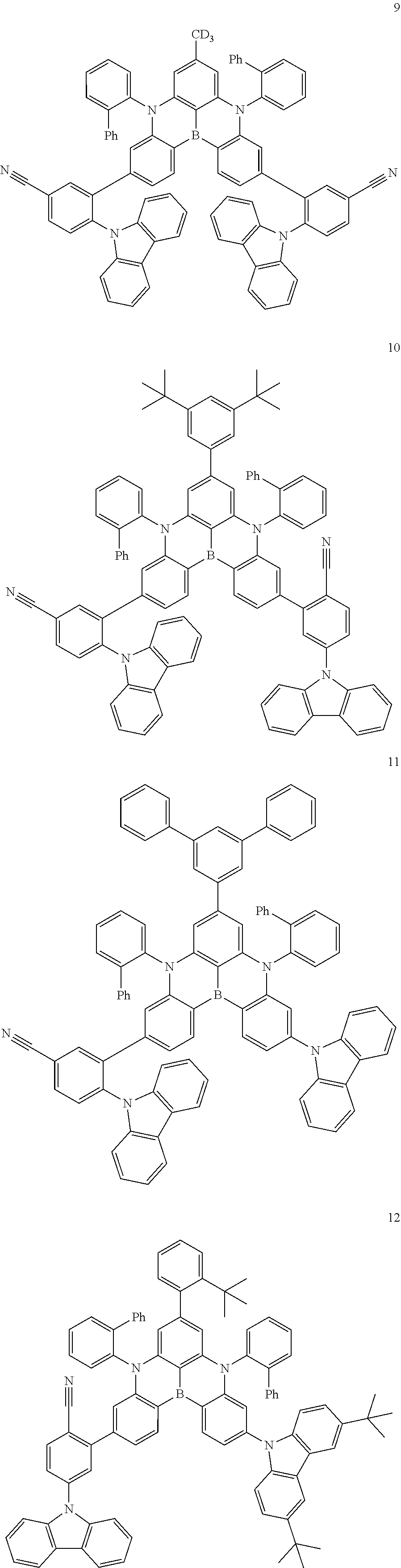 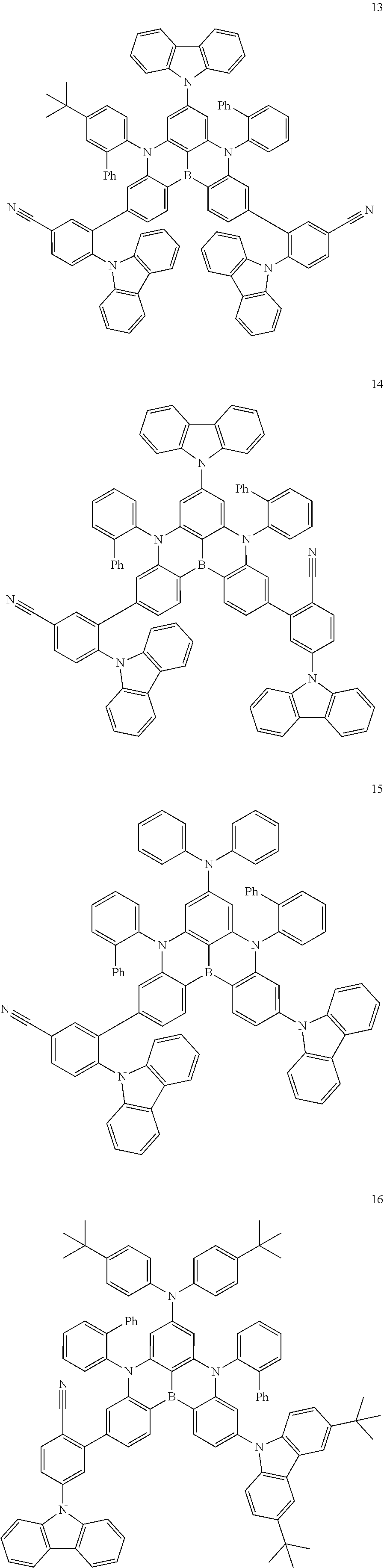 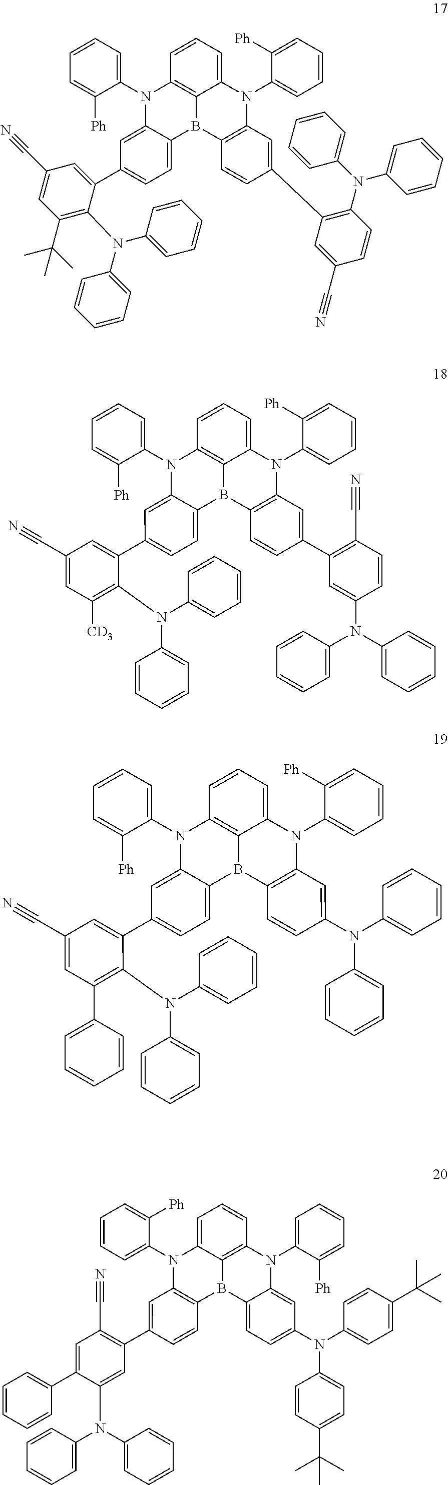 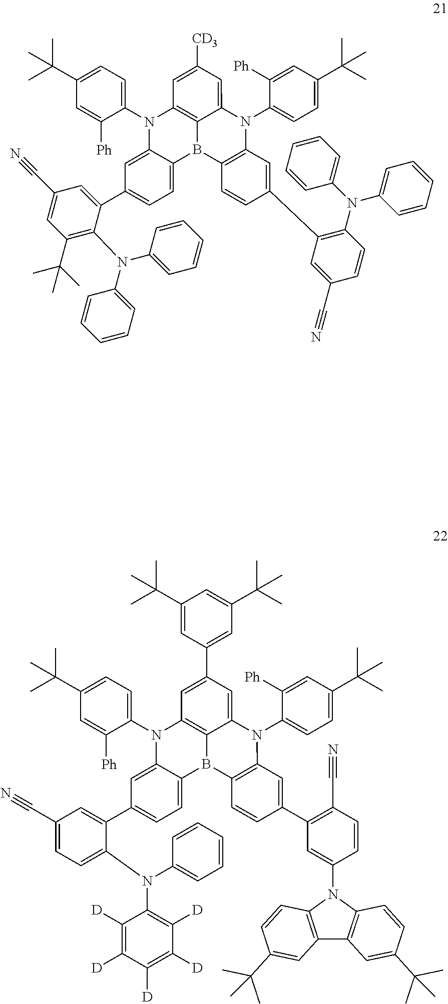 [SMILES: [2H]C([2H])([2H])c1cc2c3c(c1)N(c1ccc(C(C)(C)C)cc1-c1ccccc1)c1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1N2c1ccc(C(C)(C)C)cc1-c1ccccc1 ; [2H]c1c([2H])c([2H])c(N(c2ccccc2)c2ccc(C#N)cc2-c2ccc3c(c2)N(c2ccc(C(C)(C)C)cc2-c2ccccc2)c2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2N4c2ccc(C(C)(C)C)cc2-c2ccccc2)c([2H])c1[2H]] 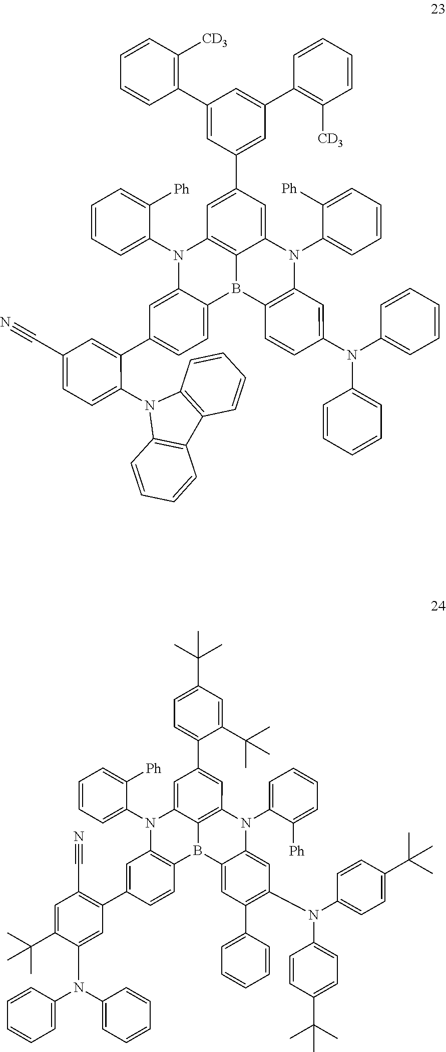 [SMILES: [2H]C([2H])([2H])c1ccccc1-c1cc(-c2cc3c4c(c2)N(c2ccccc2-c2ccccc2)c2cc(N(c5ccccc5)c5ccccc5)ccc2B4c2ccc(-c4cc(C#N)ccc4-n4c5ccccc5c5ccccc54)cc2N3c2ccccc2-c2ccccc2)cc(-c2ccccc2C([2H])([2H])[2H])c1 ; CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4N(c4ccccc4-c4ccccc4)c4cc(-c5ccc(C(C)(C)C)cc5C(C)(C)C)cc(c42)N3c2ccccc2-c2ccccc2)cc1] 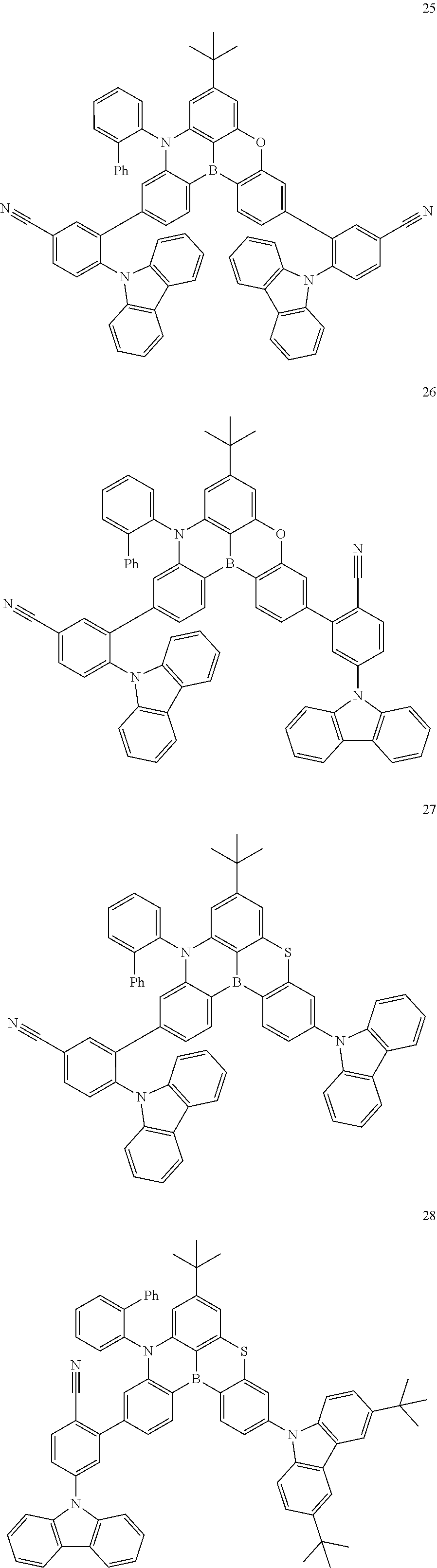 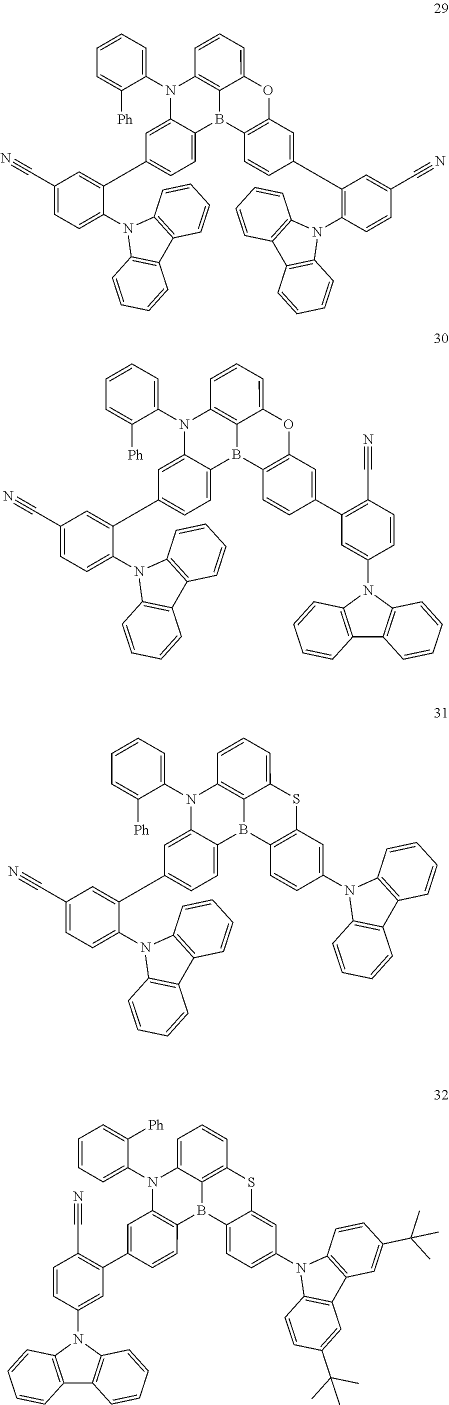 [SMILES: N#Cc1ccc(-n2c3ccccc3c3ccccc32)c(-c2ccc3c(c2)Oc2cccc4c2B3c2ccc(-c3cc(C#N)ccc3-n3c5ccccc5c5ccccc53)cc2N4c2ccccc2-c2ccccc2)c1 ; N#Cc1ccc(-n2c3ccccc3c3ccccc32)c(-c2ccc3c(c2)N(c2ccccc2-c2ccccc2)c2cccc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)N(c2ccccc2-c2ccccc2)c2cccc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cccc3c1B2c1ccc(-c2cc(-n4c5ccccc5c5ccccc54)ccc2C#N)cc1N3c1ccccc1-c1ccccc1] 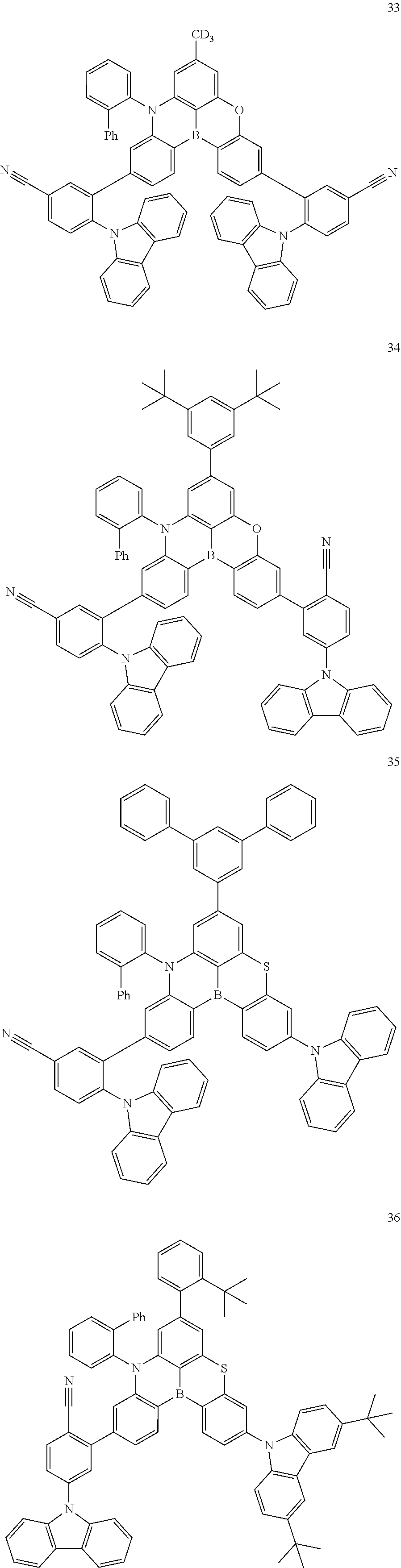 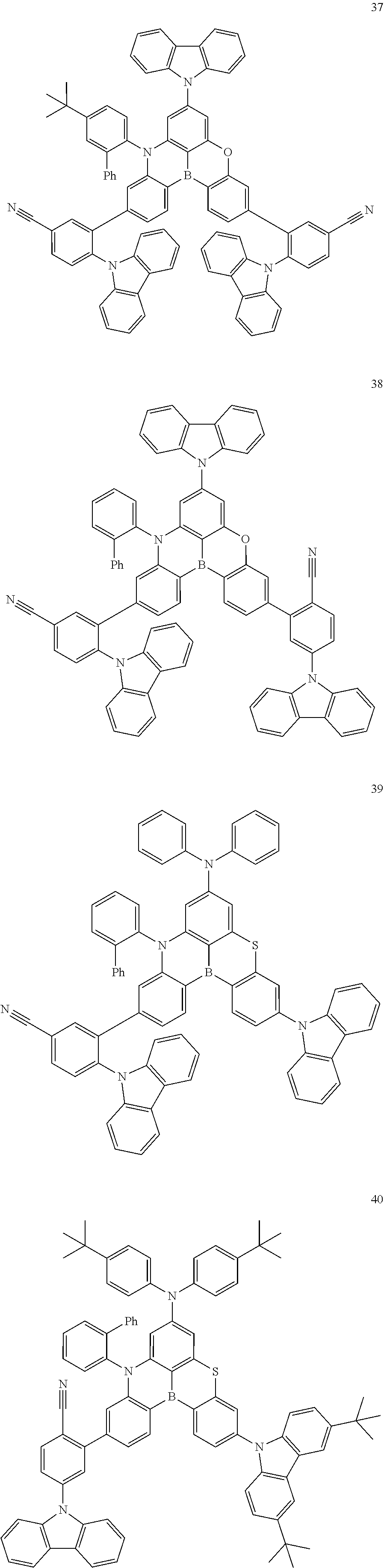 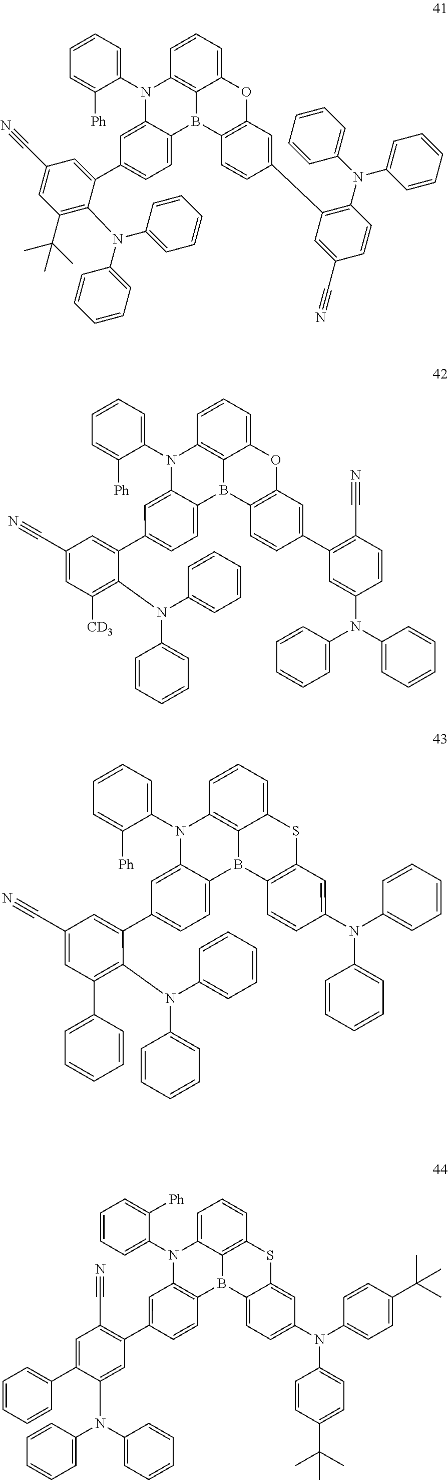 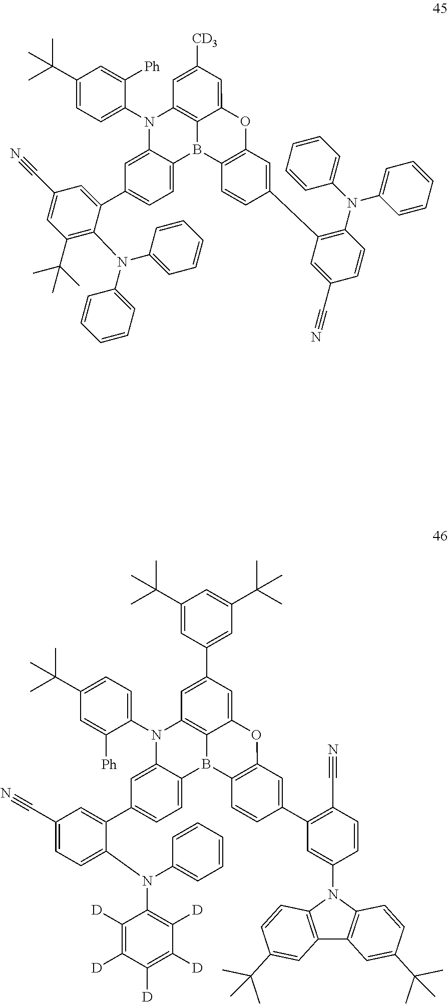 [SMILES: [2H]C([2H])([2H])c1cc2c3c(c1)N(c1ccc(C(C)(C)C)cc1-c1ccccc1)c1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1O2 ; [2H]c1c([2H])c([2H])c(N(c2ccccc2)c2ccc(C#N)cc2-c2ccc3c(c2)N(c2ccc(C(C)(C)C)cc2-c2ccccc2)c2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2O4)c([2H])c1[2H]] 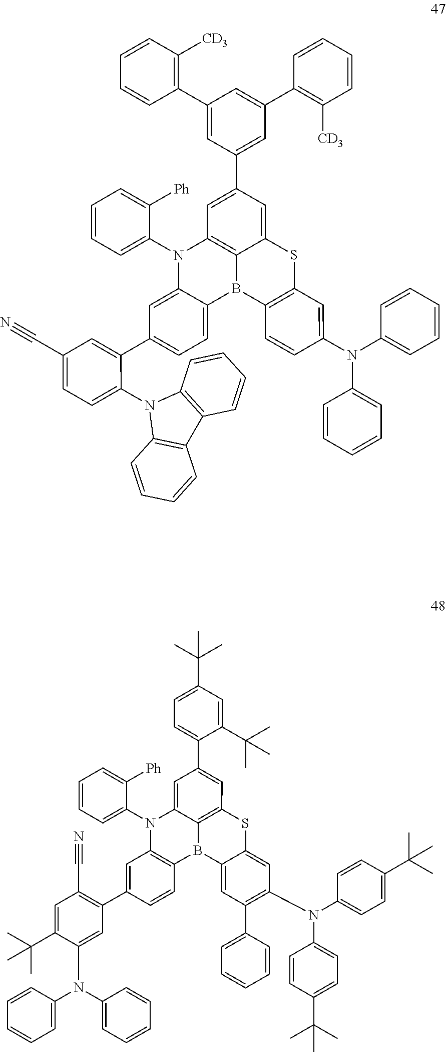 [SMILES: [2H]C([2H])([2H])c1ccccc1-c1cc(-c2cc3c4c(c2)N(c2ccccc2-c2ccccc2)c2cc(-c5cc(C#N)ccc5-n5c6ccccc6c6ccccc65)ccc2B4c2ccc(N(c4ccccc4)c4ccccc4)cc2S3)cc(-c2ccccc2C([2H])([2H])[2H])c1 ; CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4N(c4ccccc4-c4ccccc4)c4cc(-c5ccc(C(C)(C)C)cc5C(C)(C)C)cc(c42)S3)cc1] 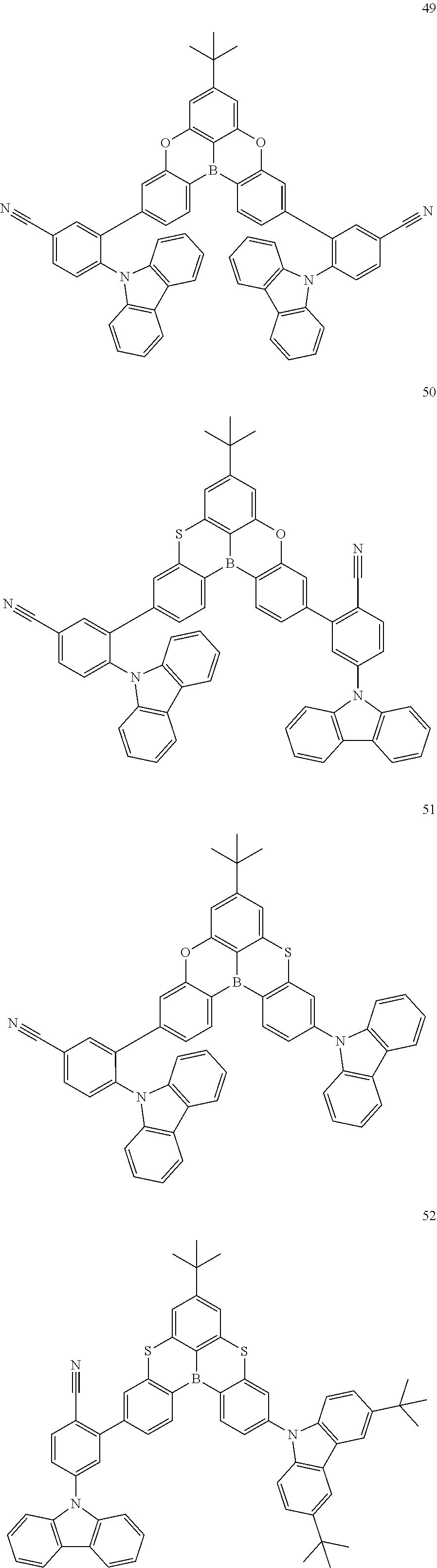 [SMILES: CC(C)(C)c1cc2c3c(c1)Oc1cc(-c4cc(C#N)ccc4-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)Sc1cc(-c4cc(C#N)ccc4-n4c5ccccc5c5ccccc54)ccc1B3c1ccc(-c3cc(-n4c5ccccc5c5ccccc54)ccc3C#N)cc1O2 ; CC(C)(C)c1cc2c3c(c1)Sc1cc(-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)Sc1cc(-n4c5ccc(C(C)(C)C)cc5c5cc(C(C)(C)C)ccc54)ccc1B3c1ccc(-c3cc(-n4c5ccccc5c5ccccc54)ccc3C#N)cc1S2] 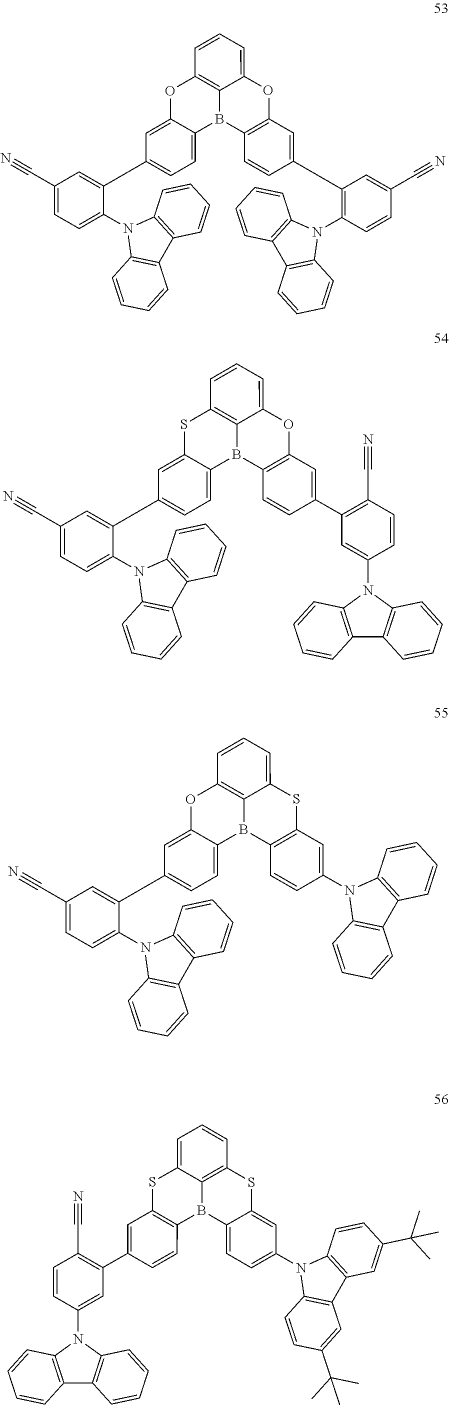 [SMILES: N#Cc1ccc(-n2c3ccccc3c3ccccc32)c(-c2ccc3c(c2)Oc2cccc4c2B3c2ccc(-c3cc(C#N)ccc3-n3c5ccccc5c5ccccc53)cc2O4)c1 ; N#Cc1ccc(-n2c3ccccc3c3ccccc32)c(-c2ccc3c(c2)Sc2cccc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)Oc2cccc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cccc3c1B2c1ccc(-c2cc(-n4c5ccccc5c5ccccc54)ccc2C#N)cc1S3] 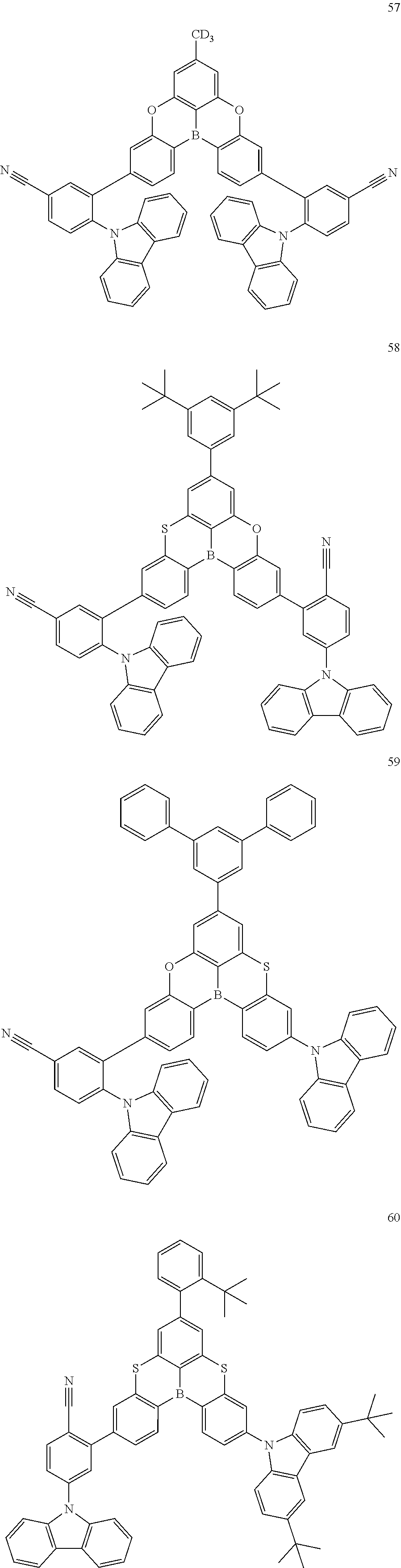 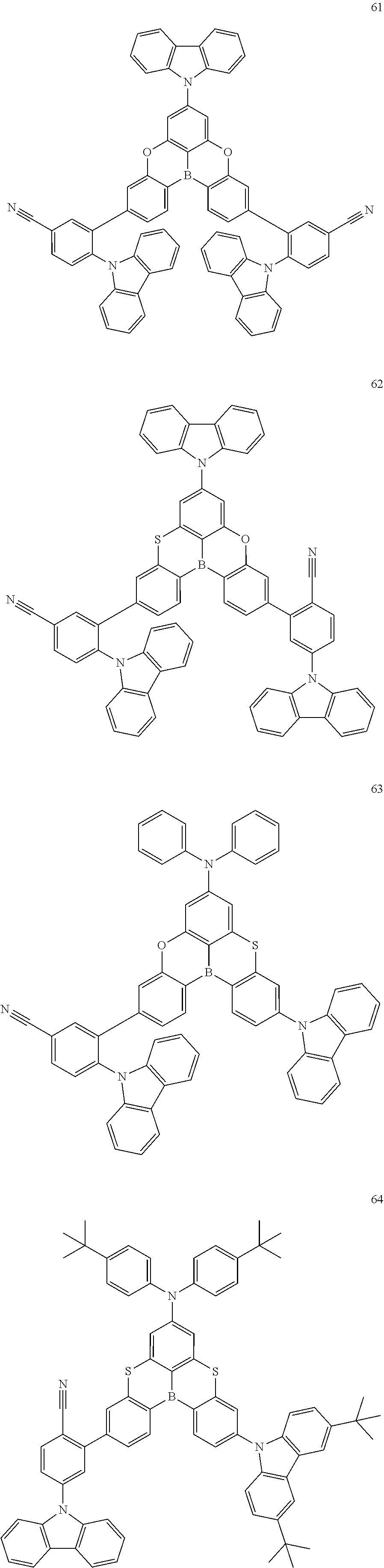 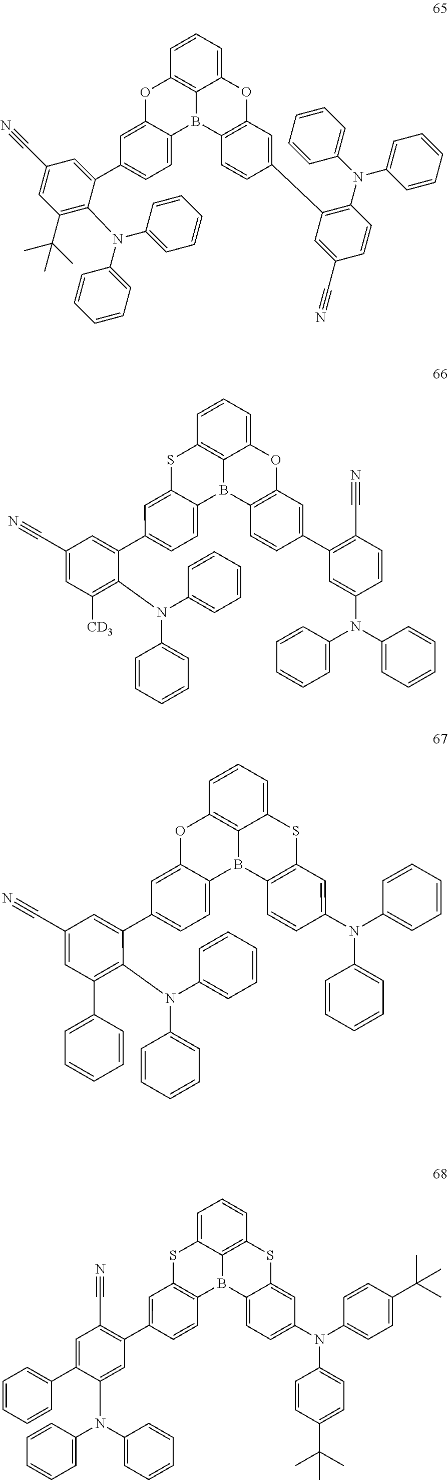 [SMILES: CC(C)(C)c1cc(C#N)cc(-c2ccc3c(c2)Oc2cccc4c2B3c2ccc(-c3cc(C#N)ccc3N(c3ccccc3)c3ccccc3)cc2O4)c1N(c1ccccc1)c1ccccc1 ; [2H]C([2H])([2H])c1cc(C#N)cc(-c2ccc3c(c2)Sc2cccc4c2B3c2ccc(-c3cc(N(c5ccccc5)c5ccccc5)ccc3C#N)cc2O4)c1N(c1ccccc1)c1ccccc1 ; N#Cc1cc(-c2ccccc2)c(N(c2ccccc2)c2ccccc2)c(-c2ccc3c(c2)Oc2cccc4c2B3c2ccc(N(c3ccccc3)c3ccccc3)cc2S4)c1 ; CC(C)(C)c1ccc(N(c2ccc(C(C)(C)C)cc2)c2ccc3c(c2)Sc2cccc4c2B3c2ccc(-c3cc(N(c5ccccc5)c5ccccc5)c(-c5ccccc5)cc3C#N)cc2S4)cc1] 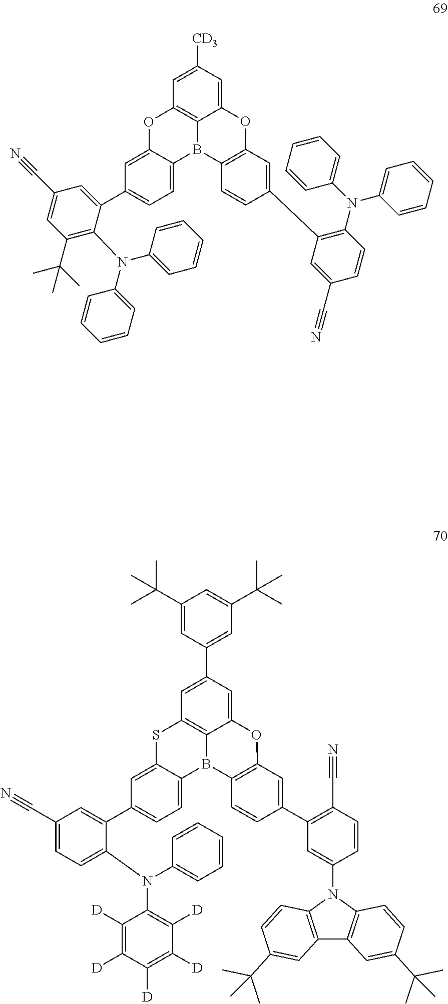 [SMILES: [2H]C([2H])([2H])c1cc2c3c(c1)Oc1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1O2 ; [2H]c1c([2H])c([2H])c(N(c2ccccc2)c2ccc(C#N)cc2-c2ccc3c(c2)Sc2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2O4)c([2H])c1[2H]] 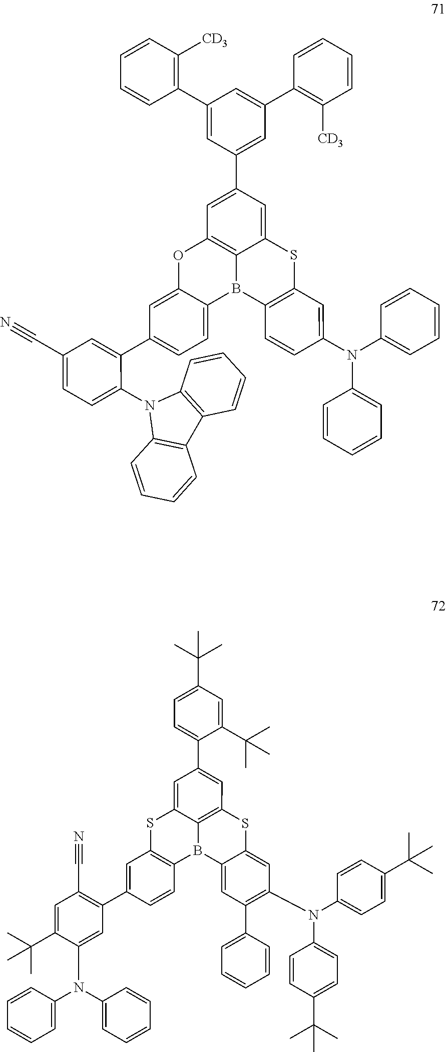 [SMILES: [2H]C([2H])([2H])c1ccccc1-c1cc(-c2cc3c4c(c2)Sc2cc(N(c5ccccc5)c5ccccc5)ccc2B4c2ccc(-c4cc(C#N)ccc4-n4c5ccccc5c5ccccc54)cc2O3)cc(-c2ccccc2C([2H])([2H])[2H])c1 ; CC(C)(C)c1ccc(N(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4Sc4cc(-c5ccc(C(C)(C)C)cc5C(C)(C)C)cc(c42)S3)cc1] 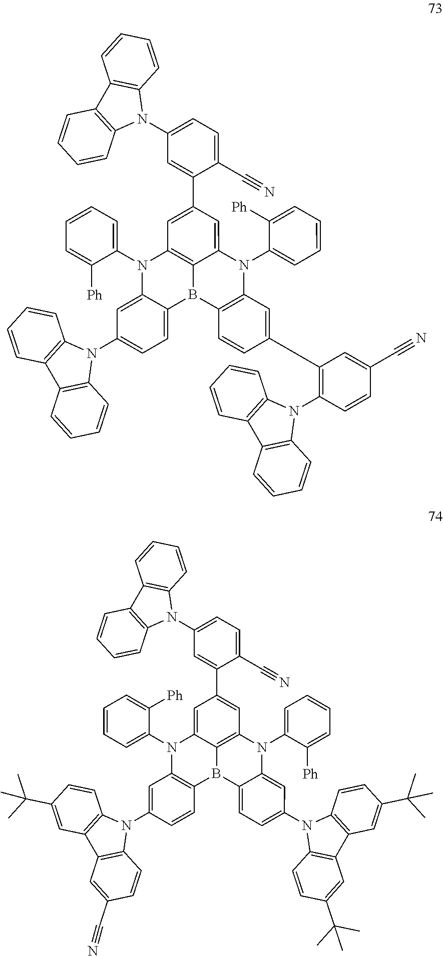 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 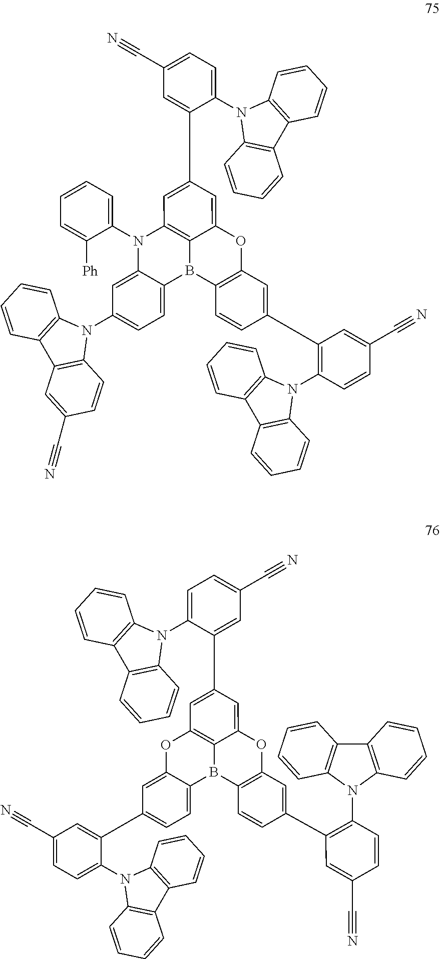 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 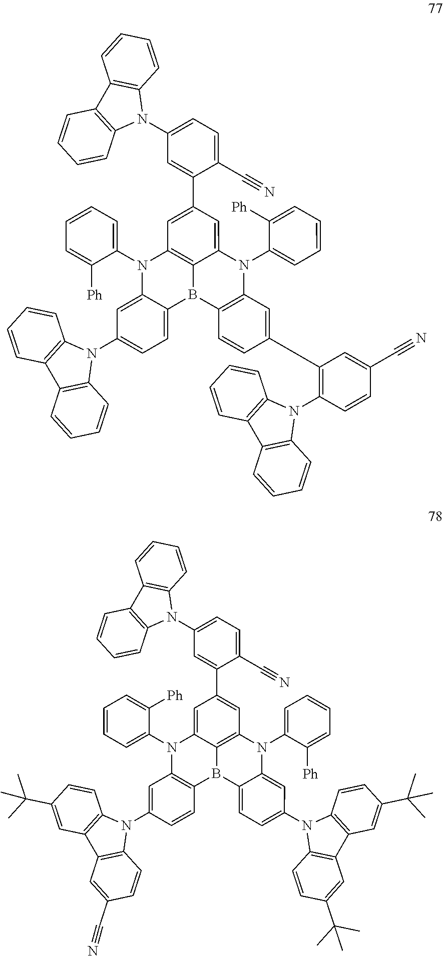 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 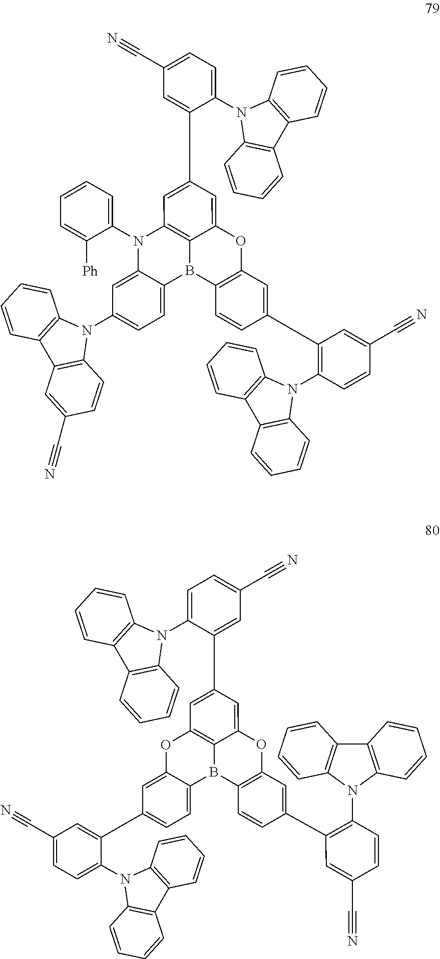 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 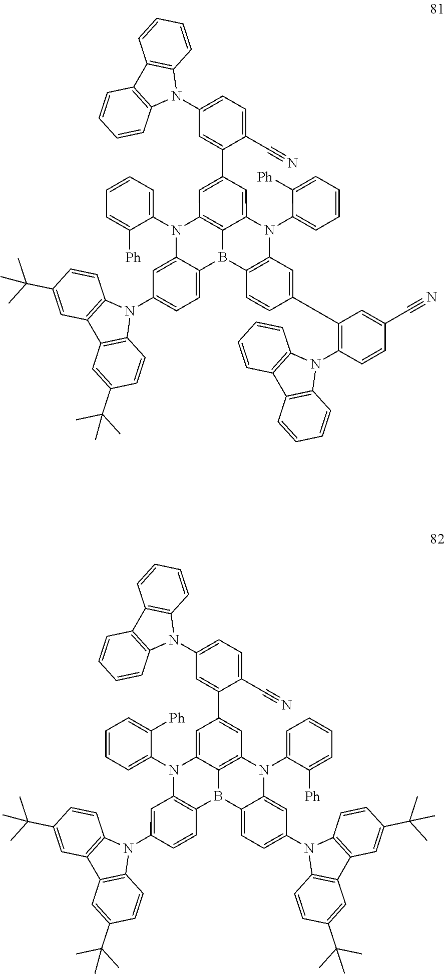 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2-n2c4ccccc4c4ccccc42)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 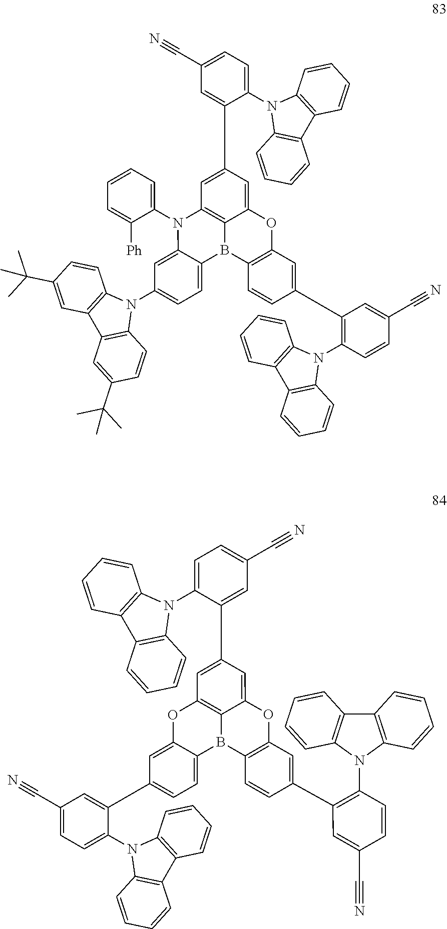 [SMILES: CC(C)(C)c1ccc2c(c1)c1cc(C(C)(C)C)ccc1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2-n2c4ccccc4c4ccccc42)cc1O3 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 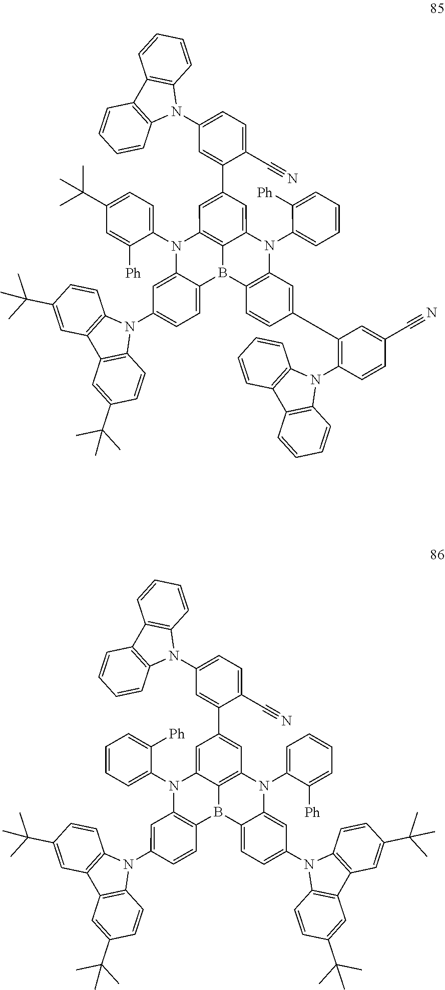 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4N(c4ccccc4-c4ccccc4)c4cc(-c5cc(-n6c7ccccc7c7ccccc76)ccc5C#N)cc2c43)c(-c2ccccc2)c1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 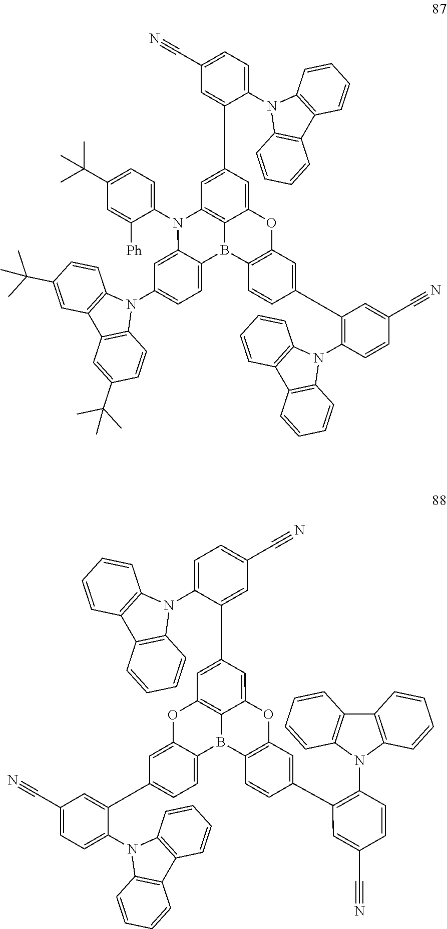 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4Oc4cc(-c5cc(C#N)ccc5-n5c6ccccc6c6ccccc65)cc2c43)c(-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 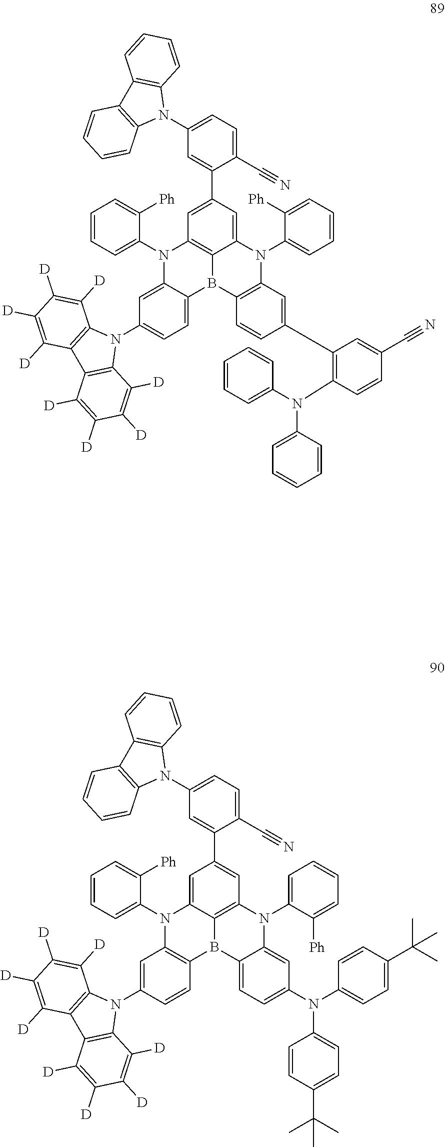 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(N(c2ccc(C(C)(C)C)cc2)c2ccc(C(C)(C)C)cc2)cc1N3c1ccccc1-c1ccccc1] 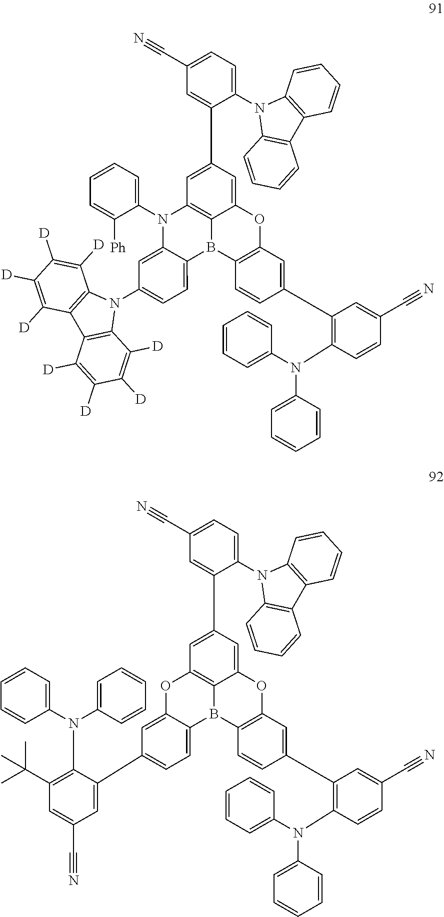 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1] 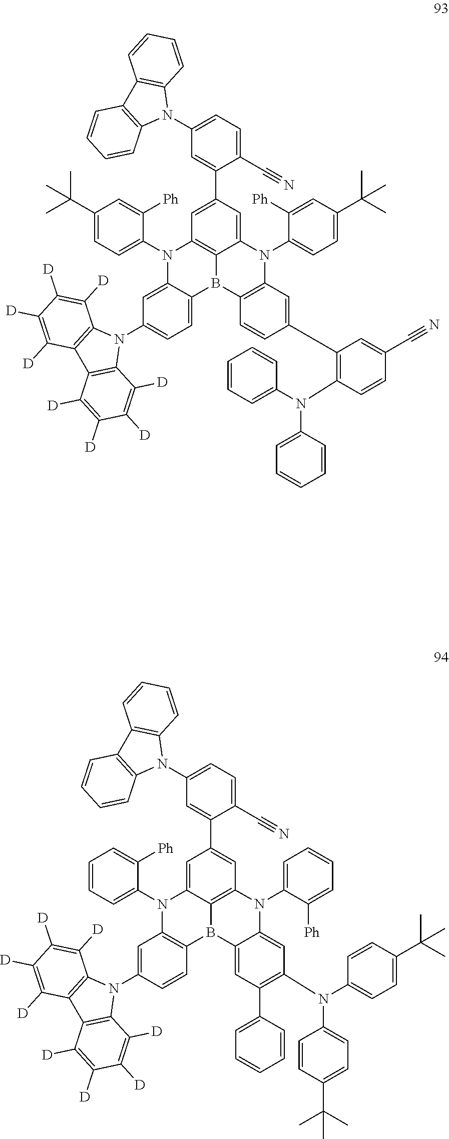 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1cc(-c2ccccc2)c(N(c2ccc(C(C)(C)C)cc2)c2ccc(C(C)(C)C)cc2)cc1N3c1ccccc1-c1ccccc1] 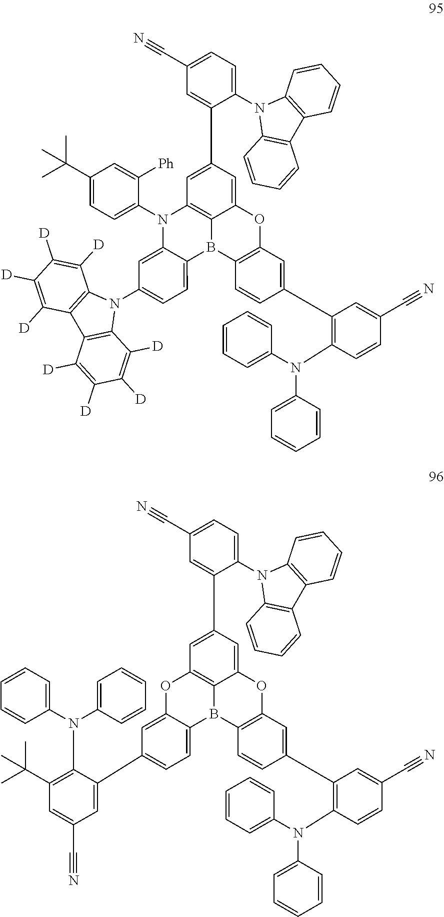 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1] 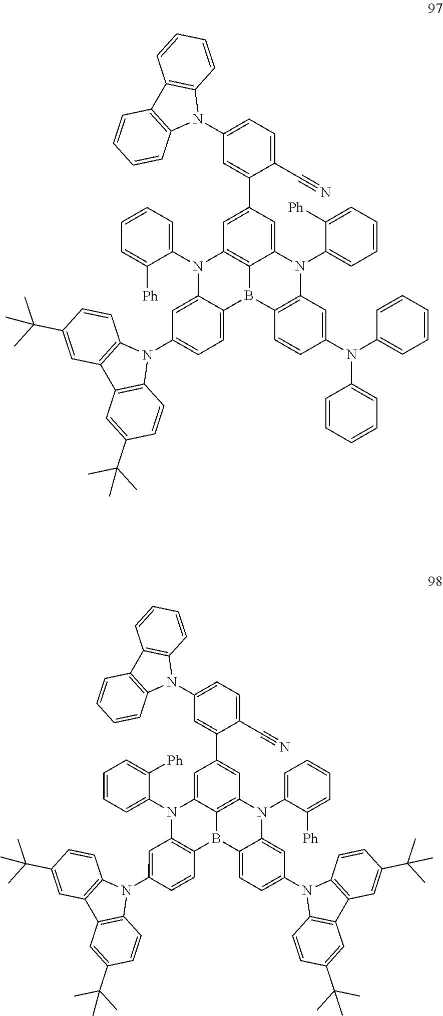 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(N(c2ccccc2)c2ccccc2)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 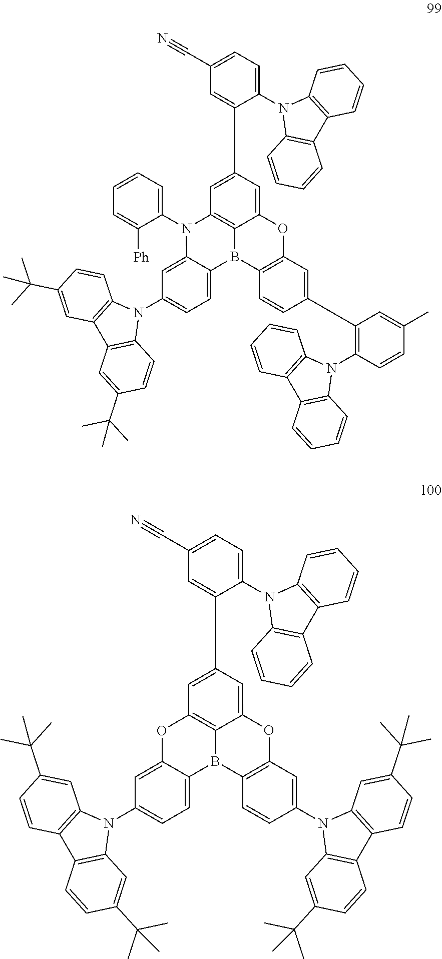 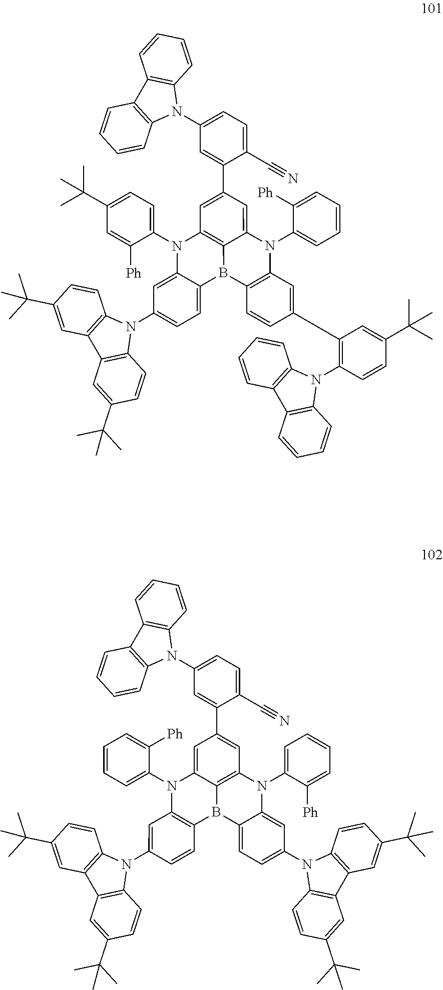 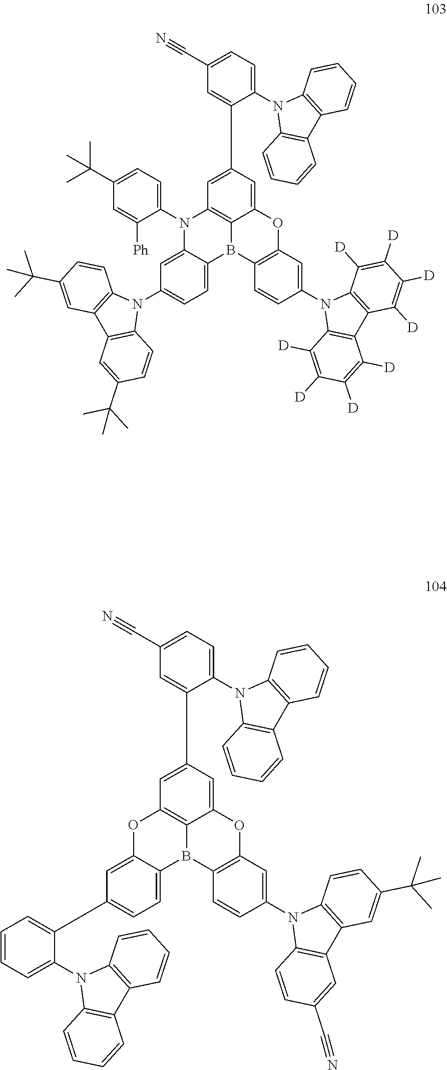 [SMILES: [2H]c1c([2H])c([2H])c2c(c1[2H])c1c([2H])c([2H])c([2H])c([2H])c1n2-c1ccc2c(c1)Oc1cc(-c3cc(C#N)ccc3-n3c4ccccc4c4ccccc43)cc3c1B2c1ccc(-n2c4ccc(C(C)(C)C)cc4c4cc(C(C)(C)C)ccc42)cc1N3c1ccc(C(C)(C)C)cc1-c1ccccc1 ; CC(C)(C)c1ccc2c(c1)c1cc(C#N)ccc1n2-c1ccc2c(c1)Oc1cc(-c3cc(C#N)ccc3-n3c4ccccc4c4ccccc43)cc3c1B2c1ccc(-c2ccccc2-n2c4ccccc4c4ccccc42)cc1O3] 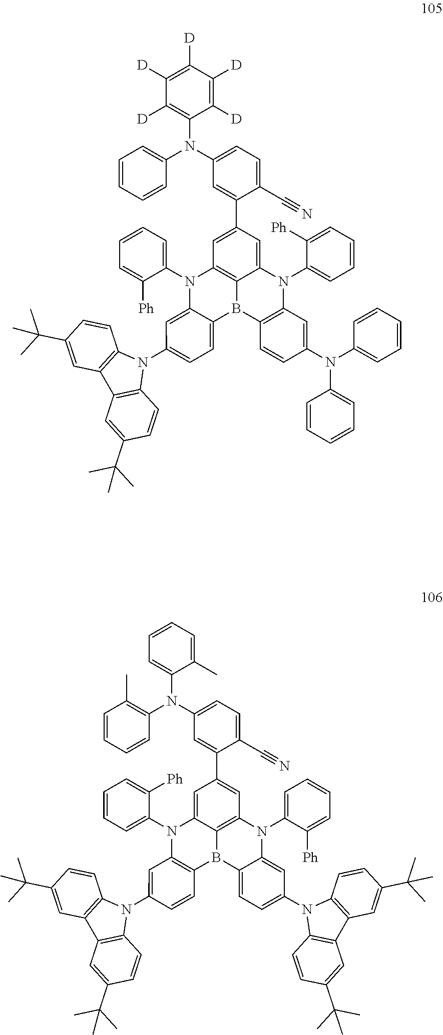 [SMILES: [2H]c1c([2H])c([2H])c(N(c2ccccc2)c2ccc(C#N)c(-c3cc4c5c(c3)N(c3ccccc3-c3ccccc3)c3cc(-n6c7ccc(C(C)(C)C)cc7c7cc(C(C)(C)C)ccc76)ccc3B5c3ccc(N(c5ccccc5)c5ccccc5)cc3N4c3ccccc3-c3ccccc3)c2)c([2H])c1[2H] ; Cc1ccccc1N(c1ccc(C#N)c(-c2cc3c4c(c2)N(c2ccccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccccc2-c2ccccc2)c1)c1ccccc1C] 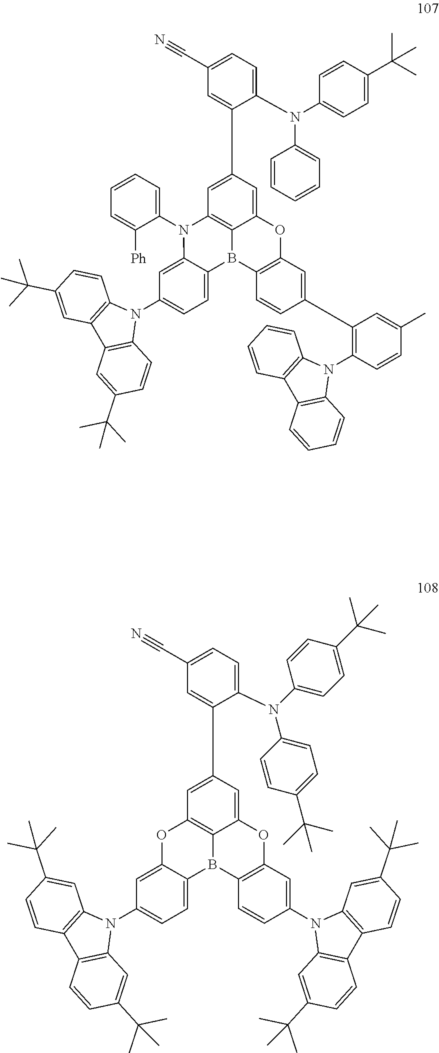 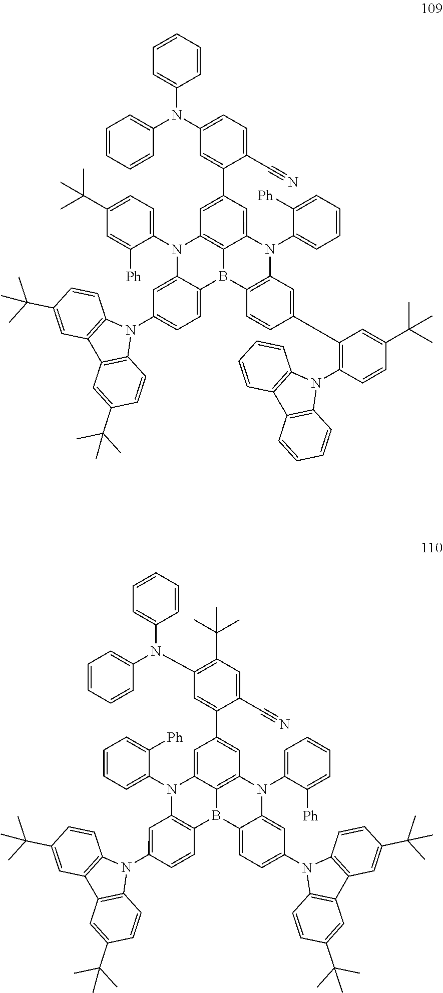 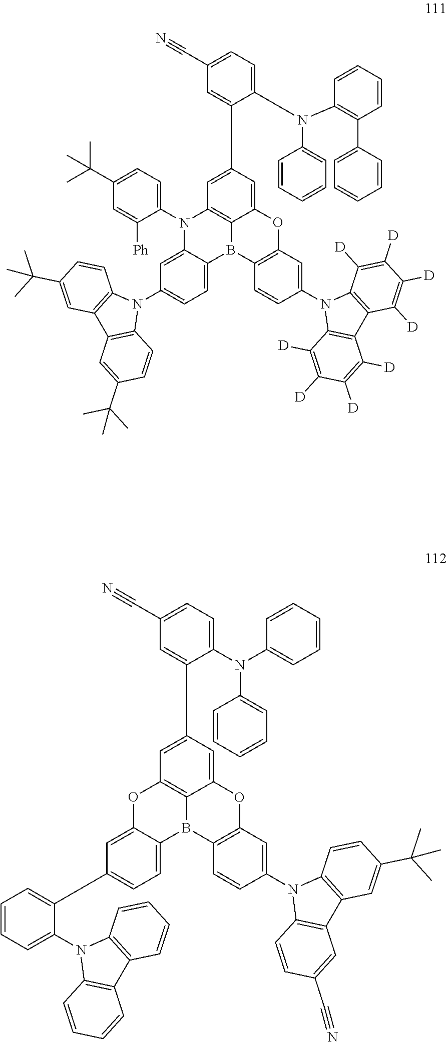
wherein in Compound Group 1, D is a deuterium atom, and Ph is a phenyl group.

13. A polycyclic compound represented by Formula 1: 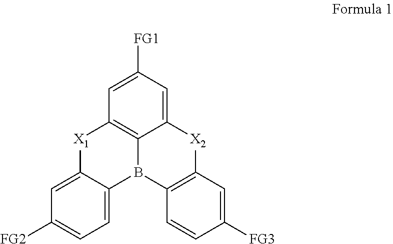
wherein, in Formula 1,
X₁ and X₂ are each independently NRₓ, O, or S,
Rₓ is a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
at least one of FG1, FG2, or FG3 is represented by Formula 2-1 or Formula 2-2, and the FG1, FG2, or FG3 that are not represented by Formula 2-1 or Formula 2-2 are each independently a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, 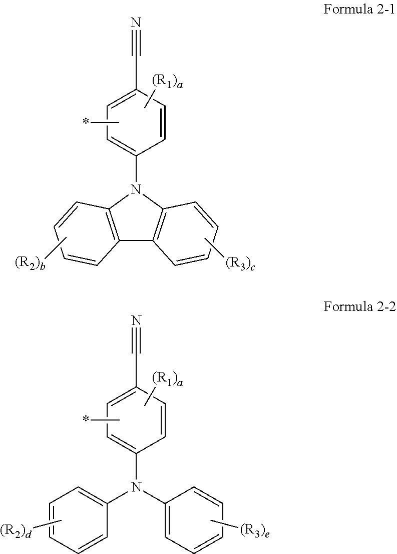
wherein, in Formula 2-1 and Formula 2-2,
a is an integer from 0 to 3,
b and c are each independently an integer from 0 to 4,
d and e are each independently an integer from 0 to 5, and
R₁ to R₃ are each independently a hydrogen atom, a deuterium atom, a halogen atom, a cyano group, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms.

14. The polycyclic compound of claim 13, wherein Formula 1 is represented by any one selected from among Formula 1-1 to Formula 1-3: 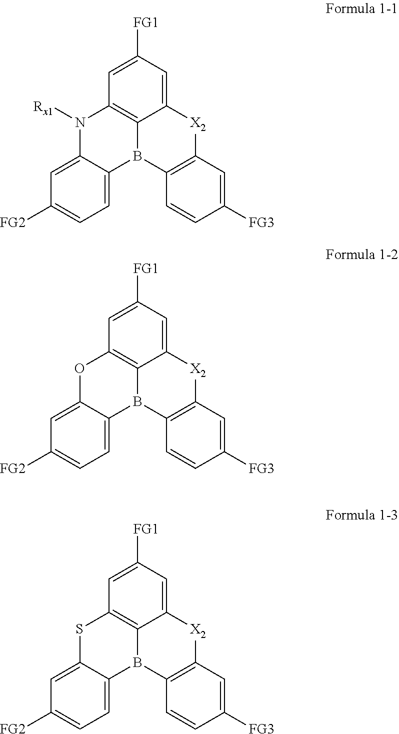
wherein, in Formula 1-1, X₂ is NRₓ₂, O, or S, and
Rₓ₁ and Rₓ₂ are each independently a hydrogen atom, a deuterium atom, a halogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms,
in Formula 1-2 and Formula 1-3, X₂ is O or S, and
in Formula 1-1 to Formula 1-3, FG1, FG2, and FG3 are the same as defined in Formula 1.

15. The polycyclic compound of claim 13, wherein Formula 1 is represented by any one selected from among Formula 1A to Formula 1E: 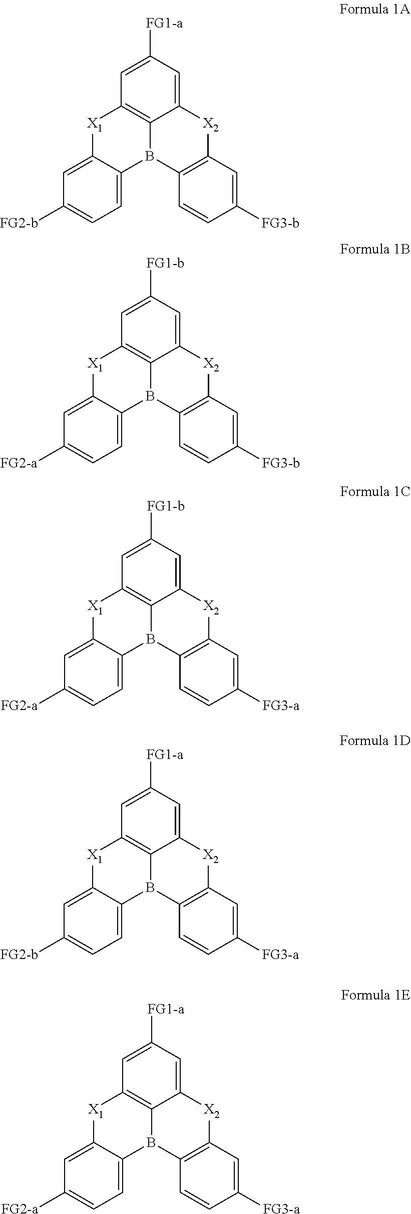
wherein, in Formula 1A to Formula 1E, FG1-a, FG2-a, and FG3-a are each independently represented by Formula 2-1 or Formula 2-2,
FG1-b, FG2-b, and FG3-b are each independently a hydrogen atom, a deuterium atom, a halogen atom, a substituted or unsubstituted alkyl group having 1 to 10 carbon atoms, a substituted or unsubstituted amine group, a substituted or unsubstituted aryl group having 6 to 30 ring-forming carbon atoms, or a substituted or unsubstituted heteroaryl group having 2 to 30 ring-forming carbon atoms, and
X₁ and X₂ are the same as defined in Formula 1.

16. The polycyclic compound of claim 15, wherein FG1-b, FG2-b, and FG3-b are each independently a hydrogen atom, an unsubstituted alkyl group having 1 to 10 carbon atoms, a deuterium-substituted alkyl group having 1 to 10 carbon atoms, a substituted or unsubstituted phenyl group, a substituted or unsubstituted terphenyl group, a substituted or unsubstituted diphenylamine group, or a substituted or unsubstituted carbazole group.

17. The polycyclic compound of claim 13, wherein Rₓ is a substituted or unsubstituted phenyl group.

18. The polycyclic compound of claim 13, wherein R₁ is represented by any one selected from among R₁₋ₐ to R_{1-c}: 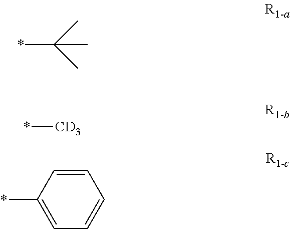
wherein, in R_{1-b}, D is a deuterium atom.

19. The polycyclic compound of claim 13, wherein at least one selected from among X₁, X₂, and FG1 to FG3 in Formula 1 comprises a deuterium atom, or a substituent containing a deuterium atom.

20. The polycyclic compound of claim 13, wherein the compound represented by Formula 1 is a thermally activated delayed fluorescence material.

21. The polycyclic compound of claim 13, wherein Formula 1 is represented by any one selected from among compounds of Compound Group 1:
Compound Group 1 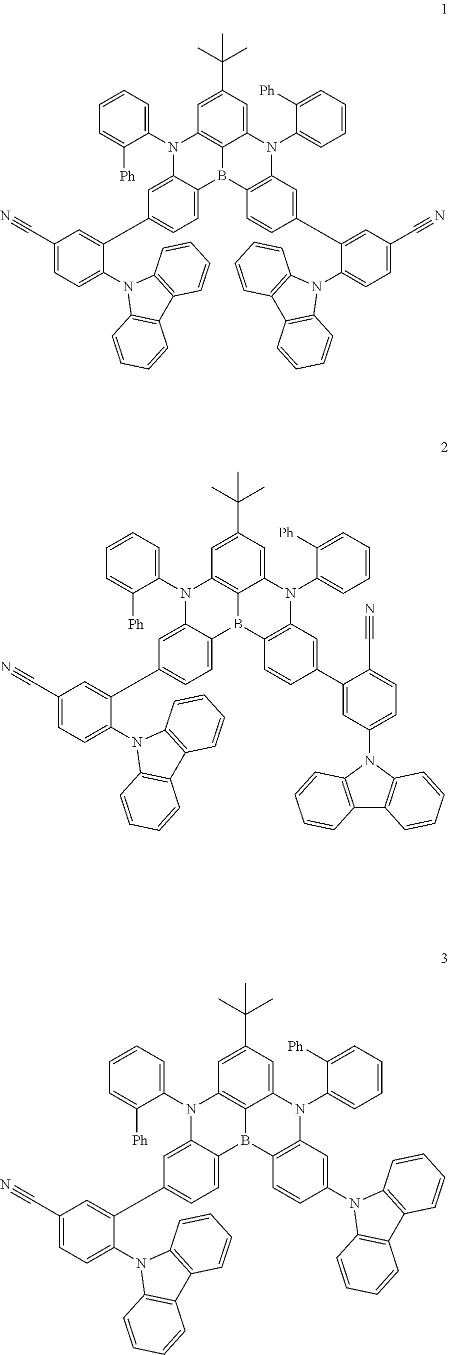 [SMILES: CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1N2c1ccccc1-c1ccccc1 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(-n4c5ccccc5c5ccccc54)ccc3C#N)cc1N2c1ccccc1-c1ccccc1 ; CC(C)(C)c1cc2c3c(c1)N(c1ccccc1-c1ccccc1)c1cc(-n4c5ccccc5c5ccccc54)ccc1B3c1ccc(-c3cc(C#N)ccc3-n3c4ccccc4c4ccccc43)cc1N2c1ccccc1-c1ccccc1] 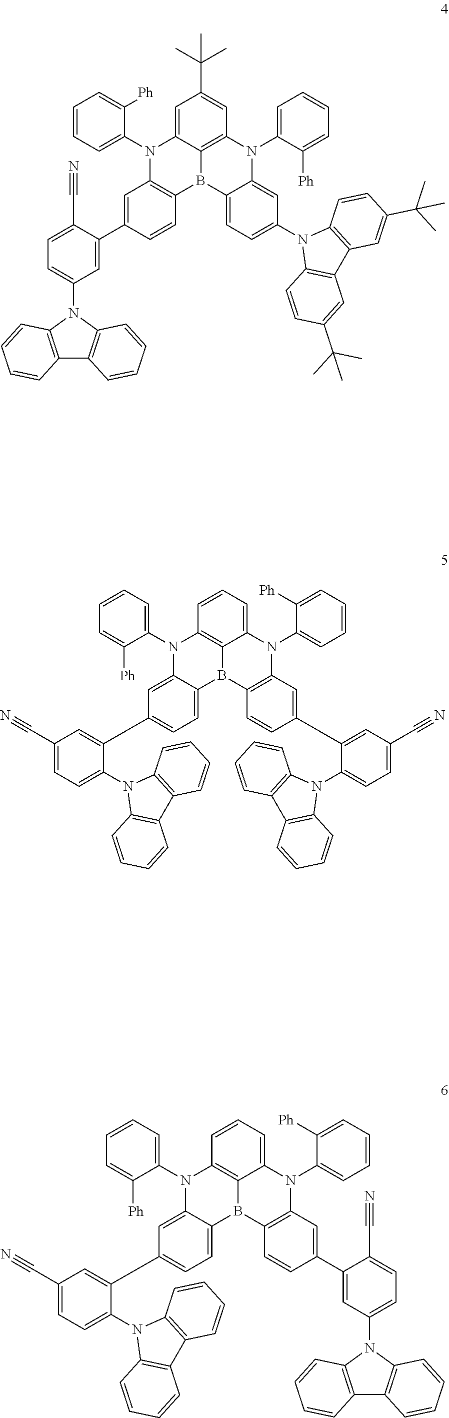 [SMILES: CC(C)(C)c1cc2c3c(c1)N(c1ccccc1-c1ccccc1)c1cc(-n4c5ccc(C(C)(C)C)cc5c5cc(C(C)(C)C)ccc54)ccc1B3c1ccc(-c3cc(-n4c5ccccc5c5ccccc54)ccc3C#N)cc1N2c1ccccc1-c1ccccc1 ; N#Cc1ccc(-n2c3ccccc3c3ccccc32)c(-c2ccc3c(c2)N(c2ccccc2-c2ccccc2)c2cccc4c2B3c2ccc(-c3cc(C#N)ccc3-n3c5ccccc5c5ccccc53)cc2N4c2ccccc2-c2ccccc2)c1 ; N#Cc1ccc(-n2c3ccccc3c3ccccc32)c(-c2ccc3c(c2)N(c2ccccc2-c2ccccc2)c2cccc4c2B3c2ccc(-c3cc(-n5c6ccccc6c6ccccc65)ccc3C#N)cc2N4c2ccccc2-c2ccccc2)c1] 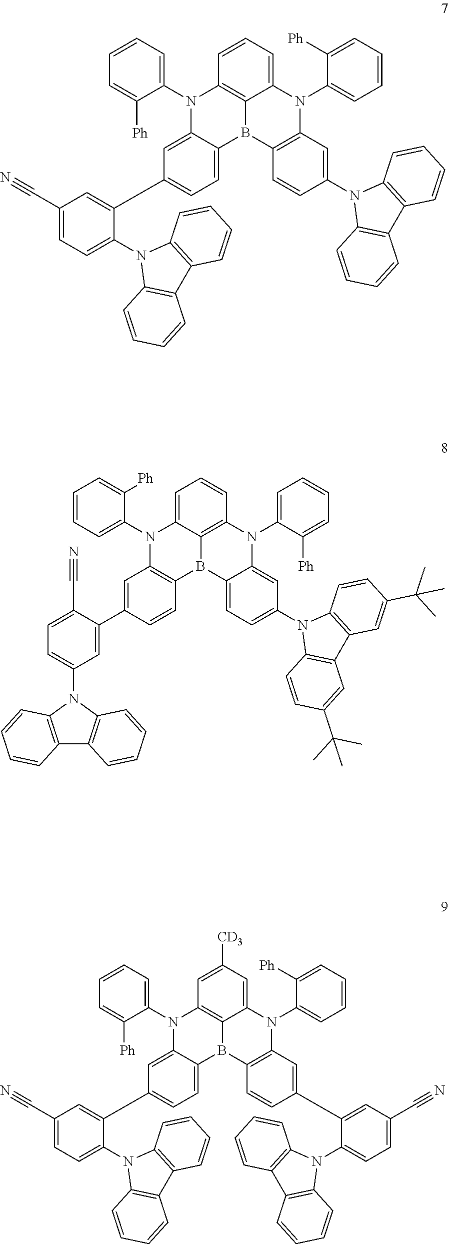 [SMILES: N#Cc1ccc(-n2c3ccccc3c3ccccc32)c(-c2ccc3c(c2)N(c2ccccc2-c2ccccc2)c2cccc4c2B3c2ccc(-n3c5ccccc5c5ccccc53)cc2N4c2ccccc2-c2ccccc2)c1 ; CC(C)(C)c1ccc2c(c1)c1cc(C(C)(C)C)ccc1n2-c1ccc2c(c1)N(c1ccccc1-c1ccccc1)c1cccc3c1B2c1ccc(-c2cc(-n4c5ccccc5c5ccccc54)ccc2C#N)cc1N3c1ccccc1-c1ccccc1 ; [2H]C([2H])([2H])c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1N2c1ccccc1-c1ccccc1] 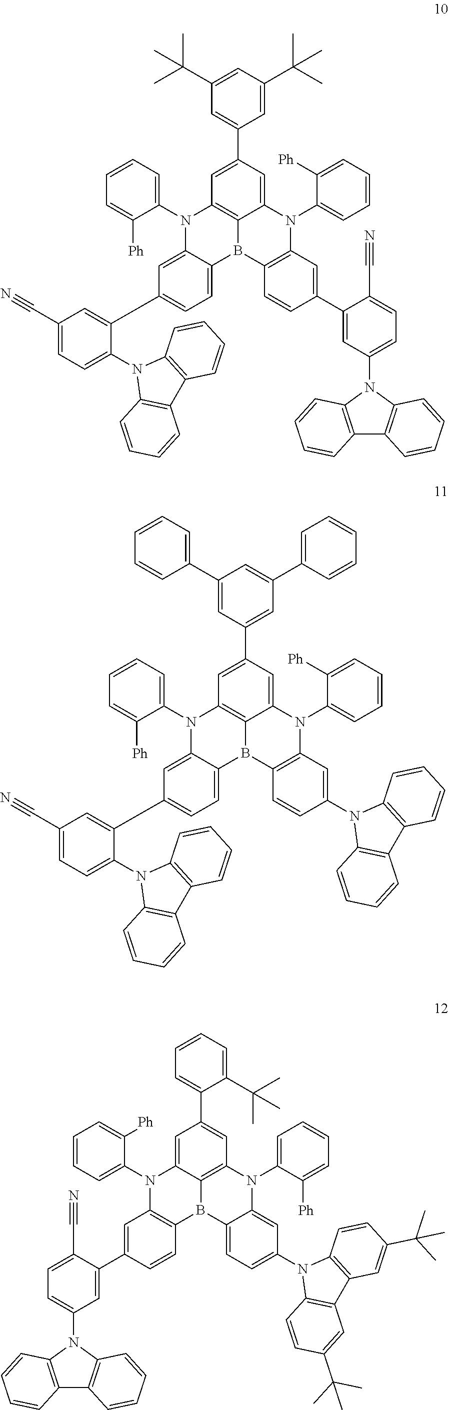 [SMILES: CC(C)(C)c1cc(-c2cc3c4c(c2)N(c2ccccc2-c2ccccc2)c2cc(-c5cc(C#N)ccc5-n5c6ccccc6c6ccccc65)ccc2B4c2ccc(-c4cc(-n5c6ccccc6c6ccccc65)ccc4C#N)cc2N3c2ccccc2-c2ccccc2)cc(C(C)(C)C)c1 ; N#Cc1ccc(-n2c3ccccc3c3ccccc32)c(-c2ccc3c(c2)N(c2ccccc2-c2ccccc2)c2cc(-c4cc(-c5ccccc5)cc(-c5ccccc5)c4)cc4c2B3c2ccc(-n3c5ccccc5c5ccccc53)cc2N4c2ccccc2-c2ccccc2)c1 ; CC(C)(C)c1ccc2c(c1)c1cc(C(C)(C)C)ccc1n2-c1ccc2c(c1)N(c1ccccc1-c1ccccc1)c1cc(-c3ccccc3C(C)(C)C)cc3c1B2c1ccc(-c2cc(-n4c5ccccc5c5ccccc54)ccc2C#N)cc1N3c1ccccc1-c1ccccc1] 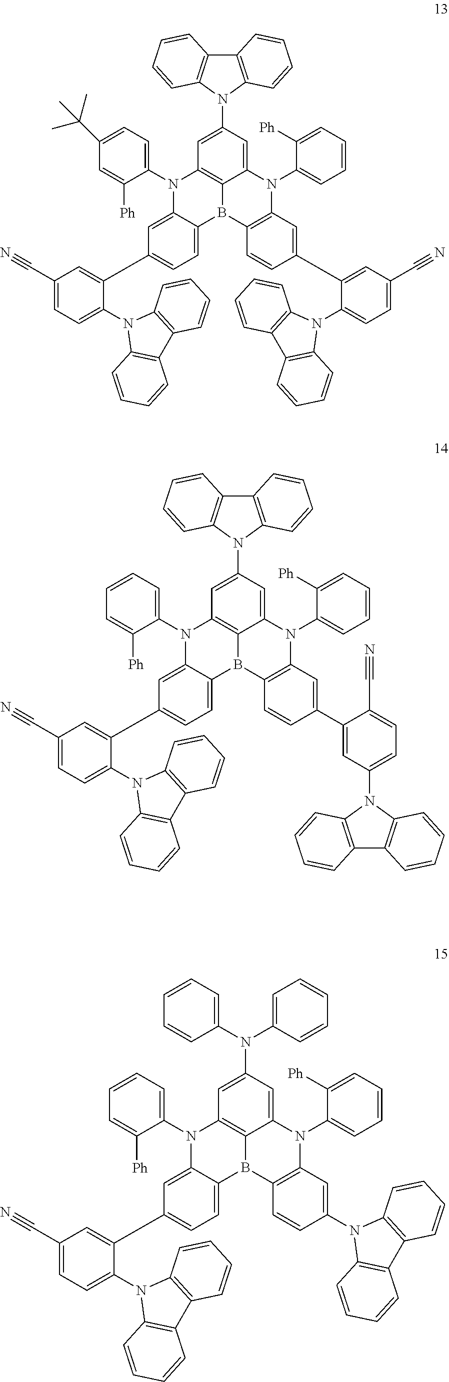 [SMILES: CC(C)(C)c1ccc(N2c3cc(-c4cc(C#N)ccc4-n4c5ccccc5c5ccccc54)ccc3B3c4ccc(-c5cc(C#N)ccc5-n5c6ccccc6c6ccccc65)cc4N(c4ccccc4-c4ccccc4)c4cc(-n5c6ccccc6c6ccccc65)cc2c43)c(-c2ccccc2)c1 ; N#Cc1ccc(-n2c3ccccc3c3ccccc32)c(-c2ccc3c(c2)N(c2ccccc2-c2ccccc2)c2cc(-n4c5ccccc5c5ccccc54)cc4c2B3c2ccc(-c3cc(-n5c6ccccc6c6ccccc65)ccc3C#N)cc2N4c2ccccc2-c2ccccc2)c1 ; N#Cc1ccc(-n2c3ccccc3c3ccccc32)c(-c2ccc3c(c2)N(c2ccccc2-c2ccccc2)c2cc(N(c4ccccc4)c4ccccc4)cc4c2B3c2ccc(-n3c5ccccc5c5ccccc53)cc2N4c2ccccc2-c2ccccc2)c1] 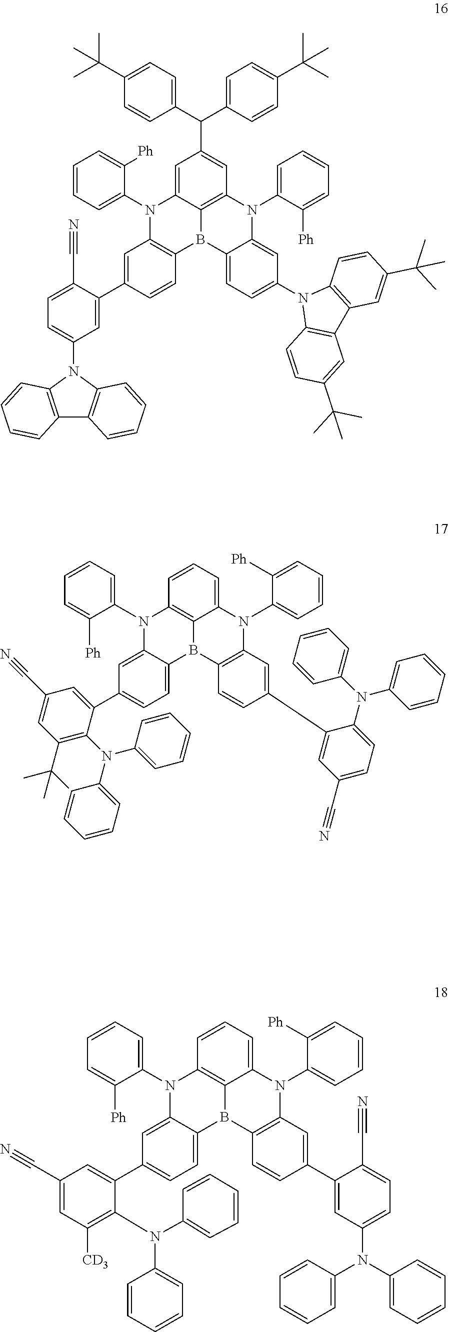 [SMILES: CC(C)(C)c1ccc(C(c2ccc(C(C)(C)C)cc2)c2cc3c4c(c2)N(c2ccccc2-c2ccccc2)c2cc(-n5c6ccc(C(C)(C)C)cc6c6cc(C(C)(C)C)ccc65)ccc2B4c2ccc(-c4cc(-n5c6ccccc6c6ccccc65)ccc4C#N)cc2N3c2ccccc2-c2ccccc2)cc1 ; CC(C)(C)c1cc(C#N)cc(-c2ccc3c(c2)N(c2ccccc2-c2ccccc2)c2cccc4c2B3c2ccc(-c3cc(C#N)ccc3N(c3ccccc3)c3ccccc3)cc2N4c2ccccc2-c2ccccc2)c1N(c1ccccc1)c1ccccc1 ; [2H]C([2H])([2H])c1cc(C#N)cc(-c2ccc3c(c2)N(c2ccccc2-c2ccccc2)c2cccc4c2B3c2ccc(-c3cc(N(c5ccccc5)c5ccccc5)ccc3C#N)cc2N4c2ccccc2-c2ccccc2)c1N(c1ccccc1)c1ccccc1] 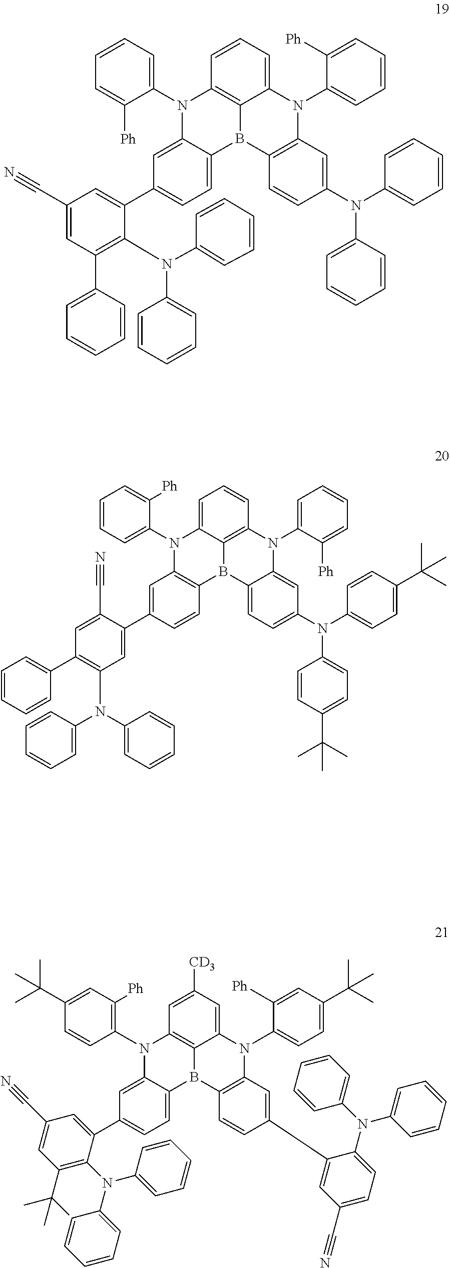 [SMILES: N#Cc1cc(-c2ccccc2)c(N(c2ccccc2)c2ccccc2)c(-c2ccc3c(c2)N(c2ccccc2-c2ccccc2)c2cccc4c2B3c2ccc(N(c3ccccc3)c3ccccc3)cc2N4c2ccccc2-c2ccccc2)c1 ; CC(C)(C)c1ccc(N(c2ccc(C(C)(C)C)cc2)c2ccc3c(c2)N(c2ccccc2-c2ccccc2)c2cccc4c2B3c2ccc(-c3cc(N(c5ccccc5)c5ccccc5)c(-c5ccccc5)cc3C#N)cc2N4c2ccccc2-c2ccccc2)cc1 ; [2H]C([2H])([2H])c1cc2c3c(c1)N(c1ccc(C(C)(C)C)cc1-c1ccccc1)c1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1N2c1ccc(C(C)(C)C)cc1-c1ccccc1] 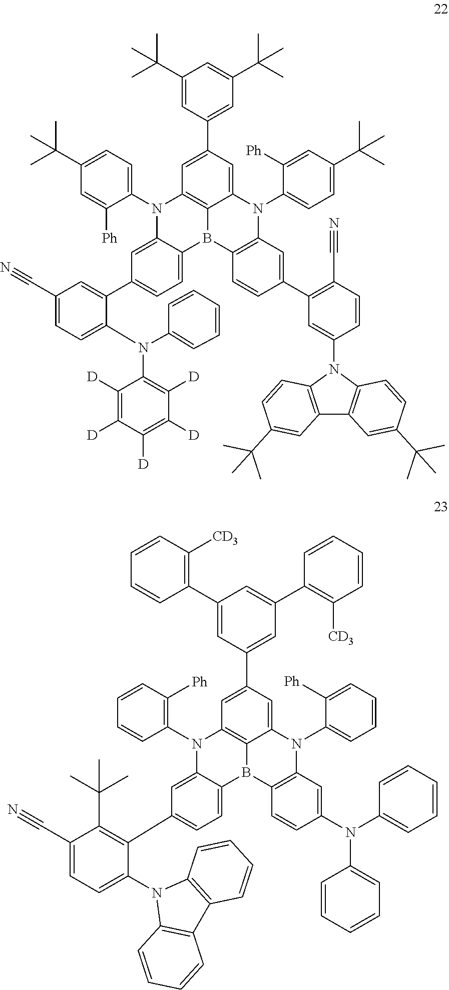 [SMILES: [2H]c1c([2H])c([2H])c(N(c2ccccc2)c2ccc(C#N)cc2-c2ccc3c(c2)N(c2ccc(C(C)(C)C)cc2-c2ccccc2)c2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2N4c2ccc(C(C)(C)C)cc2-c2ccccc2)c([2H])c1[2H] ; [2H]C([2H])([2H])c1ccccc1-c1cc(-c2cc3c4c(c2)N(c2ccccc2-c2ccccc2)c2cc(N(c5ccccc5)c5ccccc5)ccc2B4c2ccc(-c4c(-n5c6ccccc6c6ccccc65)ccc(C#N)c4C(C)(C)C)cc2N3c2ccccc2-c2ccccc2)cc(-c2ccccc2C([2H])([2H])[2H])c1] 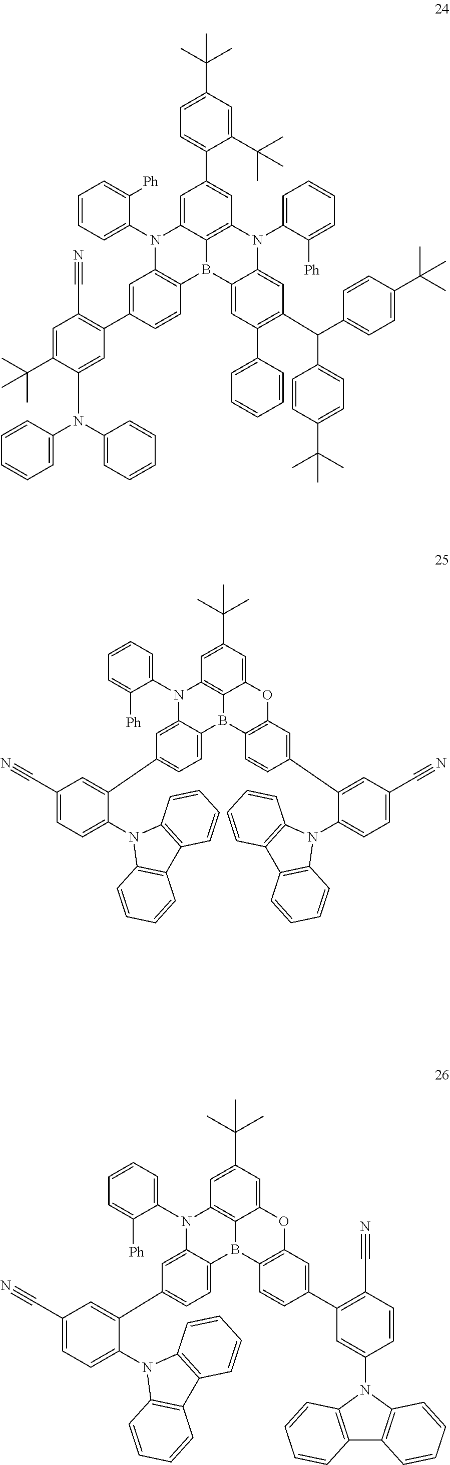 [SMILES: CC(C)(C)c1ccc(C(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4N(c4ccccc4-c4ccccc4)c4cc(-c5ccc(C(C)(C)C)cc5C(C)(C)C)cc(c42)N3c2ccccc2-c2ccccc2)cc1 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(C#N)ccc3-n3c4ccccc4c4ccccc43)cc1O2 ; CC(C)(C)c1cc2c3c(c1)N(c1ccccc1-c1ccccc1)c1cc(-c4cc(C#N)ccc4-n4c5ccccc5c5ccccc54)ccc1B3c1ccc(-c3cc(-n4c5ccccc5c5ccccc54)ccc3C#N)cc1O2] 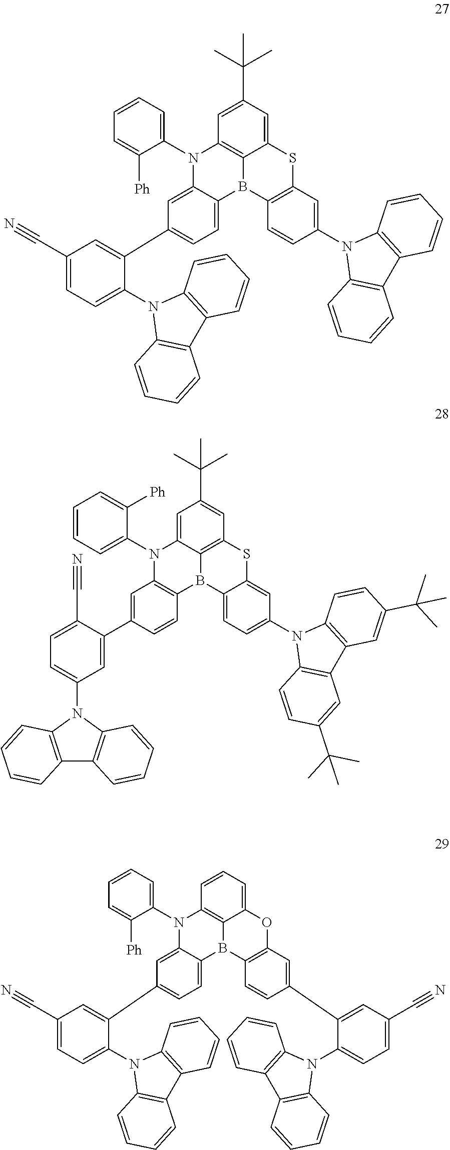 [SMILES: CC(C)(C)c1cc2c3c(c1)N(c1ccccc1-c1ccccc1)c1cc(-c4cc(C#N)ccc4-n4c5ccccc5c5ccccc54)ccc1B3c1ccc(-n3c4ccccc4c4ccccc43)cc1S2 ; CC(C)(C)c1cc2c3c(c1)N(c1ccccc1-c1ccccc1)c1cc(-c4cc(-n5c6ccccc6c6ccccc65)ccc4C#N)ccc1B3c1ccc(-n3c4ccc(C(C)(C)C)cc4c4cc(C(C)(C)C)ccc43)cc1S2 ; N#Cc1ccc(-n2c3ccccc3c3ccccc32)c(-c2ccc3c(c2)Oc2cccc4c2B3c2ccc(-c3cc(C#N)ccc3-n3c5ccccc5c5ccccc53)cc2N4c2ccccc2-c2ccccc2)c1] 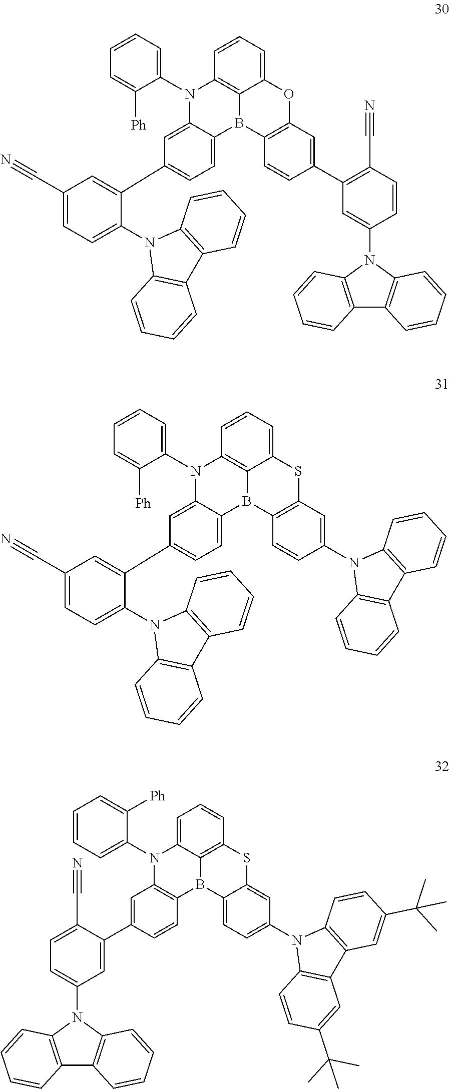 [SMILES: N#Cc1ccc(-n2c3ccccc3c3ccccc32)c(-c2ccc3c(c2)N(c2ccccc2-c2ccccc2)c2cccc4c2B3c2ccc(-c3cc(-n5c6ccccc6c6ccccc65)ccc3C#N)cc2O4)c1 ; N#Cc1ccc(-n2c3ccccc3c3ccccc32)c(-c2ccc3c(c2)N(c2ccccc2-c2ccccc2)c2cccc4c2B3c2ccc(-n3c5ccccc5c5ccccc53)cc2S4)c1 ; CC(C)(C)c1ccc2c(c1)c1cc(C(C)(C)C)ccc1n2-c1ccc2c(c1)Sc1cccc3c1B2c1ccc(-c2cc(-n4c5ccccc5c5ccccc54)ccc2C#N)cc1N3c1ccccc1-c1ccccc1] 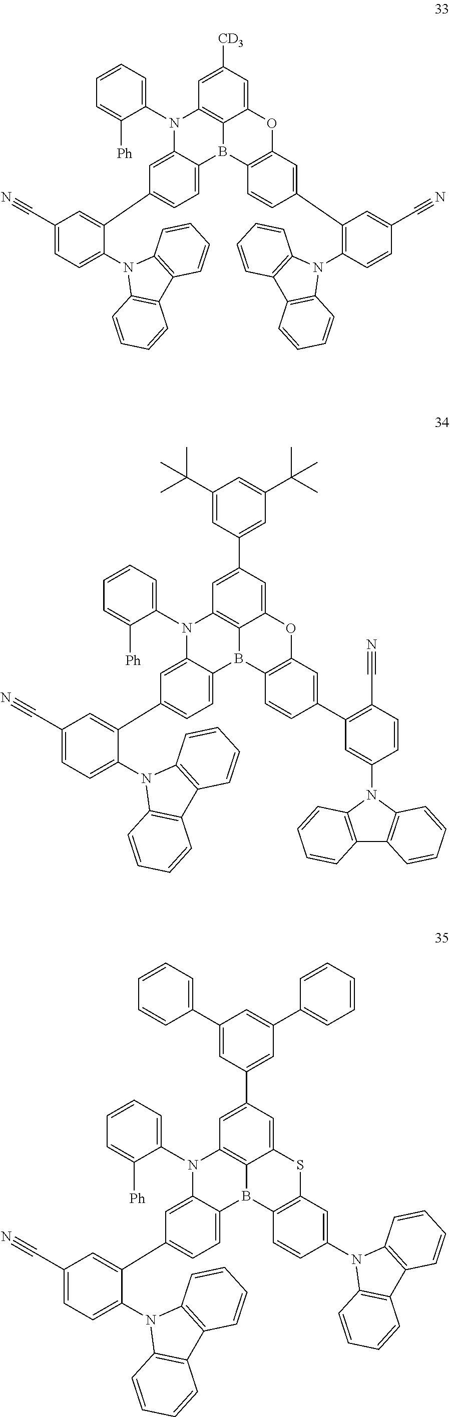 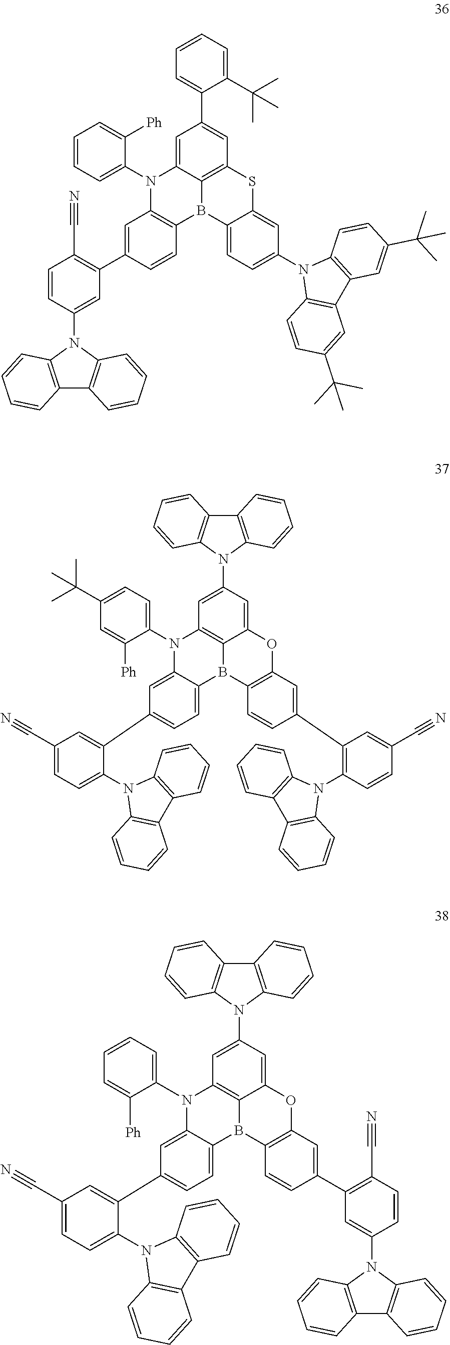 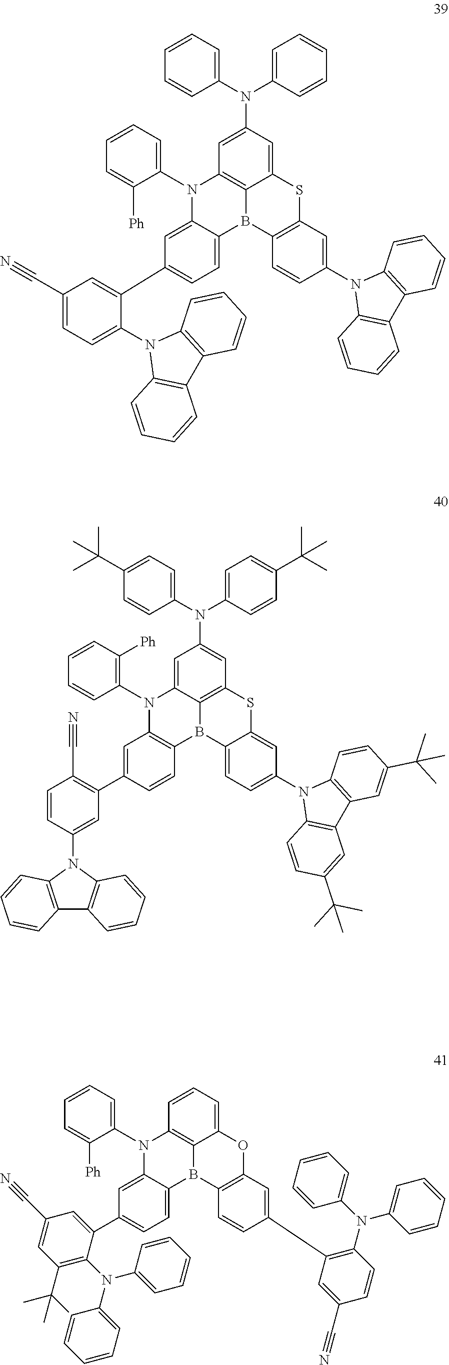 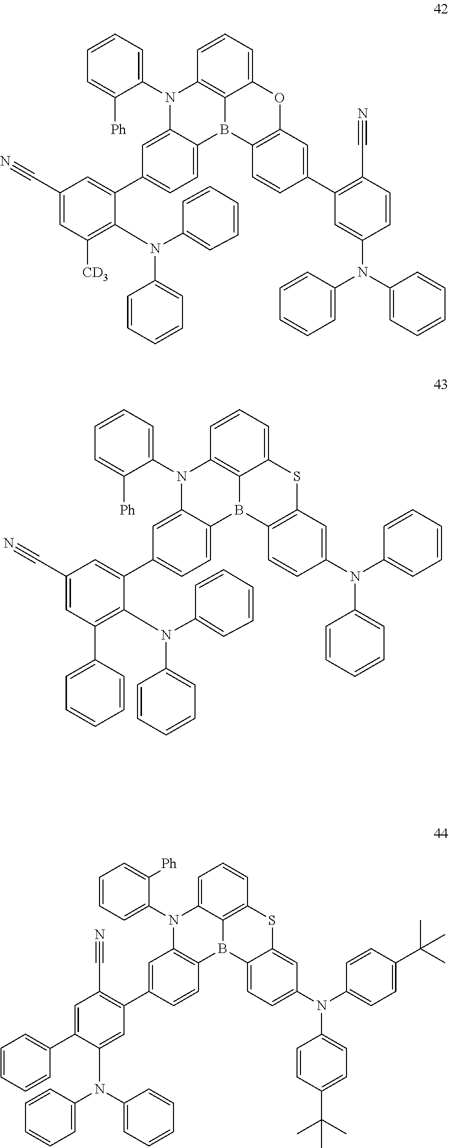 [SMILES: [2H]C([2H])([2H])c1cc(C#N)cc(-c2ccc3c(c2)N(c2ccccc2-c2ccccc2)c2cccc4c2B3c2ccc(-c3cc(N(c5ccccc5)c5ccccc5)ccc3C#N)cc2O4)c1N(c1ccccc1)c1ccccc1 ; N#Cc1cc(-c2ccccc2)c(N(c2ccccc2)c2ccccc2)c(-c2ccc3c(c2)N(c2ccccc2-c2ccccc2)c2cccc4c2B3c2ccc(N(c3ccccc3)c3ccccc3)cc2S4)c1 ; CC(C)(C)c1ccc(N(c2ccc(C(C)(C)C)cc2)c2ccc3c(c2)Sc2cccc4c2B3c2ccc(-c3cc(N(c5ccccc5)c5ccccc5)c(-c5ccccc5)cc3C#N)cc2N4c2ccccc2-c2ccccc2)cc1] 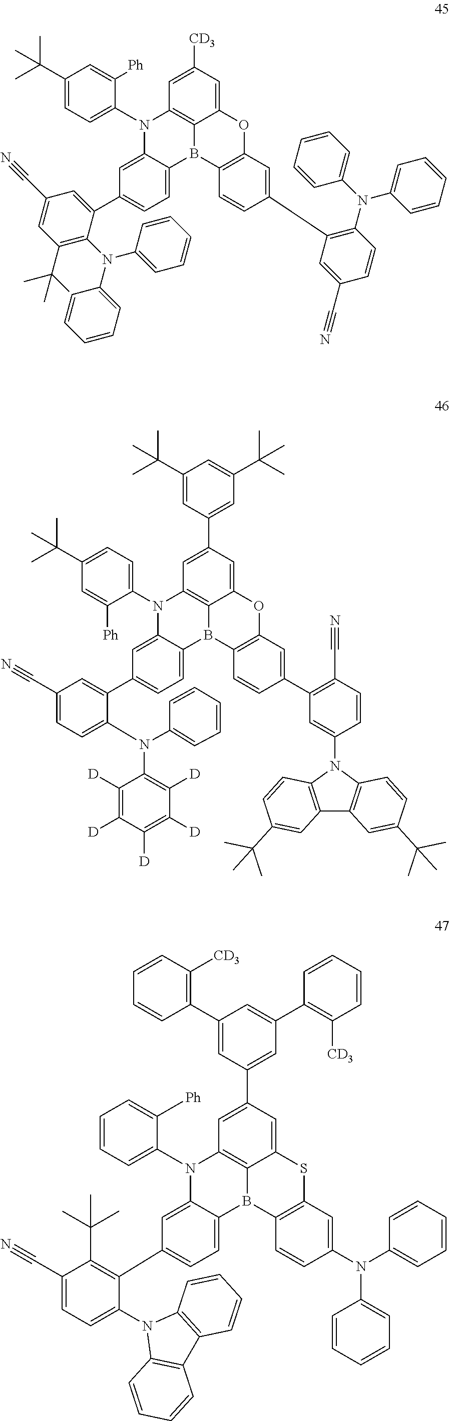 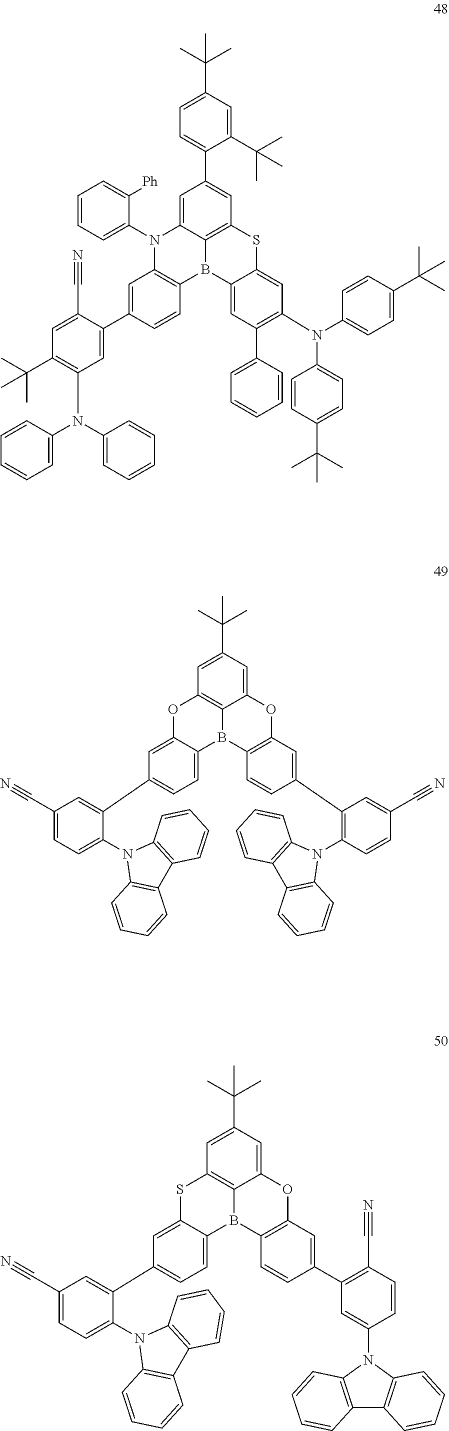 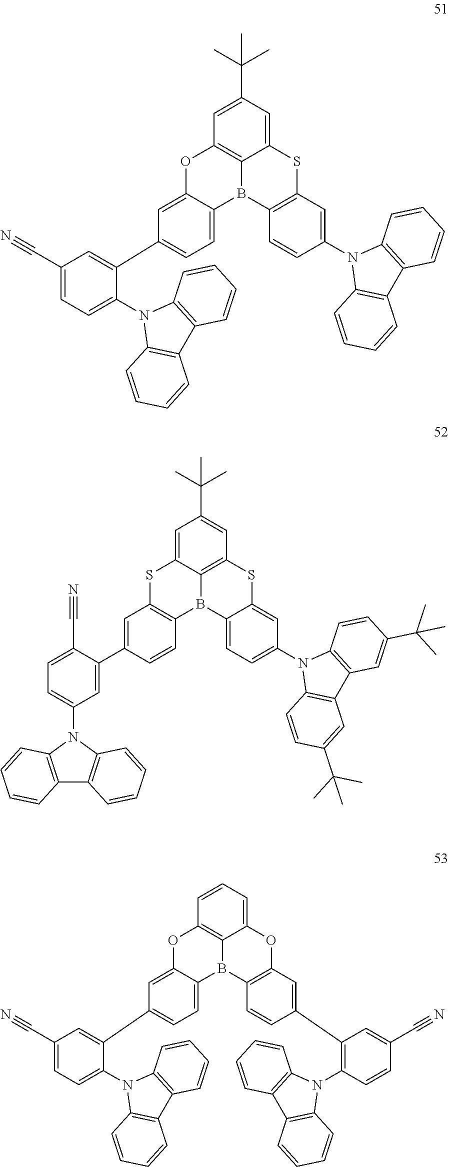 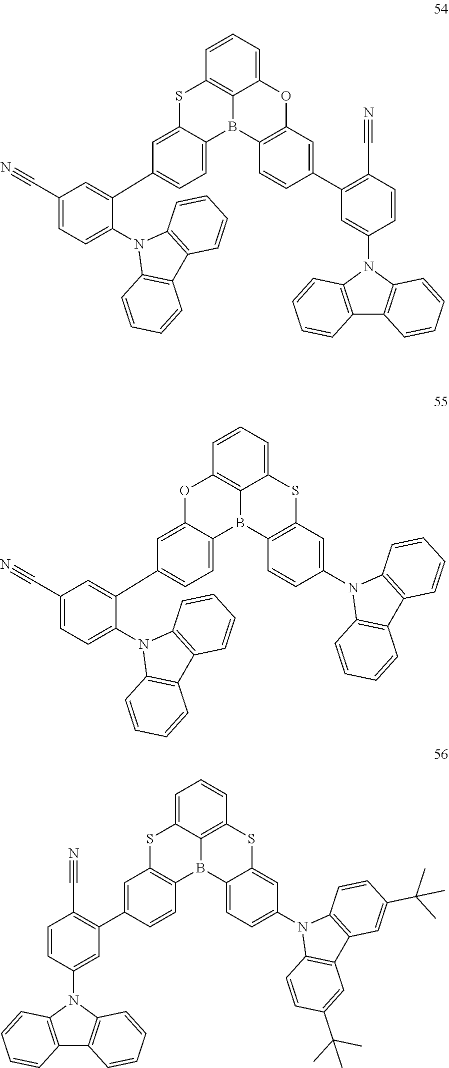 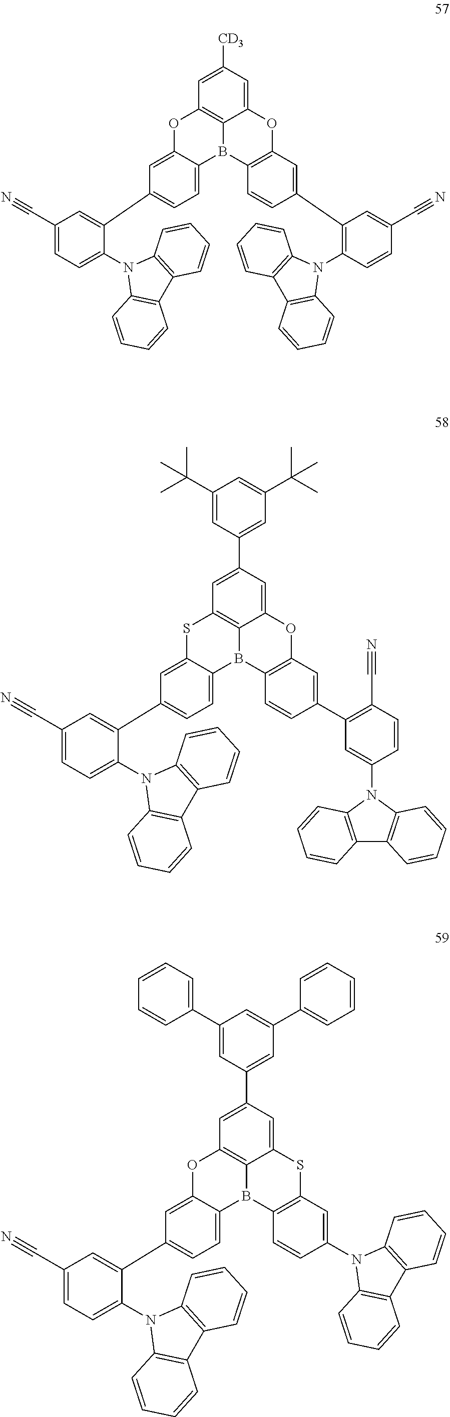 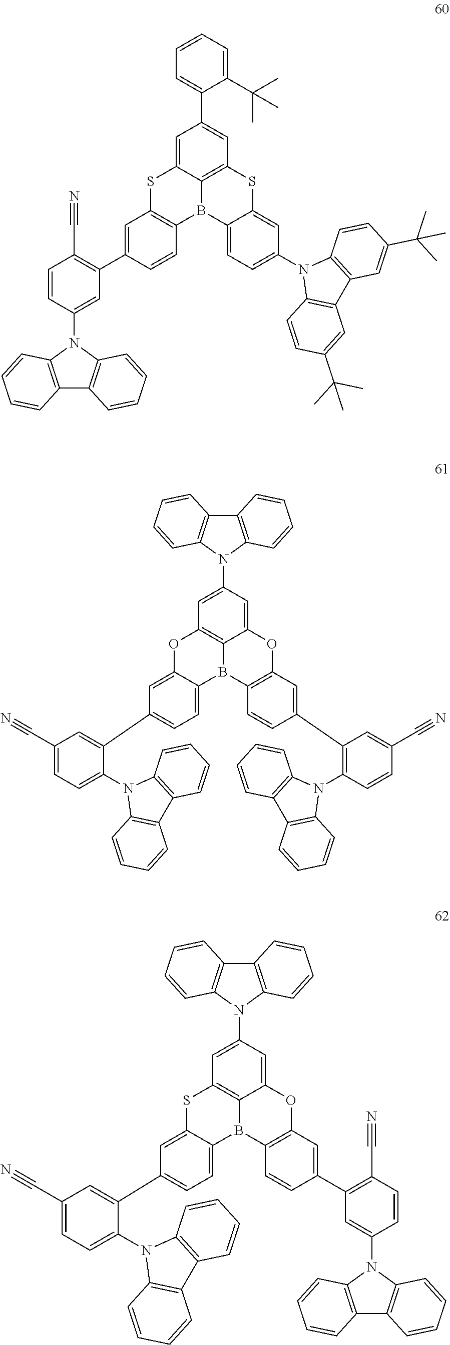 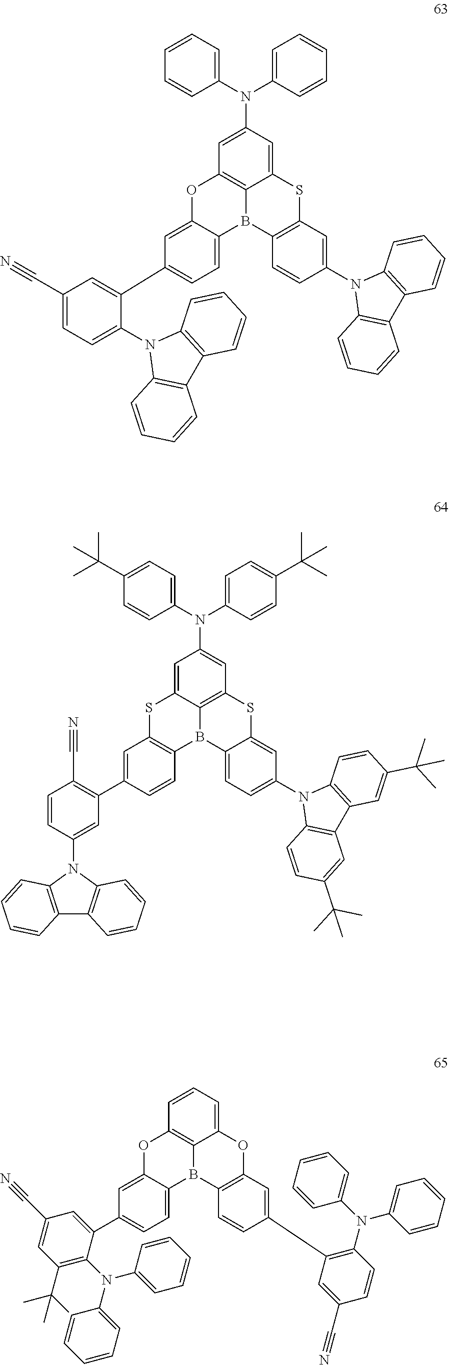 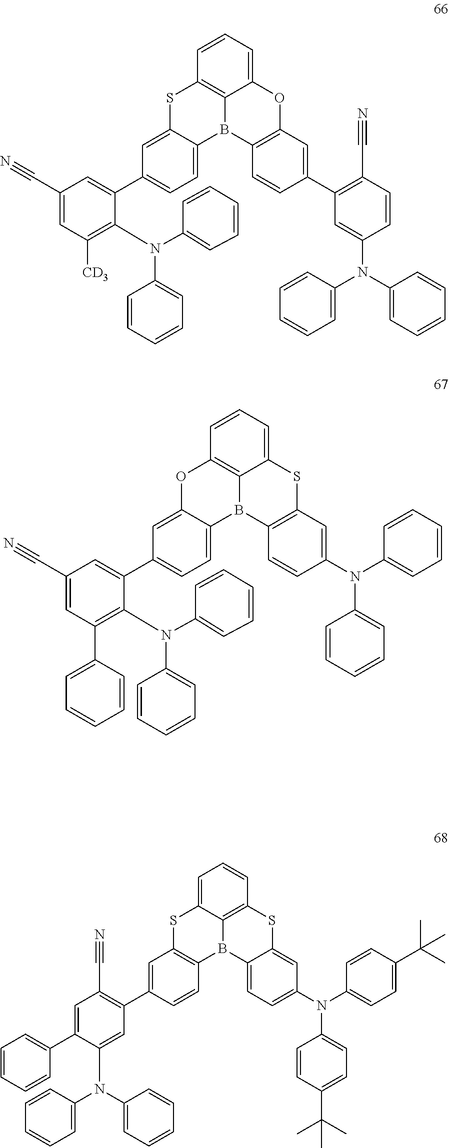 [SMILES: [2H]C([2H])([2H])c1cc(C#N)cc(-c2ccc3c(c2)Sc2cccc4c2B3c2ccc(-c3cc(N(c5ccccc5)c5ccccc5)ccc3C#N)cc2O4)c1N(c1ccccc1)c1ccccc1 ; N#Cc1cc(-c2ccccc2)c(N(c2ccccc2)c2ccccc2)c(-c2ccc3c(c2)Oc2cccc4c2B3c2ccc(N(c3ccccc3)c3ccccc3)cc2S4)c1 ; CC(C)(C)c1ccc(N(c2ccc(C(C)(C)C)cc2)c2ccc3c(c2)Sc2cccc4c2B3c2ccc(-c3cc(N(c5ccccc5)c5ccccc5)c(-c5ccccc5)cc3C#N)cc2S4)cc1] 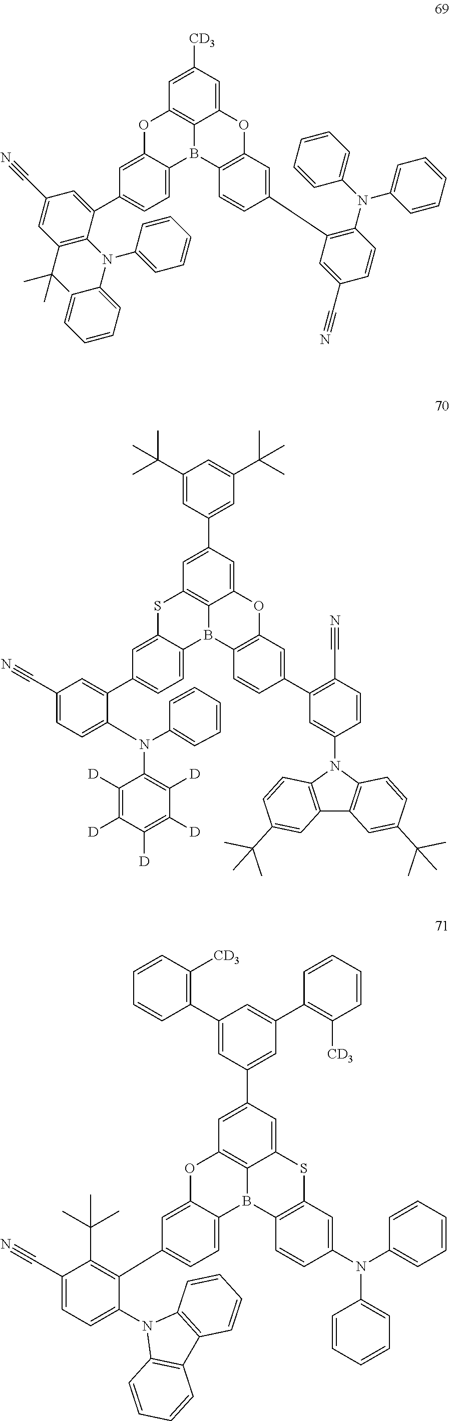 [SMILES: [2H]C([2H])([2H])c1cc2c3c(c1)Oc1cc(-c4cc(C#N)cc(C(C)(C)C)c4N(c4ccccc4)c4ccccc4)ccc1B3c1ccc(-c3cc(C#N)ccc3N(c3ccccc3)c3ccccc3)cc1O2 ; [2H]c1c([2H])c([2H])c(N(c2ccccc2)c2ccc(C#N)cc2-c2ccc3c(c2)Sc2cc(-c4cc(C(C)(C)C)cc(C(C)(C)C)c4)cc4c2B3c2ccc(-c3cc(-n5c6ccc(C(C)(C)C)cc6c6cc(C(C)(C)C)ccc65)ccc3C#N)cc2O4)c([2H])c1[2H] ; [2H]C([2H])([2H])c1ccccc1-c1cc(-c2cc3c4c(c2)Sc2cc(N(c5ccccc5)c5ccccc5)ccc2B4c2ccc(-c4c(-n5c6ccccc6c6ccccc65)ccc(C#N)c4C(C)(C)C)cc2O3)cc(-c2ccccc2C([2H])([2H])[2H])c1] 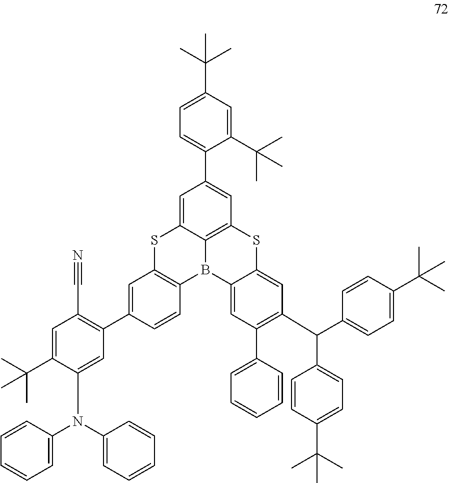 [SMILES: CC(C)(C)c1ccc(C(c2ccc(C(C)(C)C)cc2)c2cc3c(cc2-c2ccccc2)B2c4ccc(-c5cc(N(c6ccccc6)c6ccccc6)c(C(C)(C)C)cc5C#N)cc4Sc4cc(-c5ccc(C(C)(C)C)cc5C(C)(C)C)cc(c42)S3)cc1] 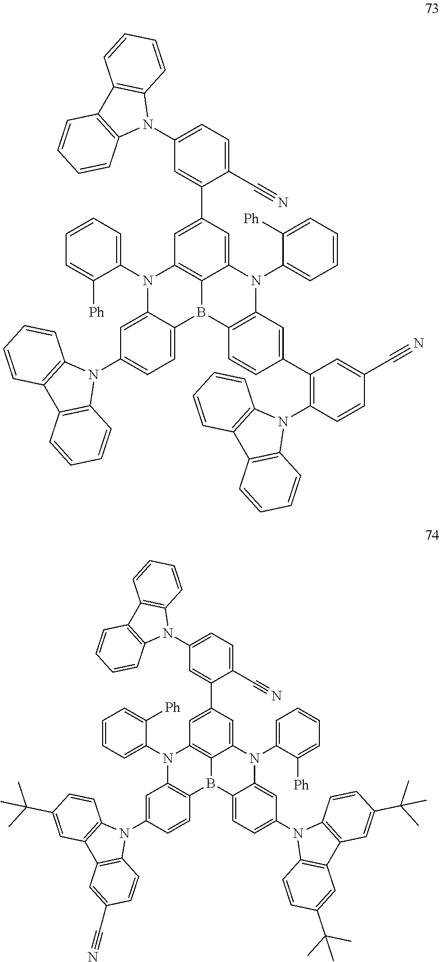 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 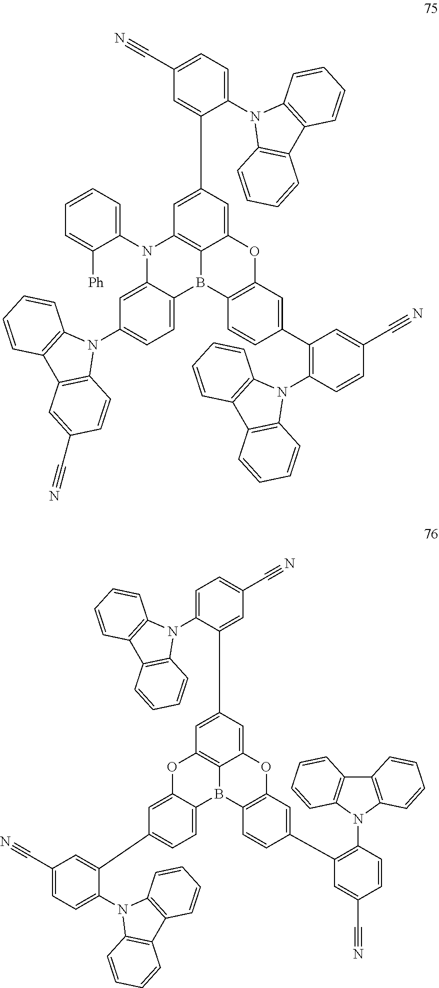 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 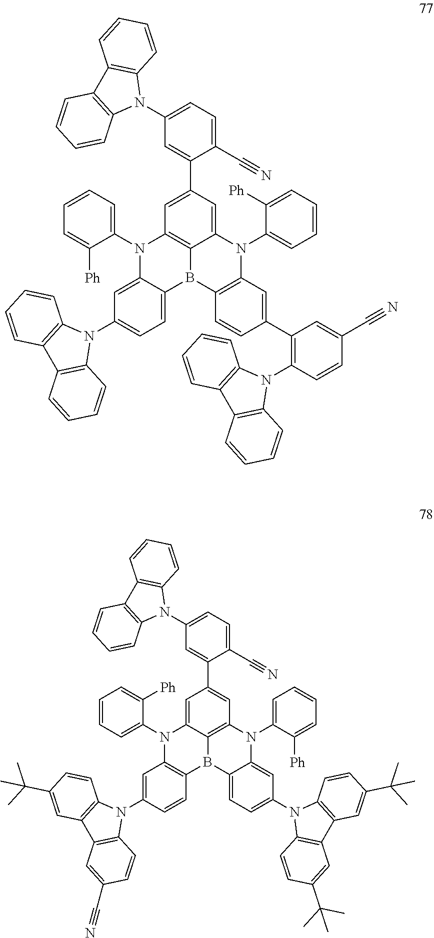 [SMILES: N#Cc1ccc(-n2c3ccccc3c3ccccc32)c(-c2ccc3c(c2)N(c2ccccc2-c2ccccc2)c2cc(-c4cc(-n5c6ccccc6c6ccccc65)ccc4C#N)cc4c2B3c2ccc(-n3c5ccccc5c5ccccc53)cc2N4c2ccccc2-c2ccccc2)c1 ; CC(C)(C)c1ccc2c(c1)c1cc(C#N)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 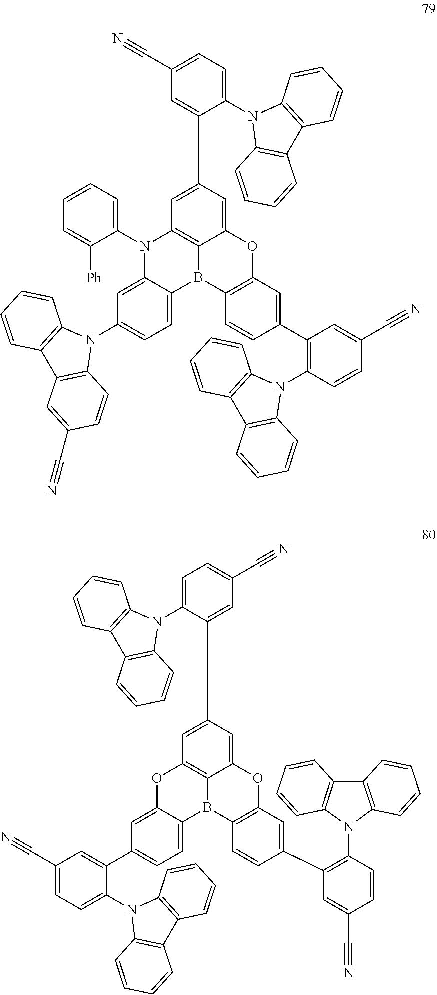 [SMILES: N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-n3c5ccccc5c5cc(C#N)ccc53)cc2N4c2ccccc2-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 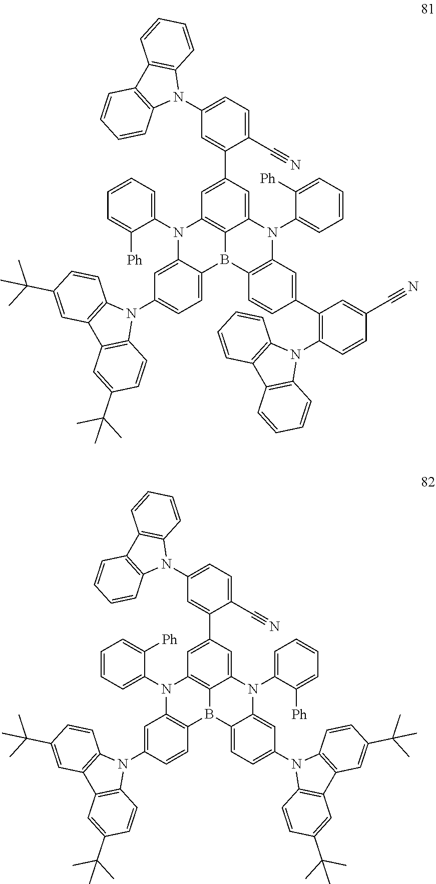 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2-n2c4ccccc4c4ccccc42)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 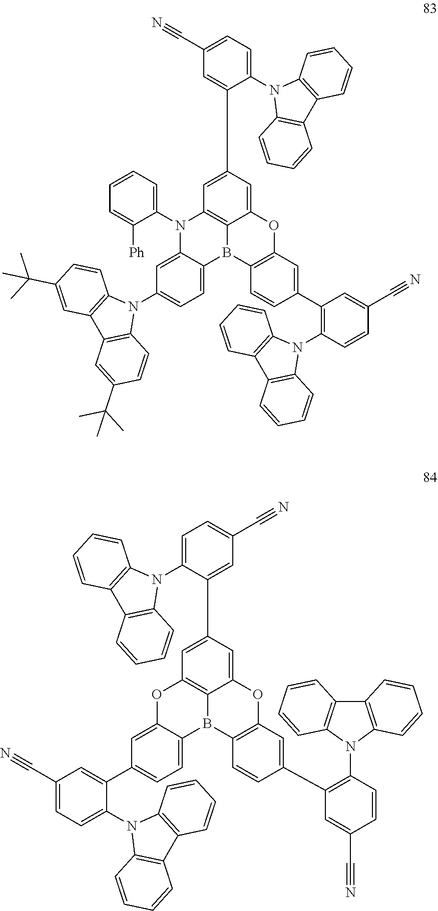 [SMILES: CC(C)(C)c1ccc2c(c1)c1cc(C(C)(C)C)ccc1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2-n2c4ccccc4c4ccccc42)cc1O3 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 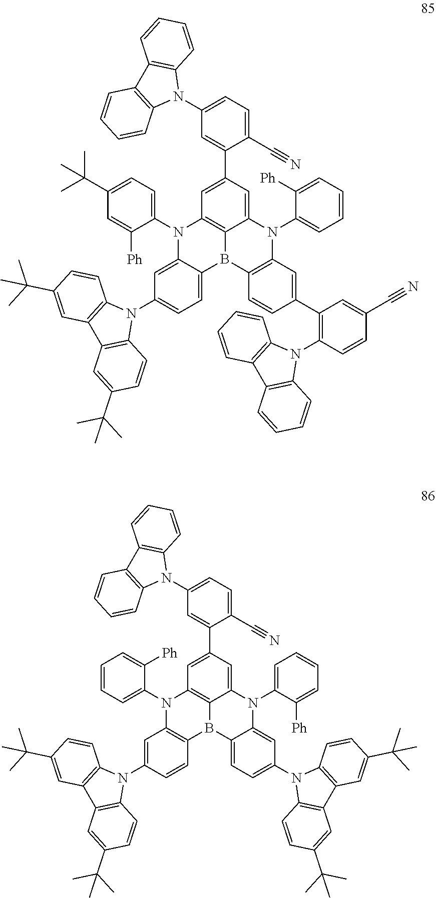 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4N(c4ccccc4-c4ccccc4)c4cc(-c5cc(-n6c7ccccc7c7ccccc76)ccc5C#N)cc2c43)c(-c2ccccc2)c1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 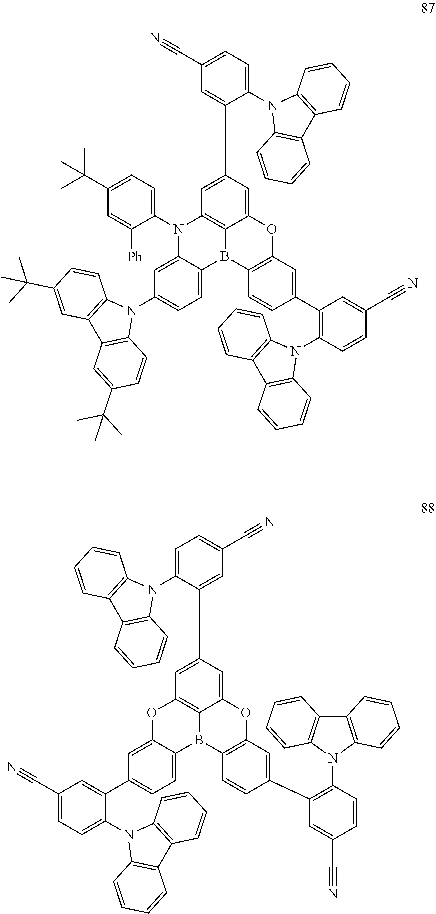 [SMILES: CC(C)(C)c1ccc(N2c3cc(-n4c5ccc(C(C)(C)C)cc5c5cc(C(C)(C)C)ccc54)ccc3B3c4ccc(-c5cc(C#N)ccc5-n5c6ccccc6c6ccccc65)cc4Oc4cc(-c5cc(C#N)ccc5-n5c6ccccc6c6ccccc65)cc2c43)c(-c2ccccc2)c1 ; N#Cc1ccc(-n2c3ccccc3c3ccccc32)c(-c2ccc3c(c2)Oc2cc(-c4cc(C#N)ccc4-n4c5ccccc5c5ccccc54)cc4c2B3c2ccc(-c3cc(C#N)ccc3-n3c5ccccc5c5ccccc53)cc2O4)c1] 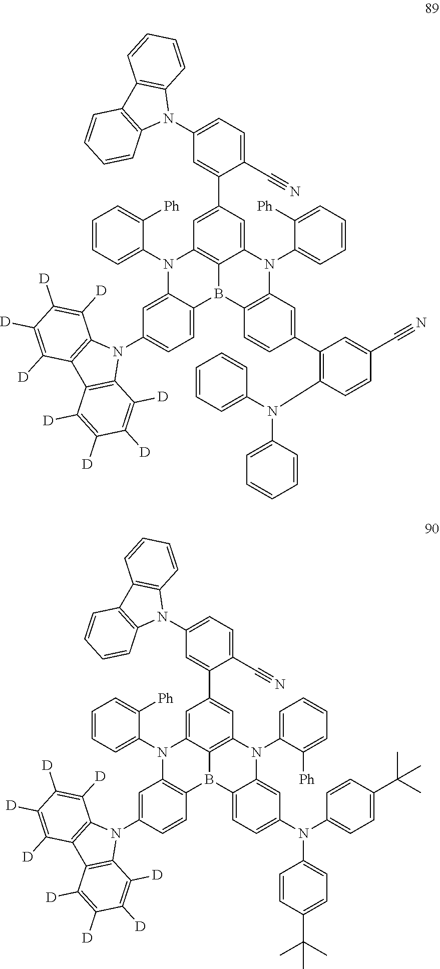 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccccc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1ccc(N(c2ccc(C(C)(C)C)cc2)c2ccc(C(C)(C)C)cc2)cc1N3c1ccccc1-c1ccccc1] 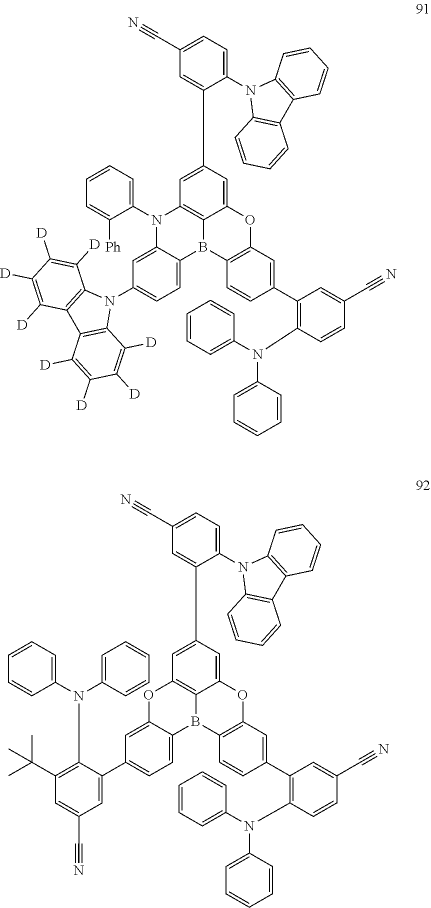 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1] 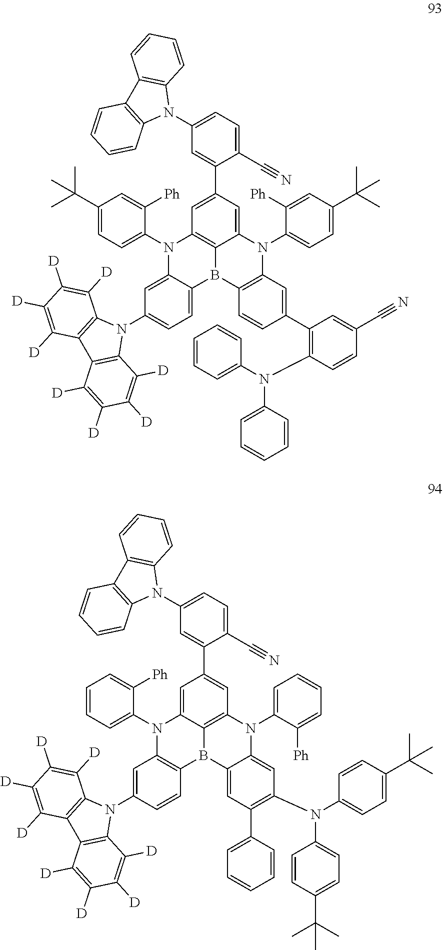 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(-n4c5ccccc5c5ccccc54)ccc3C#N)cc3c1B2c1ccc(-c2cc(C#N)ccc2N(c2ccccc2)c2ccccc2)cc1N3c1ccc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3cc(-n4c5ccccc5c5ccccc54)ccc3C#N)cc3c1B2c1cc(-c2ccccc2)c(N(c2ccc(C(C)(C)C)cc2)c2ccc(C(C)(C)C)cc2)cc1N3c1ccccc1-c1ccccc1] 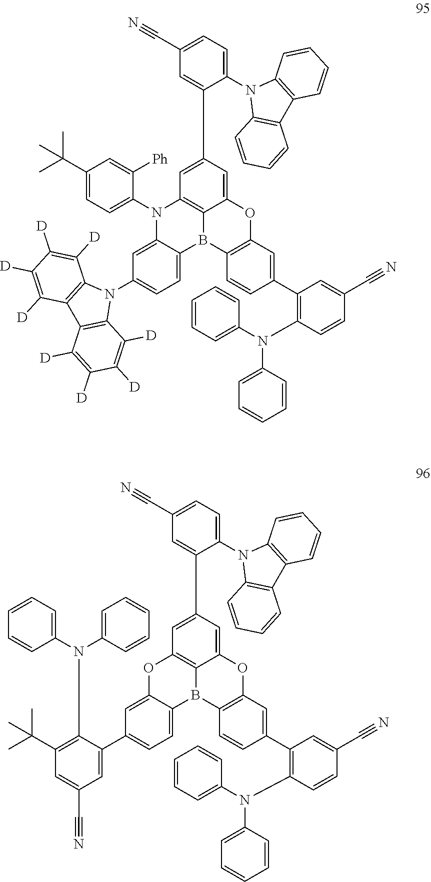 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1ccccc1)c1cc(-c3cc(C#N)ccc3-n3c4ccccc4c4ccccc43)cc3c1B2c1ccc(-c2cc(C#N)ccc2N(c2ccccc2)c2ccccc2)cc1O3 ; CC(C)(C)c1cc(C#N)cc(-c2ccc3c(c2)Oc2cc(-c4cc(C#N)ccc4-n4c5ccccc5c5ccccc54)cc4c2B3c2ccc(-c3cc(C#N)ccc3N(c3ccccc3)c3ccccc3)cc2O4)c1N(c1ccccc1)c1ccccc1] 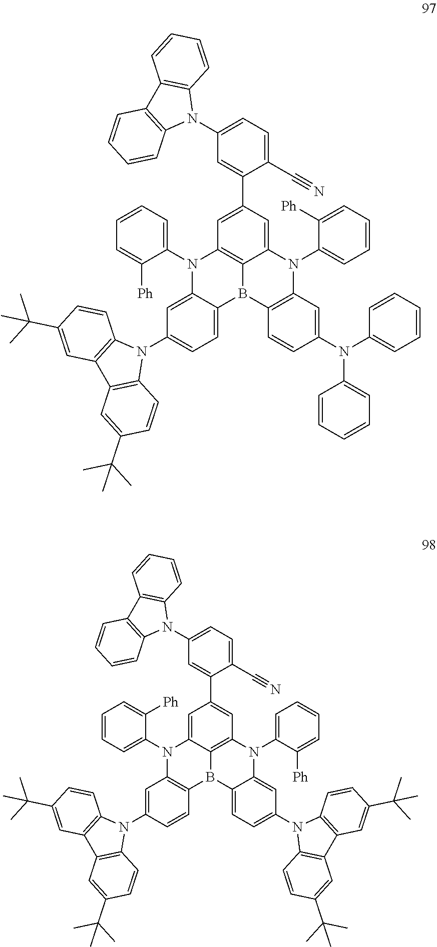 [SMILES: CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(N(c2ccccc2)c2ccccc2)cc1N3c1ccccc1-c1ccccc1 ; CC(C)(C)c1ccc2c(c1)c1cc(C(C)(C)C)ccc1n2-c1ccc2c(c1)N(c1ccccc1-c1ccccc1)c1cc(-c3cc(-n4c5ccccc5c5ccccc54)ccc3C#N)cc3c1B2c1ccc(-n2c4ccc(C(C)(C)C)cc4c4cc(C(C)(C)C)ccc42)cc1N3c1ccccc1-c1ccccc1] 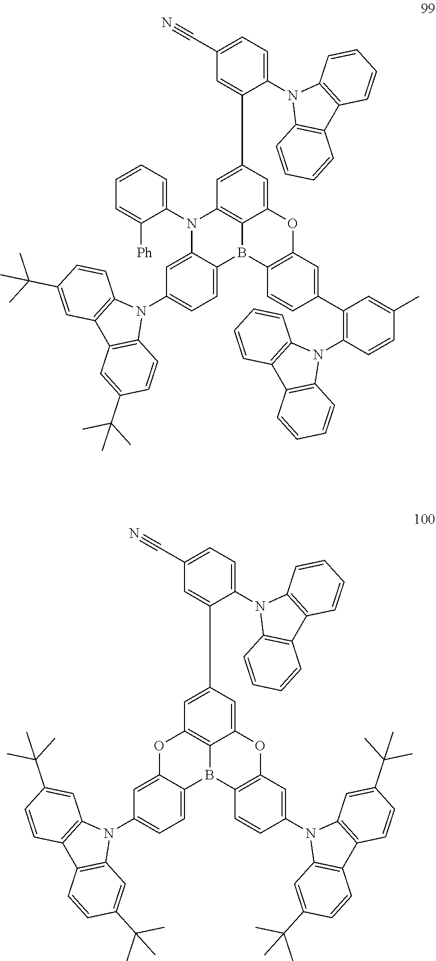 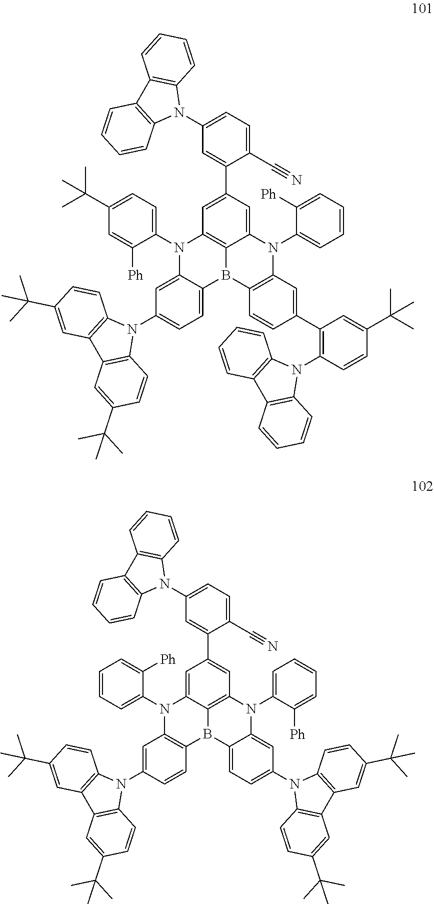 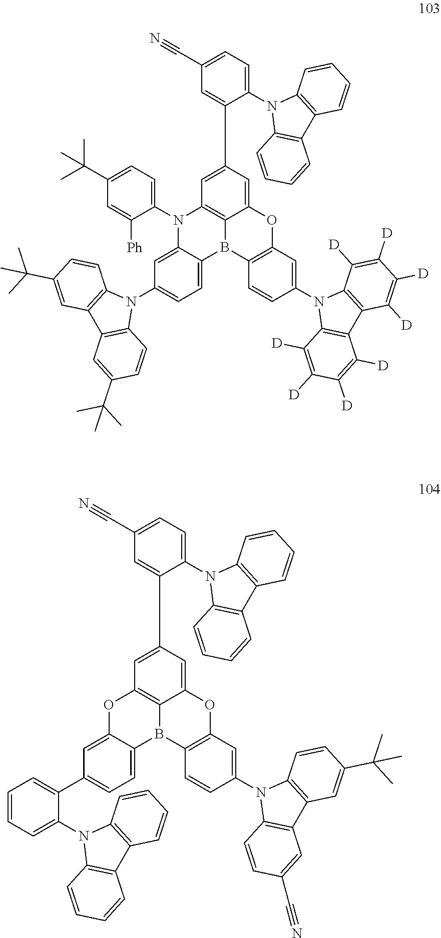 [SMILES: [2H]c1c([2H])c([2H])c2c(c1[2H])c1c([2H])c([2H])c([2H])c([2H])c1n2-c1ccc2c(c1)Oc1cc(-c3cc(C#N)ccc3-n3c4ccccc4c4ccccc43)cc3c1B2c1ccc(-n2c4ccc(C(C)(C)C)cc4c4cc(C(C)(C)C)ccc42)cc1N3c1ccc(C(C)(C)C)cc1-c1ccccc1 ; CC(C)(C)c1ccc2c(c1)c1cc(C#N)ccc1n2-c1ccc2c(c1)Oc1cc(-c3cc(C#N)ccc3-n3c4ccccc4c4ccccc43)cc3c1B2c1ccc(-c2ccccc2-n2c4ccccc4c4ccccc42)cc1O3] 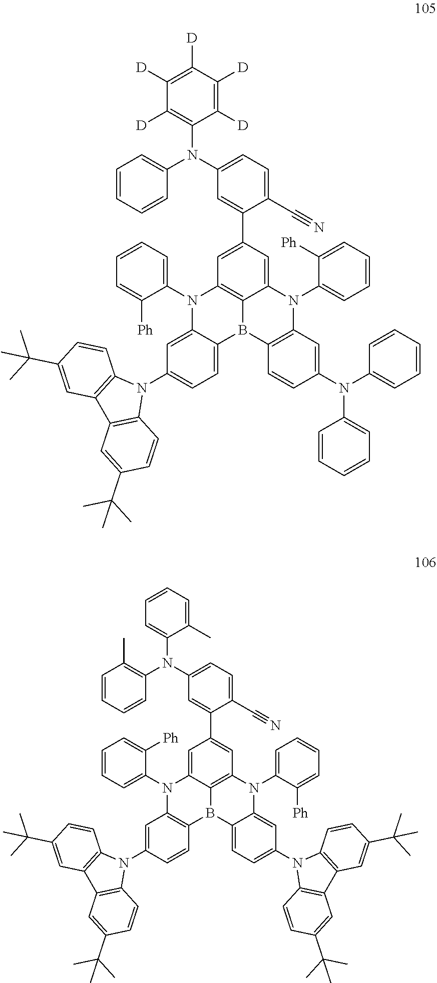 [SMILES: [2H]c1c([2H])c([2H])c(N(c2ccccc2)c2ccc(C#N)c(-c3cc4c5c(c3)N(c3ccccc3-c3ccccc3)c3cc(-n6c7ccc(C(C)(C)C)cc7c7cc(C(C)(C)C)ccc76)ccc3B5c3ccc(N(c5ccccc5)c5ccccc5)cc3N4c3ccccc3-c3ccccc3)c2)c([2H])c1[2H] ; Cc1ccccc1N(c1ccc(C#N)c(-c2cc3c4c(c2)N(c2ccccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccccc2-c2ccccc2)c1)c1ccccc1C] 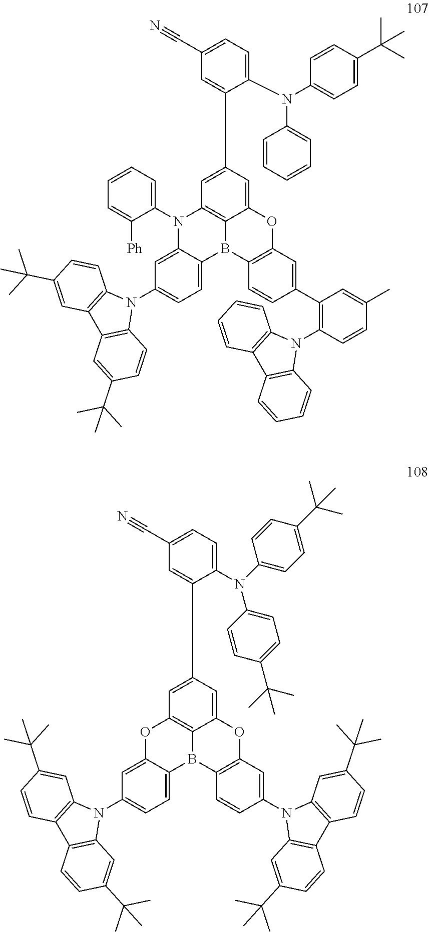 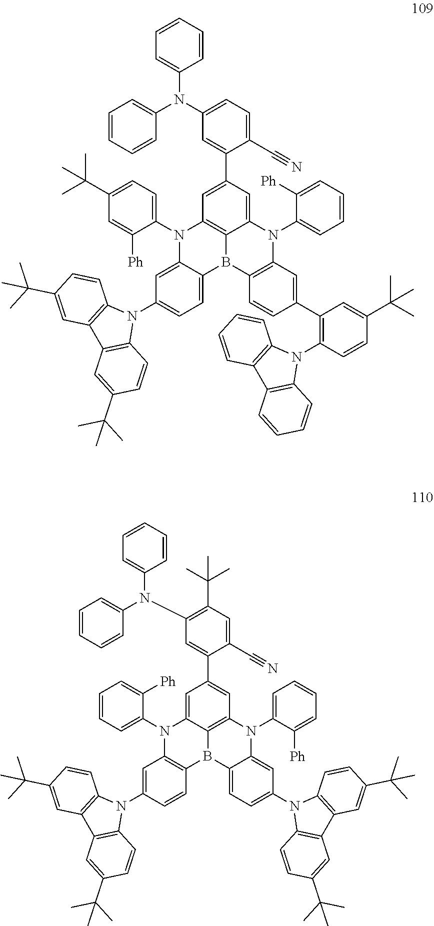 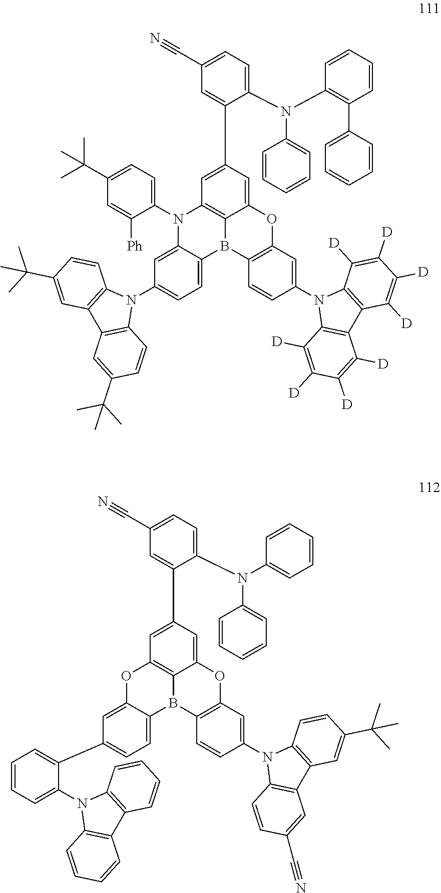 [SMILES: [2H]c1c([2H])c([2H])c2c(c1[2H])c1c([2H])c([2H])c([2H])c([2H])c1n2-c1ccc2c(c1)Oc1cc(-c3cc(C#N)ccc3N(c3ccccc3)c3ccccc3-c3ccccc3)cc3c1B2c1ccc(-n2c4ccc(C(C)(C)C)cc4c4cc(C(C)(C)C)ccc42)cc1N3c1ccc(C(C)(C)C)cc1-c1ccccc1 ; CC(C)(C)c1ccc2c(c1)c1cc(C#N)ccc1n2-c1ccc2c(c1)Oc1cc(-c3cc(C#N)ccc3N(c3ccccc3)c3ccccc3)cc3c1B2c1ccc(-c2ccccc2-n2c4ccccc4c4ccccc42)cc1O3]
wherein in Compound Group 1, D is a deuterium atom, and Ph is a phenyl group.
